(19) United States
(12) Patent Application Publication
(10) Pub. No.: US 2023/0371376 A1
(43) Pub. Date: Nov. 16, 2023

(54) POLYCYCLIC COMPOUND AND ORGANIC LIGHT-EMITTING DEVICE USING SAME

(71) Applicant: SFC CO., LTD., Chungcheongbuk-do (KR)

(72) Inventors: Sung-hoon JOO, Chungcheongbuk-do (KR); Bong-ki SHIN, Chungcheongbuk-do (KR); Byung-sun YANG, Chungcheongbuk-do (KR); Ji-hwan KIM, Chungcheongbuk-do (KR); Hyeon-jun JO, Chungcheongbuk-do (KR); Sung-eun CHOI, Chungcheongbuk-do (KR); Seong-eun WOO, Chungcheongbuk-do (KR); Dong-myung PARK, Chungcheongbuk-do (KR); Jun-young MOON, Chungcheongbuk-do (KR); Soo-kyung KANG, Chungcheongbuk-do (KR)

(21) Appl. No.: 18/029,953

(22) PCT Filed: Oct. 19, 2021
(86) PCT No.: PCT/KR2021/014583

§ 371 Date: Apr. 3, 2023

(30) Foreign Application Priority Data
Oct. 19, 2020 (KR) 10-2020-0135042
Jun. 11, 2021 (KR) 10-2021-0075801

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

The present invention relates to: a polycyclic compound that can be employed in various organic layers provided in an organic light-emitting device; and a high-efficiency and long-lifespan organic light-emitting device comprising same to have significantly improved luminous efficiency and lifespan characteristics. By using same, the present invention can be industrially and effectively used in lighting devices and various display devices, such as a flat-panel display apparatus, a flexible display apparatus, a monochrome or white flat-panel lighting apparatus, a monochrome or white flexible lighting apparatus, a vehicle display apparatus, and a virtual or augmented reality display apparatus.

### TECHNICAL FIELD

The present invention relates to a polycyclic compound and a highly efficient and long-lasting organic electroluminescent device with significantly improved life characteristics and luminous efficiency using the polycyclic compound.

### BACKGROUND

Organic electroluminescent devices are self-luminous devices in which electrons injected from an electron injecting electrode (cathode) recombine with holes injected from a hole injecting electrode (anode) in a light emitting layer to form excitons, which emit light while releasing energy. Such organic electroluminescent devices have the advantages of low driving voltage, high luminance, large viewing angle, and short response time and can be applied to full-color light emitting flat panel displays. Due to these advantages, organic electroluminescent devices have received attention as next-generation light sources.

The above characteristics of organic electroluminescent devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized structures of organic layers for organic electroluminescent devices and stable and efficient materials for organic layers of organic electroluminescent devices.

As such, there is a continued need to develop structures of organic electroluminescent devices optimized to improve their luminescent properties and new materials capable of supporting the optimized structures of organic electroluminescent devices.

### DETAILED DESCRIPTION

### Technical Problems

Accordingly, the present invention is intended to provide a compound that can be employed in an organic layer of an organic electroluminescent device to achieve high efficiency and long lifetime of the device. The present invention is also intended to provide an organic electroluminescent device including the compound.

### Means for Solving the Problems

One aspect of the present invention provides a polycyclic compound represented by Formula A-1 or A-2 and including a structure represented by Structural Formula 1 introduced therein.

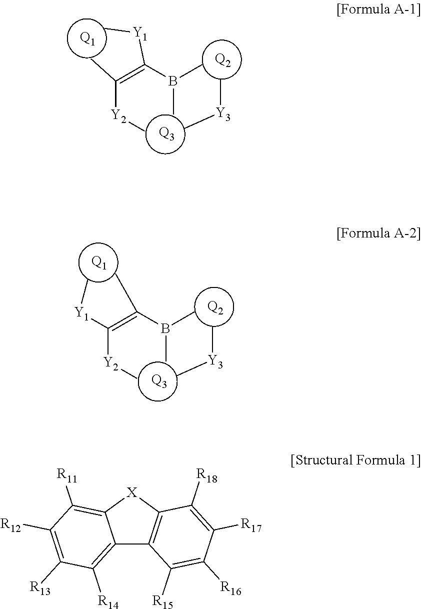

The structures of Formulae A-1 and A-2 and Structural Formula 1 and specific compounds that can be represented by Formulae A-1 and A-2 and Structural Formula 1 are described below. The rings Q₁ to Q₃, X, Y₁ to Y₃, and R₁₁ to Y₁₈ in Formulae A-1 and A-2 and Structural Formula 1 are as defined below.

A further aspect of the present invention provides an organic electroluminescent device including a first electrode, a second electrode opposite to the first electrode, and one or more organic layers interposed between the first and second electrodes wherein one of the organic layers includes at least one of the specific polycyclic compounds that can be represented by Formula A-1 or A-2.

### Effects of the Invention

The polycyclic compound of the present invention can be employed in an organic layer of an organic electroluminescent device to achieve high efficiency and long lifetime of the device.

### BEST MODE FOR CARRYING OUT THE INVENTION

The present invention will now be described in more detail.

One aspect of the present invention is directed to a polycyclic compound for use in an organic electroluminescent device, represented by Formula A-1 or A-2:

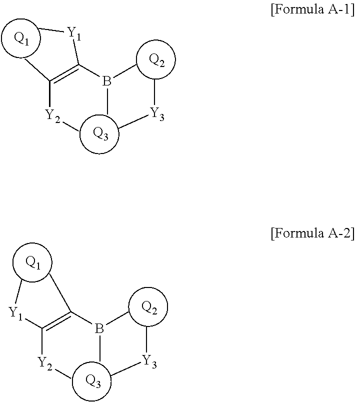

wherein Q₁ to Q₃ are the same as or different from each other and are each independently selected from substituted or unsubstituted C₆-C₅₀ monocyclic or polycyclic aromatic hydrocarbon rings, substituted or unsubstituted C₂-C₅₀ monocyclic or polycyclic aromatic heterocyclic rings, substituted or unsubstituted C₆-C₅₀ fused polycyclic non-aromatic hydrocarbon rings, and substituted or unsubstituted C₂-C₅₀ fused polycyclic non-aromatic heterocyclic rings, Y₁ to Y₃ are the same as or different from each other and are each independently N—R₁, CR₂R₃, O, S, Se, and SiR₄R₅, and R₁ to R₅ are the same as or different from each other and are each independently selected from hydrogen, deuterium, substituted or unsubstituted C₁-C₃₀ alkyl, substituted or unsubstituted C₂-C₃₀ alkenyl, substituted or unsubstituted C₆-C₆₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₆₀ heteroaryl, substituted or unsubstituted C₆-C₆₀ fused polycyclic non-aromatic hydrocarbon rings, substituted or unsubstituted C₂-C₆₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₆-C₃₀ arylthioxy, substituted or unsubstituted amine, substituted or unsubstituted silyl, nitro, cyano, and halogen, with the proviso that each of R₁ to R₅ is optionally bonded to either one of the rings Q₁ to Q₃ to form an alicyclic or aromatic monocyclic or polycyclic ring, R₂ and R₃ are optionally linked to each other to form an alicyclic or aromatic monocyclic or polycyclic ring, and R₄ and R₅ are optionally linked to each other to form an alicyclic or aromatic monocyclic or polycyclic ring, with the proviso that at least one of Y₂ and Y₃ is N—R₆ and R₆ is represented by Structural Formula 1:

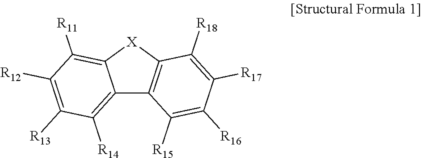

wherein X is O or S, R₁₁ to R₁₈ are the same as or different from each other and are each independently selected from hydrogen, deuterium, substituted or unsubstituted C₁-C₃₀ alkyl, substituted or unsubstituted C₂-C₃₀ alkenyl, substituted or unsubstituted C₂-C₃₀ alkynyl, substituted or unsubstituted C₆-C₆₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₆₀ heteroaryl, substituted or unsubstituted C₆-C₅₀ fused polycyclic non-aromatic hydrocarbon rings, substituted or unsubstituted C₂-C₅₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, substituted or unsubstituted boron, substituted or unsubstituted aluminum, phosphoryl, hydroxyl, selenium, tellurium, nitro, cyano, and halogen, with the proviso that either one of R₁₁ to R₁₈ is optionally bonded to Y₂ or Y₃, the others of R₁₁ to R₁₈ are optionally linked to each other or one or more adjacent substituents to form an alicyclic or aromatic monocyclic or polycyclic ring, and the carbon atoms in the alicyclic or aromatic monocyclic or polycyclic ring are optionally substituted with one or more heteroatoms selected from N, S, and O.

The compound represented by Formula A-1 or A-2 according to the present invention is characterized in that at least one dibenzofuran or dibenzothiophene derivative represented by Structural Formula 1 is introduced at a specific position.

The use of the polycyclic compound makes the organic electroluminescent device highly efficient.

The characteristic structures and ring-forming structures in Formula A-1 or A-2 based on the definitions provided above can be identified from the specific compounds listed below.

According to one embodiment of the present invention, the compound represented by Formula A-1 or A-2 may be a compound represented by Formula A-3 or A-4:

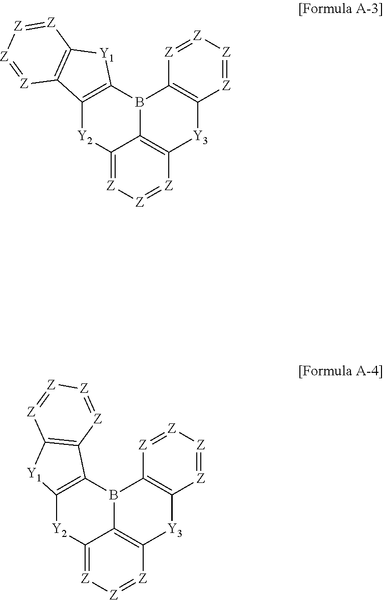

wherein each Z is independently CR or N, each R is independently selected from hydrogen, deuterium, substituted or unsubstituted C₁-C₃₀ alkyl, substituted or unsubstituted C₂-C₃₀ alkenyl, substituted or unsubstituted C₂-C₃₀ alkynyl, substituted or unsubstituted C₆-C₅₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₅₀ heteroaryl, substituted or unsubstituted C₆-C₅₀ fused polycyclic non-aromatic hydrocarbon rings, substituted or unsubstituted C₂-C₅₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, substituted or unsubstituted boron, substituted or unsubstituted aluminum, phosphoryl, hydroxyl, selenium, tellurium, nitro, cyano, and halogen, the moieties Z are the same as or different from each other, the groups R are the same as or different from each other, with the proviso that the groups R are optionally linked to each other or one or more adjacent substituents to form an alicyclic or aromatic monocyclic or polycyclic ring and the carbon atoms in the alicyclic or aromatic monocyclic or polycyclic ring are optionally substituted with one or more heteroatoms selected from N, S, and O, and Y₁ to Y₃ are as defined in Formulae A-1 and A-2.

As used herein, the term “substituted” in the definition of the rings Q₁ to Q₃, R₁ to R₆, R₁₁ to R₁₈, etc. in Formulae A-1 and A-2 indicates substitution with one or more substituents selected from deuterium, cyano, halogen, hydroxyl, nitro, amino, alkyl, cycloalkyl, haloalkyl, alkenyl, alkynyl, heteroalkyl, heterocycloalkyl, aryl, arylalkyl, alkylaryl, heteroaryl, heteroarylalkyl, alkoxy, alkylamino, arylamino, heteroarylamino, alkylsilyl, arylsilyl, and aryloxy, or a combination thereof. The term “unsubstituted” in the same definition indicates having no substituent.

In the “substituted or unsubstituted C₁-C₃₀ alkyl”, “substituted or unsubstituted C₆-C₅₀ aryl”, etc., the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “form a ring with an adjacent substituent” means that the corresponding substituent combines with an adjacent substituent to form a substituted or unsubstituted alicyclic or aromatic ring and the term “adjacent substituent” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other.

In the present invention, the alkyl groups may be straight or branched. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The aromatic hydrocarbon rings or aryl groups may be monocyclic or polycyclic ones. Examples of the monocyclic aryl groups include, but are not limited to, phenyl, biphenyl, terphenyl, and stilbenyl groups. Examples of the polycyclic aryl groups include naphthyl, anthracenyl, phenanthrenyl, pyrenyl, perylenyl, tetracenyl, chrysenyl, fluorenyl, acenaphathcenyl, triphenylene, and fluoranthrene groups but the scope of the present invention is not limited thereto.

The aromatic heterocyclic rings or heteroaryl groups refer to aromatic groups interrupted by one or more heteroatoms. Examples of the aromatic heterocyclic rings or heteroaryl groups include, but are not limited to, thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The aliphatic hydrocarbon rings refer to non-aromatic rings consisting only of carbon and hydrogen atoms. The aliphatic hydrocarbon ring is intended to include monocyclic and polycyclic ones and may be optionally substituted with one or more other substituents. As used herein, the term “polycyclic” means that the aliphatic hydrocarbon ring may be directly attached or fused to one or more other cyclic groups. The other cyclic groups may be aliphatic hydrocarbon rings and other examples thereof include aliphatic heterocyclic, aryl, and heteroaryl groups. Specific examples of the aliphatic hydrocarbon rings include, but are not limited to, cycloalkyl groups such as cyclopropyl, cyclobutyl, cyclopentyl, adamantyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, and cyclooctyl, cycloalkanes such as cyclohexane and cyclopentane, and cycloalkenes such as cyclohexene and cyclobutene.

The aliphatic heterocyclic rings refer to aliphatic rings interrupted by one or more heteroatoms such as O, S, Se, N, and Si. The aliphatic heterocyclic ring is intended to include monocyclic or polycyclic ones and may be optionally substituted with one or more other substituents. As used herein, the term “polycyclic” means that the aliphatic heterocyclic ring such as heterocycloalkyl, heterocycloalkane or heterocycloalkene may be directly attached or fused to one or more other cyclic groups. The other cyclic groups may be aliphatic heterocyclic rings and other examples thereof include aliphatic hydrocarbon rings, aryl groups, and heteroaryl groups.

The fused polycyclic non-aromatic hydrocarbon rings refer to ring structures in which two or more rings are fused together and which are overall non-aromatic. The fused polycyclic non-aromatic heterocyclic rings refer to fused non-aromatic hydrocarbon rings which are interrupted by one or more heteroatoms selected from N, O, P, and S other than carbon atoms (C). Examples of the fused polycyclic non-aromatic hydrocarbon rings and the fused polycyclic non-aromatic heterocyclic rings include, but are not limited to, the following structures:

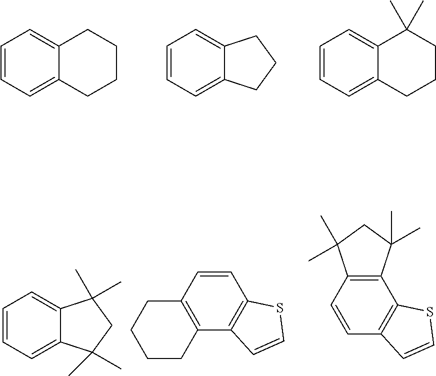

The alkoxy group may be specifically a methoxy, ethoxy, propoxy, isobutyloxy, sec-butyloxy, pentyloxy, iso-amyloxy or hexyloxy group but is not limited thereto.

The silyl group may be, for example, —SiH₃, alkylsilyl, arylsilyl, alkylarylsilyl or arylheteroarylsilyl. Specific examples of the silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl.

The amine group may be, for example, —NH₂, alkylamine, arylamine or arylheteroarylamine. The arylamine refers to an aryl-substituted amine group, the alkylamine refers to an alkyl-substituted amine group, and the arylheteroarylamine refers to an aryl- and heteroaryl-substituted amine group. The arylamine may be, for example, substituted or unsubstituted monoarylamine, substituted or unsubstituted diarylamine, or substituted or unsubstituted triarylamine. The aryl and/or heteroaryl groups in the arylamine and arylheteroarylamine groups may be monocyclic or polycyclic ones. The arylamine and arylheteroarylamine groups may include two or more aryl and/or heteroaryl groups. In this case, the aryl groups may be monocyclic and/or polycyclic ones and the heteroaryl groups may be monocyclic and/or polycyclic ones. The aryl and/or heteroaryl groups in the arylamine and arylheteroarylamine groups may be selected from those exemplified above.

The aryl groups in the aryloxy and arylthioxy groups are the same as those exemplified above. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. Specific examples of the arylthioxy groups include, but are not limited to, phenylthioxy, 2-methylphenylthioxy, and 4-tert-butylphenylthioxy groups.

The halogen group may be, for example, fluorine, chlorine, bromine or iodine.

More specifically, the polycyclic aromatic derivative represented by Formula A-1 or A-2 according to the present invention may be selected from the following compounds 1 to 156:

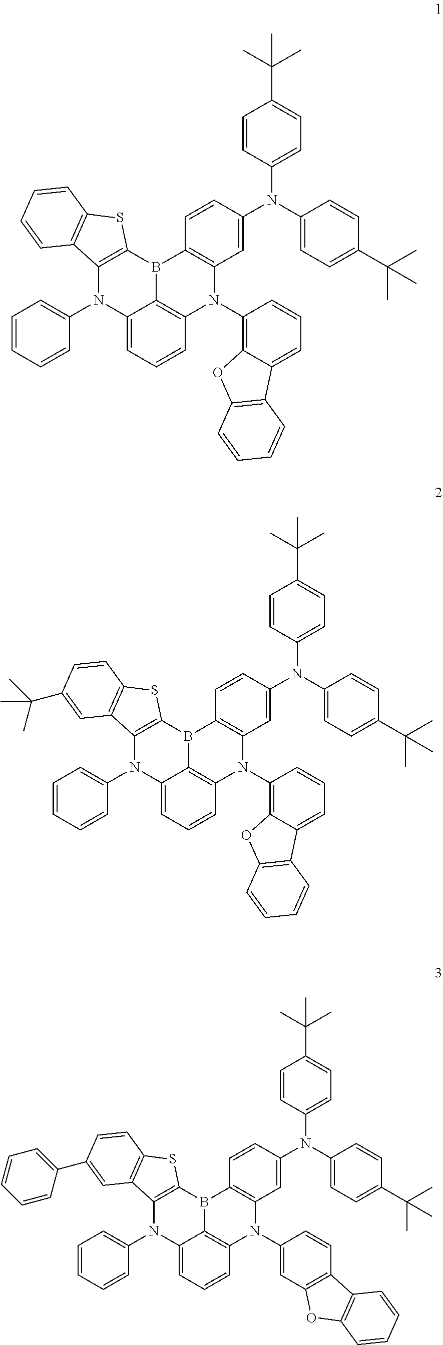

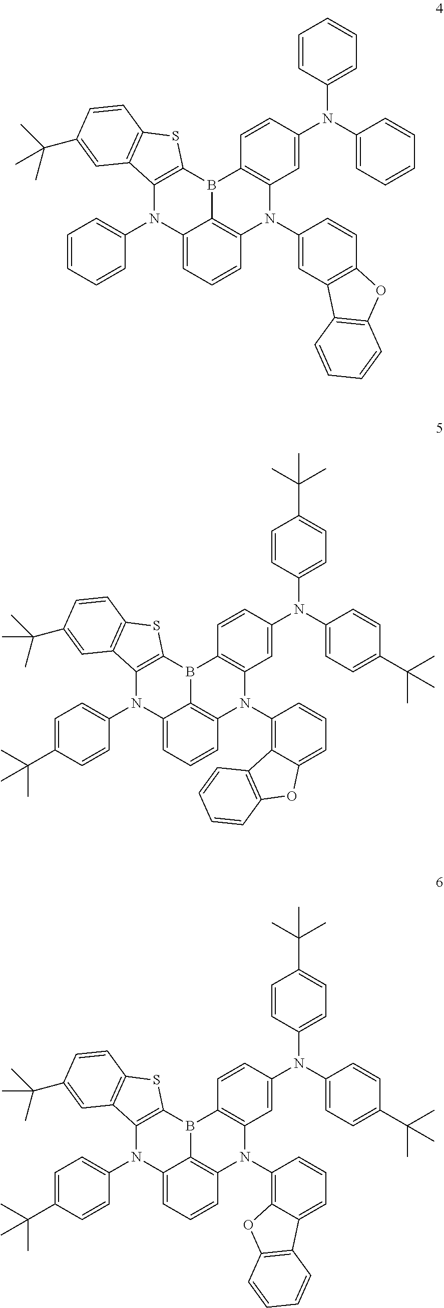

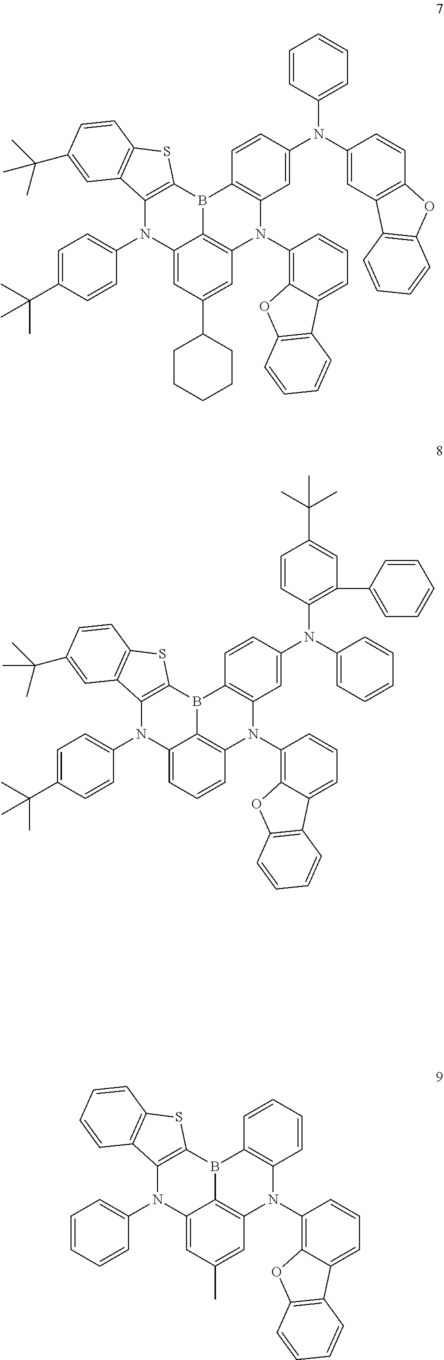 [SMILES: CC(C)(C)c1ccc(N2c3cc(C4CCCCC4)cc4c3B(c3ccc(N(c5ccccc5)c5ccc6oc7ccccc7c6c5)cc3N4c3cccc4c3oc3ccccc34)c3sc4ccc(C(C)(C)C)cc4c32)cc1 ; CC(C)(C)c1ccc(N2c3cccc4c3B(c3ccc(N(c5ccccc5)c5ccc(C(C)(C)C)cc5-c5ccccc5)cc3N4c3cccc4c3oc3ccccc34)c3sc4ccc(C(C)(C)C)cc4c32)cc1 ; Cc1cc2c3c(c1)N(c1cccc4c1oc1ccccc14)c1ccccc1B3c1sc3ccccc3c1N2c1ccccc1]

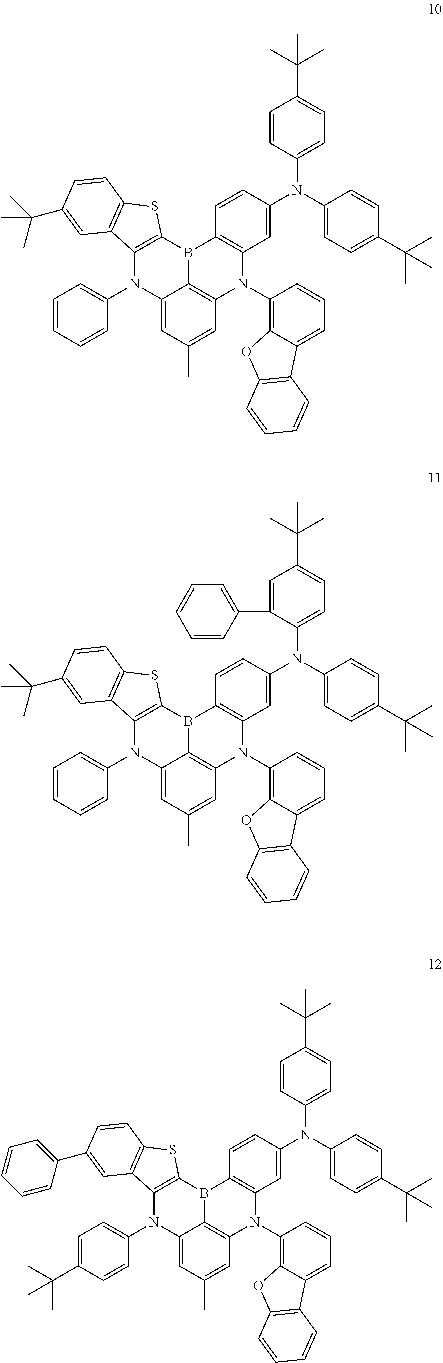

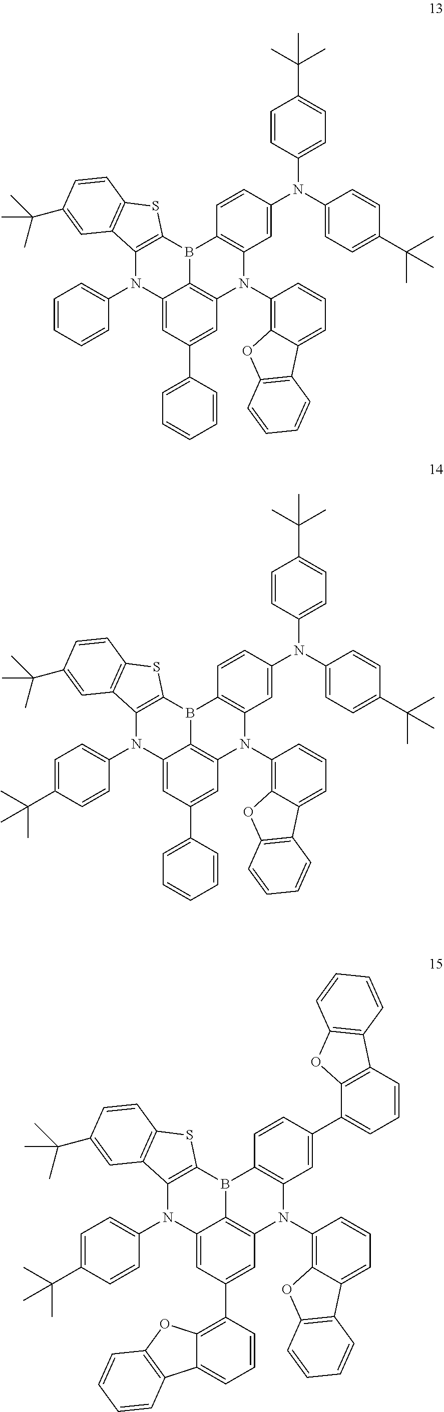

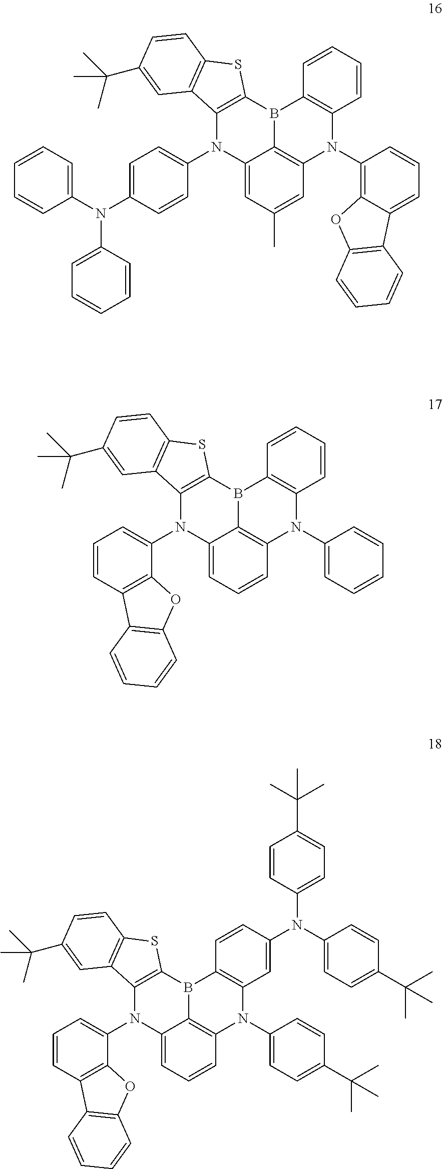 [SMILES: Cc1cc2c3c(c1)N(c1cccc4c1oc1ccccc14)c1ccccc1B3c1sc3ccc(C(C)(C)C)cc3c1N2c1ccc(N(c2ccccc2)c2ccccc2)cc1 ; CC(C)(C)c1ccc2sc3c(c2c1)N(c1cccc2c1oc1ccccc12)c1cccc2c1B3c1ccccc1N2c1ccccc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(C(C)(C)C)cc3c2N4c2cccc3c2oc2ccccc23)cc1]

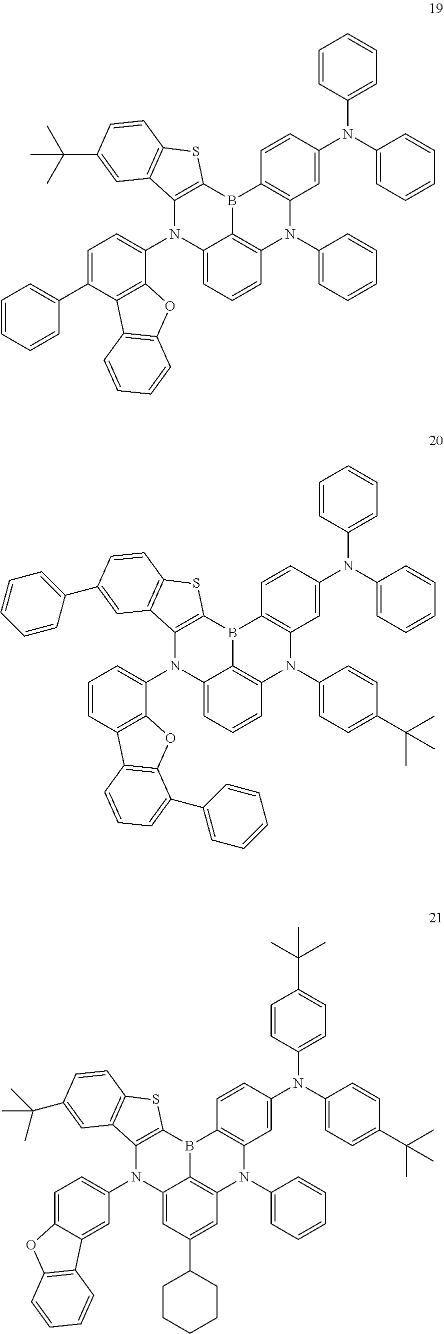

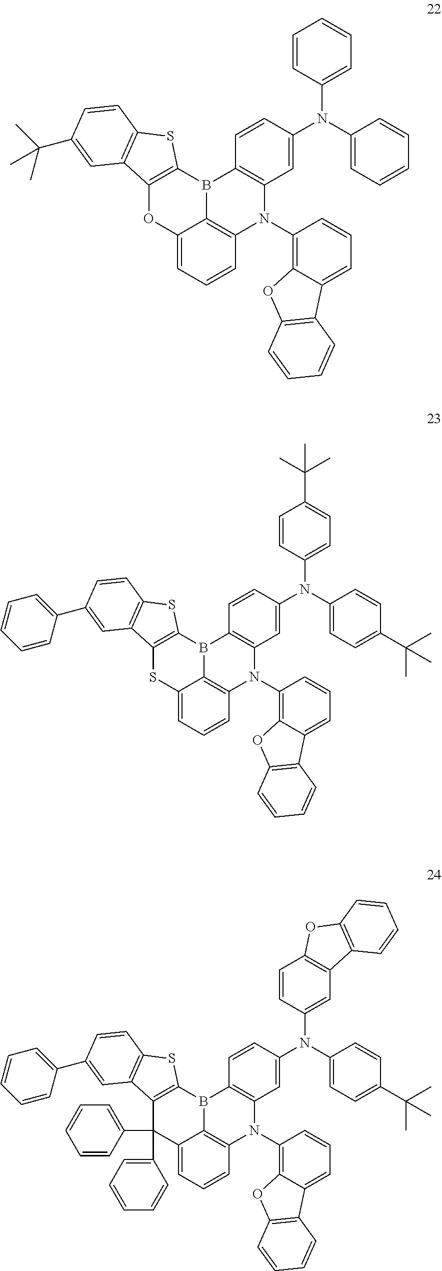 [SMILES: CC(C)(C)c1ccc2sc3c(c2c1)Oc1cccc2c1B3c1ccc(N(c3ccccc3)c3ccccc3)cc1N2c1cccc2c1oc1ccccc12 ; CC(C)(C)c1ccc(N(c2ccc(C(C)(C)C)cc2)c2ccc3c(c2)N(c2cccc4c2oc2ccccc24)c2cccc4c2B3c2sc3ccc(-c5ccccc5)cc3c2S4)cc1 ; CC(C)(C)c1ccc(N(c2ccc3c(c2)N(c2cccc4c2oc2ccccc24)c2cccc4c2B3c2sc3ccc(-c5ccccc5)cc3c2C4(c2ccccc2)c2ccccc2)c2ccc3oc4ccccc4c3c2)cc1]

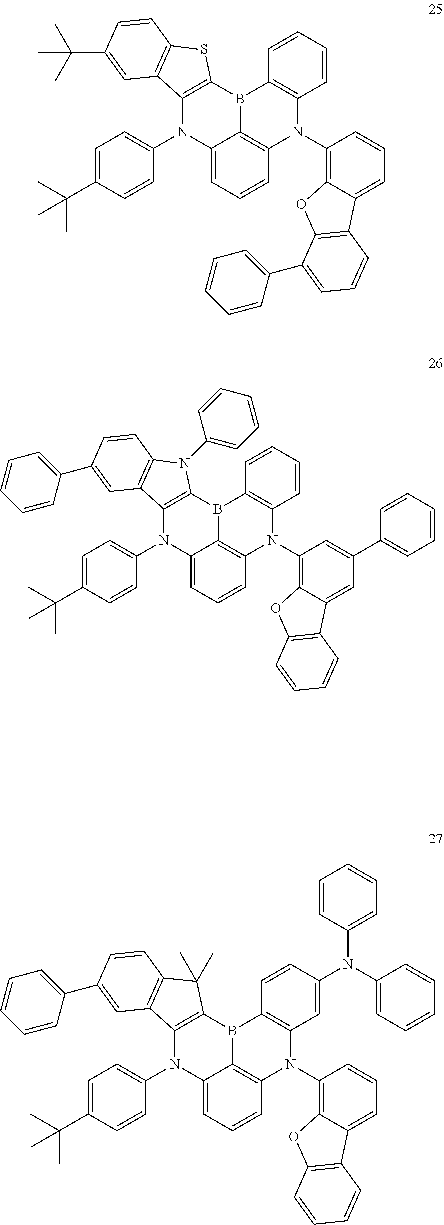 [SMILES: CC(C)(C)c1ccc(N2c3cccc4c3B(c3ccccc3N4c3cccc4c3oc3c(-c5ccccc5)cccc34)c3sc4ccc(C(C)(C)C)cc4c32)cc1 ; CC(C)(C)c1ccc(N2c3cccc4c3B(c3ccccc3N4c3cc(-c4ccccc4)cc4c3oc3ccccc34)c3c2c2cc(-c4ccccc4)ccc2n3-c2ccccc2)cc1 ; CC(C)(C)c1ccc(N2C3=C(B4c5ccc(N(c6ccccc6)c6ccccc6)cc5N(c5cccc6c5oc5ccccc56)c5cccc2c54)C(C)(C)c2ccc(-c4ccccc4)cc23)cc1]

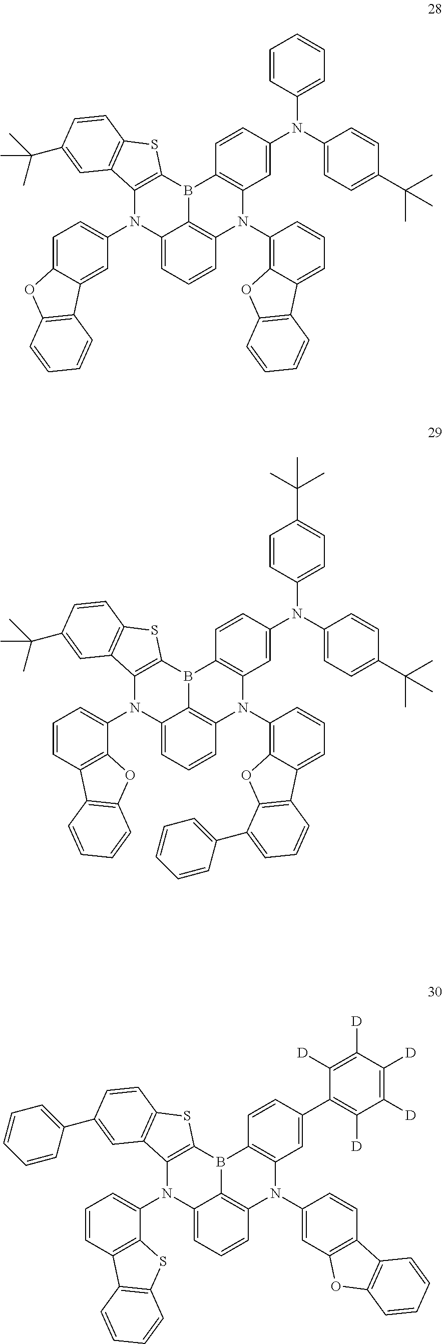

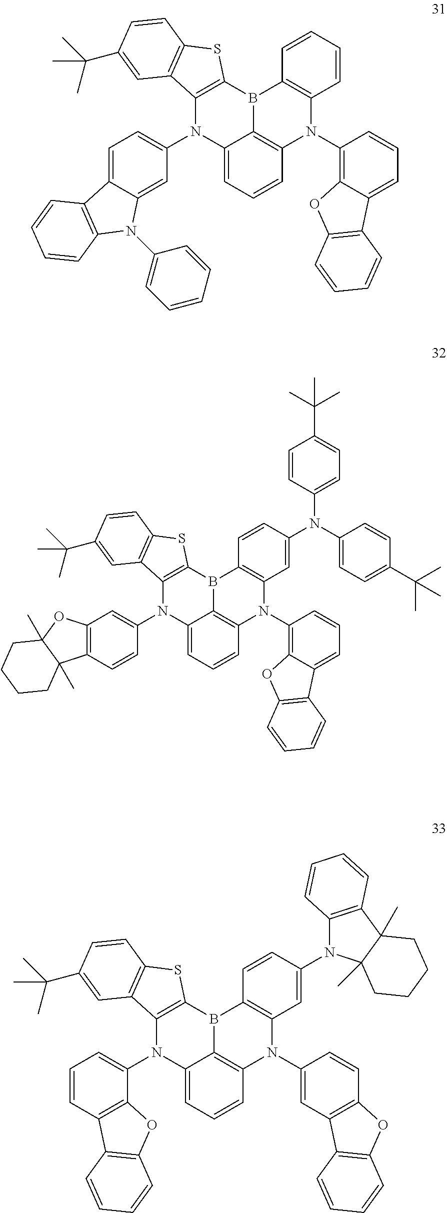

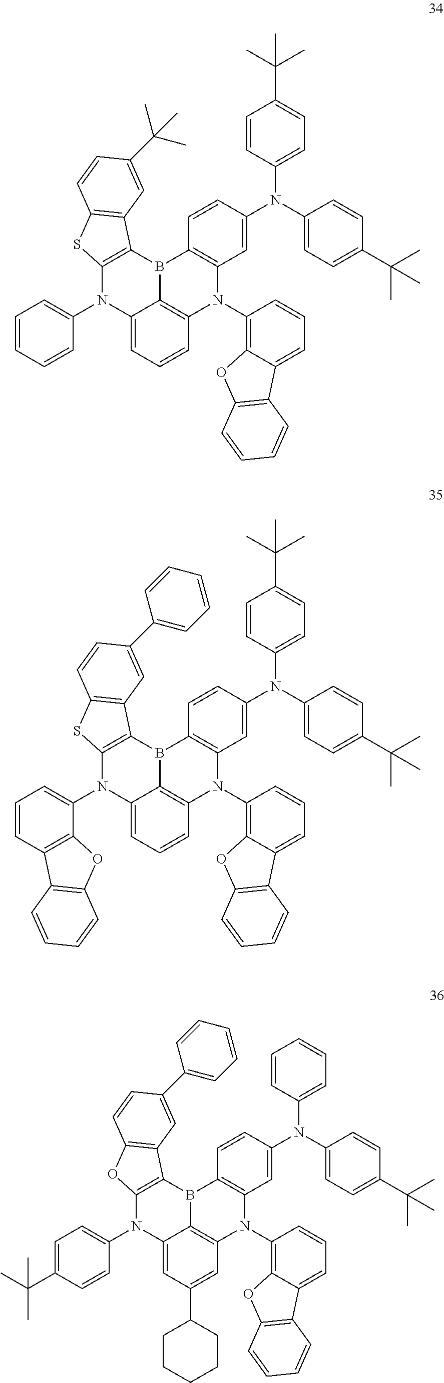

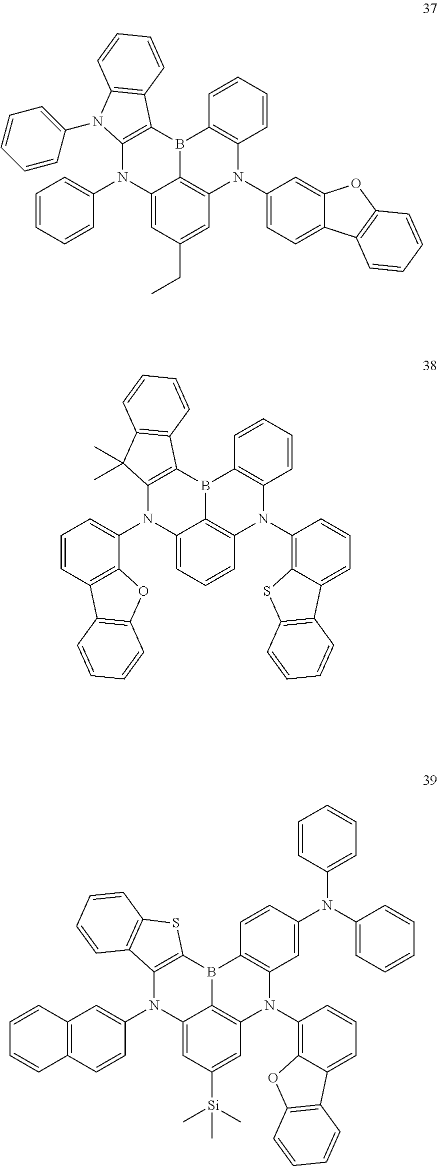 [SMILES: CCc1cc2c3c(c1)N(c1ccccc1)c1c(c4ccccc4n1-c1ccccc1)B3c1ccccc1N2c1ccc2c(c1)oc1ccccc12 ; CC1(C)C2=C(B3c4ccccc4N(c4cccc5c4sc4ccccc45)c4cccc(c43)N2c2cccc3c2oc2ccccc23)c2ccccc21 ; C[Si](C)(C)c1cc2c3c(c1)N(c1cccc4c1oc1ccccc14)c1cc(N(c4ccccc4)c4ccccc4)ccc1B3c1sc3ccccc3c1N2c1ccc2ccccc2c1]

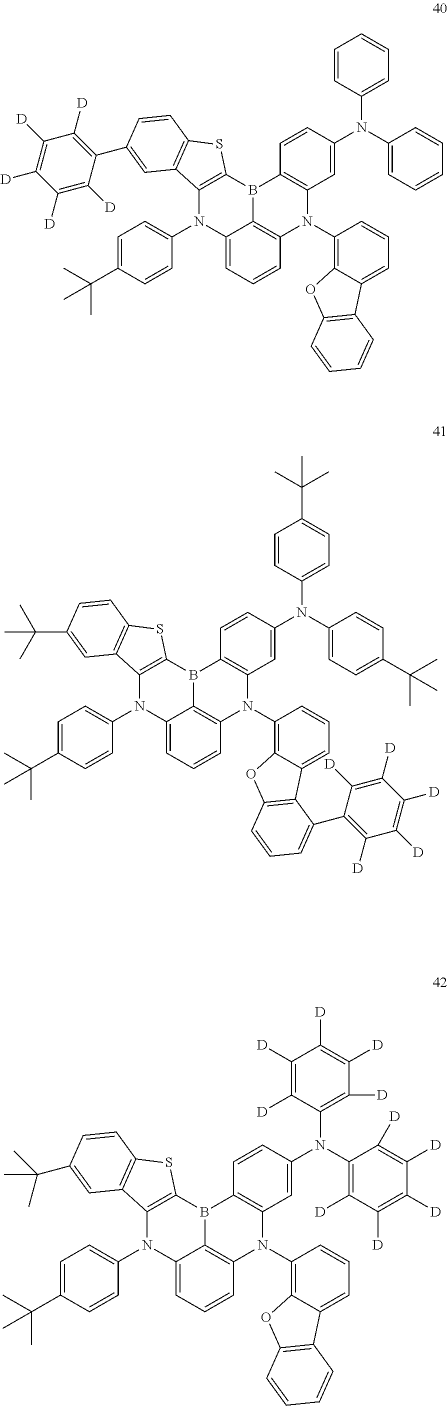

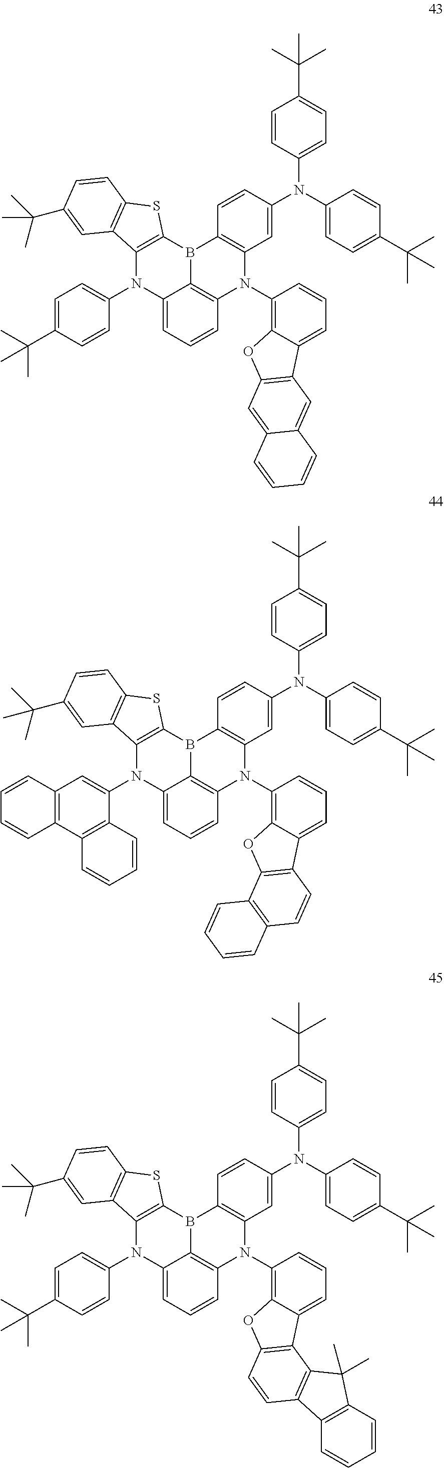

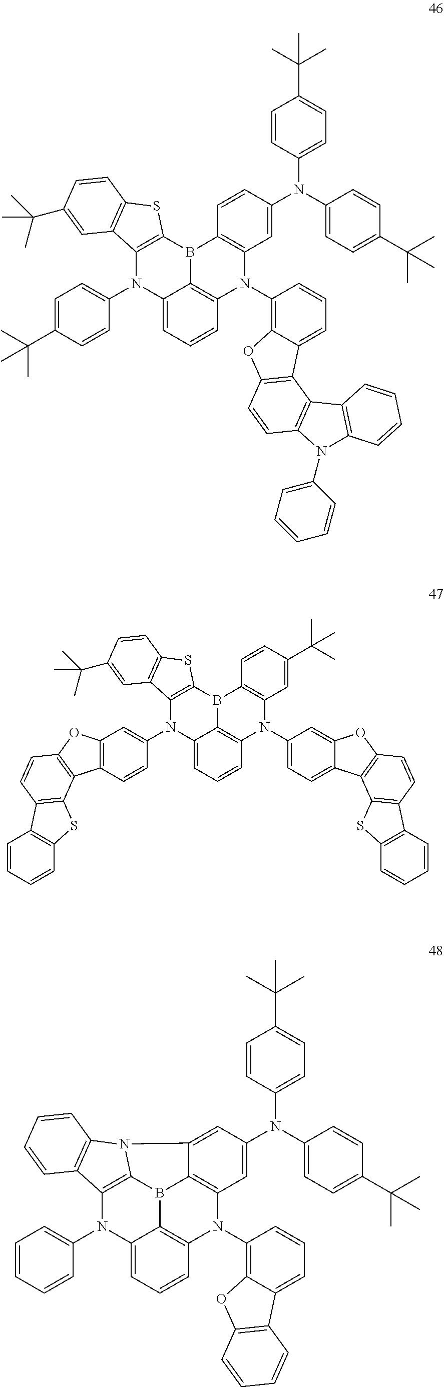 [SMILES: CC(C)(C)c1ccc(N(c2ccc(C(C)(C)C)cc2)c2ccc3c(c2)N(c2cccc4c2oc2ccc5c(c6ccccc6n5-c5ccccc5)c24)c2cccc4c2B3c2sc3ccc(C(C)(C)C)cc3c2N4c2ccc(C(C)(C)C)cc2)cc1 ; CC(C)(C)c1ccc2c(c1)N(c1ccc3c(c1)oc1ccc4c5ccccc5sc4c13)c1cccc3c1B2c1sc2ccc(C(C)(C)C)cc2c1N3c1ccc2c(c1)oc1ccc3c4ccccc4sc3c12 ; CC(C)(C)c1ccc(N(c2ccc(C(C)(C)C)cc2)c2cc3c4c(c2)-n2c5c(c6ccccc62)N(c2ccccc2)c2cccc(c2B45)N3c2cccc3c2oc2ccccc23)cc1]

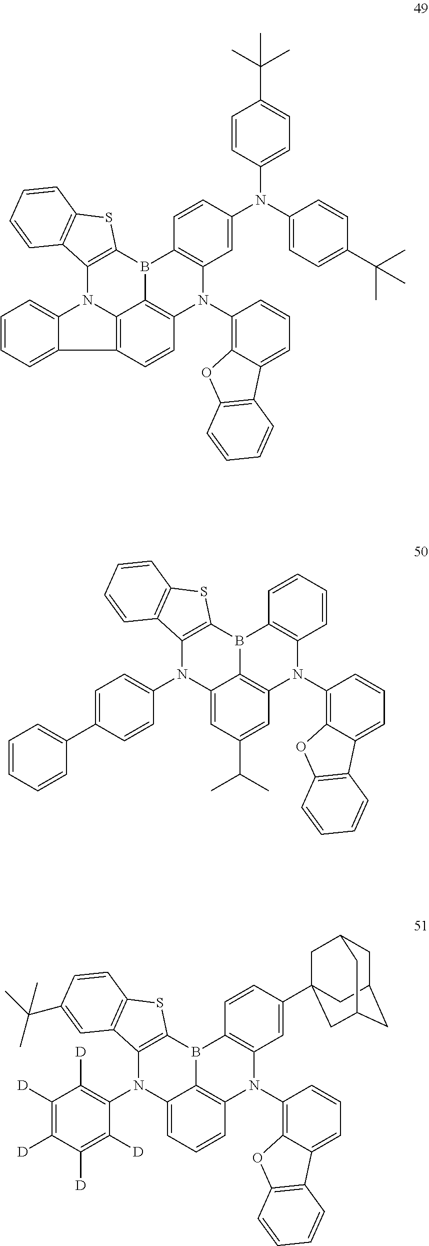

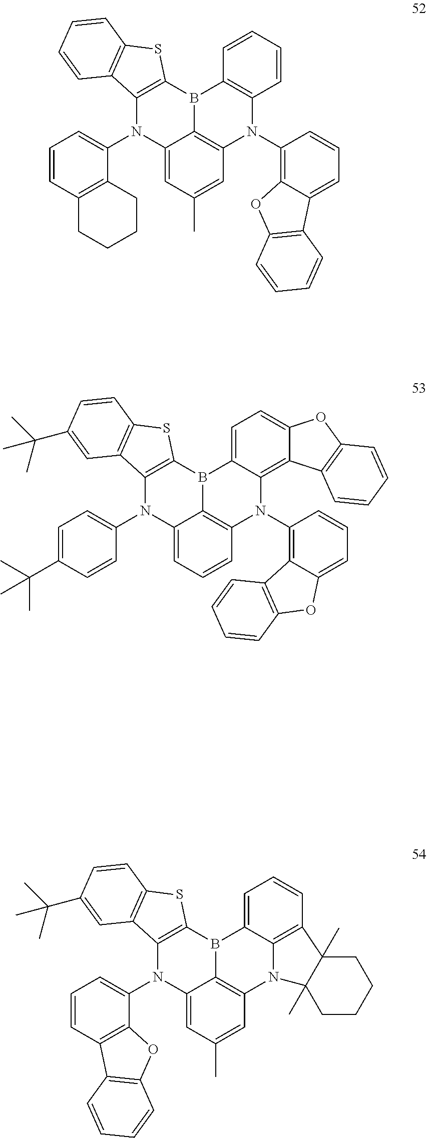 [SMILES: Cc1cc2c3c(c1)N(c1cccc4c1oc1ccccc14)c1ccccc1B3c1sc3ccccc3c1N2c1cccc2c1CCCC2 ; CC(C)(C)c1ccc(N2c3cccc4c3B(c3ccc5oc6ccccc6c5c3N4c3cccc4oc5ccccc5c34)c3sc4ccc(C(C)(C)C)cc4c32)cc1 ; Cc1cc2c3c(c1)N1c4c(cccc4C4(C)CCCCC14C)B3c1sc3ccc(C(C)(C)C)cc3c1N2c1cccc2c1oc1ccccc12]

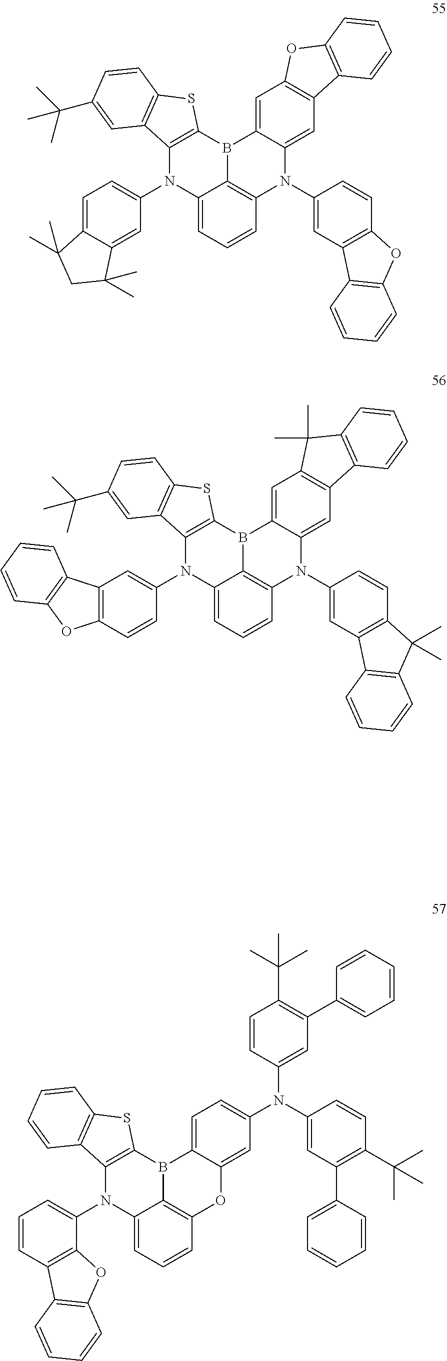 [SMILES: CC(C)(C)c1ccc2sc3c(c2c1)N(c1ccc2c(c1)C(C)(C)CC2(C)C)c1cccc2c1B3c1cc3oc4ccccc4c3cc1N2c1ccc2oc3ccccc3c2c1 ; CC(C)(C)c1ccc2sc3c(c2c1)N(c1ccc2oc4ccccc4c2c1)c1cccc2c1B3c1cc3c(cc1N2c1ccc2c(c1)-c1ccccc1C2(C)C)-c1ccccc1C3(C)C ; CC(C)(C)c1ccc(N(c2ccc3c(c2)Oc2cccc4c2B3c2sc3ccccc3c2N4c2cccc3c2oc2ccccc23)c2ccc(C(C)(C)C)c(-c3ccccc3)c2)cc1-c1ccccc1]

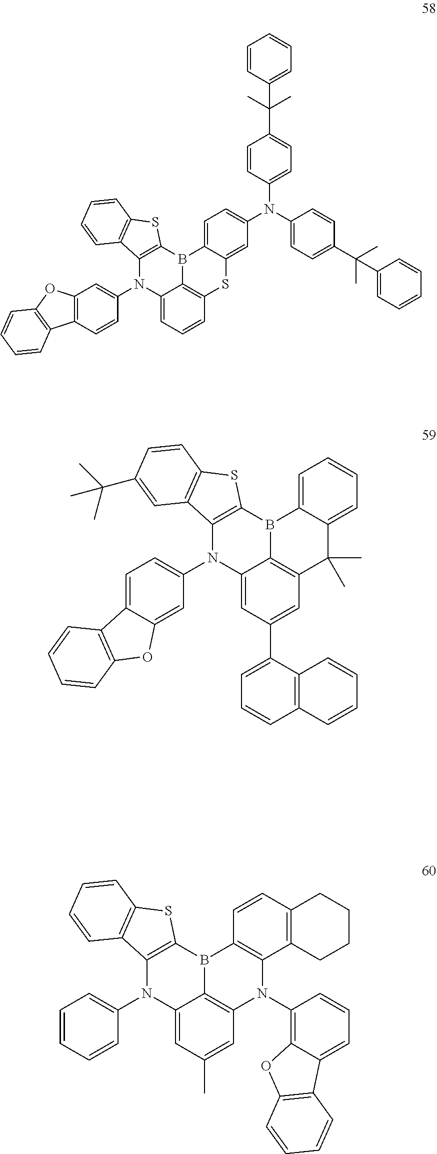 [SMILES: CC(C)(c1ccccc1)c1ccc(N(c2ccc(C(C)(C)c3ccccc3)cc2)c2ccc3c(c2)Sc2cccc4c2B3c2sc3ccccc3c2N4c2ccc3c(c2)oc2ccccc23)cc1 ; CC(C)(C)c1ccc2sc3c(c2c1)N(c1ccc2c(c1)oc1ccccc12)c1cc(-c2cccc4ccccc24)cc2c1B3c1ccccc1C2(C)C ; Cc1cc2c3c(c1)N(c1cccc4c1oc1ccccc14)c1c(ccc4c1CCCC4)B3c1sc3ccccc3c1N2c1ccccc1]

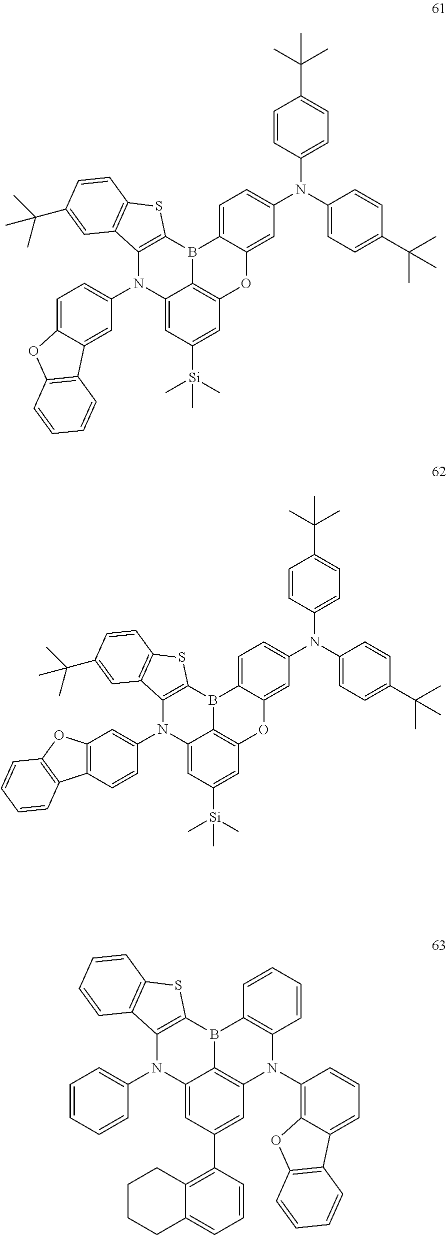 [SMILES: CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3oc4ccccc4c3c2)cc1 ; CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3c(c2)oc2ccccc23)cc1 ; c1ccc(N2c3cc(-c4cccc5c4CCCC5)cc4c3B(c3ccccc3N4c3cccc4c3oc3ccccc34)c3sc4ccccc4c32)cc1]

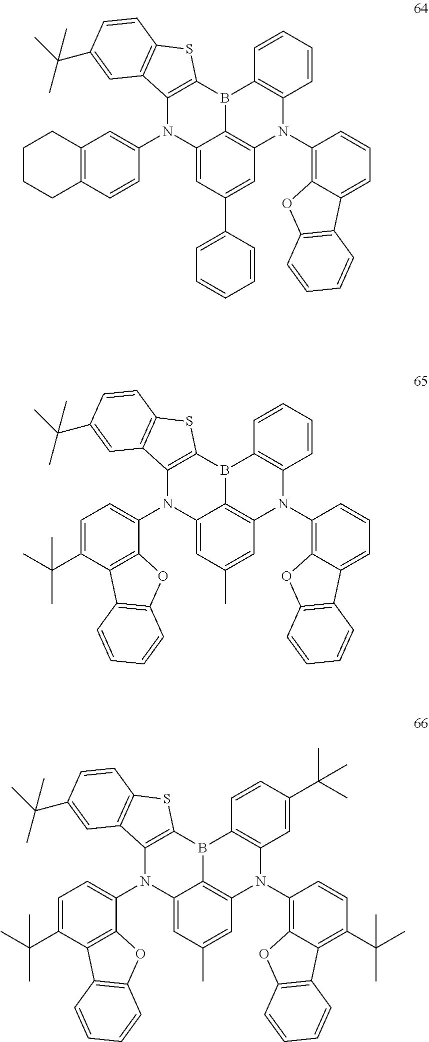 [SMILES: CC(C)(C)c1ccc2sc3c(c2c1)N(c1ccc2c(c1)CCCC2)c1cc(-c2ccccc2)cc2c1B3c1ccccc1N2c1cccc2c1oc1ccccc12 ; Cc1cc2c3c(c1)N(c1ccc(C(C)(C)C)c4c1oc1ccccc14)c1c(sc4ccc(C(C)(C)C)cc14)B3c1ccccc1N2c1cccc2c1oc1ccccc12 ; Cc1cc2c3c(c1)N(c1ccc(C(C)(C)C)c4c1oc1ccccc14)c1c(sc4ccc(C(C)(C)C)cc14)B3c1ccc(C(C)(C)C)cc1N2c1ccc(C(C)(C)C)c2c1oc1ccccc12]

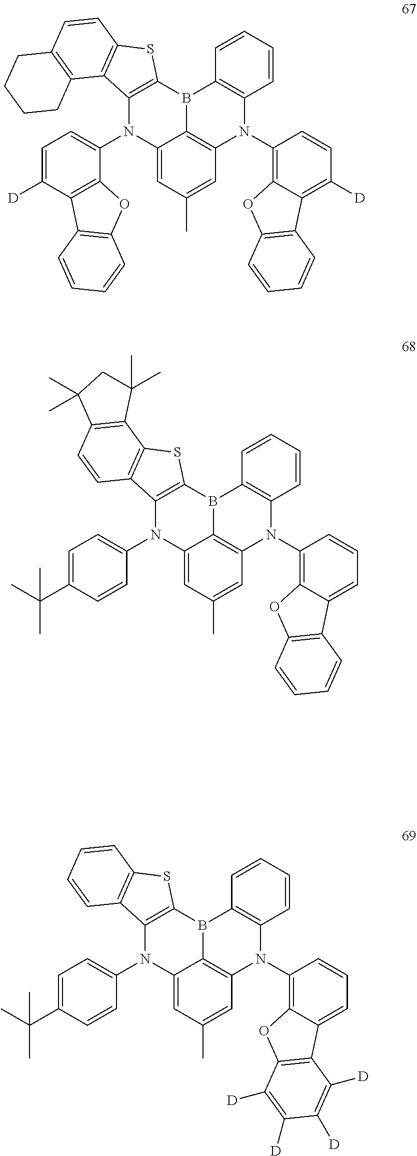 [SMILES: [2H]c1ccc(N2c3ccccc3B3c4sc5ccc6c(c5c4N(c4ccc([2H])c5c4oc4ccccc45)c4cc(C)cc2c43)CCCC6)c2oc3ccccc3c12 ; Cc1cc2c3c(c1)N(c1cccc4c1oc1ccccc14)c1ccccc1B3c1sc3c4c(ccc3c1N2c1ccc(C(C)(C)C)cc1)C(C)(C)CC4(C)C ; [2H]c1c([2H])c([2H])c2c(oc3c(N4c5ccccc5B5c6sc7ccccc7c6N(c6ccc(C(C)(C)C)cc6)c6cc(C)cc4c65)cccc32)c1[2H]]

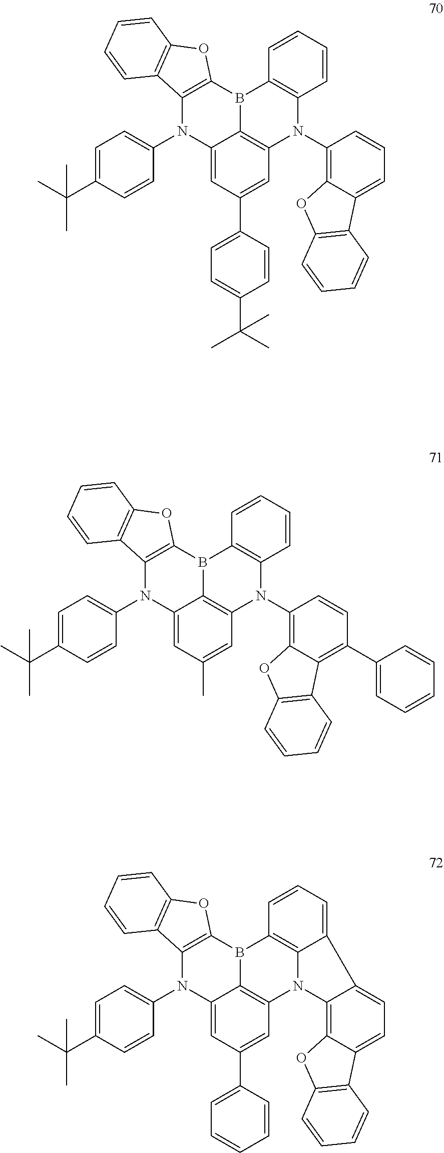 [SMILES: CC(C)(C)c1ccc(-c2cc3c4c(c2)N(c2cccc5c2oc2ccccc25)c2ccccc2B4c2oc4ccccc4c2N3c2ccc(C(C)(C)C)cc2)cc1 ; Cc1cc2c3c(c1)N(c1ccc(-c4ccccc4)c4c1oc1ccccc14)c1ccccc1B3c1oc3ccccc3c1N2c1ccc(C(C)(C)C)cc1 ; CC(C)(C)c1ccc(N2c3cc(-c4ccccc4)cc4c3B(c3oc5ccccc5c32)c2cccc3c5ccc6c7ccccc7oc6c5n-4c23)cc1]

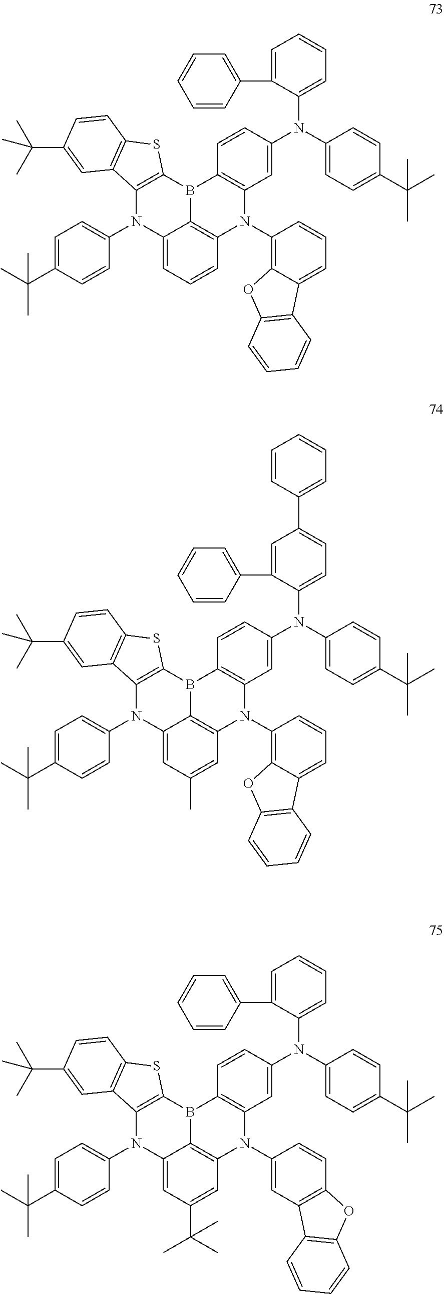

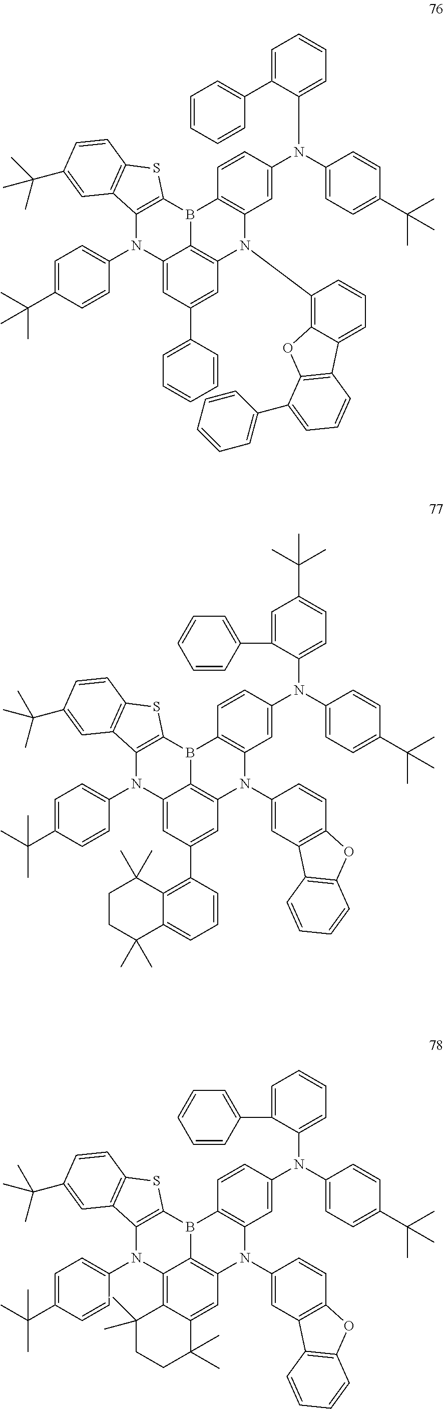

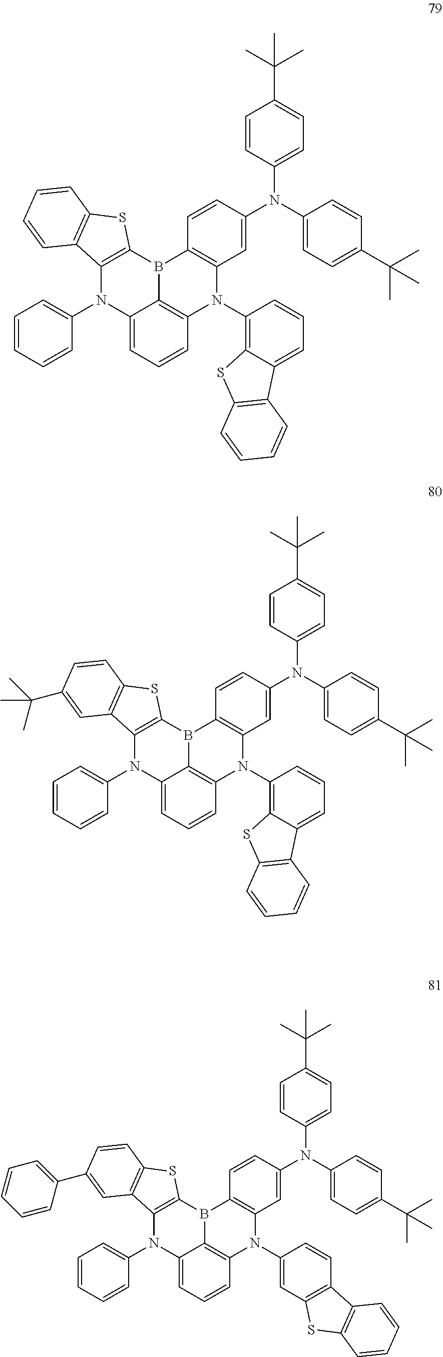

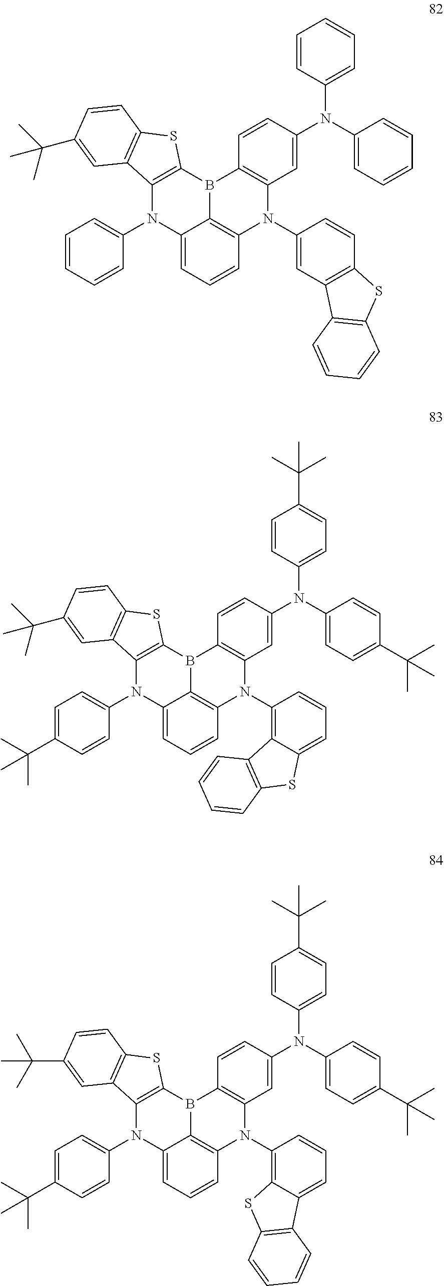

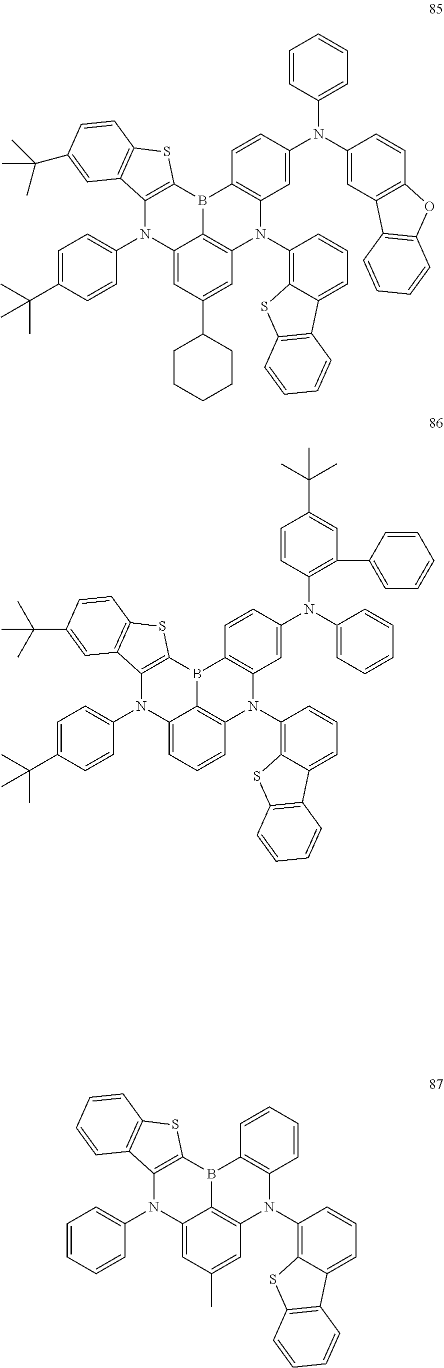 [SMILES: CC(C)(C)c1ccc(N2c3cc(C4CCCCC4)cc4c3B(c3ccc(N(c5ccccc5)c5ccc6oc7ccccc7c6c5)cc3N4c3cccc4c3sc3ccccc34)c3sc4ccc(C(C)(C)C)cc4c32)cc1 ; CC(C)(C)c1ccc(N2c3cccc4c3B(c3ccc(N(c5ccccc5)c5ccc(C(C)(C)C)cc5-c5ccccc5)cc3N4c3cccc4c3sc3ccccc34)c3sc4ccc(C(C)(C)C)cc4c32)cc1 ; Cc1cc2c3c(c1)N(c1cccc4c1sc1ccccc14)c1ccccc1B3c1sc3ccccc3c1N2c1ccccc1]

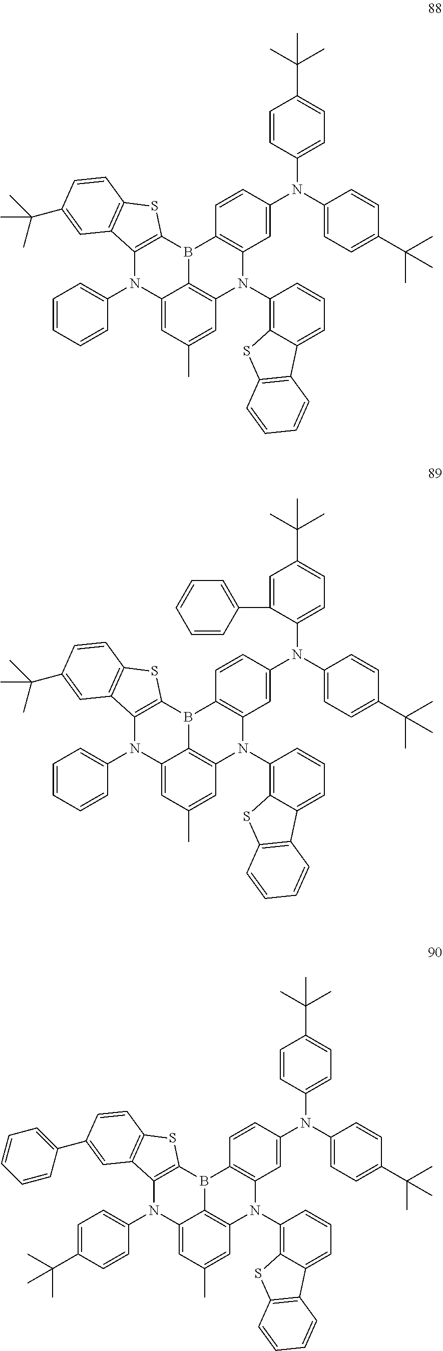

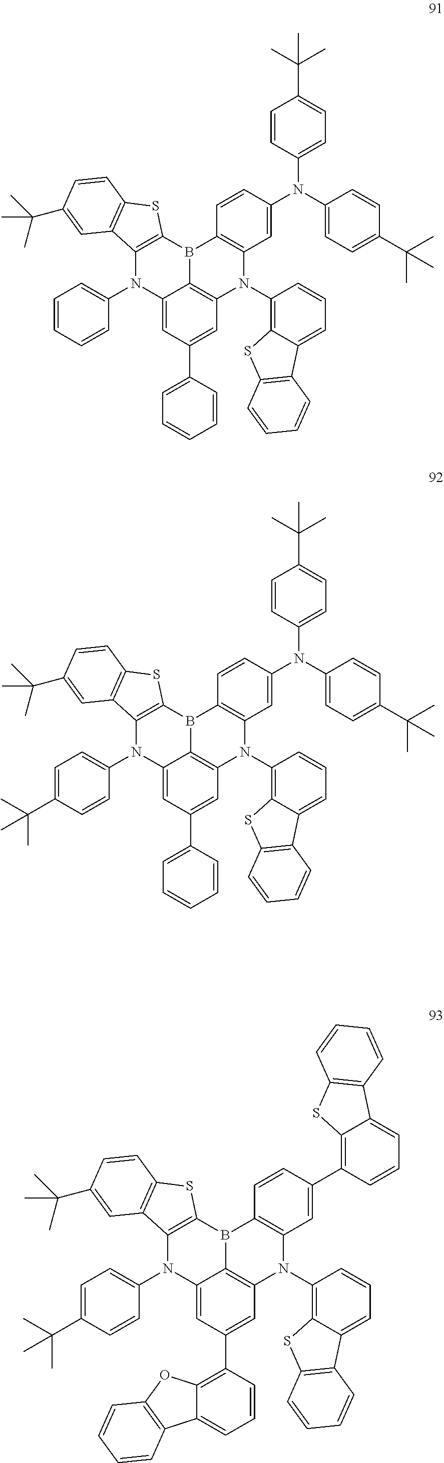

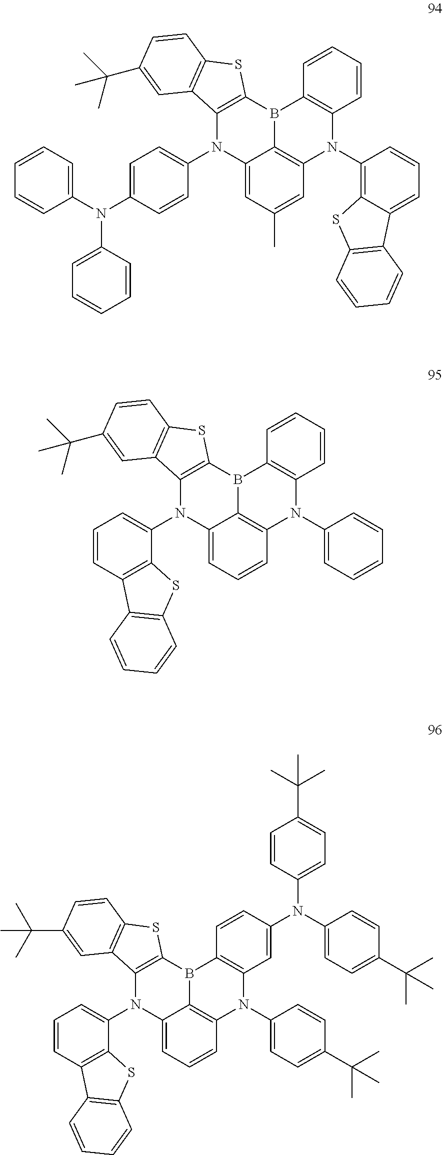 [SMILES: Cc1cc2c3c(c1)N(c1cccc4c1sc1ccccc14)c1ccccc1B3c1sc3ccc(C(C)(C)C)cc3c1N2c1ccc(N(c2ccccc2)c2ccccc2)cc1 ; CC(C)(C)c1ccc2sc3c(c2c1)N(c1cccc2c1sc1ccccc12)c1cccc2c1B3c1ccccc1N2c1ccccc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(C(C)(C)C)cc3c2N4c2cccc3c2sc2ccccc23)cc1]

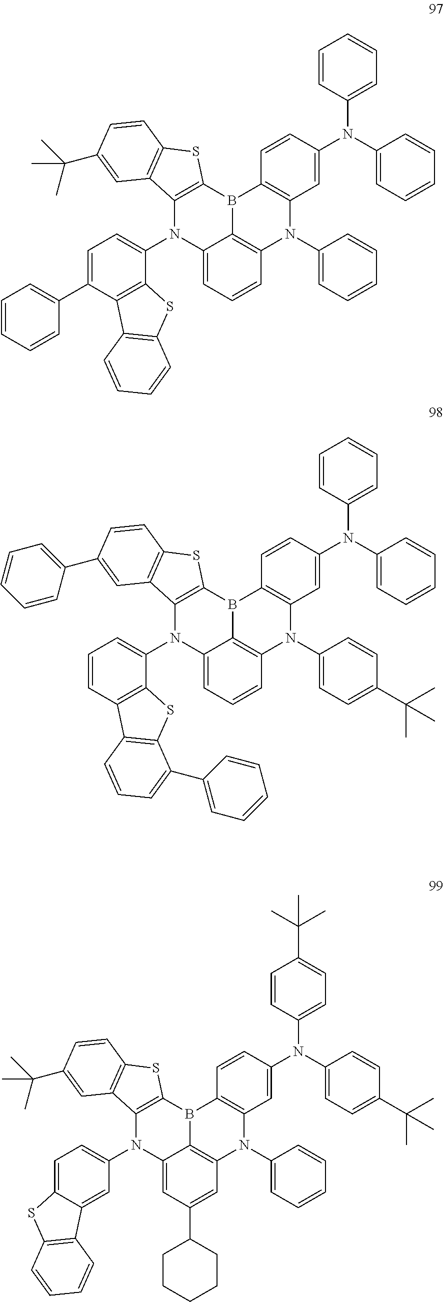

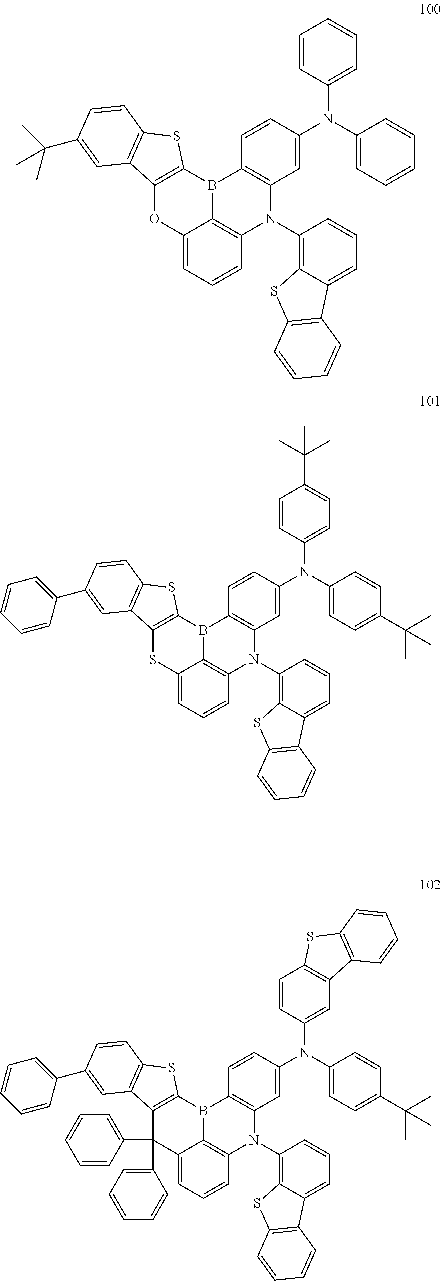 [SMILES: CC(C)(C)c1ccc2sc3c(c2c1)Oc1cccc2c1B3c1ccc(N(c3ccccc3)c3ccccc3)cc1N2c1cccc2c1sc1ccccc12 ; CC(C)(C)c1ccc(N(c2ccc(C(C)(C)C)cc2)c2ccc3c(c2)N(c2cccc4c2sc2ccccc24)c2cccc4c2B3c2sc3ccc(-c5ccccc5)cc3c2S4)cc1 ; CC(C)(C)c1ccc(N(c2ccc3c(c2)N(c2cccc4c2sc2ccccc24)c2cccc4c2B3c2sc3ccc(-c5ccccc5)cc3c2C4(c2ccccc2)c2ccccc2)c2ccc3sc4ccccc4c3c2)cc1]

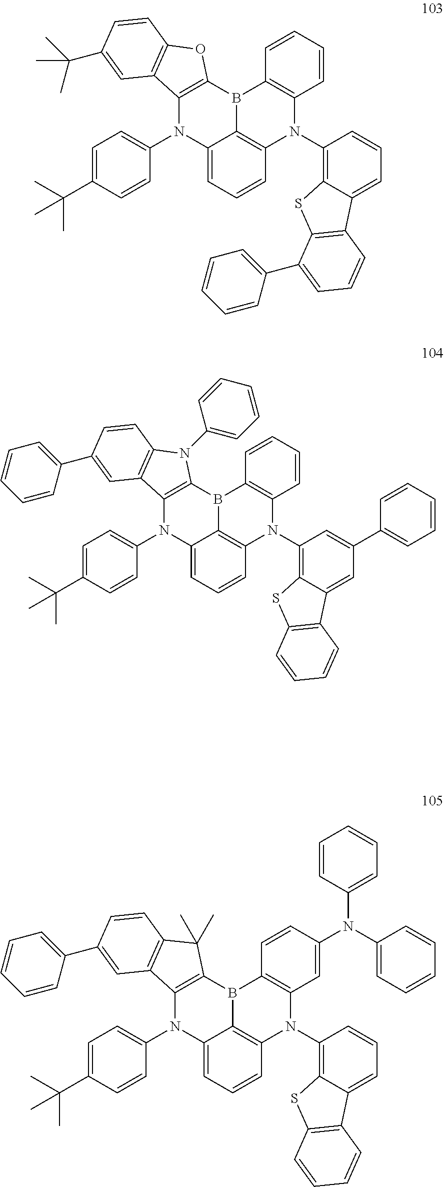 [SMILES: CC(C)(C)c1ccc(N2c3cccc4c3B(c3ccccc3N4c3cccc4c3sc3c(-c5ccccc5)cccc34)c3oc4ccc(C(C)(C)C)cc4c32)cc1 ; CC(C)(C)c1ccc(N2c3cccc4c3B(c3ccccc3N4c3cc(-c4ccccc4)cc4c3sc3ccccc34)c3c2c2cc(-c4ccccc4)ccc2n3-c2ccccc2)cc1 ; CC(C)(C)c1ccc(N2C3=C(B4c5ccc(N(c6ccccc6)c6ccccc6)cc5N(c5cccc6c5sc5ccccc56)c5cccc2c54)C(C)(C)c2ccc(-c4ccccc4)cc23)cc1]

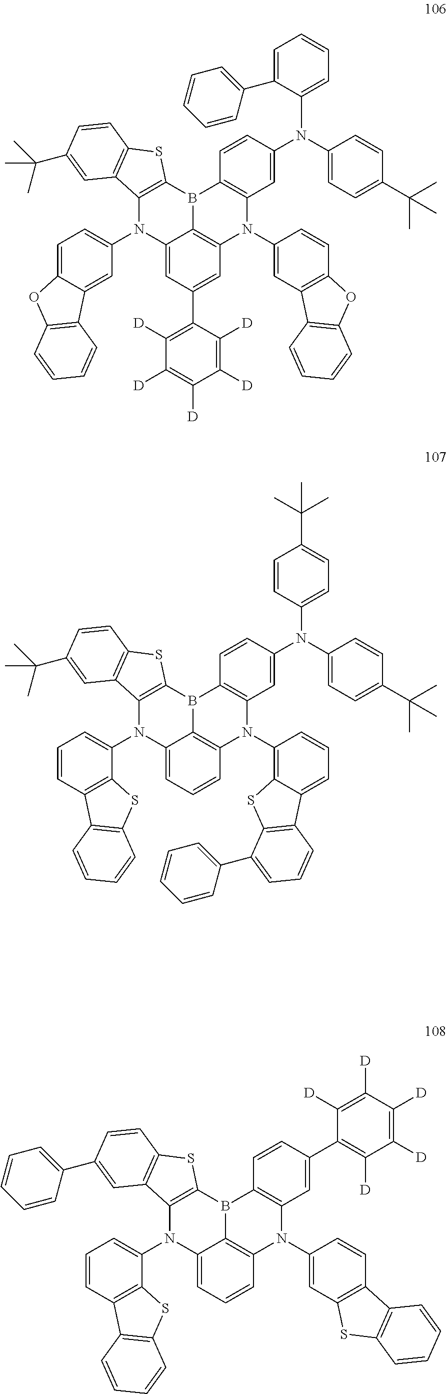

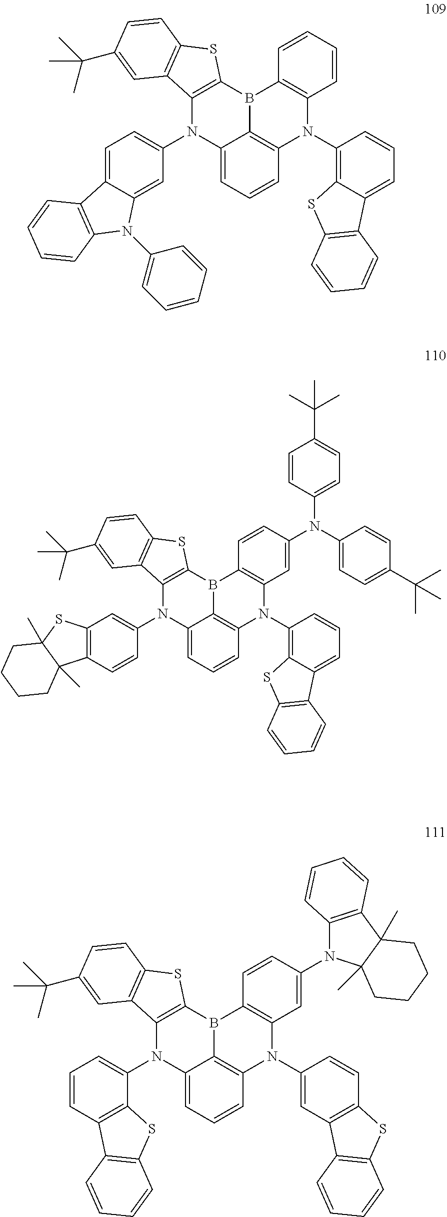

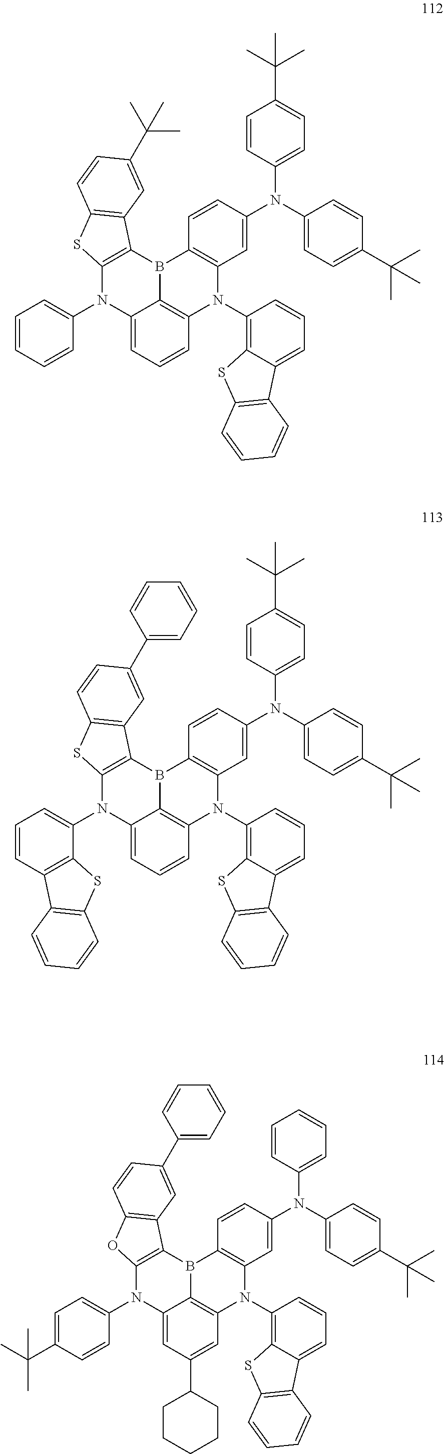

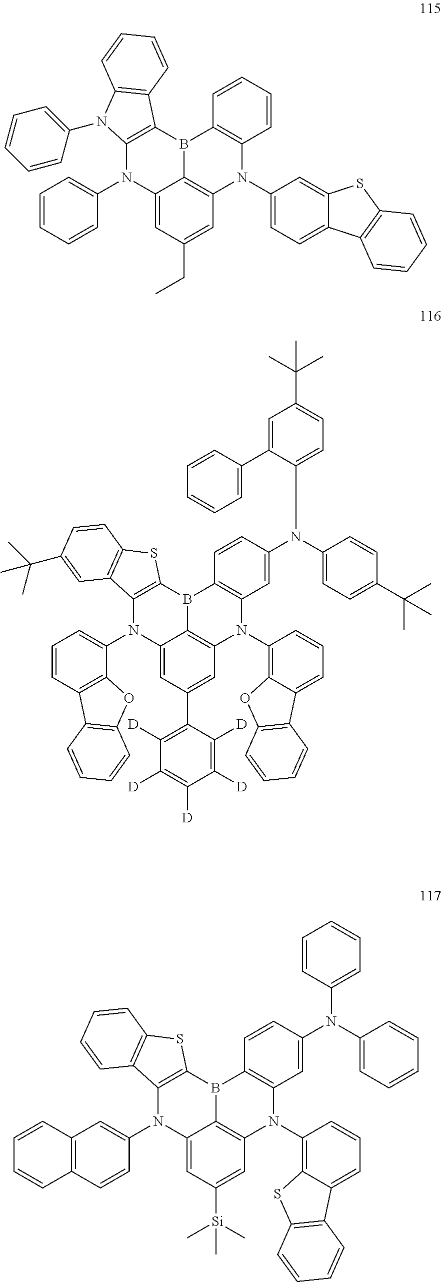 [SMILES: CCc1cc2c3c(c1)N(c1ccccc1)c1c(c4ccccc4n1-c1ccccc1)B3c1ccccc1N2c1ccc2c(c1)sc1ccccc12 ; [2H]c1c([2H])c([2H])c(-c2cc3c4c(c2)N(c2cccc5c2oc2ccccc25)c2c(sc5ccc(C(C)(C)C)cc25)B4c2ccc(N(c4ccc(C(C)(C)C)cc4)c4ccc(C(C)(C)C)cc4-c4ccccc4)cc2N3c2cccc3c2oc2ccccc23)c([2H])c1[2H] ; C[Si](C)(C)c1cc2c3c(c1)N(c1cccc4c1sc1ccccc14)c1cc(N(c4ccccc4)c4ccccc4)ccc1B3c1sc3ccccc3c1N2c1ccc2ccccc2c1]

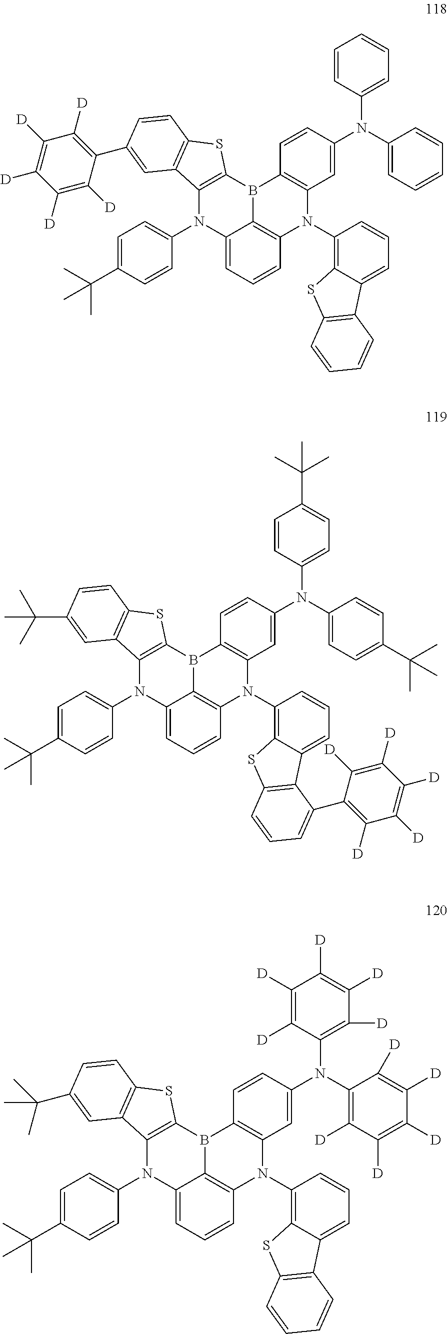

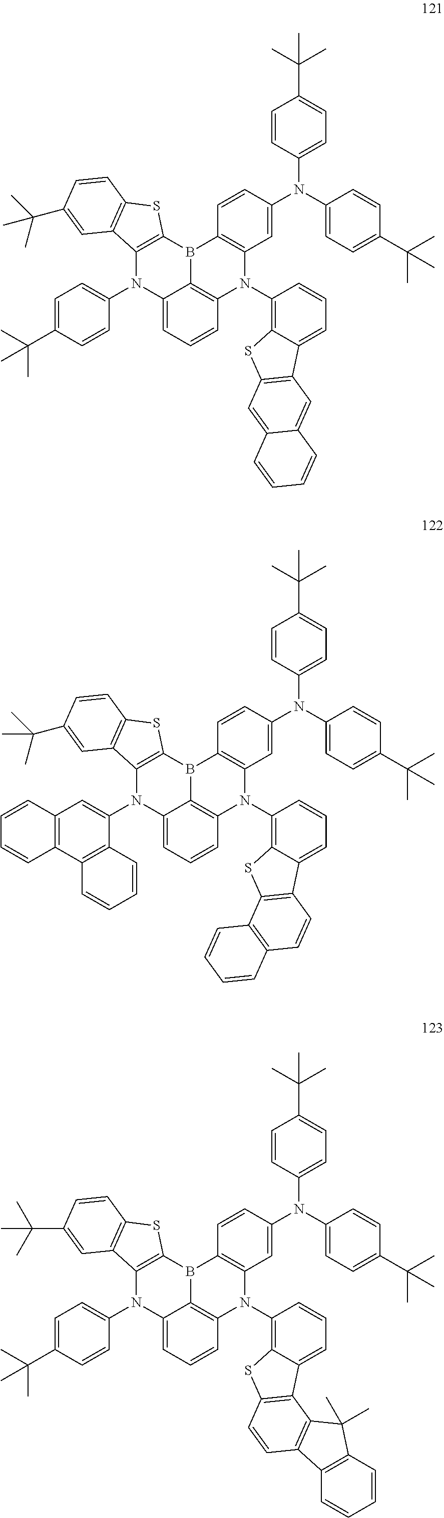

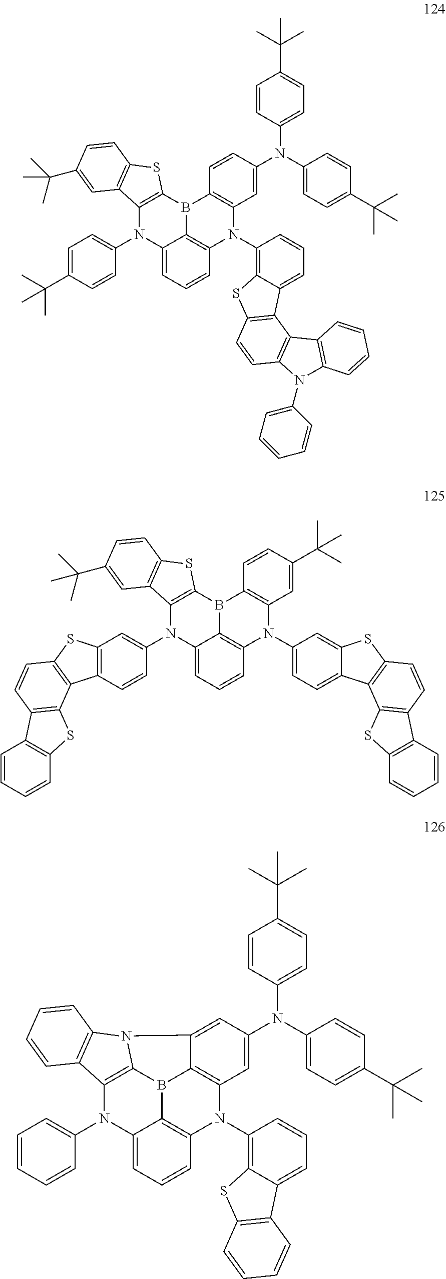 [SMILES: CC(C)(C)c1ccc(N(c2ccc(C(C)(C)C)cc2)c2ccc3c(c2)N(c2cccc4c2sc2ccc5c(c6ccccc6n5-c5ccccc5)c24)c2cccc4c2B3c2sc3ccc(C(C)(C)C)cc3c2N4c2ccc(C(C)(C)C)cc2)cc1 ; CC(C)(C)c1ccc2c(c1)N(c1ccc3c(c1)sc1ccc4c5ccccc5sc4c13)c1cccc3c1B2c1sc2ccc(C(C)(C)C)cc2c1N3c1ccc2c(c1)sc1ccc3c4ccccc4sc3c12 ; CC(C)(C)c1ccc(N(c2ccc(C(C)(C)C)cc2)c2cc3c4c(c2)-n2c5c(c6ccccc62)N(c2ccccc2)c2cccc(c2B45)N3c2cccc3c2sc2ccccc23)cc1]

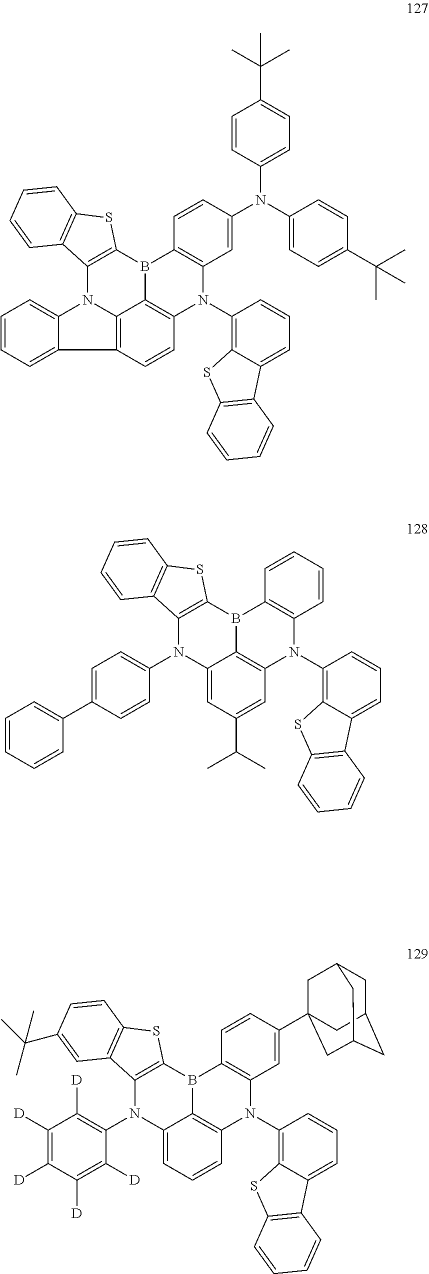

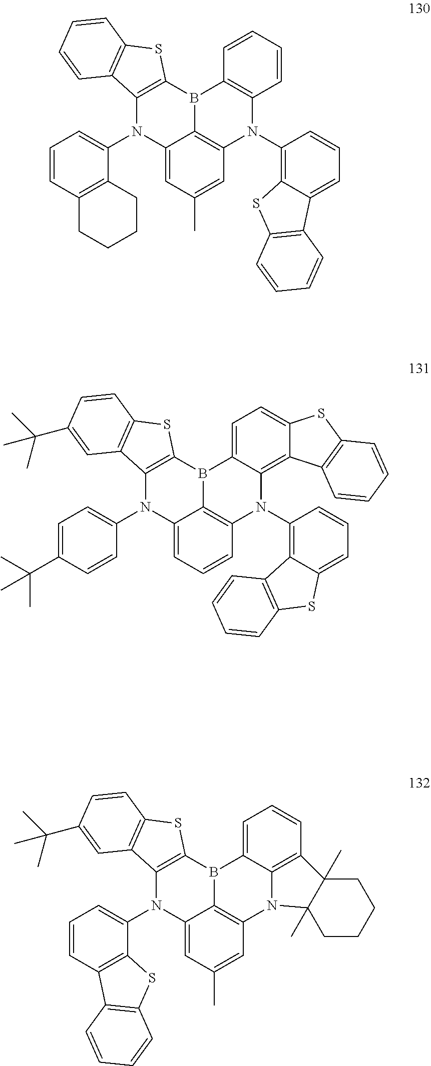 [SMILES: Cc1cc2c3c(c1)N(c1cccc4c1sc1ccccc14)c1ccccc1B3c1sc3ccccc3c1N2c1cccc2c1CCCC2 ; CC(C)(C)c1ccc(N2c3cccc4c3B(c3ccc5sc6ccccc6c5c3N4c3cccc4sc5ccccc5c34)c3sc4ccc(C(C)(C)C)cc4c32)cc1 ; Cc1cc2c3c(c1)N1c4c(cccc4C4(C)CCCCC14C)B3c1sc3ccc(C(C)(C)C)cc3c1N2c1cccc2c1sc1ccccc12]

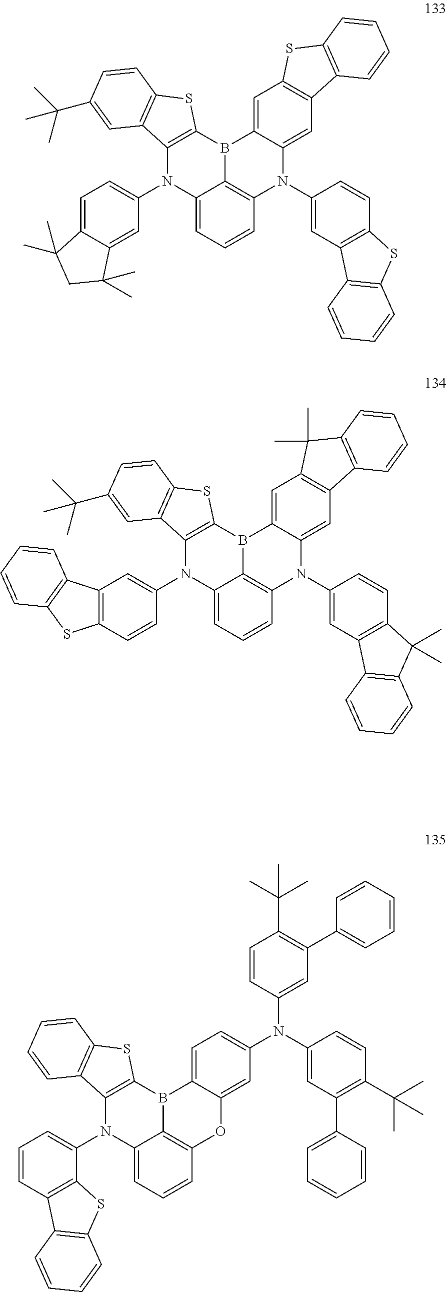 [SMILES: CC(C)(C)c1ccc2sc3c(c2c1)N(c1ccc2c(c1)C(C)(C)CC2(C)C)c1cccc2c1B3c1cc3sc4ccccc4c3cc1N2c1ccc2sc3ccccc3c2c1 ; CC(C)(C)c1ccc2sc3c(c2c1)N(c1ccc2sc4ccccc4c2c1)c1cccc2c1B3c1cc3c(cc1N2c1ccc2c(c1)-c1ccccc1C2(C)C)-c1ccccc1C3(C)C ; CC(C)(C)c1ccc(N(c2ccc3c(c2)Oc2cccc4c2B3c2sc3ccccc3c2N4c2cccc3c2sc2ccccc23)c2ccc(C(C)(C)C)c(-c3ccccc3)c2)cc1-c1ccccc1]

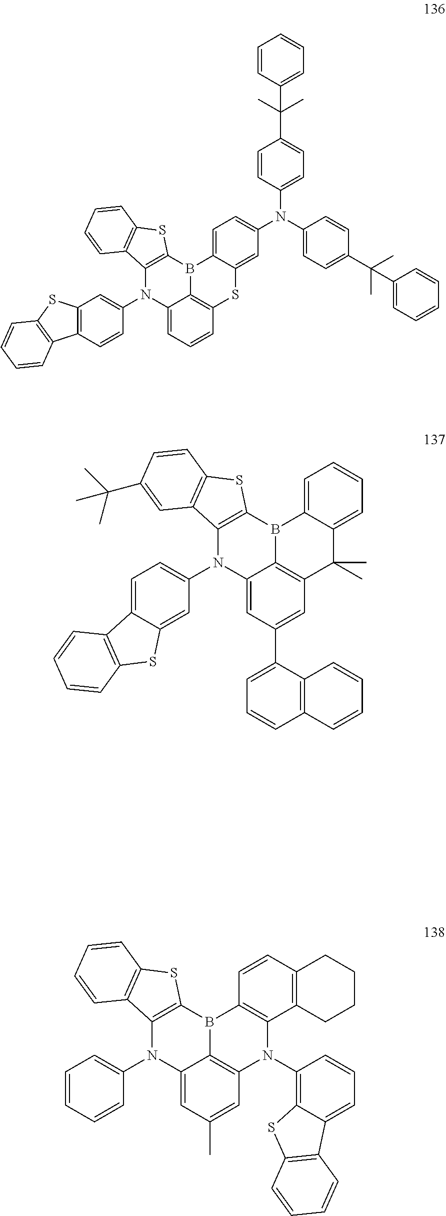 [SMILES: CC(C)(c1ccccc1)c1ccc(N(c2ccc(C(C)(C)c3ccccc3)cc2)c2ccc3c(c2)Sc2cccc4c2B3c2sc3ccccc3c2N4c2ccc3c(c2)sc2ccccc23)cc1 ; CC(C)(C)c1ccc2sc3c(c2c1)N(c1ccc2c(c1)sc1ccccc12)c1cc(-c2cccc4ccccc24)cc2c1B3c1ccccc1C2(C)C ; Cc1cc2c3c(c1)N(c1cccc4c1sc1ccccc14)c1c(ccc4c1CCCC4)B3c1sc3ccccc3c1N2c1ccccc1]

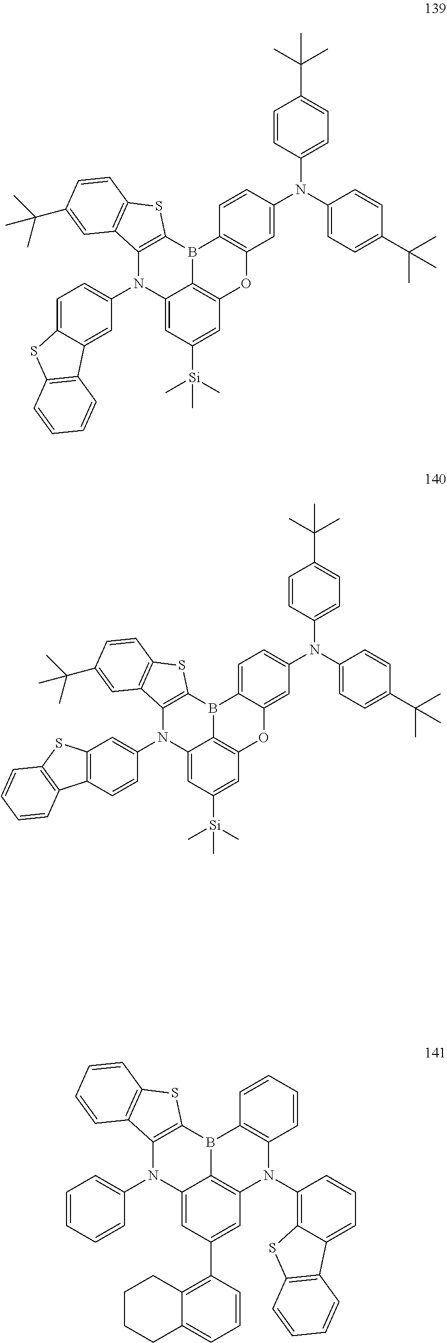 [SMILES: CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3sc4ccccc4c3c2)cc1 ; CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3c(c2)sc2ccccc23)cc1 ; c1ccc(N2c3cc(-c4cccc5c4CCCC5)cc4c3B(c3ccccc3N4c3cccc4c3sc3ccccc34)c3sc4ccccc4c32)cc1]

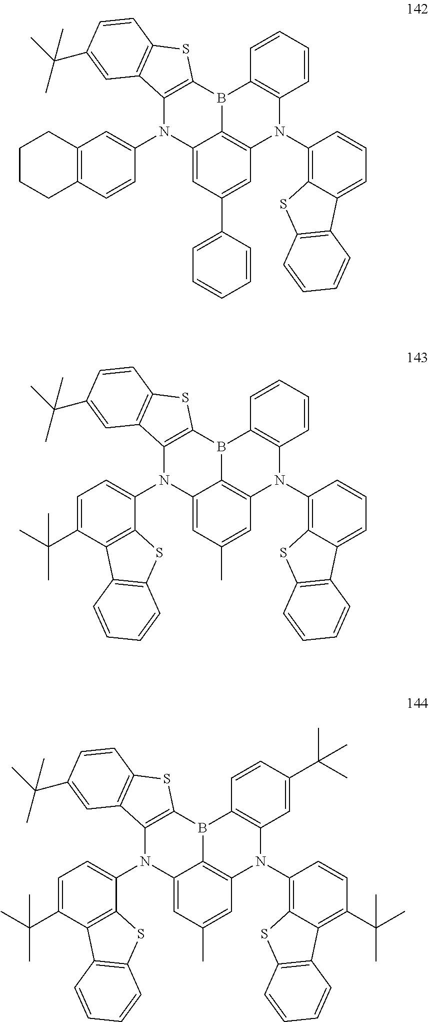 [SMILES: CC(C)(C)c1ccc2sc3c(c2c1)N(c1ccc2c(c1)CCCC2)c1cc(-c2ccccc2)cc2c1B3c1ccccc1N2c1cccc2c1sc1ccccc12 ; Cc1cc2c3c(c1)N(c1ccc(C(C)(C)C)c4c1sc1ccccc14)c1c(sc4ccc(C(C)(C)C)cc14)B3c1ccccc1N2c1cccc2c1sc1ccccc12 ; Cc1cc2c3c(c1)N(c1ccc(C(C)(C)C)c4c1sc1ccccc14)c1c(sc4ccc(C(C)(C)C)cc14)B3c1ccc(C(C)(C)C)cc1N2c1ccc(C(C)(C)C)c2c1sc1ccccc12]

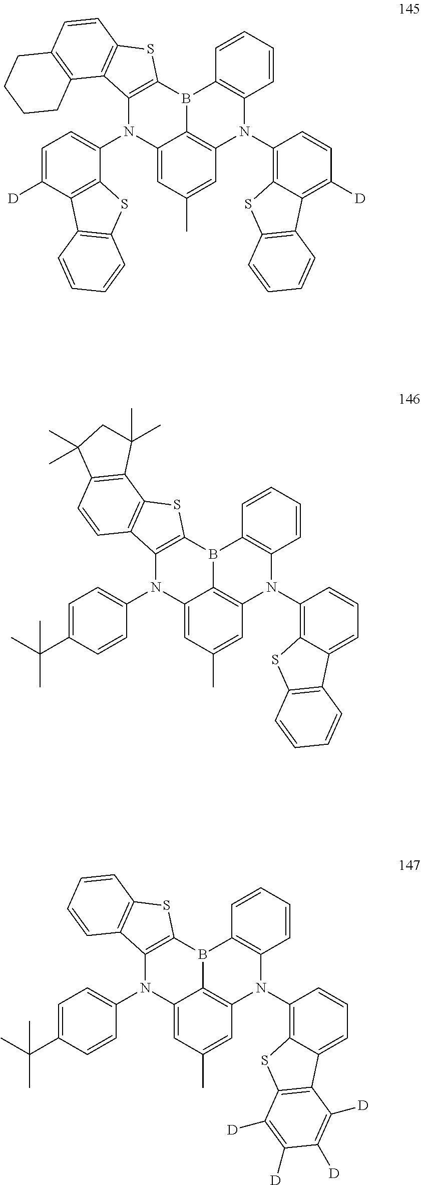 [SMILES: [2H]c1ccc(N2c3ccccc3B3c4sc5ccc6c(c5c4N(c4ccc([2H])c5c4sc4ccccc45)c4cc(C)cc2c43)CCCC6)c2sc3ccccc3c12 ; Cc1cc2c3c(c1)N(c1cccc4c1sc1ccccc14)c1ccccc1B3c1sc3c4c(ccc3c1N2c1ccc(C(C)(C)C)cc1)C(C)(C)CC4(C)C ; [2H]c1c([2H])c([2H])c2c(sc3c(N4c5ccccc5B5c6sc7ccccc7c6N(c6ccc(C(C)(C)C)cc6)c6cc(C)cc4c65)cccc32)c1[2H]]

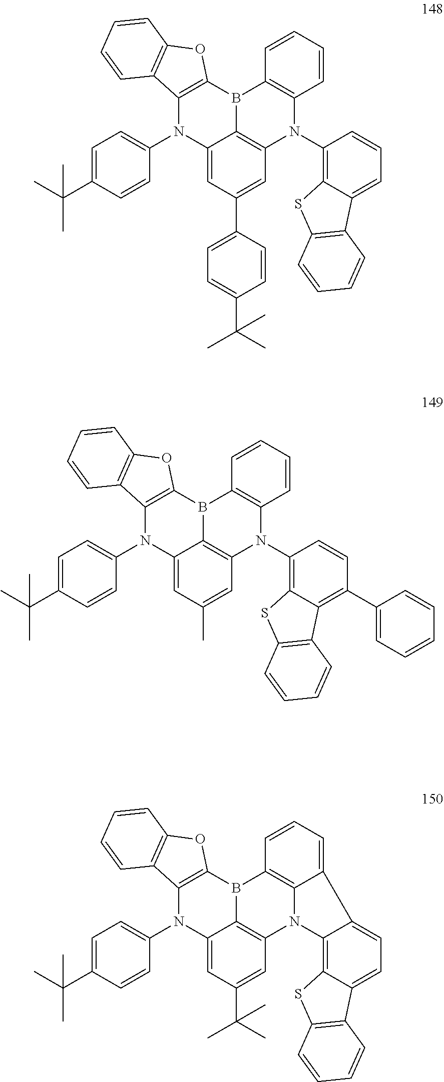 [SMILES: CC(C)(C)c1ccc(-c2cc3c4c(c2)N(c2cccc5c2sc2ccccc25)c2ccccc2B4c2oc4ccccc4c2N3c2ccc(C(C)(C)C)cc2)cc1 ; Cc1cc2c3c(c1)N(c1ccc(-c4ccccc4)c4c1sc1ccccc14)c1ccccc1B3c1oc3ccccc3c1N2c1ccc(C(C)(C)C)cc1 ; CC(C)(C)c1ccc(N2c3cc(C(C)(C)C)cc4c3B(c3oc5ccccc5c32)c2cccc3c5ccc6c7ccccc7sc6c5n-4c23)cc1]

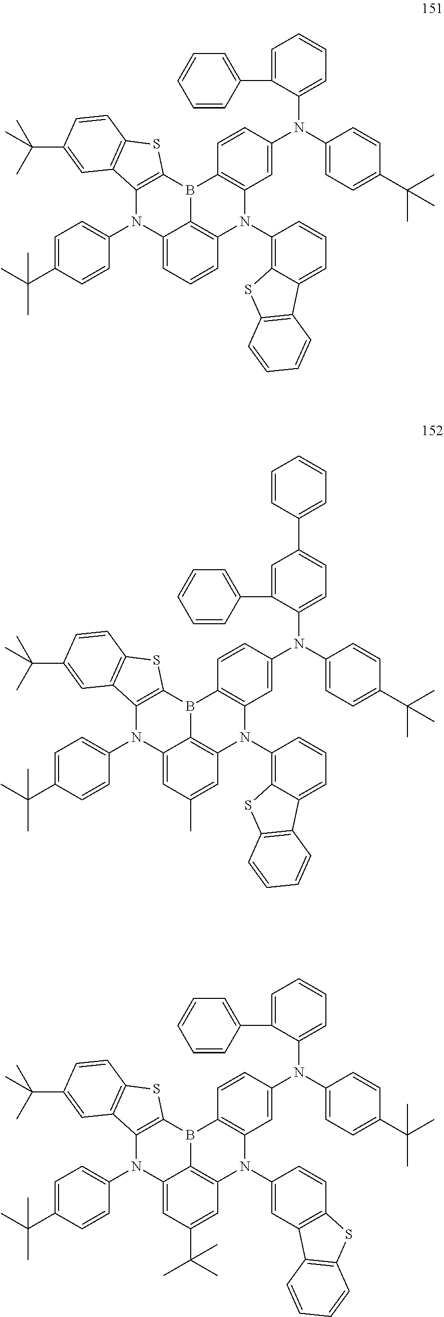

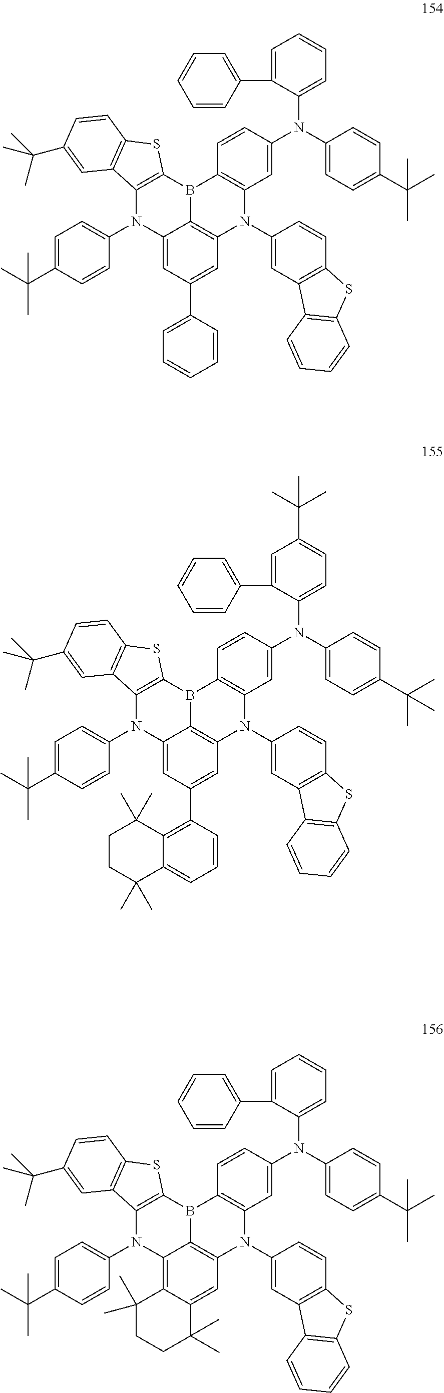

The specific substituents in Formula A-1 or A-2 can be clearly seen from the structures of the compounds 1 to 156. However, the compounds 1 to 156 are not intended to limit the scope of Formula A-1 or A-2.

Each of the above specific compounds contains boron (B) and has a polycyclic structure. The introduction of specific substituents, including the substituent represented by Structural Formula 1, into the polycyclic structure enables the synthesis of organic materials with inherent characteristics of the substituents. For example, the substituents are designed for use in materials for hole injecting layers, hole transport layers, light emitting layers, electron transport layers, electron injecting layers, electron blocking layers, and hole blocking layers, preferably light emitting layers, of organic electroluminescent devices. This introduction meets the requirements of materials for the organic layers, making the organic electroluminescent devices highly efficient.

A further aspect of the present invention is directed to an organic electroluminescent device including a first electrode, a second electrode, and one or more organic layers interposed between the first and second electrodes wherein one of the organic layers includes at least one of the organic electroluminescent compounds that can be represented by Formula A-1 or A-2.

That is, according to one embodiment of the present invention, the organic electroluminescent device has a structure in which one or more organic layers are arranged between a first electrode and a second electrode. The organic electroluminescent device of the present invention may be fabricated by a suitable method known in the art using suitable materials known in the art, except that the organic electroluminescent compound of Formula A-1 or A-2 is used to form the corresponding organic layer.

The organic layers of the organic electroluminescent device according to the present invention may form a monolayer structure. Alternatively, the organic layers may be stacked together to form a multilayer structure. For example, the organic layers may have a structure including a hole injecting layer, a hole transport layer, a hole blocking layer, a light emitting layer, an electron blocking layer, an electron transport layer, and an electron injecting layer but are not limited to this structure. The number of the organic layers is not limited and may be increased or decreased. Preferred structures of the organic layers of the organic electroluminescent device according to the present invention will be explained in more detail in the Examples section that follows.

The organic electroluminescent device of the present invention includes an anode, a hole transport layer, a light emitting layer, an electron transport layer, and a cathode. The organic electroluminescent device of the present invention may optionally further include a hole injecting layer between the anode and the hole transport layer and an electron injecting layer between the electron transport layer and the cathode. If necessary, the organic electroluminescent device of the present invention may further include one or two intermediate layers such as a hole blocking layer or an electron blocking layer.

According to one embodiment of the present invention, one of the organic layers interposed between the first and second electrodes may be a light emitting layer composed of a host and the compound represented by Formula A-1 or A-2 as a dopant.

The content of the dopant in the light emitting layer is typically in the range of about 0.01 to about 20 parts by weight, based on about 100 parts by weight of the host but is not limited to this range.

According to one embodiment of the present invention, the host may be an anthracene derivative represented by Formula B:

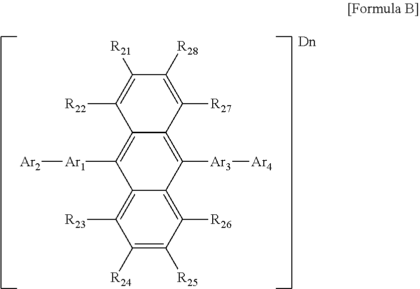

wherein R₂₁ to R₂₈ are the same as or different from each other and are each independently selected from hydrogen, substituted or unsubstituted C₁-C₃₀ alkyl, substituted or unsubstituted C₂-C₃₀ alkenyl, substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted C₂-C₅₀ fused polycyclic non-aromatic heterocyclic rings, nitro, cyano, and halogen, Ar₁ and Ar₃ are the same as or different from each other and are each independently substituted or unsubstituted C₆-C₃₀ arylene or substituted or unsubstituted C₅-C₃₀ heteroarylene, Are and Ar₄ are the same as or different from each other and are each independently selected from hydrogen, substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and substituted or unsubstituted C₂-C₅₀ fused polycyclic non-aromatic heterocyclic rings, Dₙ represents the number of deuterium atoms replacing hydrogen atoms in Ar₁ to Ar₄, and n is an integer from 0 to 30.

The anthracene host derivative represented by Formula B may be selected from the following compounds:

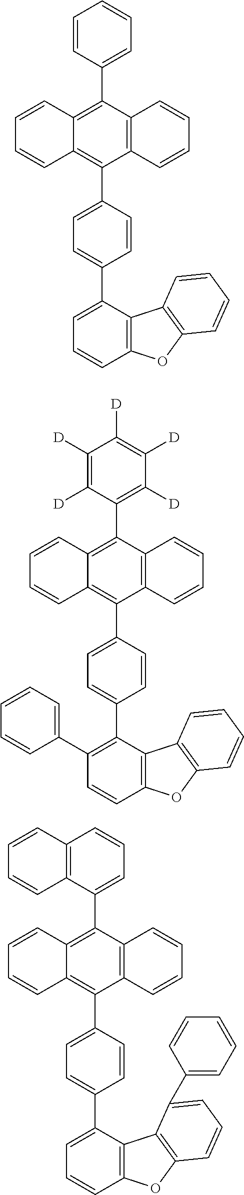

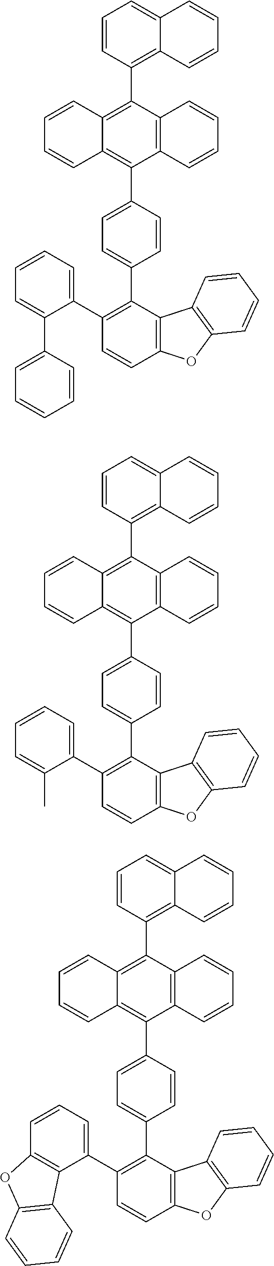

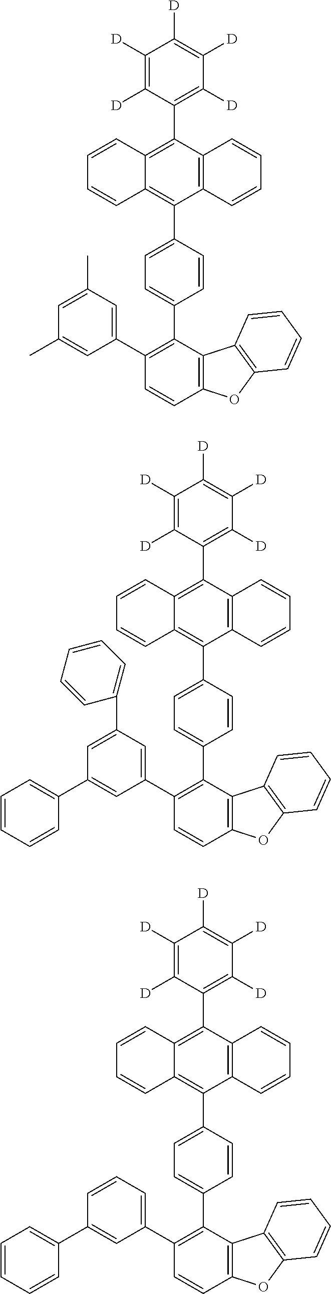 [SMILES: [2H]c1c([2H])c([2H])c(-c2c3ccccc3c(-c3ccc(-c4c(-c5cc(C)cc(C)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cc(-c6ccccc6)cc(-c6ccccc6)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cccc(-c6ccccc6)c5)ccc5oc6ccccc6c45)cc3)c3ccccc23)c([2H])c1[2H]]

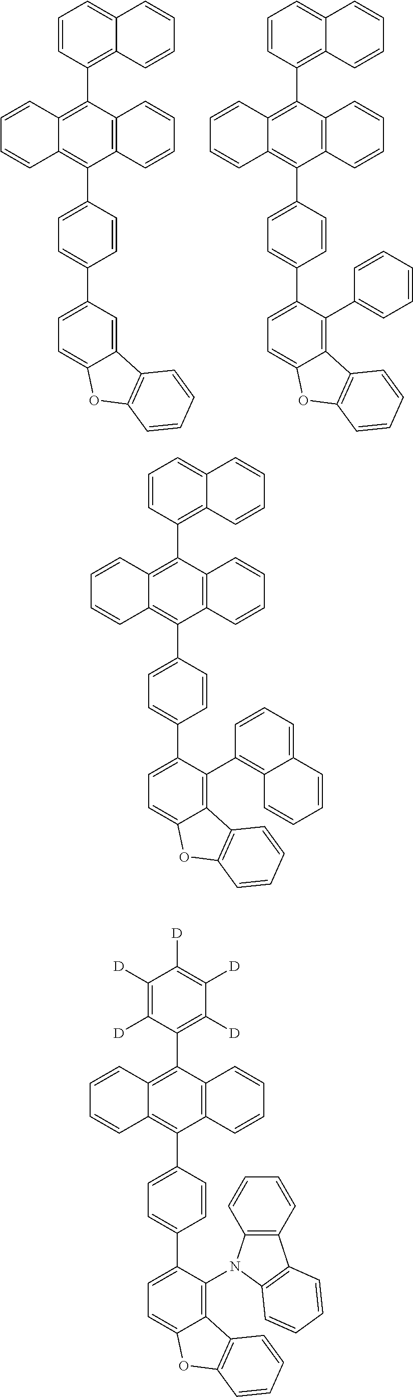

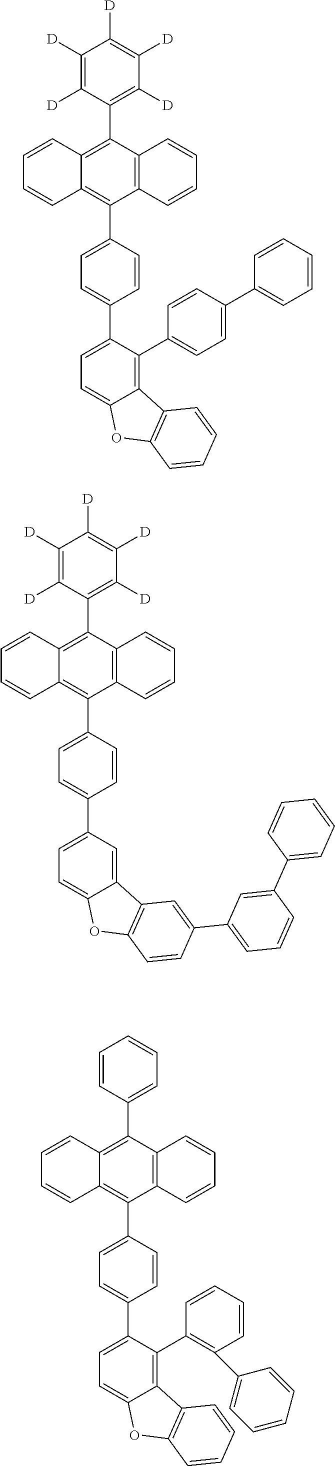 [SMILES: [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H] ; c1ccc(-c2ccccc2-c2c(-c3ccc(-c4c5ccccc5c(-c5ccccc5)c5ccccc45)cc3)ccc3oc4ccccc4c23)cc1]

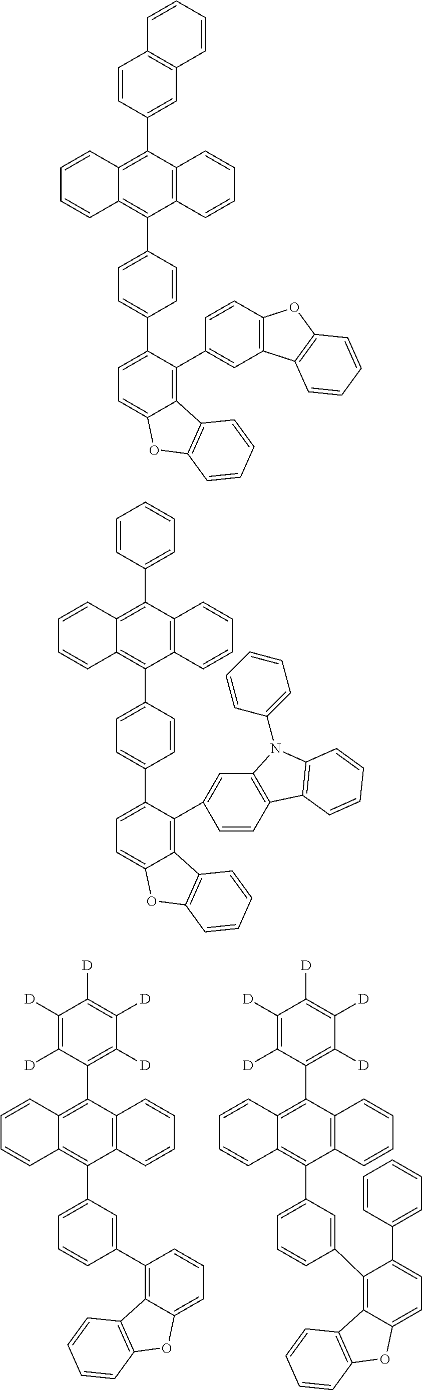

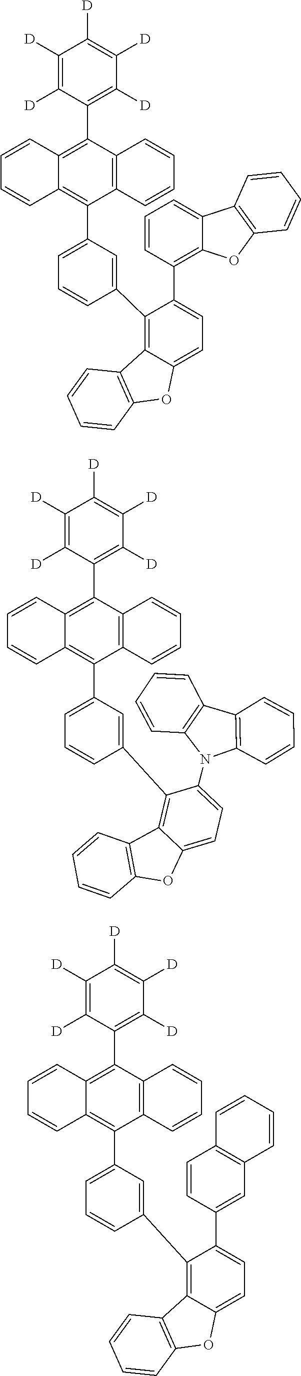

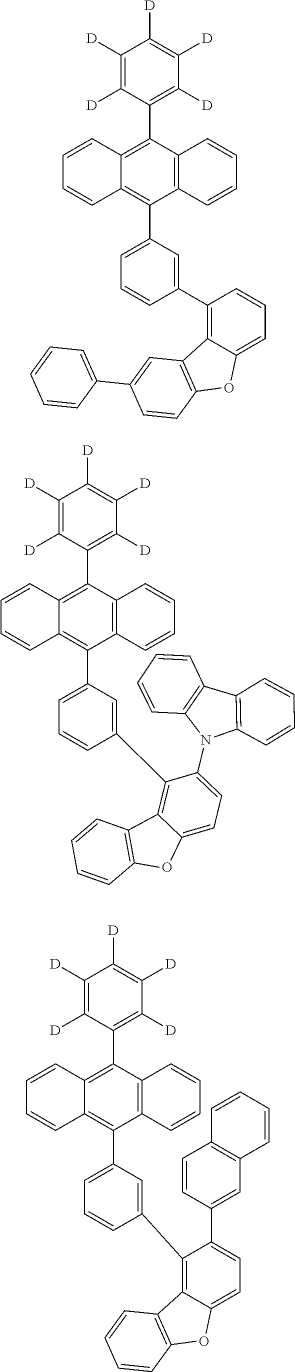

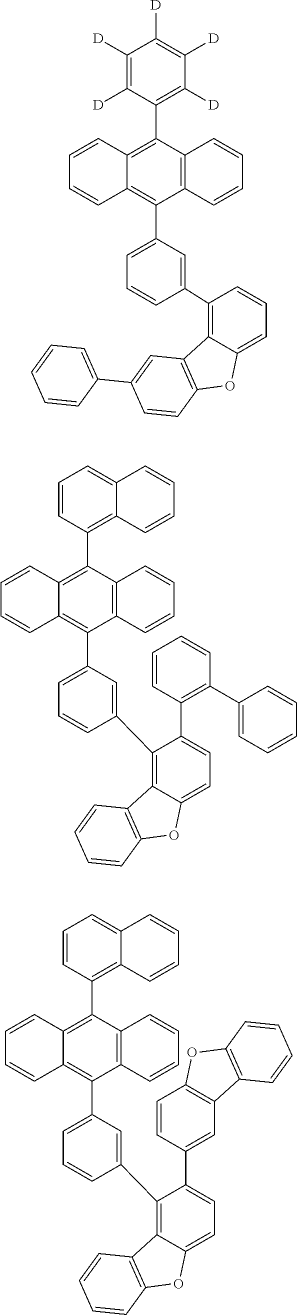 [SMILES: [2H]c1c([2H])c([2H])c(-c2c3ccccc3c(-c3cccc(-c4cccc5oc6ccc(-c7ccccc7)cc6c45)c3)c3ccccc23)c([2H])c1[2H] ; c1ccc(-c2ccccc2-c2ccc3oc4ccccc4c3c2-c2cccc(-c3c4ccccc4c(-c4cccc5ccccc45)c4ccccc34)c2)cc1 ; c1cc(-c2c3ccccc3c(-c3cccc4ccccc34)c3ccccc23)cc(-c2c(-c3ccc4oc5ccccc5c4c3)ccc3oc4ccccc4c23)c1]

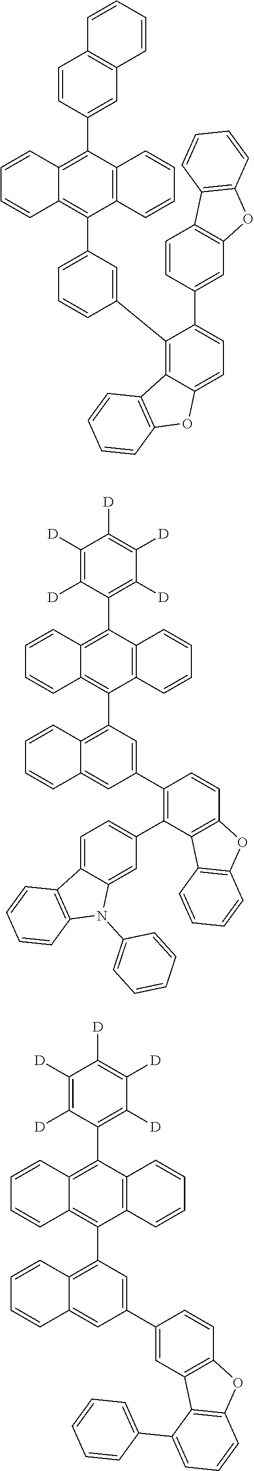 [SMILES: c1cc(-c2c3ccccc3c(-c3ccc4ccccc4c3)c3ccccc23)cc(-c2c(-c3ccc4c(c3)oc3ccccc34)ccc3oc4ccccc4c23)c1 ; [2H]c1c([2H])c([2H])c(-c2c3ccccc3c(-c3cc(-c4ccc5oc6ccccc6c5c4-c4ccc5c6ccccc6n(-c6ccccc6)c5c4)cc4ccccc34)c3ccccc23)c([2H])c1[2H] ; [2H]c1c([2H])c([2H])c(-c2c3ccccc3c(-c3cc(-c4ccc5oc6cccc(-c7ccccc7)c6c5c4)cc4ccccc34)c3ccccc23)c([2H])c1[2H]]

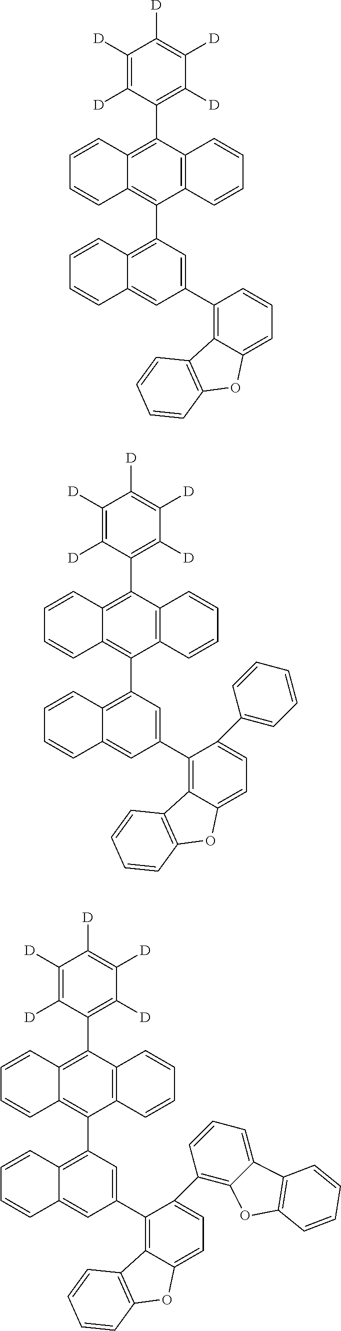 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; [2H]c1c([2H])c([2H])c(-c2c3ccccc3c(-c3cc(-c4c(-c5ccccc5)ccc5oc6ccccc6c45)cc4ccccc34)c3ccccc23)c([2H])c1[2H] ; [2H]c1c([2H])c([2H])c(-c2c3ccccc3c(-c3cc(-c4c(-c5cccc6c5oc5ccccc56)ccc5oc6ccccc6c45)cc4ccccc34)c3ccccc23)c([2H])c1[2H]]

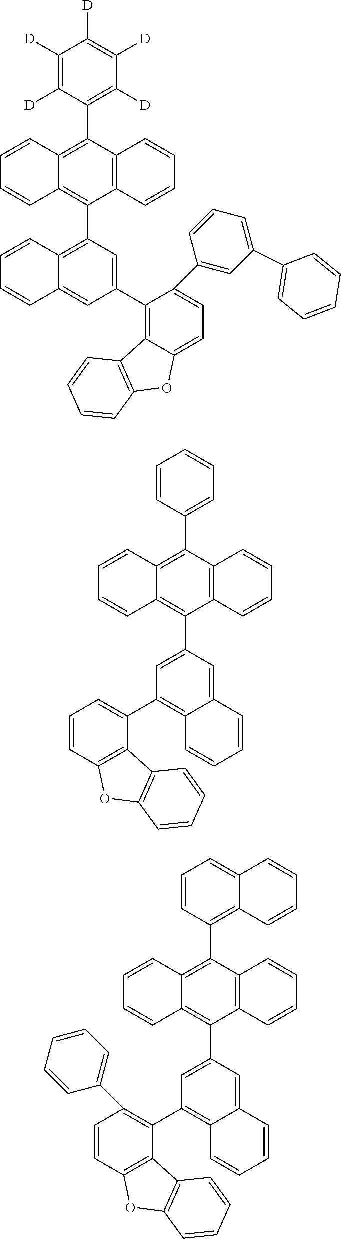

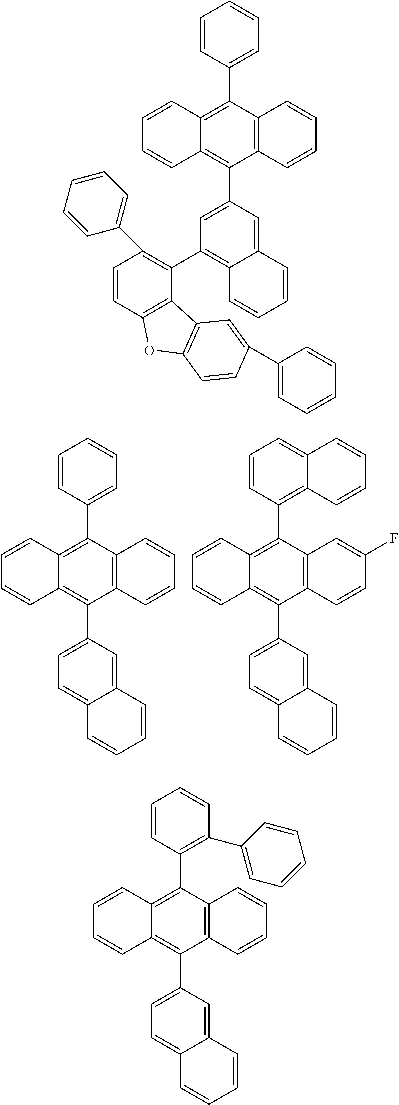

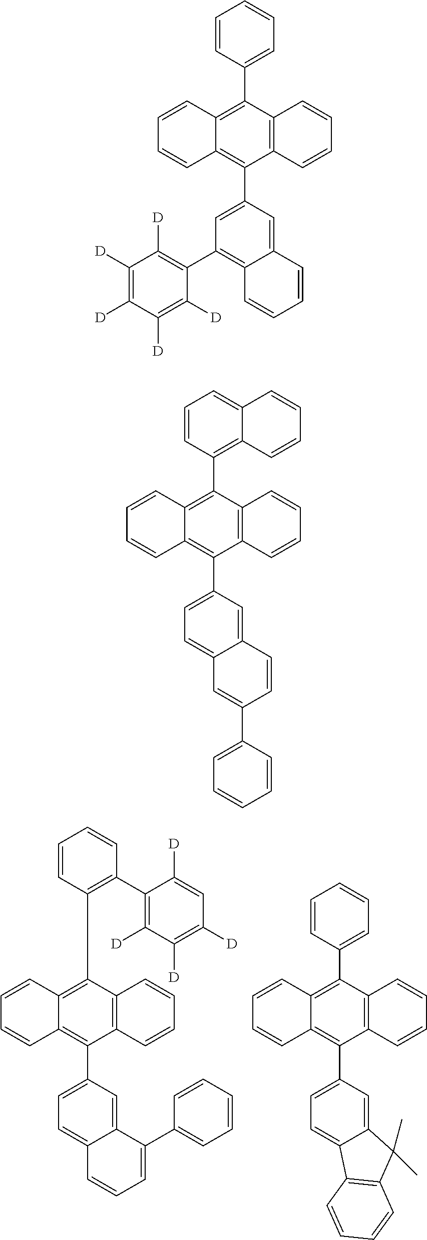

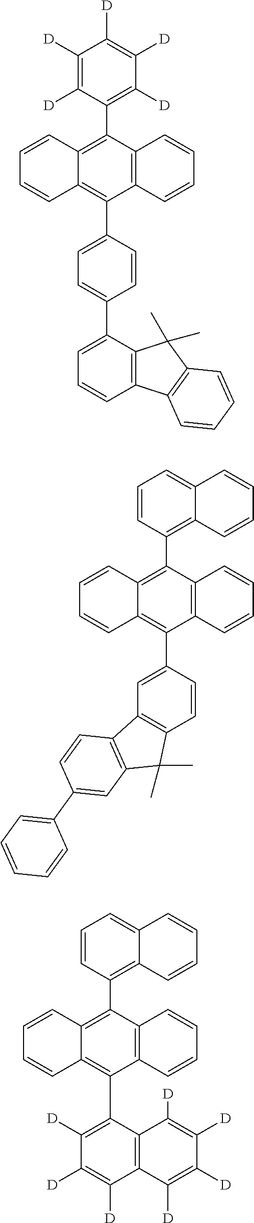

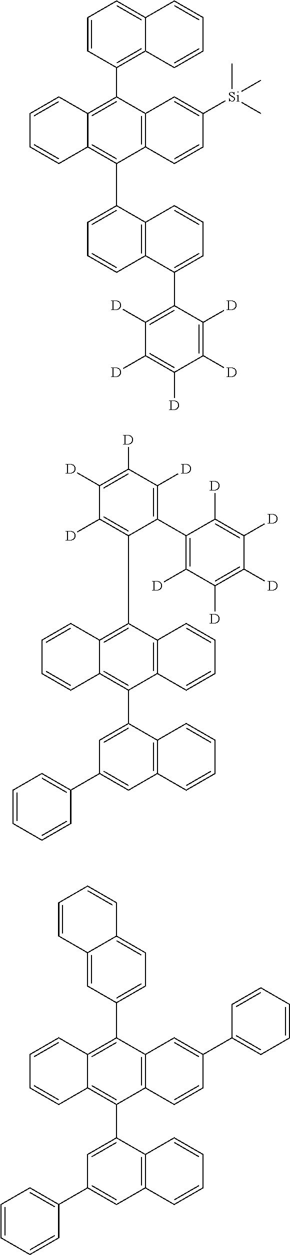

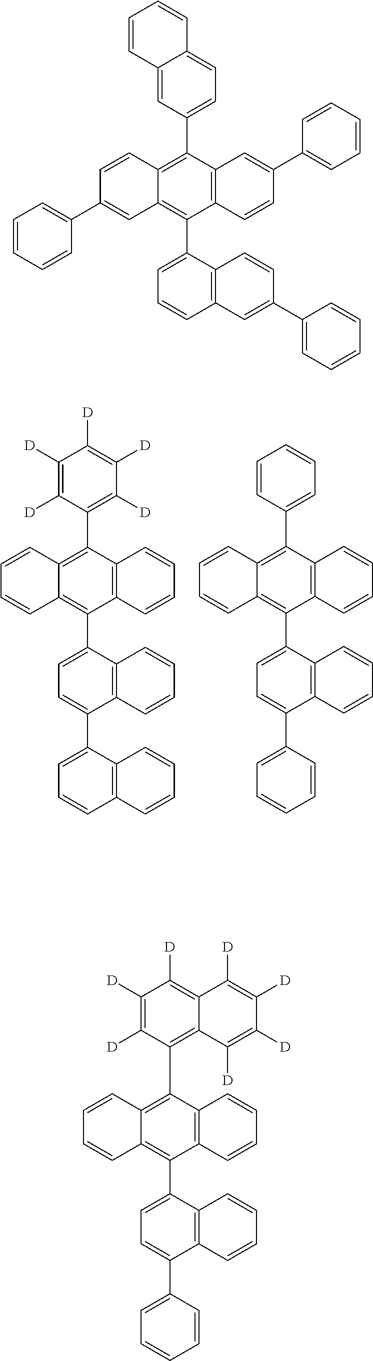

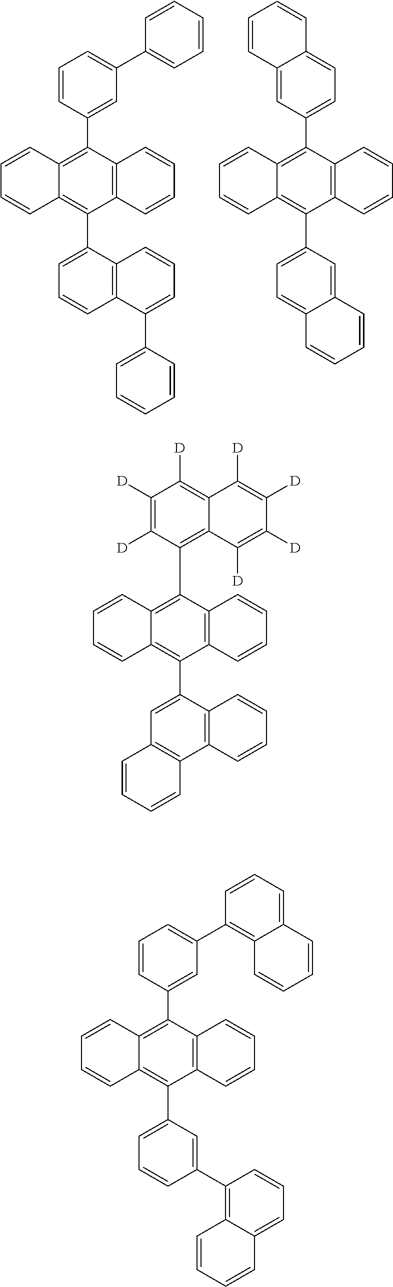

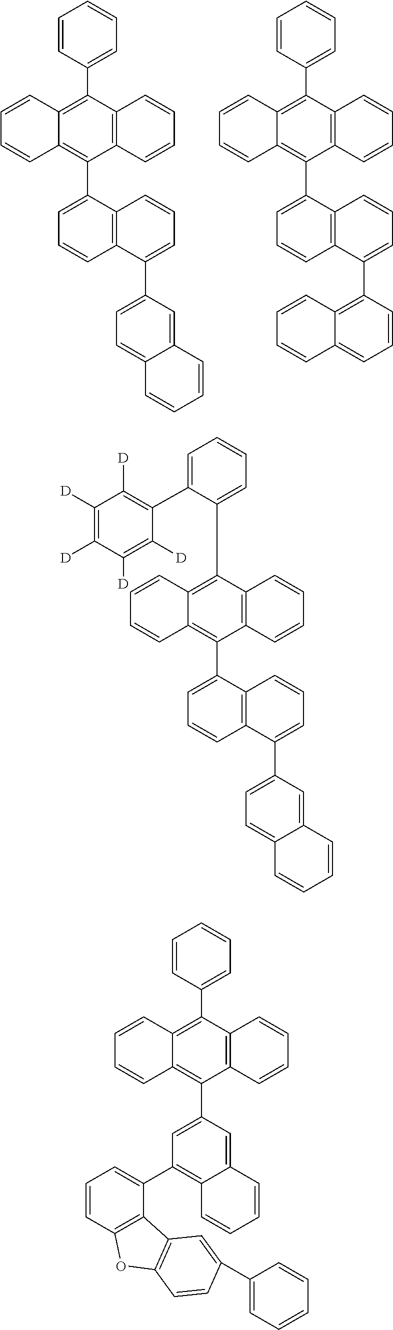

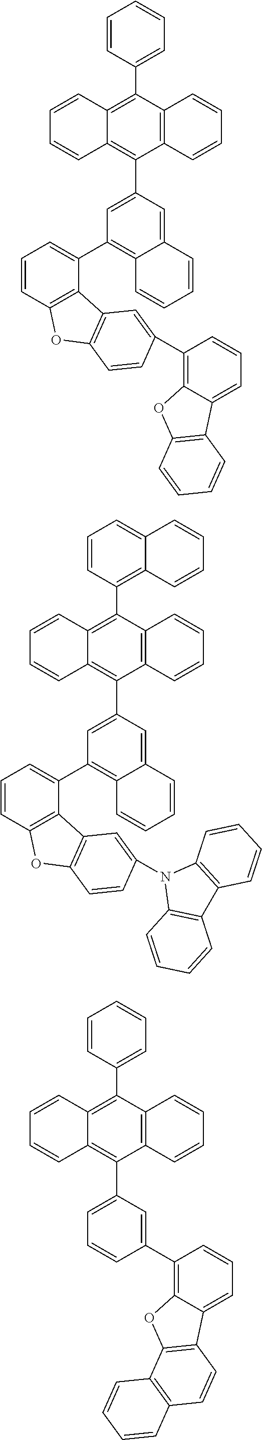

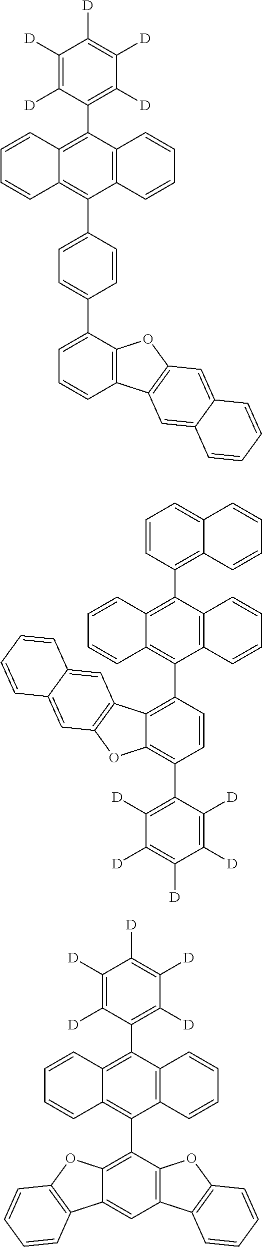

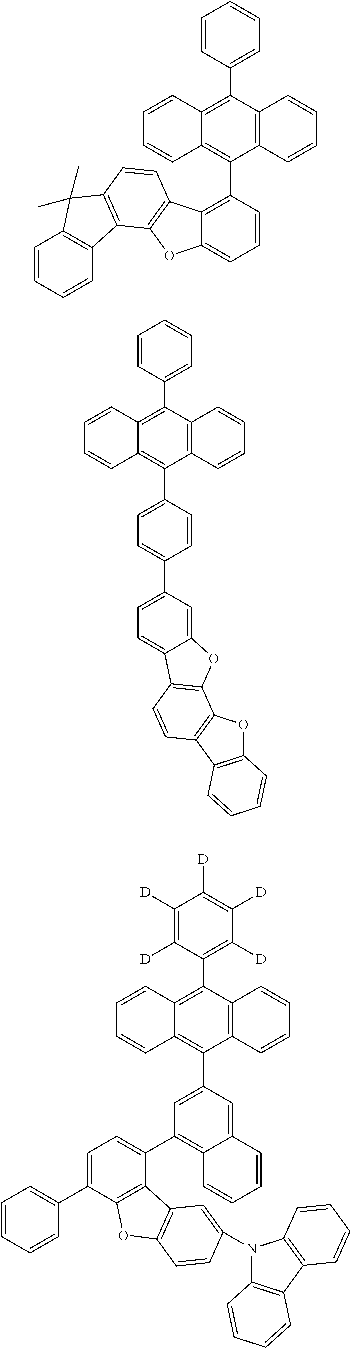 [SMILES: CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5c(c4)oc4c5ccc5c6ccccc6oc54)cc3)c3ccccc23)cc1 ; [2H]c1c([2H])c([2H])c(-c2c3ccccc3c(-c3cc(-c4ccc(-c5ccccc5)c5oc6ccc(-n7c8ccccc8c8ccccc87)cc6c45)c4ccccc4c3)c3ccccc23)c([2H])c1[2H]]

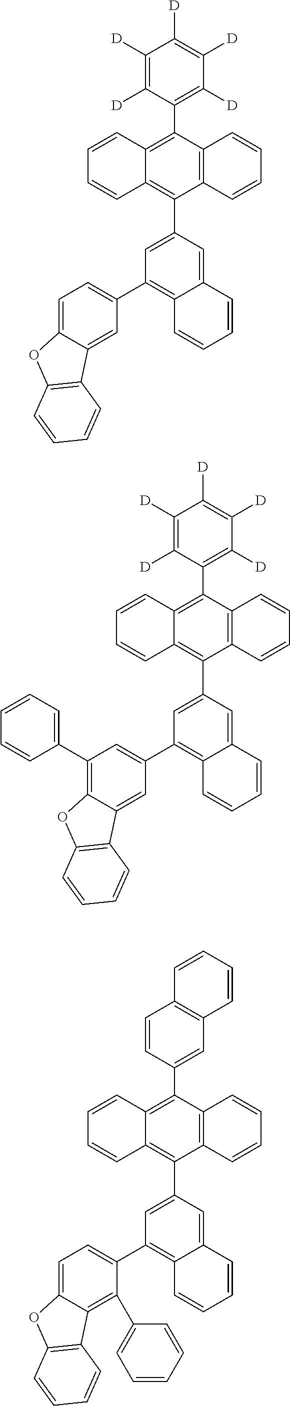 [SMILES: [2H]c1c([2H])c([2H])c(-c2c3ccccc3c(-c3cc(-c4ccc5oc6ccccc6c5c4)c4ccccc4c3)c3ccccc23)c([2H])c1[2H] ; [2H]c1c([2H])c([2H])c(-c2c3ccccc3c(-c3cc(-c4cc(-c5ccccc5)c5oc6ccccc6c5c4)c4ccccc4c3)c3ccccc23)c([2H])c1[2H] ; c1ccc(-c2c(-c3cc(-c4c5ccccc5c(-c5ccc6ccccc6c5)c5ccccc45)cc4ccccc34)ccc3oc4ccccc4c23)cc1]

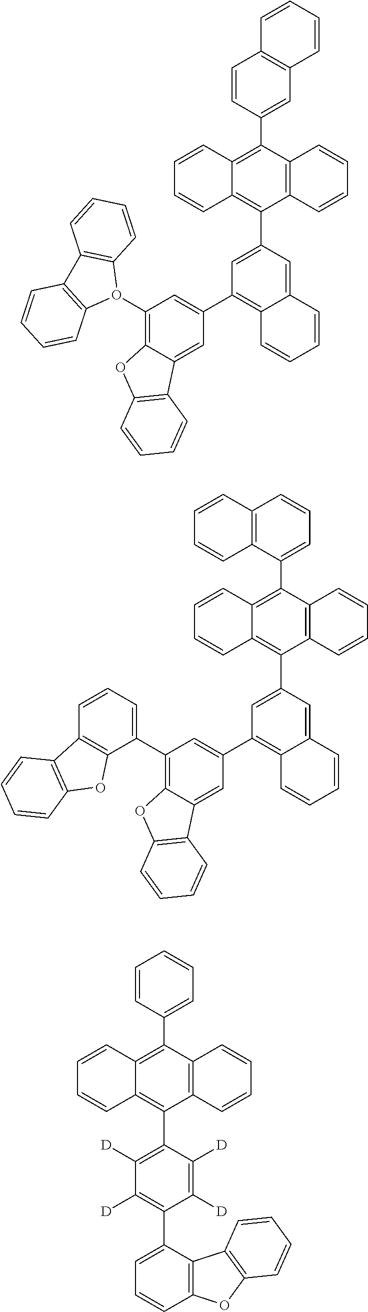

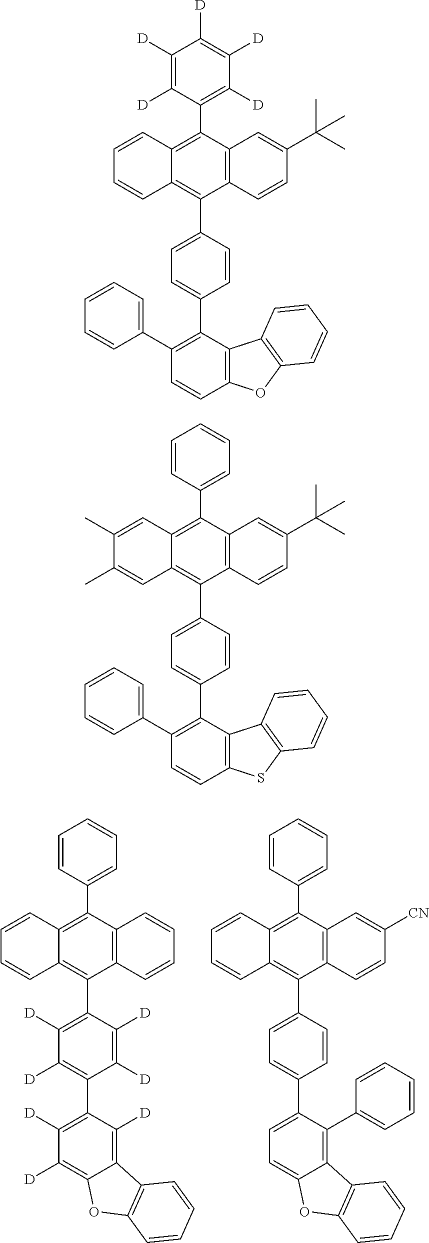

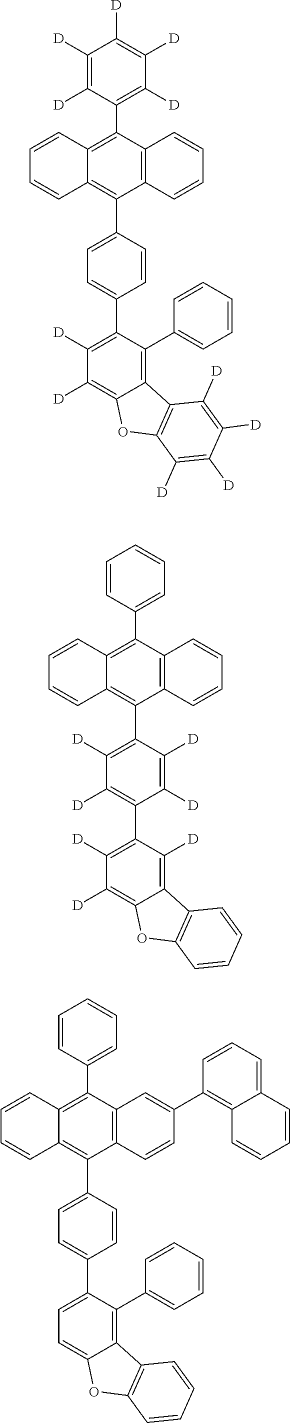 [SMILES: [2H]c1c([2H])c([2H])c(-c2c3ccccc3c(-c3ccc(-c4c([2H])c([2H])c5oc6c([2H])c([2H])c([2H])c([2H])c6c5c4-c4ccccc4)cc3)c3ccccc23)c([2H])c1[2H] ; [2H]c1c([2H])c(-c2c3ccccc3c(-c3ccccc3)c3ccccc23)c([2H])c([2H])c1-c1c([2H])c([2H])c2oc3ccccc3c2c1[2H] ; c1ccc(-c2c3ccccc3c(-c3ccc(-c4ccc5oc6ccccc6c5c4-c4ccccc4)cc3)c3ccc(-c4cccc5ccccc45)cc23)cc1]

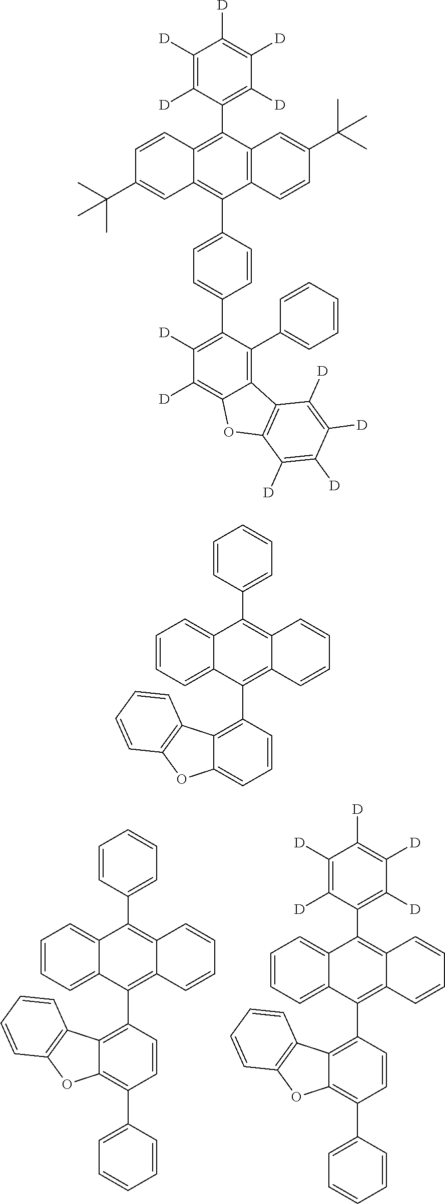

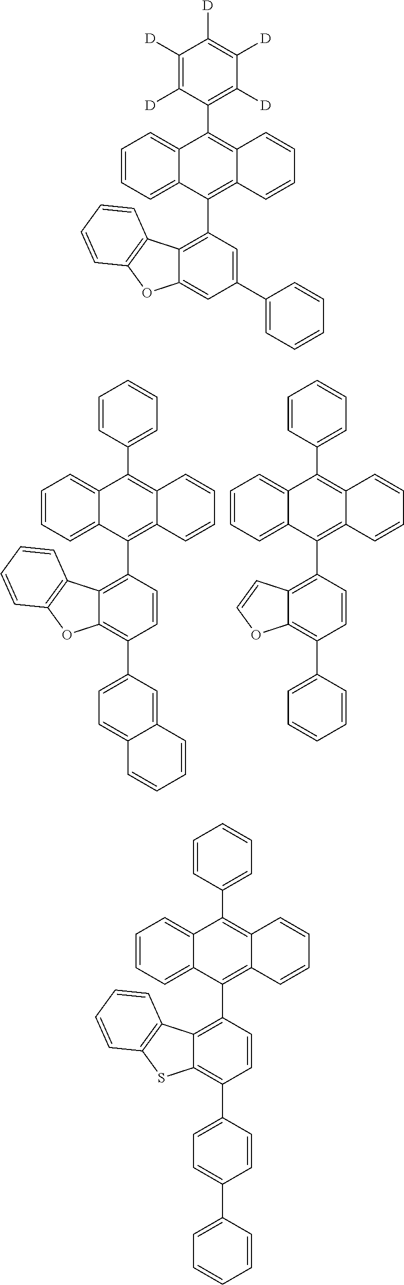

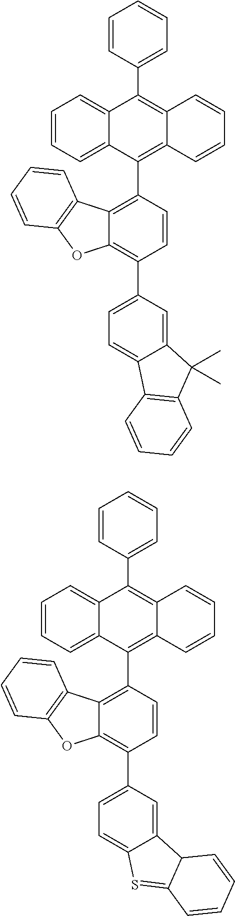

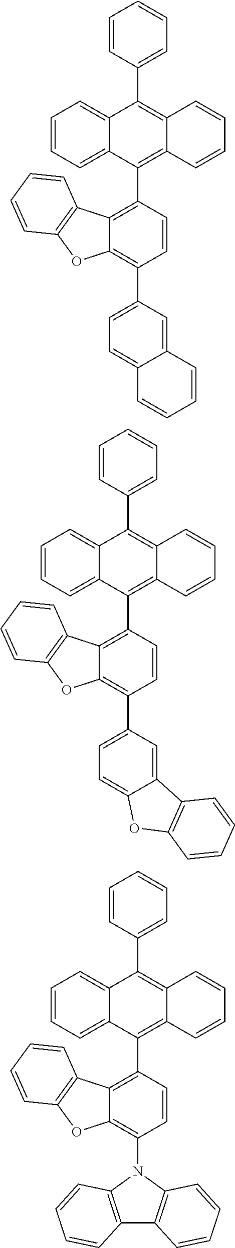

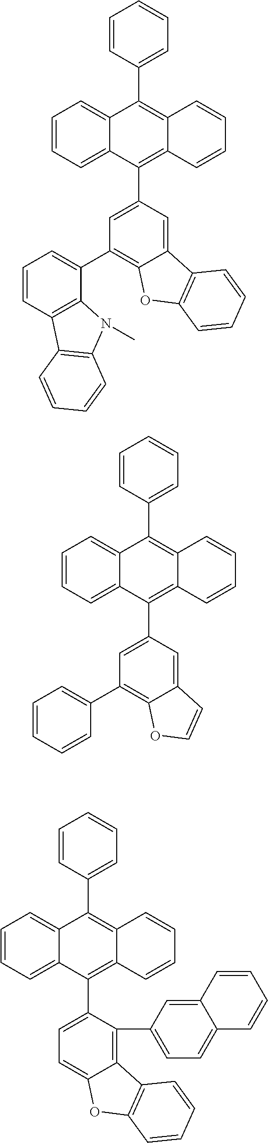 [SMILES: Cn1c2ccccc2c2cccc(-c3cc(-c4c5ccccc5c(-c5ccccc5)c5ccccc45)cc4c3oc3ccccc34)c21 ; c1ccc(-c2c3ccccc3c(-c3cc(-c4ccccc4)c4occc4c3)c3ccccc23)cc1 ; c1ccc(-c2c3ccccc3c(-c3ccc4oc5ccccc5c4c3-c3ccc4ccccc4c3)c3ccccc23)cc1]

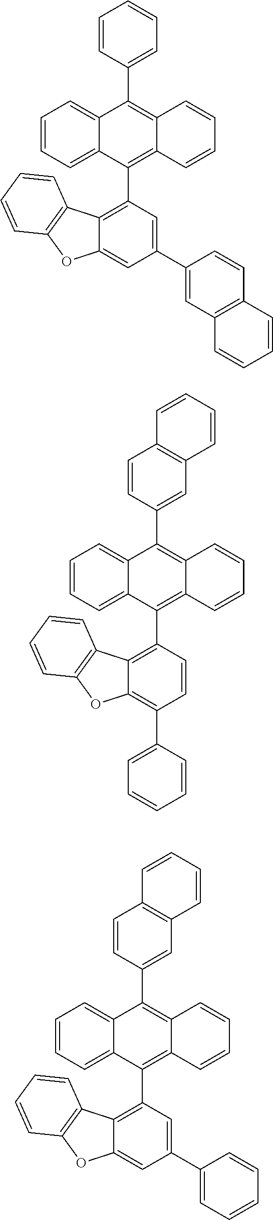

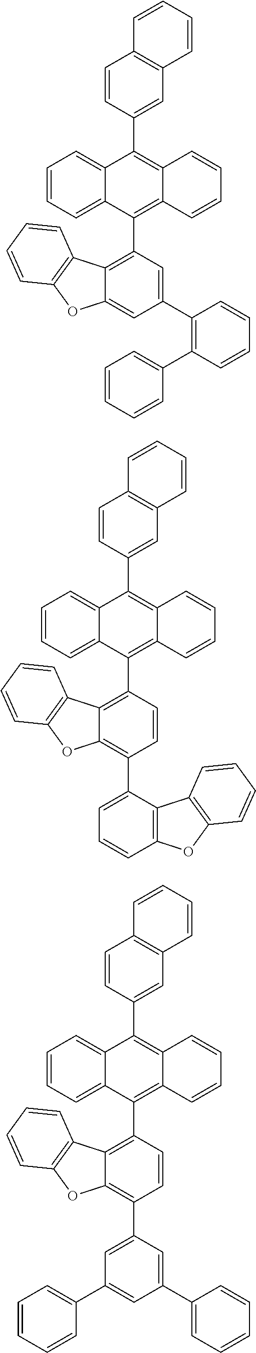

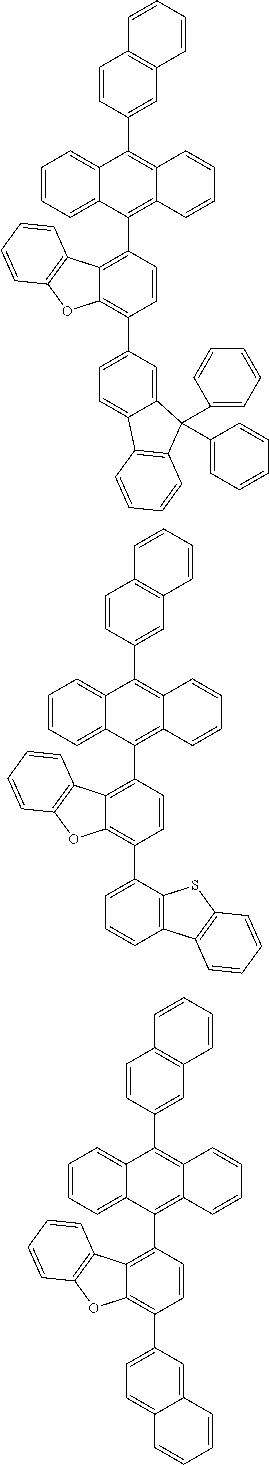

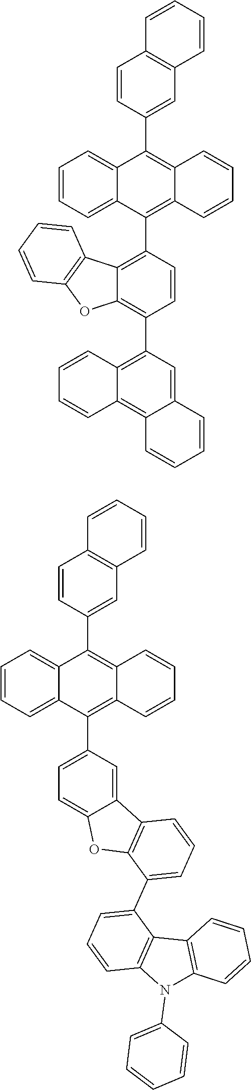 [SMILES: c1ccc2cc(-c3c4ccccc4c(-c4ccc(-c5cc6ccccc6c6ccccc56)c5oc6ccccc6c45)c4ccccc34)ccc2c1 ; c1ccc(-n2c3ccccc3c3c(-c4cccc5c4oc4ccc(-c6c7ccccc7c(-c7ccc8ccccc8c7)c7ccccc67)cc45)cccc32)cc1]

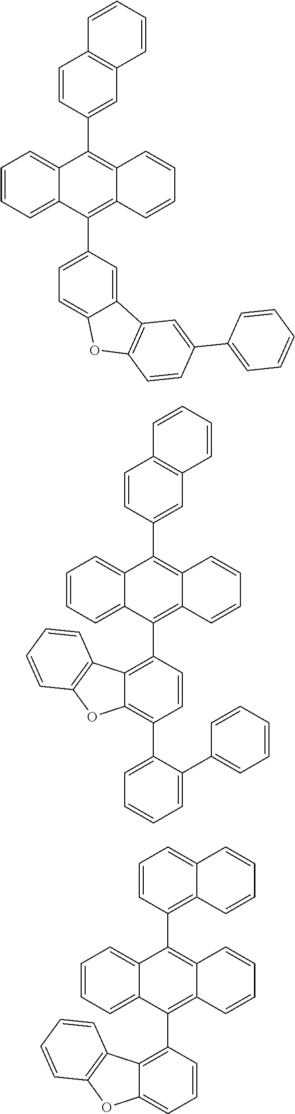

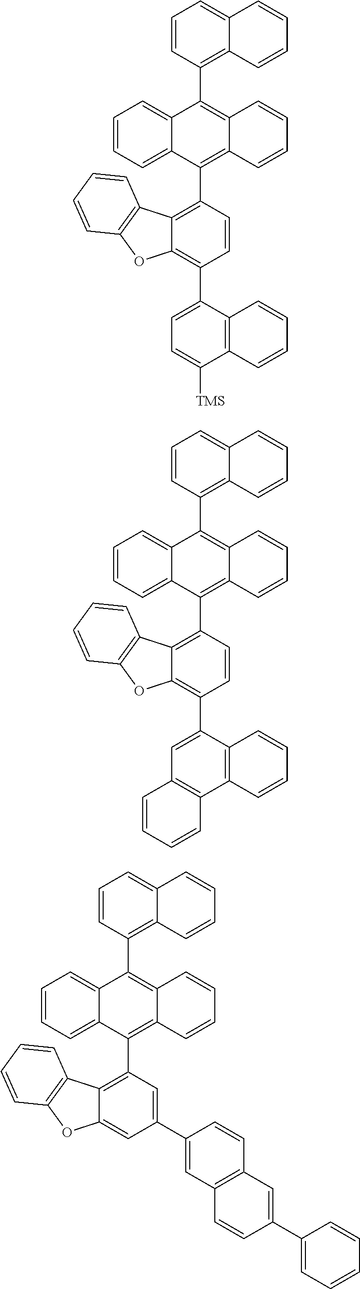

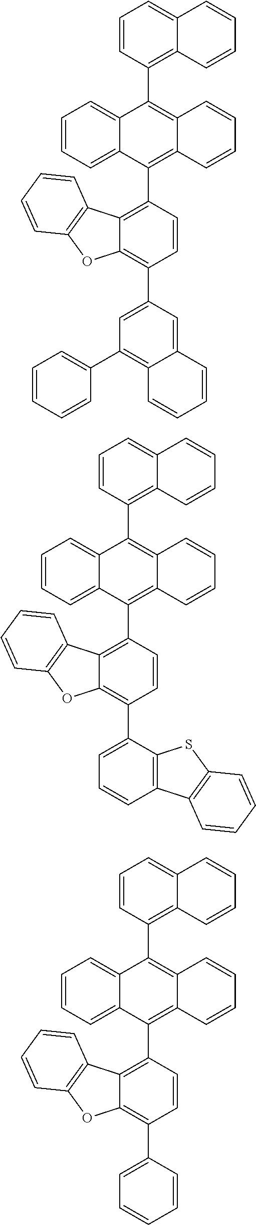

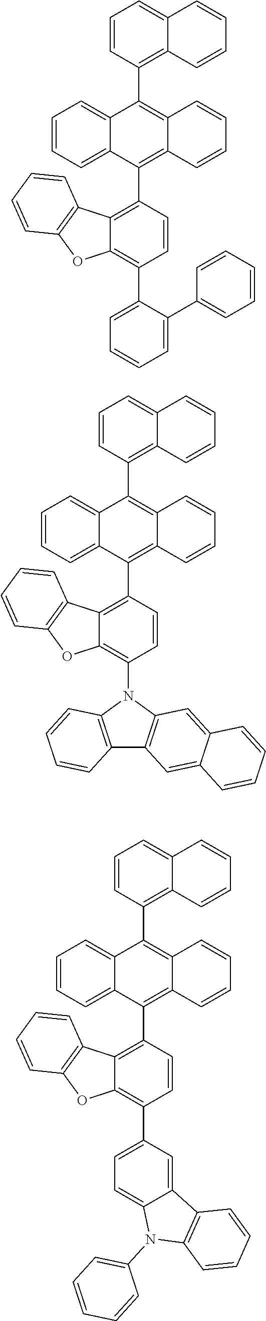

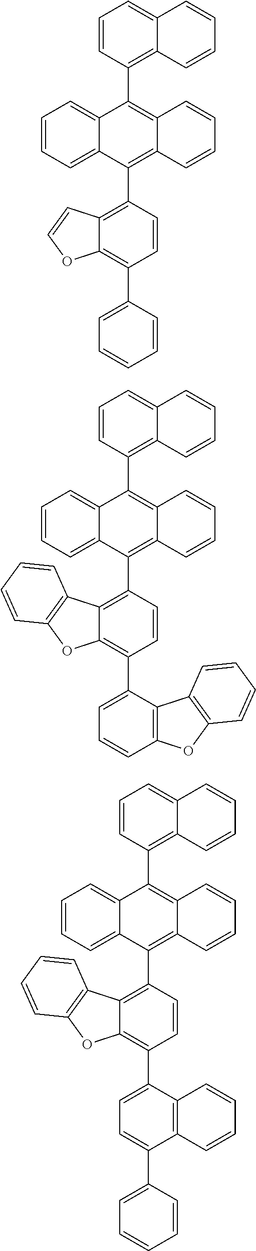

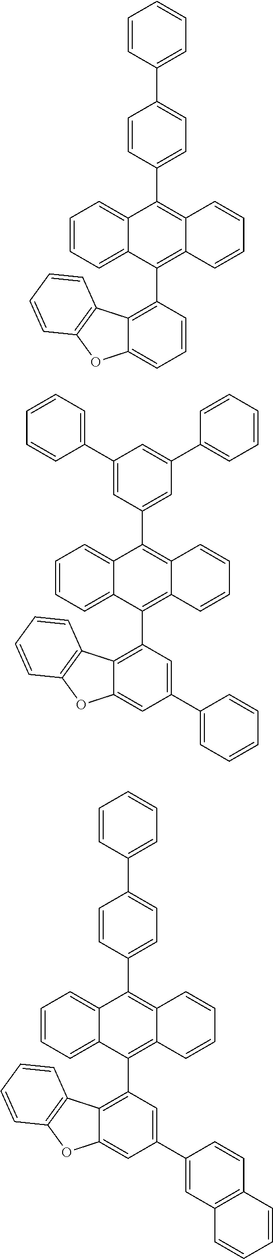 [SMILES: c1ccc(-c2ccc(-c3c4ccccc4c(-c4cccc5oc6ccccc6c45)c4ccccc34)cc2)cc1 ; c1ccc(-c2cc(-c3ccccc3)cc(-c3c4ccccc4c(-c4cc(-c5ccccc5)cc5oc6ccccc6c45)c4ccccc34)c2)cc1 ; c1ccc(-c2ccc(-c3c4ccccc4c(-c4cc(-c5ccc6ccccc6c5)cc5oc6ccccc6c45)c4ccccc34)cc2)cc1]

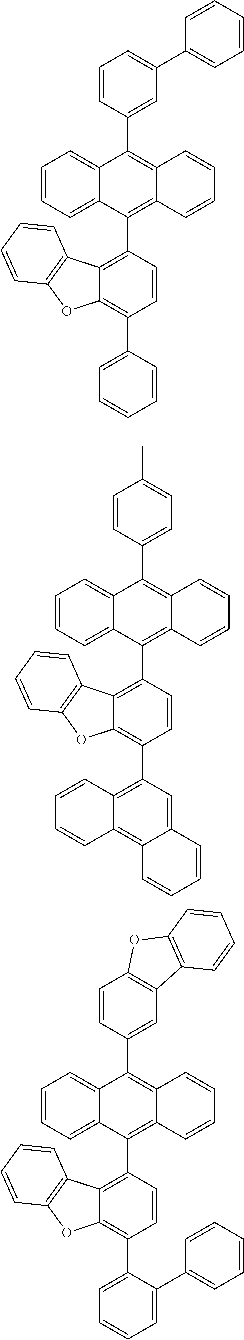

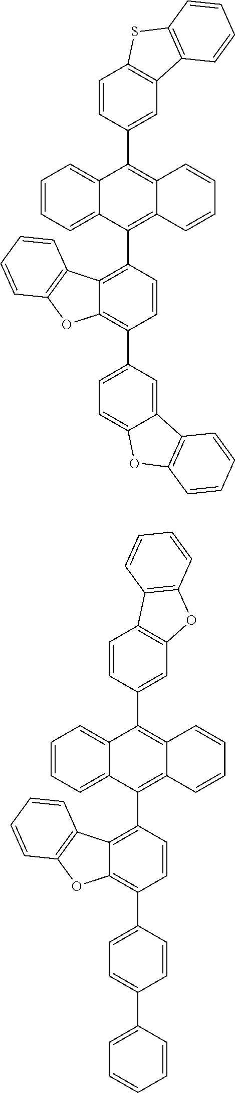

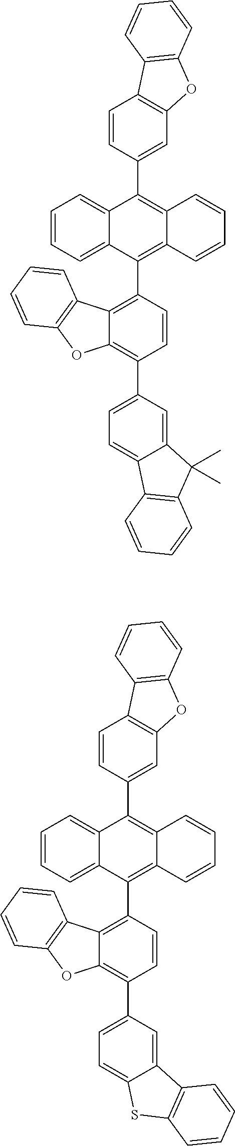 [SMILES: CC1(C)c2ccccc2-c2ccc(-c3ccc(-c4c5ccccc5c(-c5ccc6c(c5)oc5ccccc56)c5ccccc45)c4c3oc3ccccc34)cc21 ; c1ccc2c(c1)oc1cc(-c3c4ccccc4c(-c4ccc(-c5ccc6sc7ccccc7c6c5)c5oc6ccccc6c45)c4ccccc34)ccc12]

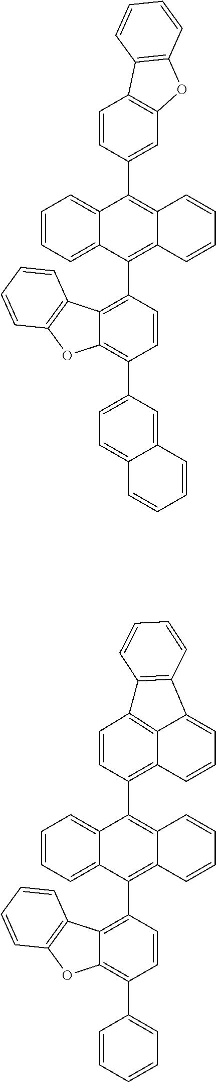 [SMILES: c1ccc2cc(-c3ccc(-c4c5ccccc5c(-c5ccc6c(c5)oc5ccccc56)c5ccccc45)c4c3oc3ccccc34)ccc2c1 ; c1ccc(-c2ccc(-c3c4ccccc4c(-c4ccc5c6c(cccc46)-c4ccccc4-5)c4ccccc34)c3c2oc2ccccc23)cc1]

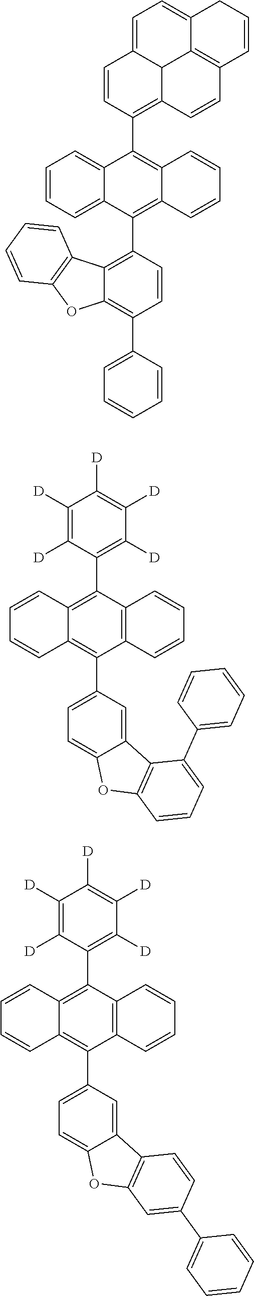 [SMILES: C1=CC2=C3C(=CC=C4C=CC(c5c6ccccc6c(-c6ccc(-c7ccccc7)c7oc8ccccc8c67)c6ccccc56)=C(C=C2)C43)C1 ; [2H]c1c([2H])c([2H])c(-c2c3ccccc3c(-c3ccc4oc5cccc(-c6ccccc6)c5c4c3)c3ccccc23)c([2H])c1[2H] ; [2H]c1c([2H])c([2H])c(-c2c3ccccc3c(-c3ccc4oc5cc(-c6ccccc6)ccc5c4c3)c3ccccc23)c([2H])c1[2H]]

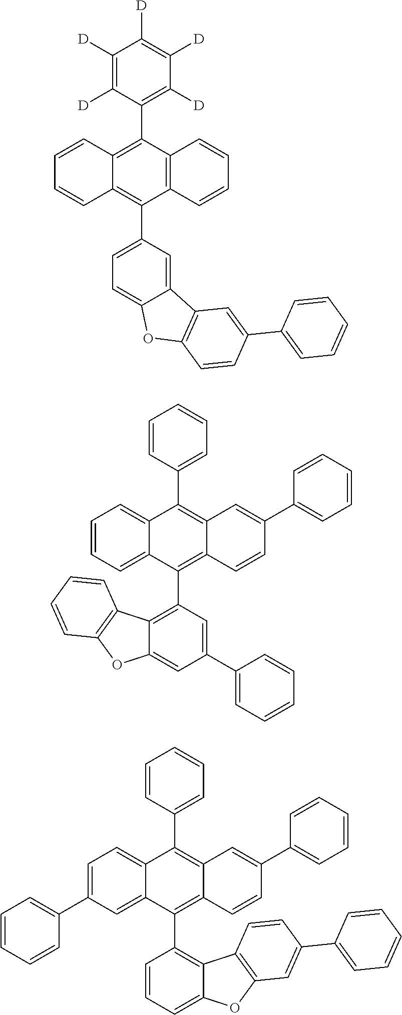

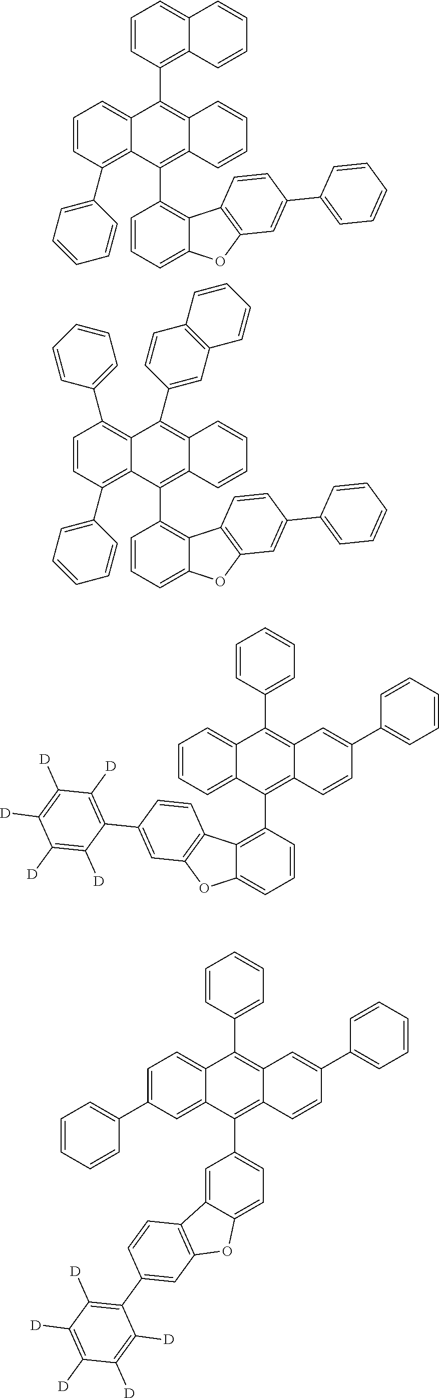

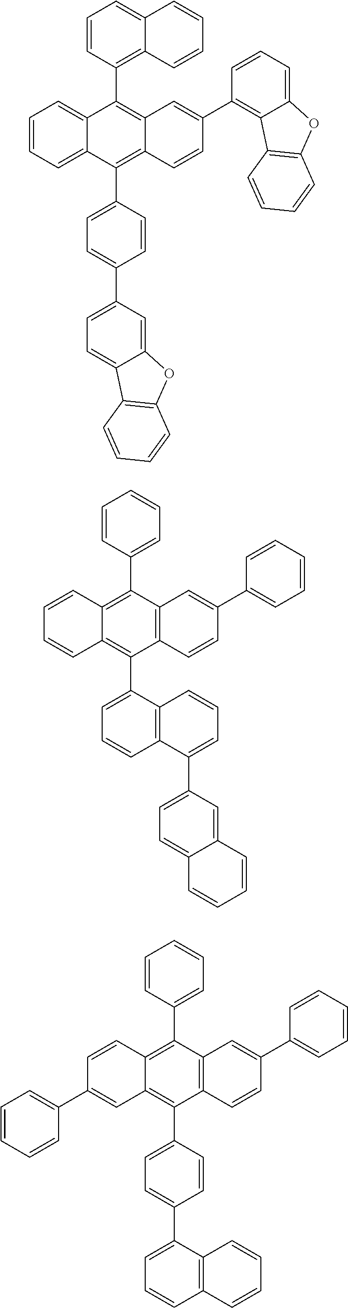

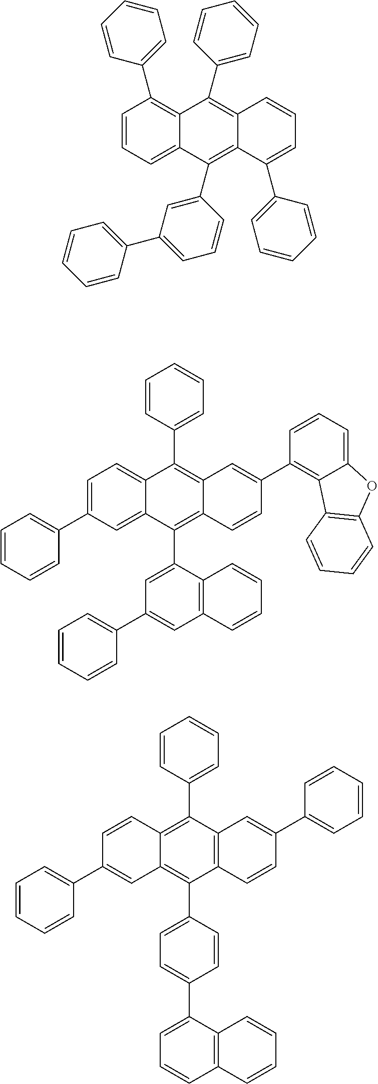

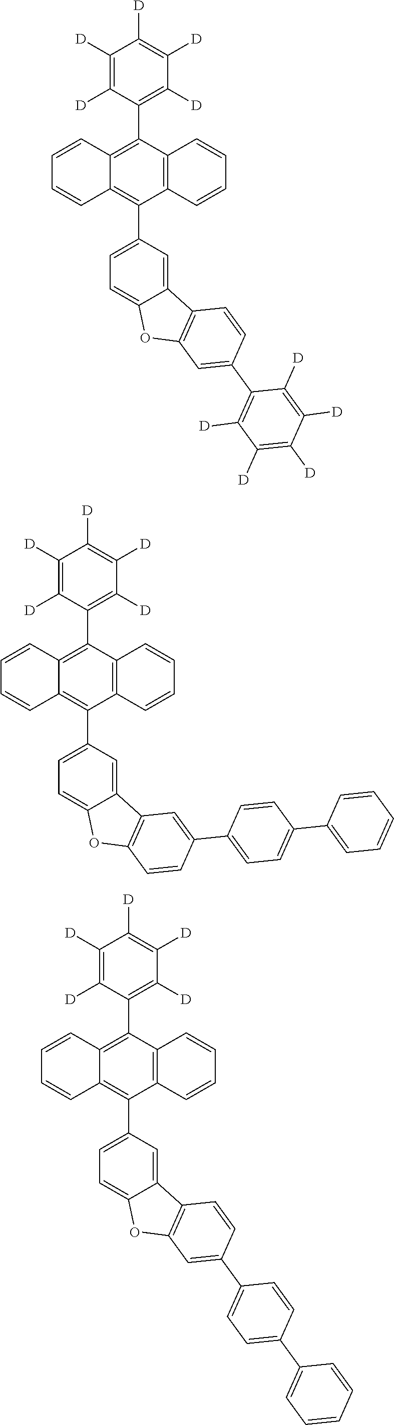

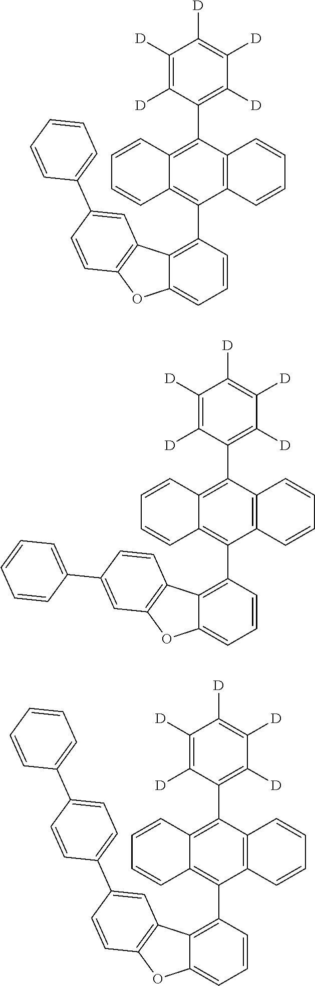

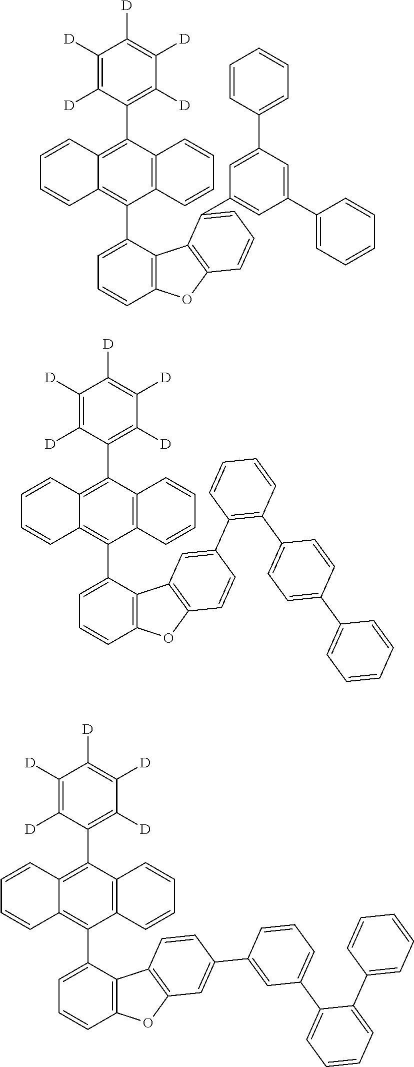

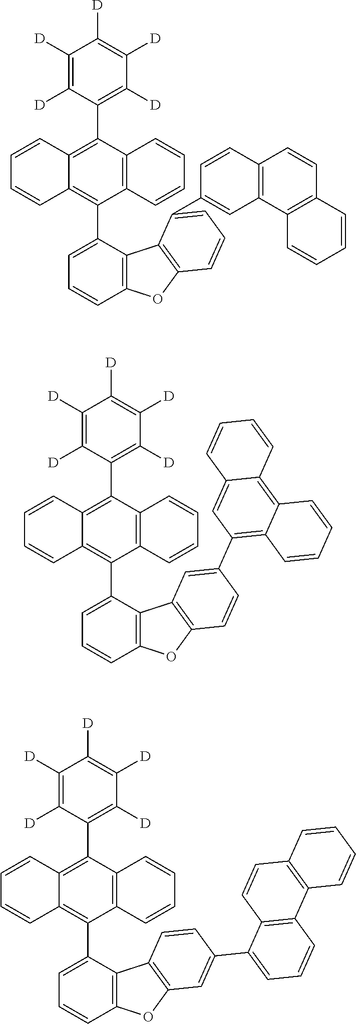 [SMILES: [2H]c1c([2H])c([2H])c(-c2c3ccccc3c(-c3cccc4oc5cccc(-c6ccc7ccc8ccccc8c7c6)c5c34)c3ccccc23)c([2H])c1[2H] ; [2H]c1c([2H])c([2H])c(-c2c3ccccc3c(-c3cccc4oc5ccc(-c6cc7ccccc7c7ccccc67)cc5c34)c3ccccc23)c([2H])c1[2H] ; [2H]c1c([2H])c([2H])c(-c2c3ccccc3c(-c3cccc4oc5cc(-c6cccc7c6ccc6ccccc67)ccc5c34)c3ccccc23)c([2H])c1[2H]]

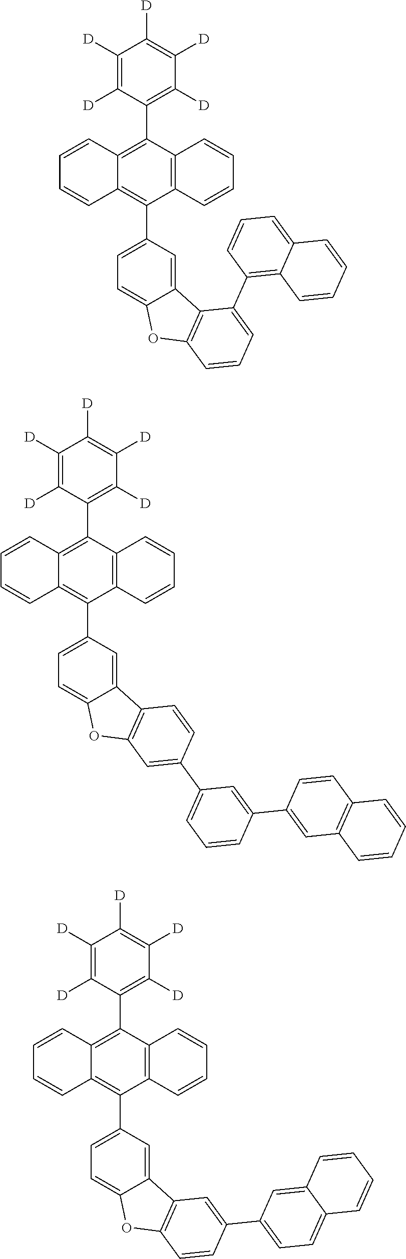 [SMILES: [2H]c1c([2H])c([2H])c(-c2c3ccccc3c(-c3ccc4oc5cccc(-c6cccc7ccccc67)c5c4c3)c3ccccc23)c([2H])c1[2H] ; [2H]c1c([2H])c([2H])c(-c2c3ccccc3c(-c3ccc4oc5cc(-c6cccc(-c7ccc8ccccc8c7)c6)ccc5c4c3)c3ccccc23)c([2H])c1[2H] ; [2H]c1c([2H])c([2H])c(-c2c3ccccc3c(-c3ccc4oc5ccc(-c6ccc7ccccc7c6)cc5c4c3)c3ccccc23)c([2H])c1[2H]]

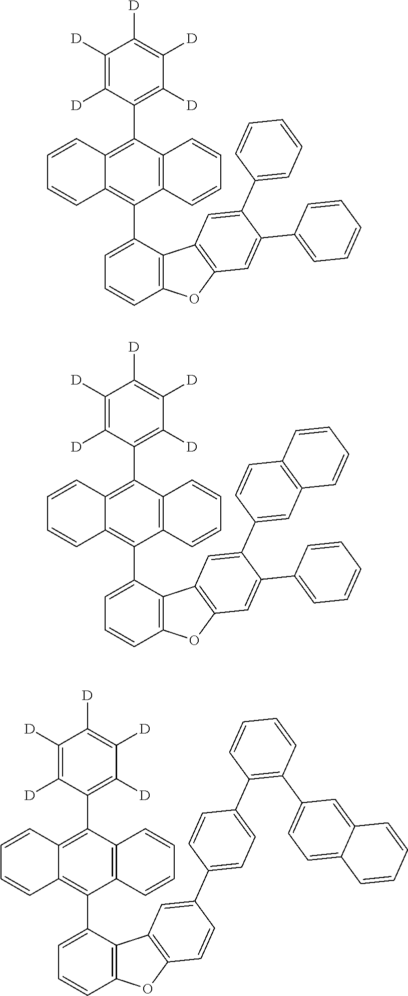

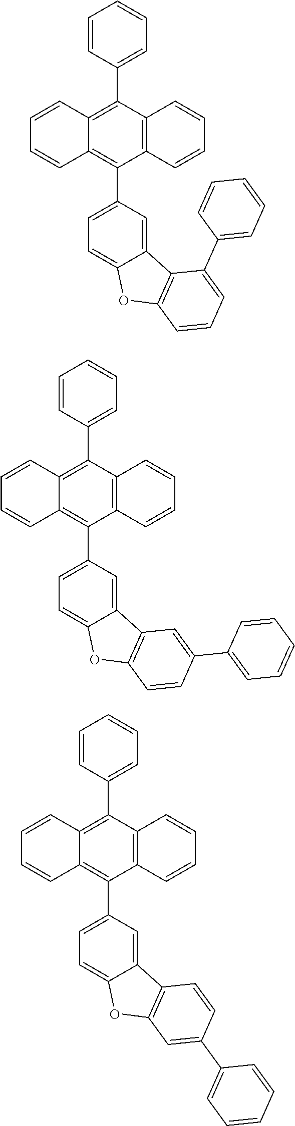

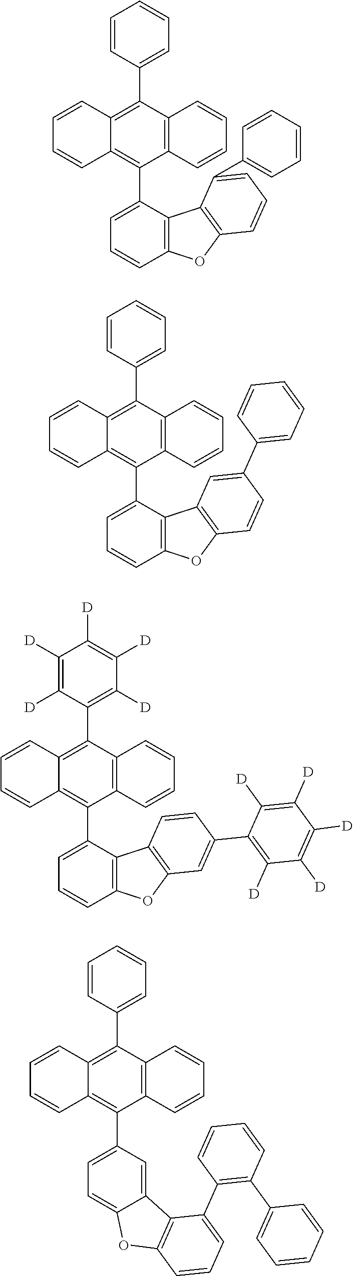

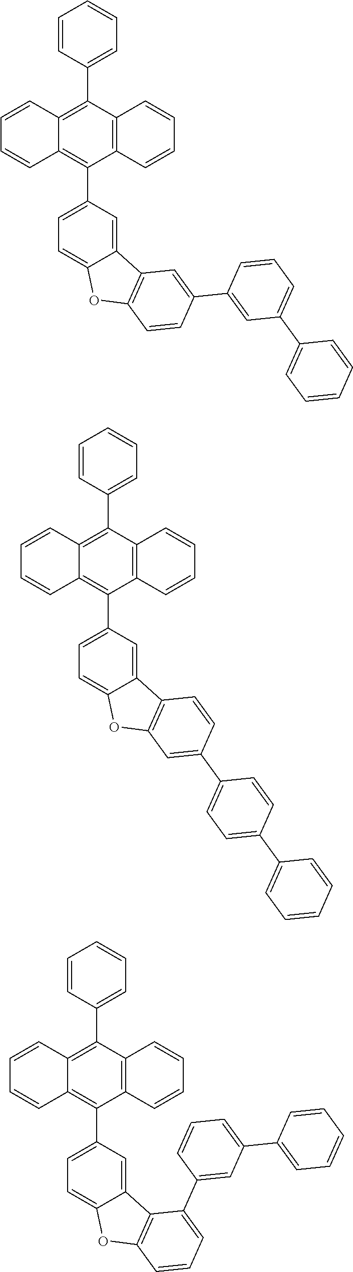 [SMILES: c1ccc(-c2cccc(-c3ccc4oc5ccc(-c6c7ccccc7c(-c7ccccc7)c7ccccc67)cc5c4c3)c2)cc1 ; c1ccc(-c2ccc(-c3ccc4c(c3)oc3ccc(-c5c6ccccc6c(-c6ccccc6)c6ccccc56)cc34)cc2)cc1 ; c1ccc(-c2cccc(-c3cccc4oc5ccc(-c6c7ccccc7c(-c7ccccc7)c7ccccc67)cc5c34)c2)cc1]

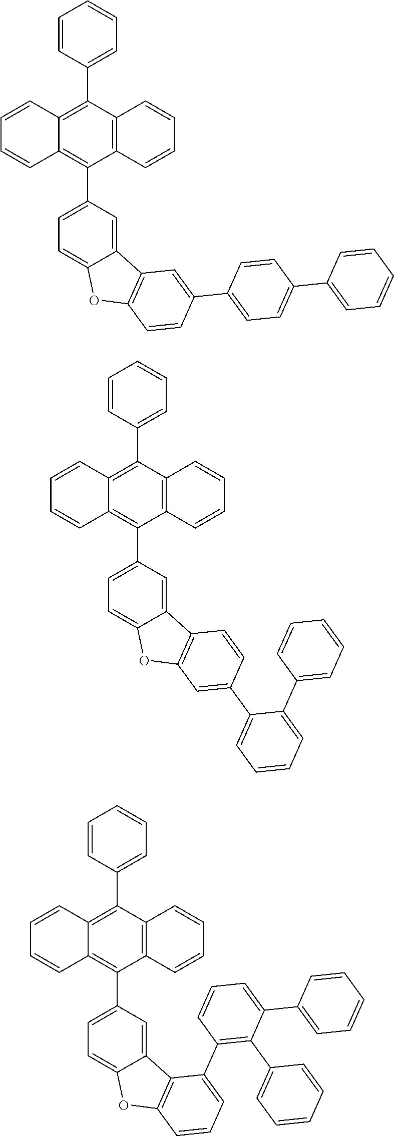

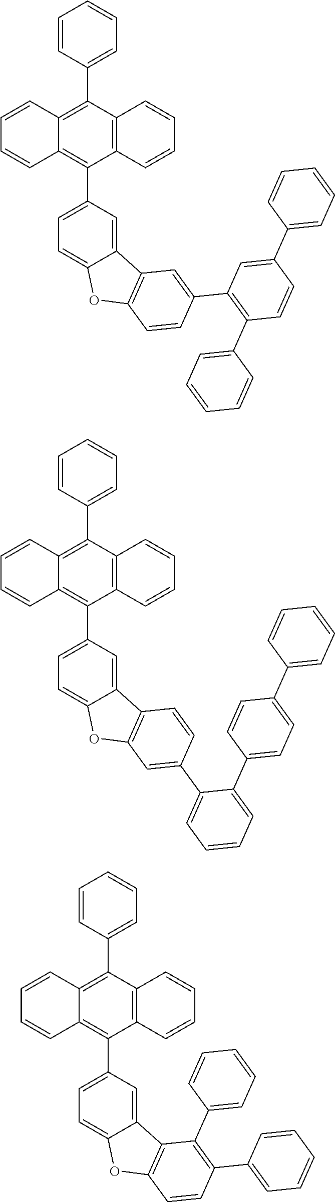 [SMILES: c1ccc(-c2ccc(-c3ccccc3)c(-c3ccc4oc5ccc(-c6c7ccccc7c(-c7ccccc7)c7ccccc67)cc5c4c3)c2)cc1 ; c1ccc(-c2ccc(-c3ccccc3-c3ccc4c(c3)oc3ccc(-c5c6ccccc6c(-c6ccccc6)c6ccccc56)cc34)cc2)cc1 ; c1ccc(-c2ccc3oc4ccc(-c5c6ccccc6c(-c6ccccc6)c6ccccc56)cc4c3c2-c2ccccc2)cc1]

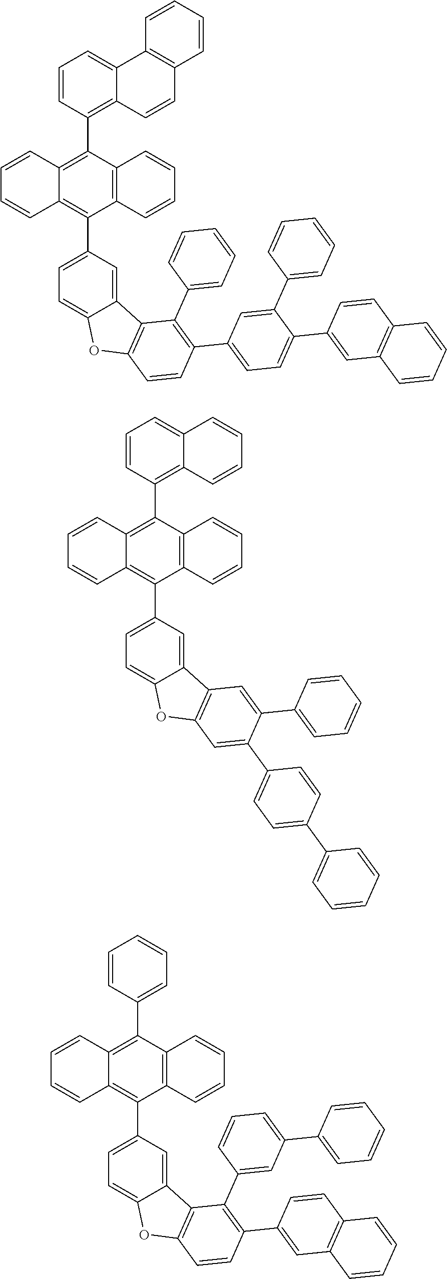

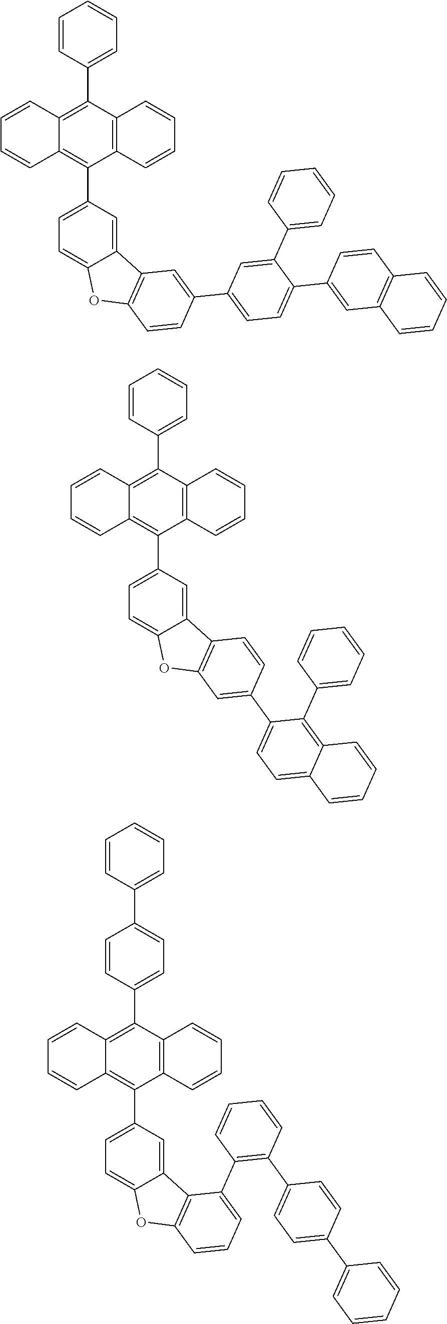

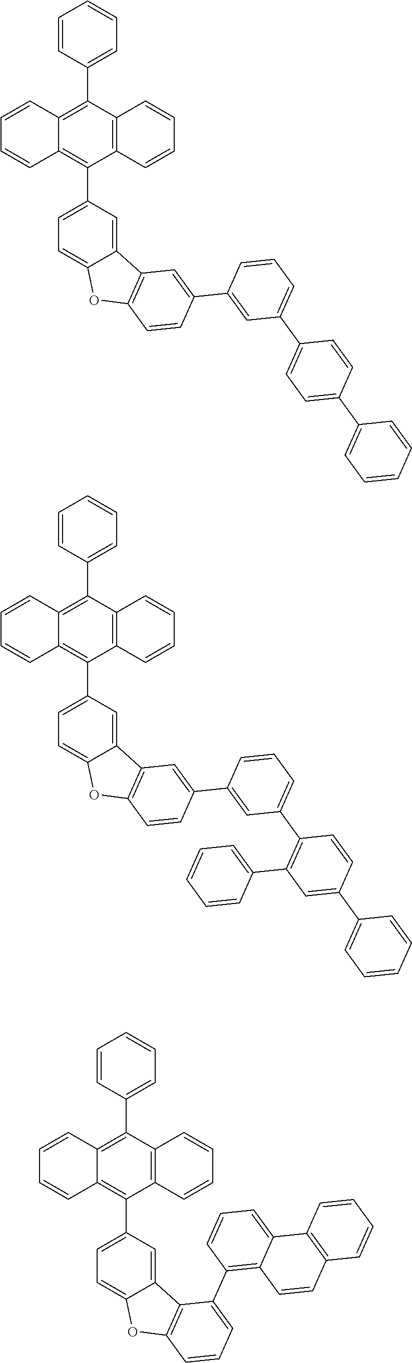 [SMILES: c1ccc(-c2ccc(-c3cccc(-c4ccc5oc6ccc(-c7c8ccccc8c(-c8ccccc8)c8ccccc78)cc6c5c4)c3)cc2)cc1 ; c1ccc(-c2ccc(-c3cccc(-c4ccc5oc6ccc(-c7c8ccccc8c(-c8ccccc8)c8ccccc78)cc6c5c4)c3)c(-c3ccccc3)c2)cc1 ; c1ccc(-c2c3ccccc3c(-c3ccc4oc5cccc(-c6cccc7c6ccc6ccccc67)c5c4c3)c3ccccc23)cc1]

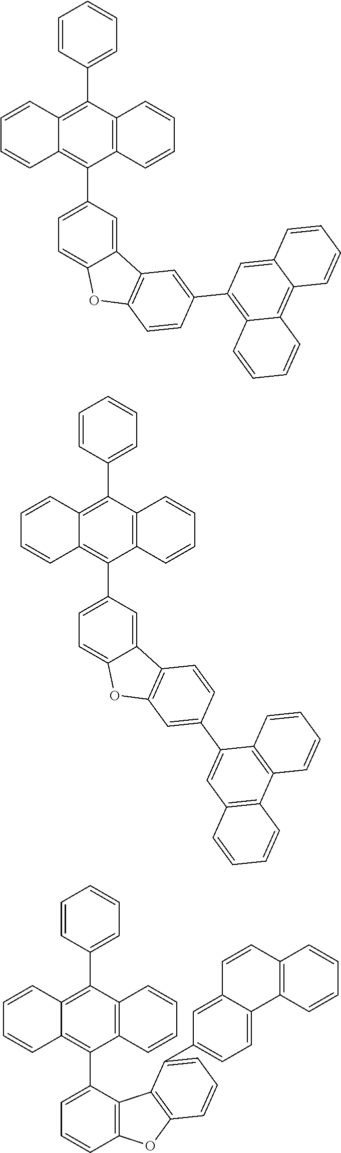 [SMILES: c1ccc(-c2c3ccccc3c(-c3ccc4oc5ccc(-c6cc7ccccc7c7ccccc67)cc5c4c3)c3ccccc23)cc1 ; c1ccc(-c2c3ccccc3c(-c3ccc4oc5cc(-c6cc7ccccc7c7ccccc67)ccc5c4c3)c3ccccc23)cc1 ; c1ccc(-c2c3ccccc3c(-c3cccc4oc5cccc(-c6ccc7c(ccc8ccccc87)c6)c5c34)c3ccccc23)cc1]

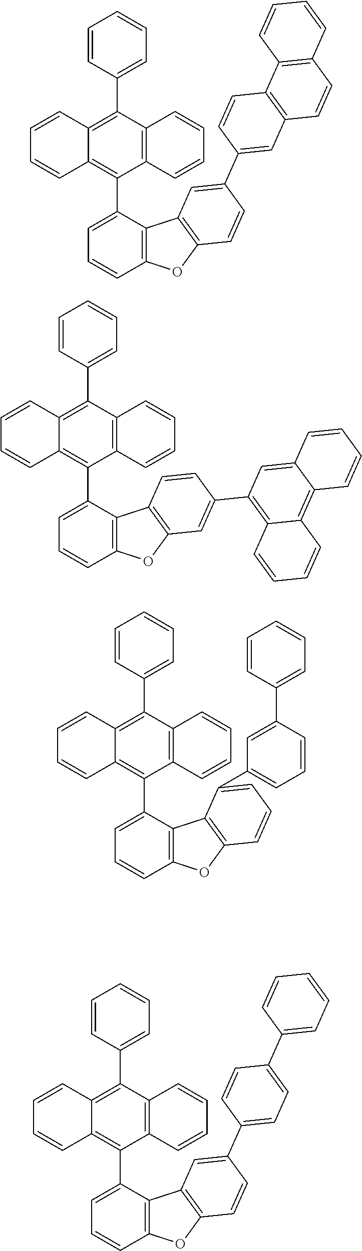

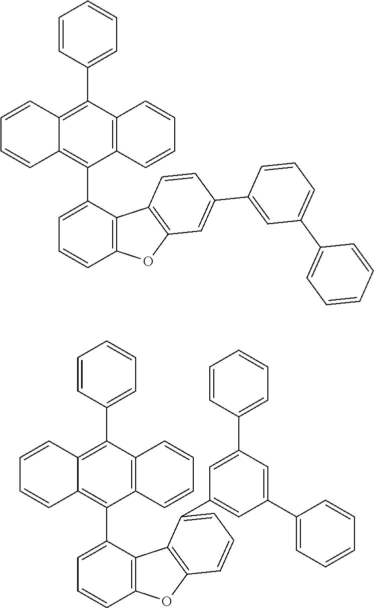 [SMILES: c1ccc(-c2cccc(-c3ccc4c(c3)oc3cccc(-c5c6ccccc6c(-c6ccccc6)c6ccccc56)c34)c2)cc1 ; c1ccc(-c2cc(-c3ccccc3)cc(-c3cccc4oc5cccc(-c6c7ccccc7c(-c7ccccc7)c7ccccc67)c5c34)c2)cc1]

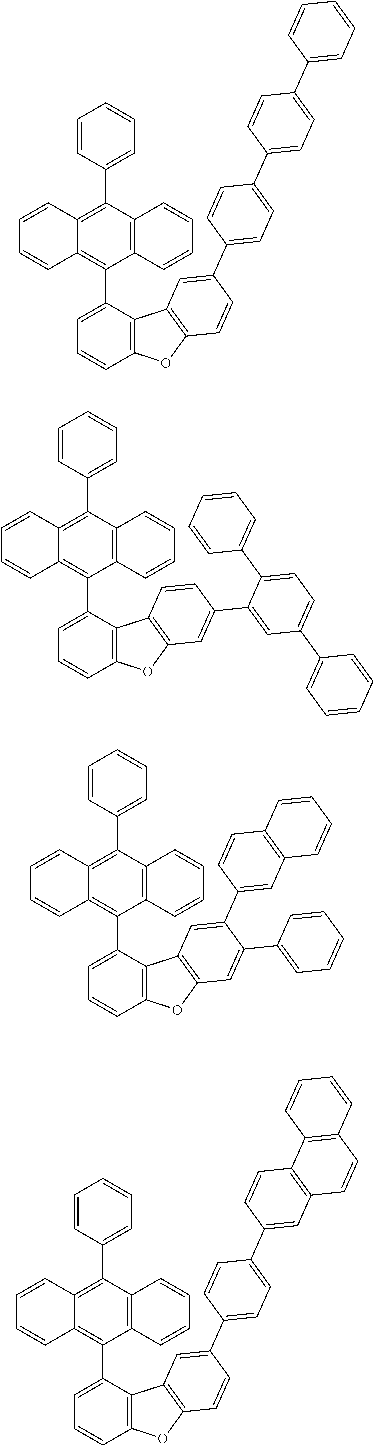

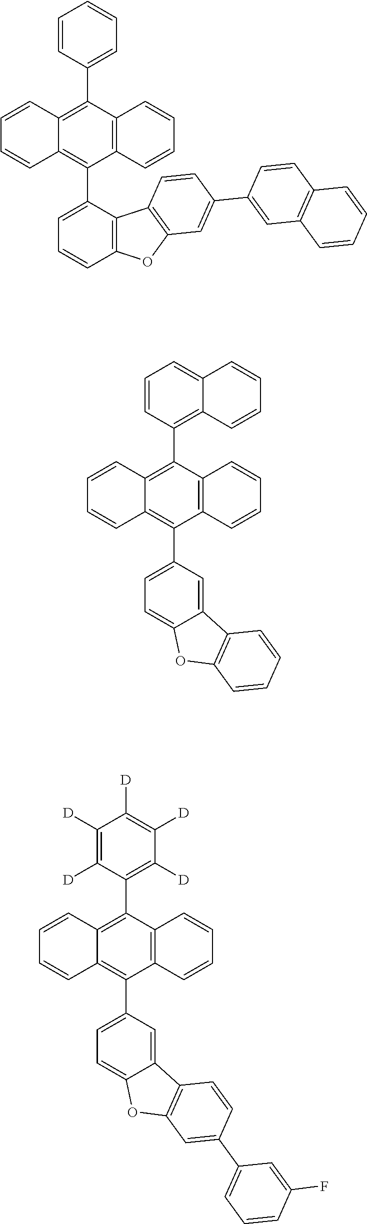 [SMILES: c1ccc(-c2c3ccccc3c(-c3cccc4oc5cc(-c6ccc7ccccc7c6)ccc5c34)c3ccccc23)cc1 ; c1ccc2c(-c3c4ccccc4c(-c4ccc5oc6ccccc6c5c4)c4ccccc34)cccc2c1 ; [2H]c1c([2H])c([2H])c(-c2c3ccccc3c(-c3ccc4oc5cc(-c6cccc(F)c6)ccc5c4c3)c3ccccc23)c([2H])c1[2H]]

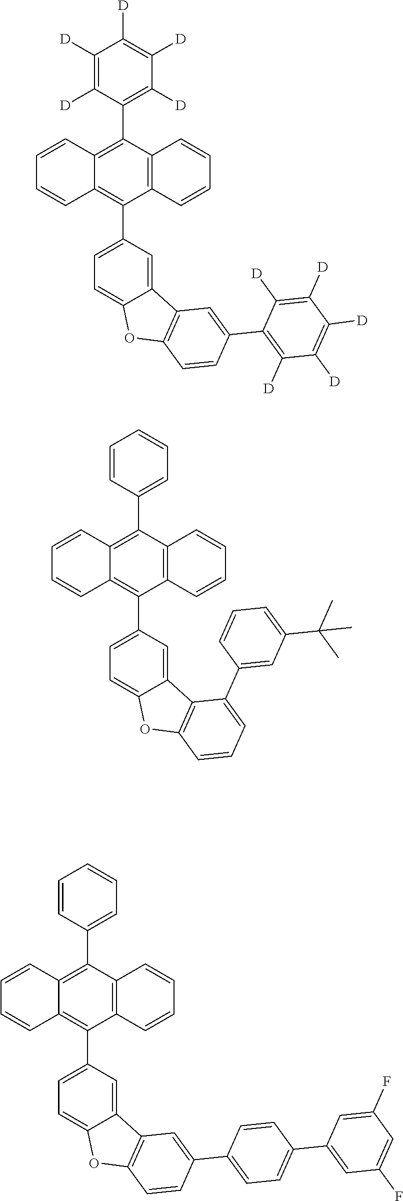 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; CC(C)(C)c1cccc(-c2cccc3oc4ccc(-c5c6ccccc6c(-c6ccccc6)c6ccccc56)cc4c23)c1 ; Fc1cc(F)cc(-c2ccc(-c3ccc4oc5ccc(-c6c7ccccc7c(-c7ccccc7)c7ccccc67)cc5c4c3)cc2)c1]

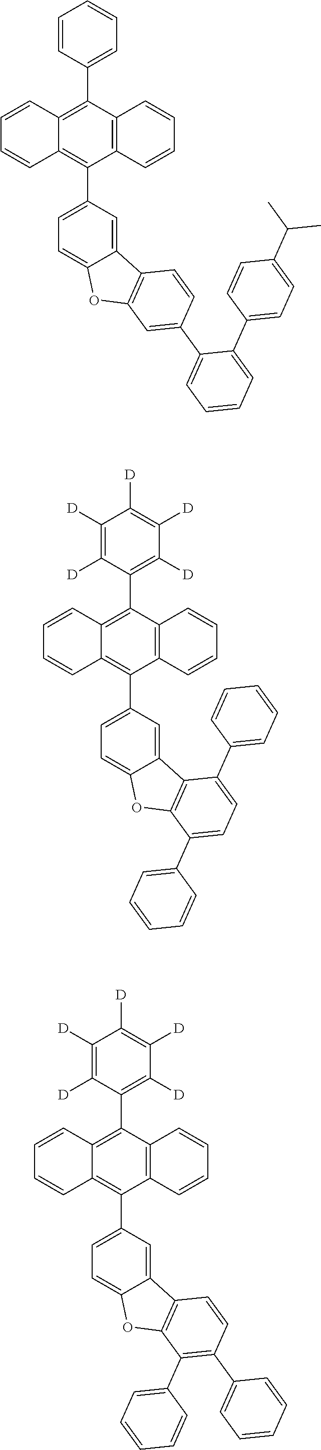 [SMILES: CC(C)c1ccc(-c2ccccc2-c2ccc3c(c2)oc2ccc(-c4c5ccccc5c(-c5ccccc5)c5ccccc45)cc23)cc1 ; [2H]c1c([2H])c([2H])c(-c2c3ccccc3c(-c3ccc4oc5c(-c6ccccc6)ccc(-c6ccccc6)c5c4c3)c3ccccc23)c([2H])c1[2H] ; [2H]c1c([2H])c([2H])c(-c2c3ccccc3c(-c3ccc4oc5c(-c6ccccc6)c(-c6ccccc6)ccc5c4c3)c3ccccc23)c([2H])c1[2H]]

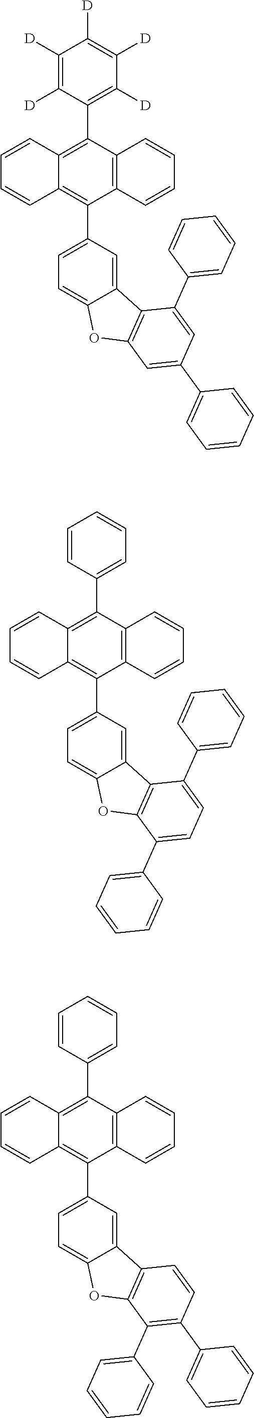 [SMILES: [2H]c1c([2H])c([2H])c(-c2c3ccccc3c(-c3ccc4oc5cc(-c6ccccc6)cc(-c6ccccc6)c5c4c3)c3ccccc23)c([2H])c1[2H] ; c1ccc(-c2c3ccccc3c(-c3ccc4oc5c(-c6ccccc6)ccc(-c6ccccc6)c5c4c3)c3ccccc23)cc1 ; c1ccc(-c2ccc3c(oc4ccc(-c5c6ccccc6c(-c6ccccc6)c6ccccc56)cc43)c2-c2ccccc2)cc1]

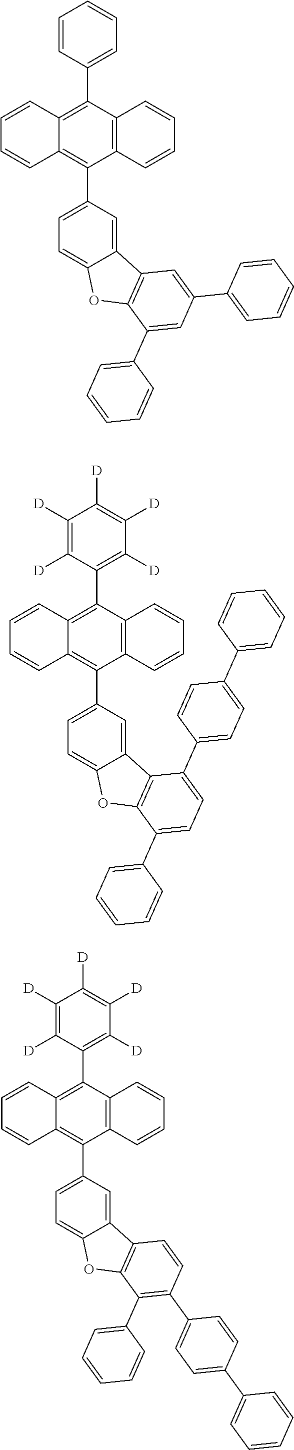

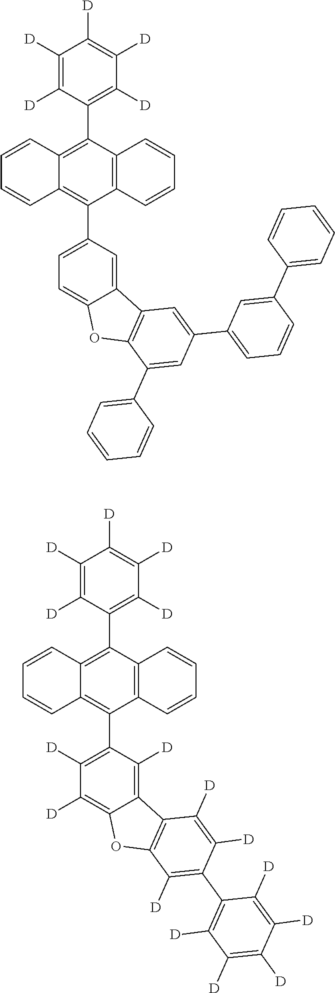 [SMILES: [2H]c1c([2H])c([2H])c(-c2c3ccccc3c(-c3ccc4oc5c(-c6ccccc6)cc(-c6cccc(-c7ccccc7)c6)cc5c4c3)c3ccccc23)c([2H])c1[2H] ; [2H]c1c([2H])c([2H])c(-c2c([2H])c([2H])c3c(oc4c([2H])c([2H])c(-c5c6ccccc6c(-c6c([2H])c([2H])c([2H])c([2H])c6[2H])c6ccccc56)c([2H])c43)c2[2H])c([2H])c1[2H]]

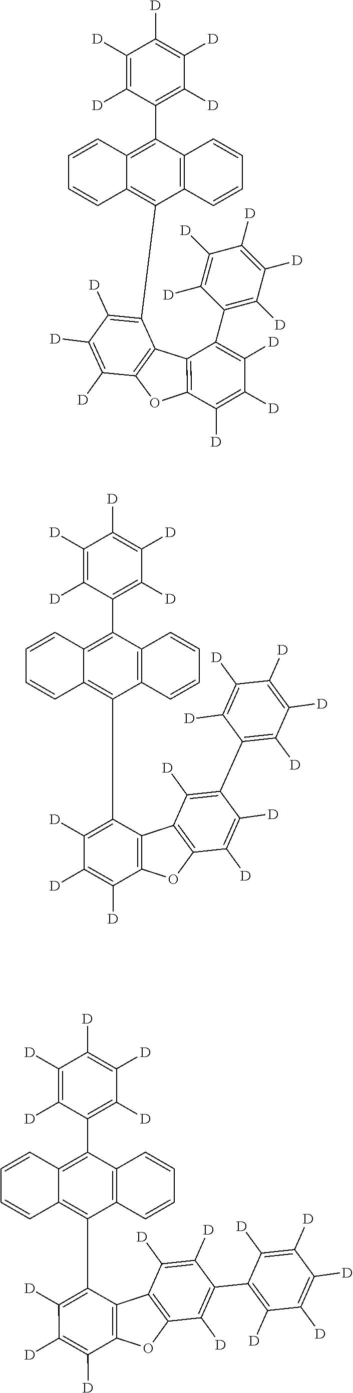 [SMILES: [2H]c1c([2H])c([2H])c(-c2c3ccccc3c(-c3c([2H])c([2H])c([2H])c4oc5c([2H])c([2H])c([2H])c(-c6c([2H])c([2H])c([2H])c([2H])c6[2H])c5c34)c3ccccc23)c([2H])c1[2H] ; [2H]c1c([2H])c([2H])c(-c2c([2H])c([2H])c3oc4c([2H])c([2H])c([2H])c(-c5c6ccccc6c(-c6c([2H])c([2H])c([2H])c([2H])c6[2H])c6ccccc56)c4c3c2[2H])c([2H])c1[2H] ; [2H]c1c([2H])c([2H])c(-c2c([2H])c([2H])c3c(oc4c([2H])c([2H])c([2H])c(-c5c6ccccc6c(-c6c([2H])c([2H])c([2H])c([2H])c6[2H])c6ccccc56)c43)c2[2H])c([2H])c1[2H]]

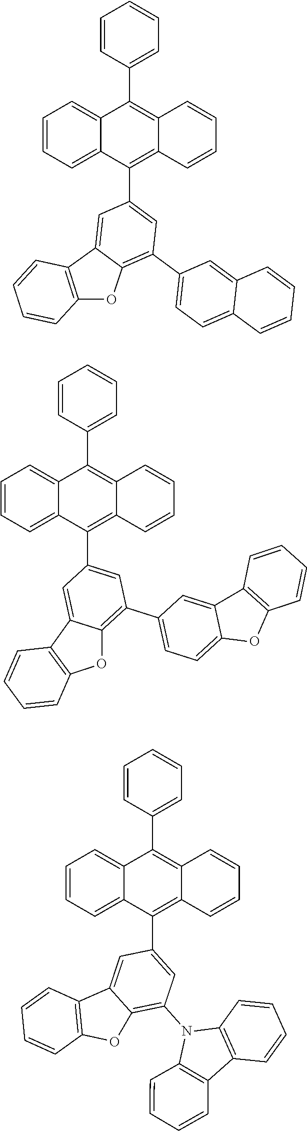 [SMILES: c1ccc(-c2c3ccccc3c(-c3cc(-c4ccc5ccccc5c4)c4oc5ccccc5c4c3)c3ccccc23)cc1 ; c1ccc(-c2c3ccccc3c(-c3cc(-c4ccc5oc6ccccc6c5c4)c4oc5ccccc5c4c3)c3ccccc23)cc1 ; c1ccc(-c2c3ccccc3c(-c3cc(-n4c5ccccc5c5ccccc54)c4oc5ccccc5c4c3)c3ccccc23)cc1]

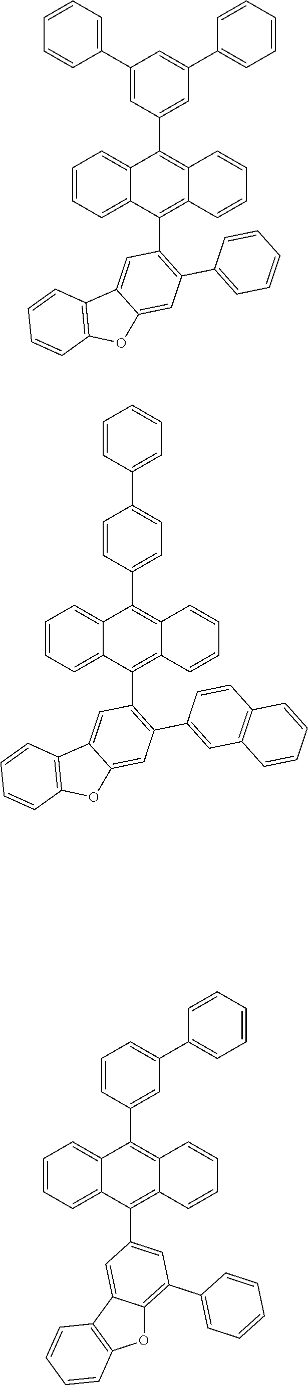 [SMILES: c1ccc(-c2cc(-c3ccccc3)cc(-c3c4ccccc4c(-c4cc5c(cc4-c4ccccc4)oc4ccccc45)c4ccccc34)c2)cc1 ; c1ccc(-c2ccc(-c3c4ccccc4c(-c4cc5c(cc4-c4ccc6ccccc6c4)oc4ccccc45)c4ccccc34)cc2)cc1 ; c1ccc(-c2cccc(-c3c4ccccc4c(-c4cc(-c5ccccc5)c5oc6ccccc6c5c4)c4ccccc34)c2)cc1]

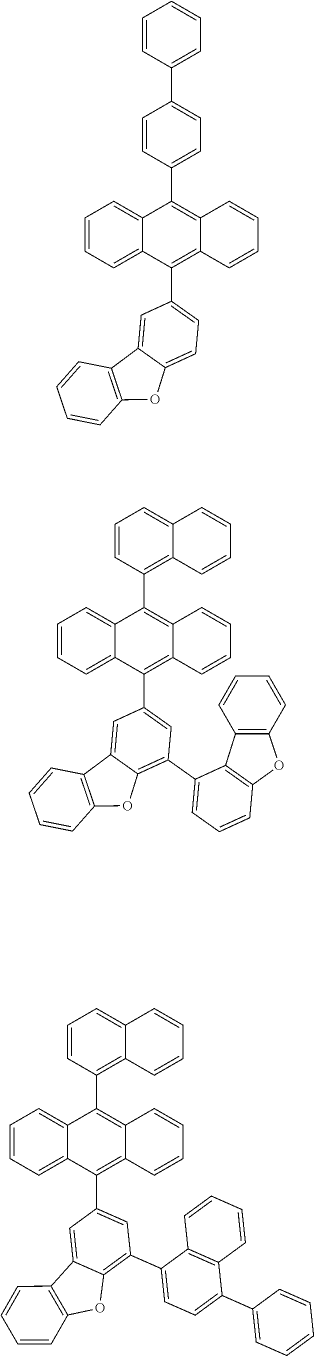 [SMILES: c1ccc(-c2ccc(-c3c4ccccc4c(-c4ccc5oc6ccccc6c5c4)c4ccccc34)cc2)cc1 ; c1ccc2c(-c3c4ccccc4c(-c4cc(-c5cccc6oc7ccccc7c56)c5oc6ccccc6c5c4)c4ccccc34)cccc2c1 ; c1ccc(-c2ccc(-c3cc(-c4c5ccccc5c(-c5cccc6ccccc56)c5ccccc45)cc4c3oc3ccccc34)c3ccccc23)cc1]

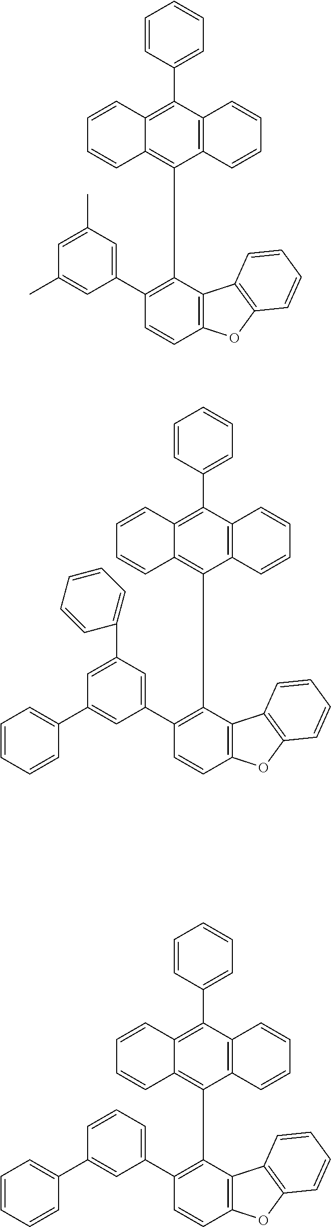 [SMILES: Cc1cc(C)cc(-c2ccc3oc4ccccc4c3c2-c2c3ccccc3c(-c3ccccc3)c3ccccc23)c1 ; c1ccc(-c2cc(-c3ccccc3)cc(-c3ccc4oc5ccccc5c4c3-c3c4ccccc4c(-c4ccccc4)c4ccccc34)c2)cc1 ; c1ccc(-c2cccc(-c3ccc4oc5ccccc5c4c3-c3c4ccccc4c(-c4ccccc4)c4ccccc34)c2)cc1]

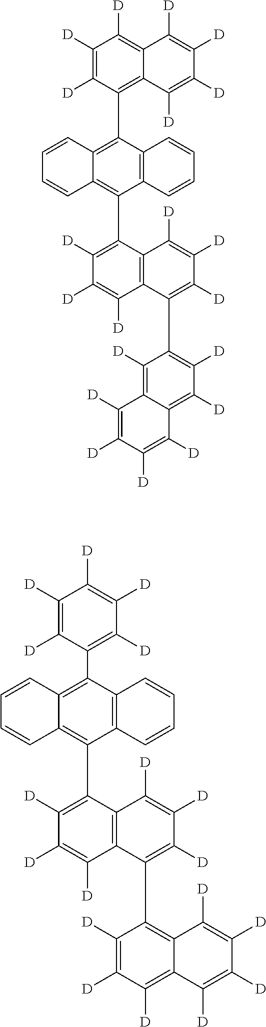 [SMILES: [2H]c1c([2H])c([2H])c2c([2H])c(-c3c([2H])c([2H])c([2H])c4c(-c5c6ccccc6c(-c6c([2H])c([2H])c([2H])c7c([2H])c([2H])c([2H])c([2H])c67)c6ccccc56)c([2H])c([2H])c([2H])c34)c([2H])c([2H])c2c1[2H] ; [2H]c1c([2H])c([2H])c(-c2c3ccccc3c(-c3c([2H])c([2H])c([2H])c4c(-c5c([2H])c([2H])c([2H])c6c([2H])c([2H])c([2H])c([2H])c56)c([2H])c([2H])c([2H])c34)c3ccccc23)c([2H])c1[2H]]

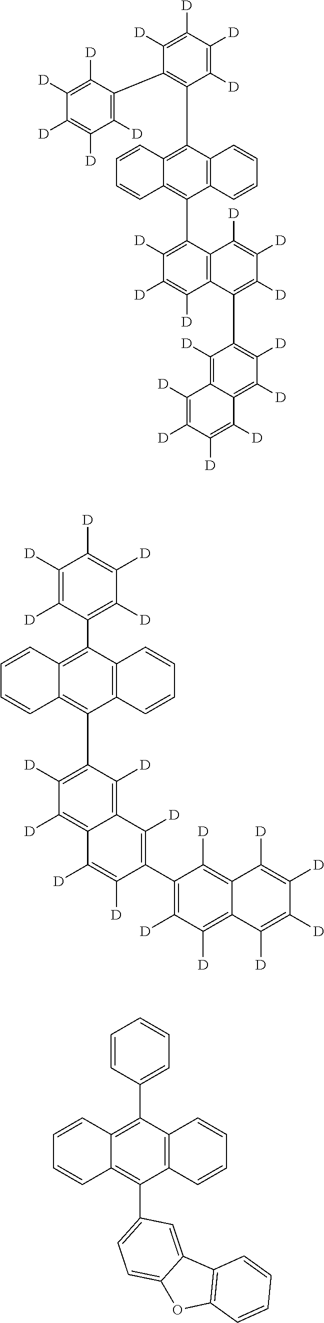 [SMILES: [2H]c1c([2H])c([2H])c(-c2c([2H])c([2H])c([2H])c([2H])c2-c2c3ccccc3c(-c3c([2H])c([2H])c([2H])c4c(-c5c([2H])c([2H])c6c([2H])c([2H])c([2H])c([2H])c6c5[2H])c([2H])c([2H])c([2H])c34)c3ccccc23)c([2H])c1[2H] ; [2H]c1c([2H])c([2H])c(-c2c3ccccc3c(-c3c([2H])c([2H])c4c([2H])c([2H])c(-c5c([2H])c([2H])c6c([2H])c([2H])c([2H])c([2H])c6c5[2H])c([2H])c4c3[2H])c3ccccc23)c([2H])c1[2H] ; c1ccc(-c2c3ccccc3c(-c3ccc4oc5ccccc5c4c3)c3ccccc23)cc1]

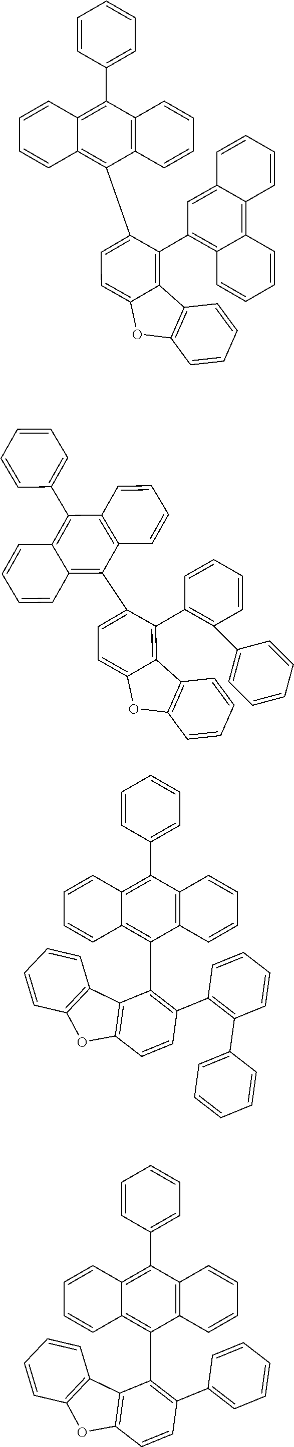 [SMILES: c1ccc(-c2c3ccccc3c(-c3ccc4oc5ccccc5c4c3-c3cc4ccccc4c4ccccc34)c3ccccc23)cc1 ; c1ccc(-c2ccccc2-c2c(-c3c4ccccc4c(-c4ccccc4)c4ccccc34)ccc3oc4ccccc4c23)cc1 ; c1ccc(-c2ccccc2-c2ccc3oc4ccccc4c3c2-c2c3ccccc3c(-c3ccccc3)c3ccccc23)cc1 ; c1ccc(-c2ccc3oc4ccccc4c3c2-c2c3ccccc3c(-c3ccccc3)c3ccccc23)cc1]

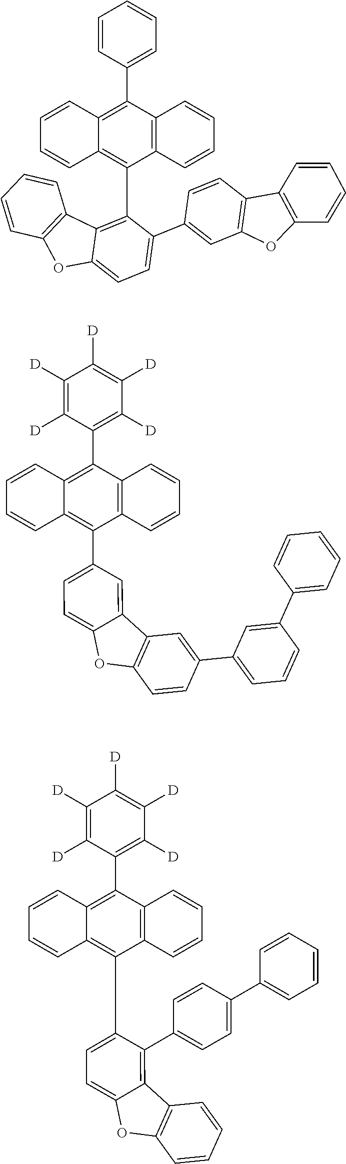 [SMILES: c1ccc(-c2c3ccccc3c(-c3c(-c4ccc5c(c4)oc4ccccc45)ccc4oc5ccccc5c34)c3ccccc23)cc1 ; [2H]c1c([2H])c([2H])c(-c2c3ccccc3c(-c3ccc4oc5ccc(-c6cccc(-c7ccccc7)c6)cc5c4c3)c3ccccc23)c([2H])c1[2H] ; [2H]c1c([2H])c([2H])c(-c2c3ccccc3c(-c3ccc4oc5ccccc5c4c3-c3ccc(-c4ccccc4)cc3)c3ccccc23)c([2H])c1[2H]]

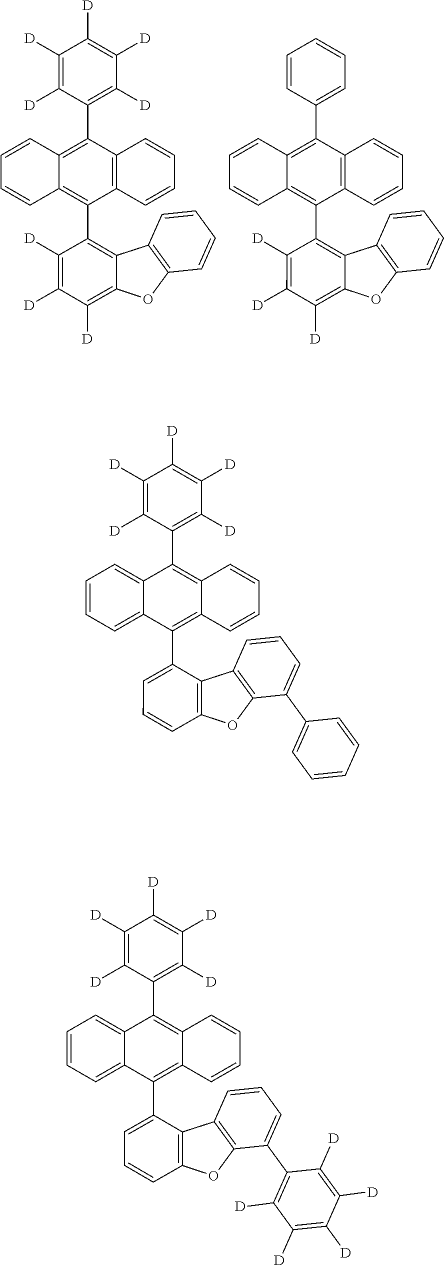

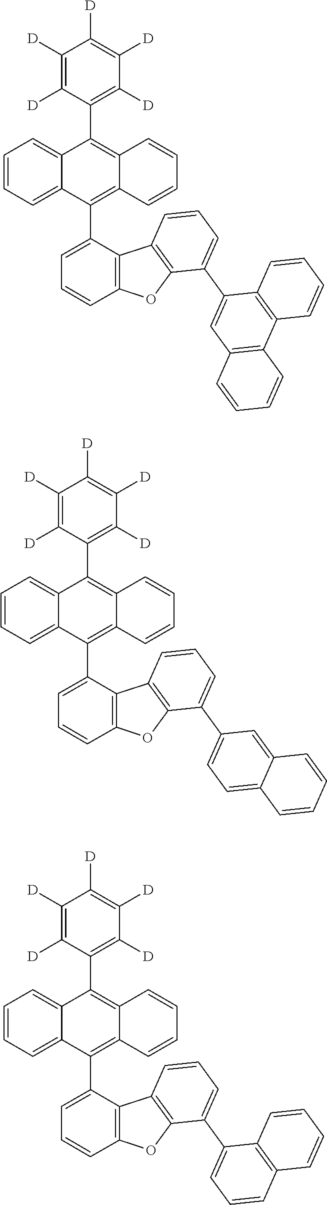 [SMILES: [2H]c1c([2H])c([2H])c(-c2c3ccccc3c(-c3cccc4oc5c(-c6cc7ccccc7c7ccccc67)cccc5c34)c3ccccc23)c([2H])c1[2H] ; [2H]c1c([2H])c([2H])c(-c2c3ccccc3c(-c3cccc4oc5c(-c6ccc7ccccc7c6)cccc5c34)c3ccccc23)c([2H])c1[2H] ; [2H]c1c([2H])c([2H])c(-c2c3ccccc3c(-c3cccc4oc5c(-c6cccc7ccccc67)cccc5c34)c3ccccc23)c([2H])c1[2H]]

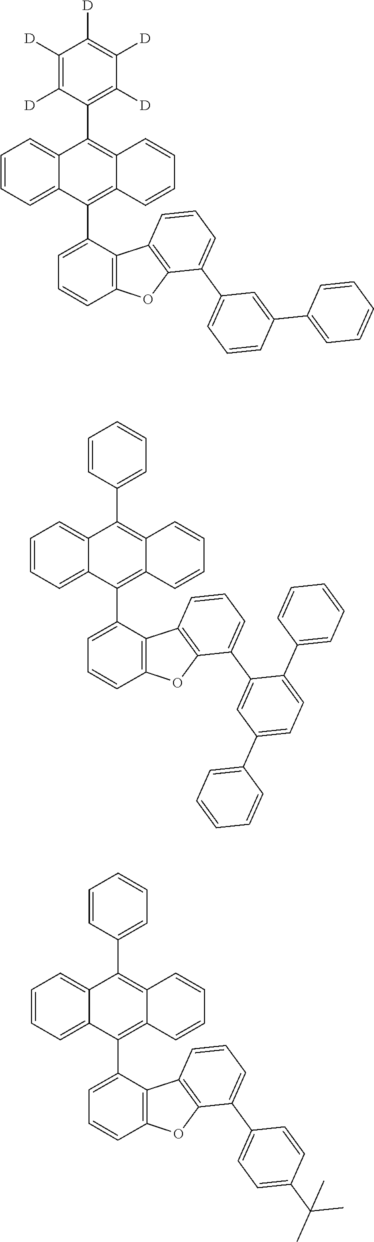 [SMILES: [2H]c1c([2H])c([2H])c(-c2c3ccccc3c(-c3cccc4oc5c(-c6cccc(-c7ccccc7)c6)cccc5c34)c3ccccc23)c([2H])c1[2H] ; c1ccc(-c2ccc(-c3ccccc3)c(-c3cccc4c3oc3cccc(-c5c6ccccc6c(-c6ccccc6)c6ccccc56)c34)c2)cc1 ; CC(C)(C)c1ccc(-c2cccc3c2oc2cccc(-c4c5ccccc5c(-c5ccccc5)c5ccccc45)c23)cc1]

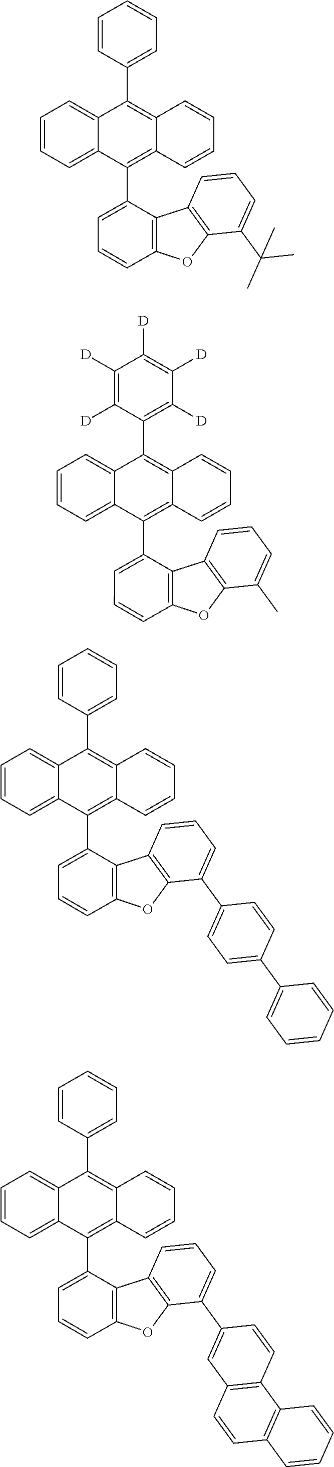 [SMILES: CC(C)(C)c1cccc2c1oc1cccc(-c3c4ccccc4c(-c4ccccc4)c4ccccc34)c12 ; [2H]c1c([2H])c([2H])c(-c2c3ccccc3c(-c3cccc4oc5c(C)cccc5c34)c3ccccc23)c([2H])c1[2H] ; c1ccc(-c2ccc(-c3cccc4c3oc3cccc(-c5c6ccccc6c(-c6ccccc6)c6ccccc56)c34)cc2)cc1 ; c1ccc(-c2c3ccccc3c(-c3cccc4oc5c(-c6ccc7c(ccc8ccccc87)c6)cccc5c34)c3ccccc23)cc1]

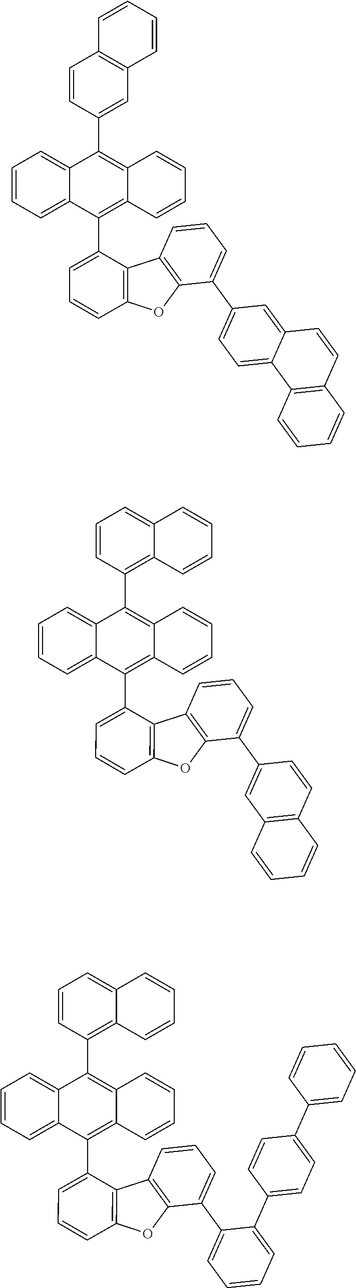 [SMILES: c1ccc2cc(-c3c4ccccc4c(-c4cccc5oc6c(-c7ccc8c(ccc9ccccc98)c7)cccc6c45)c4ccccc34)ccc2c1 ; c1ccc2cc(-c3cccc4c3oc3cccc(-c5c6ccccc6c(-c6cccc7ccccc67)c6ccccc56)c34)ccc2c1 ; c1ccc(-c2ccc(-c3ccccc3-c3cccc4c3oc3cccc(-c5c6ccccc6c(-c6cccc7ccccc67)c6ccccc56)c34)cc2)cc1]

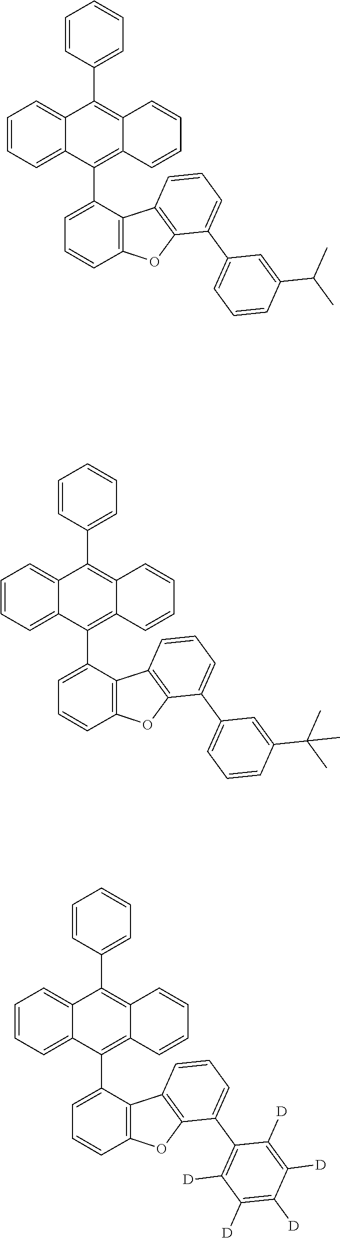 [SMILES: CC(C)c1cccc(-c2cccc3c2oc2cccc(-c4c5ccccc5c(-c5ccccc5)c5ccccc45)c23)c1 ; CC(C)(C)c1cccc(-c2cccc3c2oc2cccc(-c4c5ccccc5c(-c5ccccc5)c5ccccc45)c23)c1 ; [2H]c1c([2H])c([2H])c(-c2cccc3c2oc2cccc(-c4c5ccccc5c(-c5ccccc5)c5ccccc45)c23)c([2H])c1[2H]]

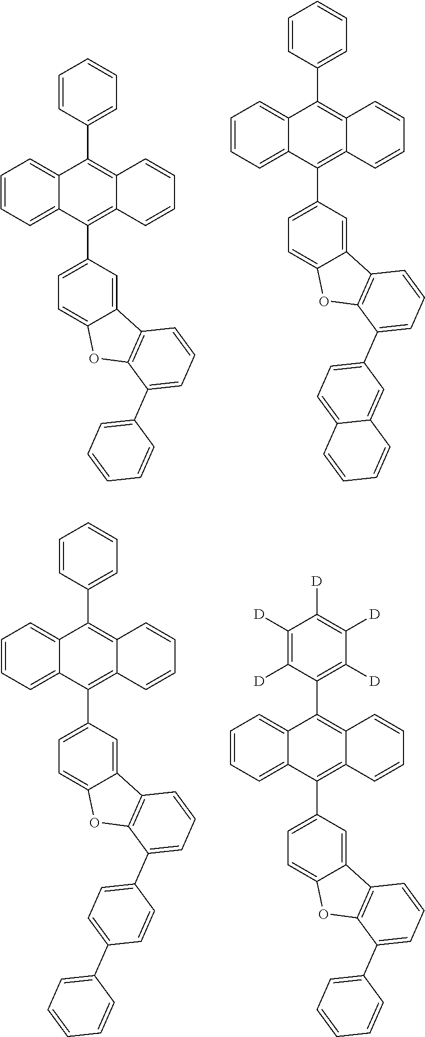

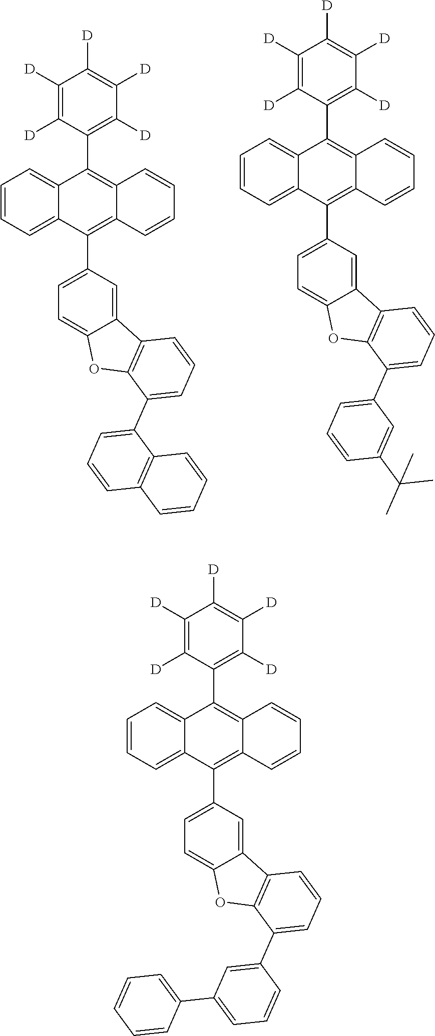 [SMILES: [2H]c1c([2H])c([2H])c(-c2c3ccccc3c(-c3ccc4oc5c(-c6cccc7ccccc67)cccc5c4c3)c3ccccc23)c([2H])c1[2H] ; [2H]c1c([2H])c([2H])c(-c2c3ccccc3c(-c3ccc4oc5c(-c6cccc(C(C)(C)C)c6)cccc5c4c3)c3ccccc23)c([2H])c1[2H] ; [2H]c1c([2H])c([2H])c(-c2c3ccccc3c(-c3ccc4oc5c(-c6cccc(-c7ccccc7)c6)cccc5c4c3)c3ccccc23)c([2H])c1[2H]]

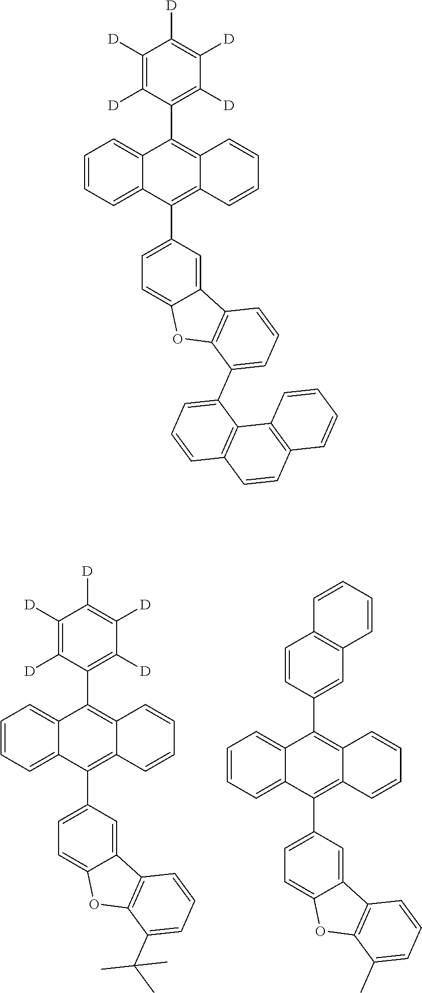 [SMILES: [2H]c1c([2H])c([2H])c(-c2c3ccccc3c(-c3ccc4oc5c(-c6cccc7ccc8ccccc8c67)cccc5c4c3)c3ccccc23)c([2H])c1[2H] ; [2H]c1c([2H])c([2H])c(-c2c3ccccc3c(-c3ccc4oc5c(C(C)(C)C)cccc5c4c3)c3ccccc23)c([2H])c1[2H] ; Cc1cccc2c1oc1ccc(-c3c4ccccc4c(-c4ccc5ccccc5c4)c4ccccc34)cc12]

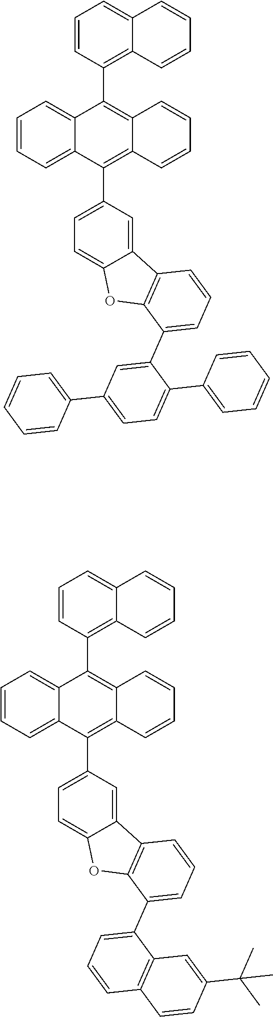 [SMILES: c1ccc(-c2ccc(-c3ccccc3)c(-c3cccc4c3oc3ccc(-c5c6ccccc6c(-c6cccc7ccccc67)c6ccccc56)cc34)c2)cc1 ; CC(C)(C)c1ccc2cccc(-c3cccc4c3oc3ccc(-c5c6ccccc6c(-c6cccc7ccccc67)c6ccccc56)cc34)c2c1]

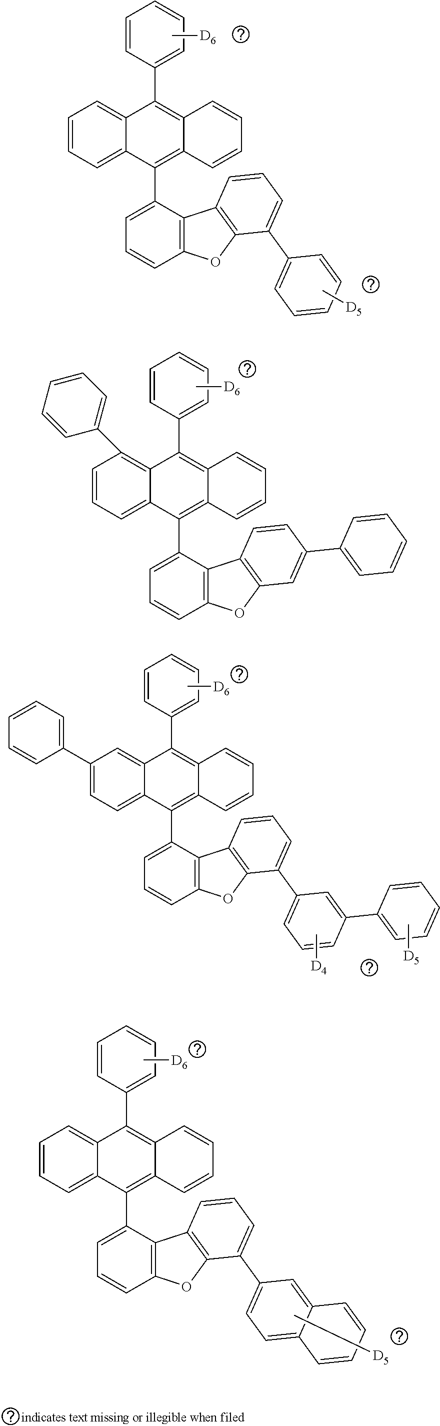

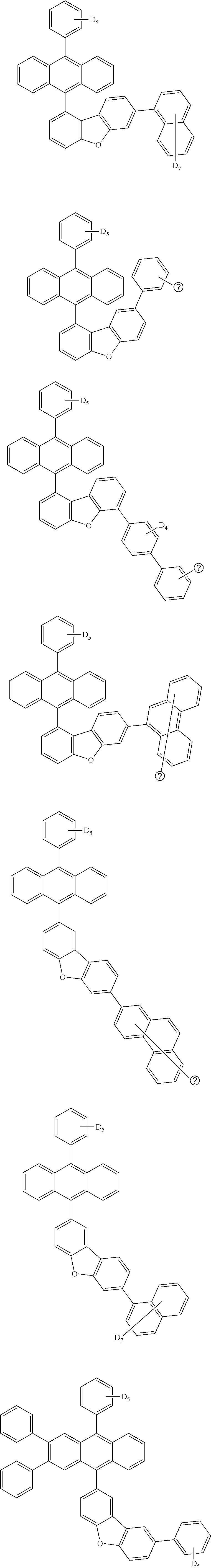

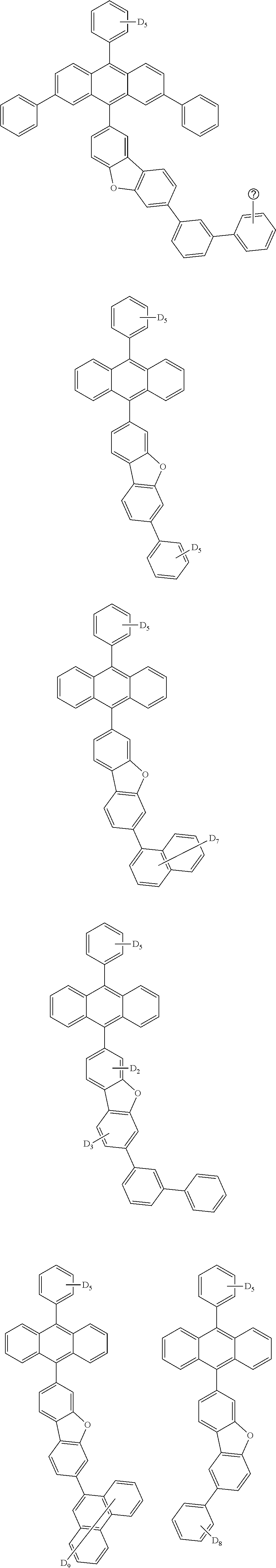

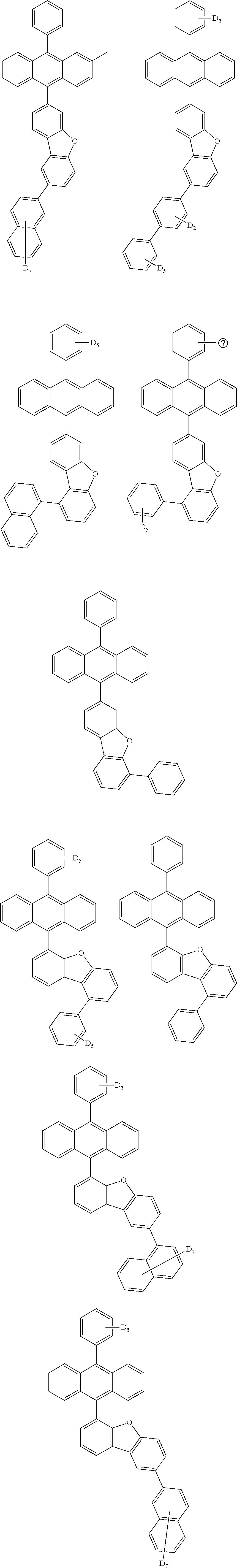

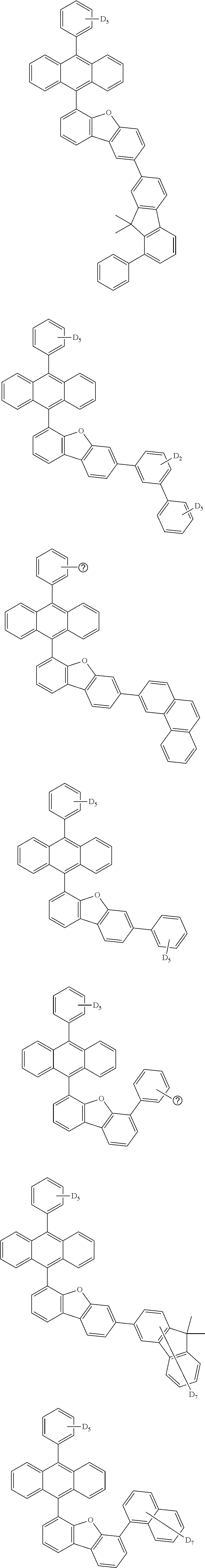

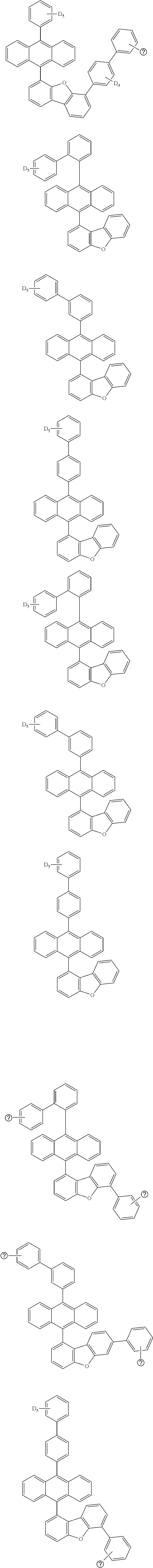

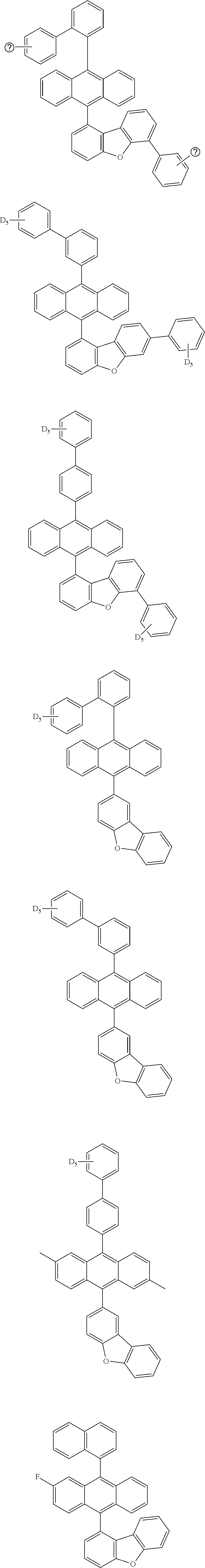

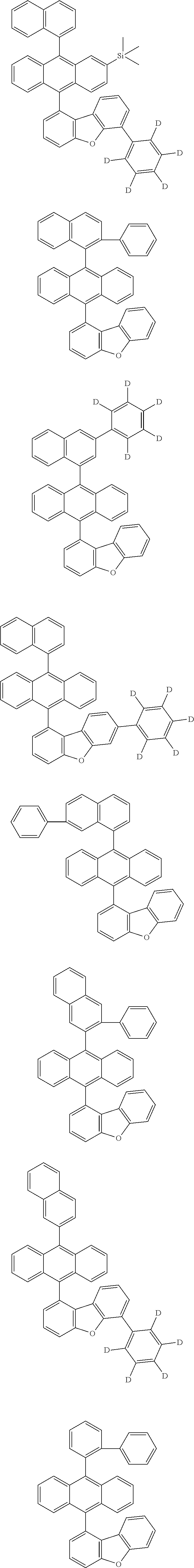

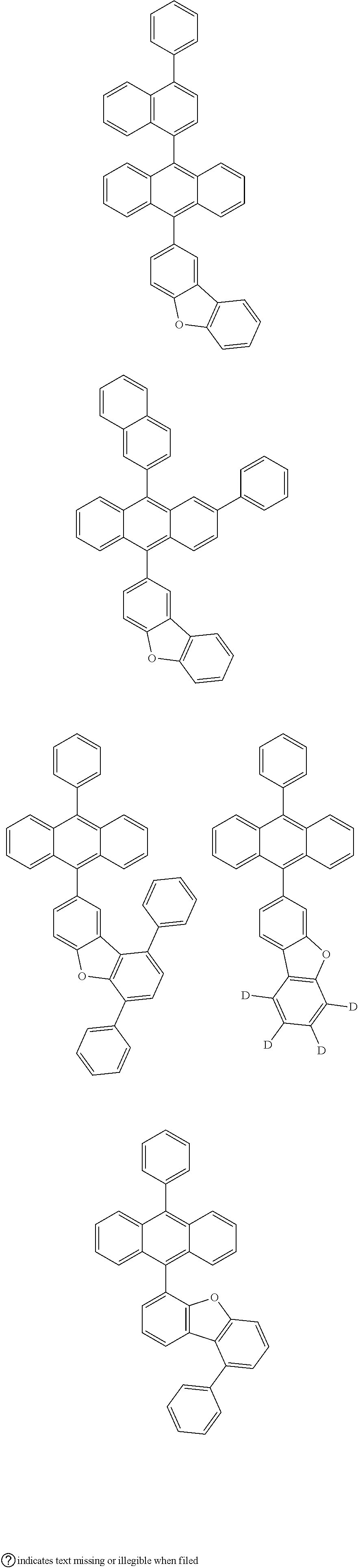 [SMILES: c1ccc(-c2ccc(-c3c4ccccc4c(-c4ccc5oc6ccccc6c5c4)c4ccccc34)c3ccccc23)cc1 ; c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5c(-c6ccccc6)ccc(-c6ccccc6)c5c4c3)c3ccccc23)cc1 ; [2H]c1c([2H])c([2H])c2c(oc3cc(-c4c5ccccc5c(-c5ccccc5)c5ccccc45)ccc32)c1[2H] ; c1ccc(-c2c3ccccc3c(-c3cccc4c3oc3cccc(-c5ccccc5)c34)c3ccccc23)cc1]

However, these compounds are not intended to limit the scope of Formula B.

According to one embodiment of the present invention, the light emitting layer including the compound represented by Formula A-1 or A-2 may have an electroluminescence (EL) maximum peak at a wavelength of 454 nm or less, preferably 440 nm to 454 nm.

The electroluminescence (EL) spectrum is the product of a photoluminescence (PL) spectrum reflecting the inherent characteristics of a host compound or a dopant compound present in a light emitting layer and an out-coupling emittance spectrum determined by the structure and optical properties of an organic electroluminescent device having other organic layers such as an electron transport layer. The peak wavelength refers to the wavelength of a peak with a maximum intensity in the PL or EL spectrum.

According to one embodiment of the present invention, the light emitting layer including the compound represented by Formula A-1 or A-2 may have an EL maximum peak at a wavelength of 454 nm or less. In this embodiment, deep blue light emission can be achieved.

In addition to the blue light emitting layer, the organic electroluminescent device of the present invention may include a plurality of blue light emitting layers having different wavelength bands. The organic electroluminescent device of the present invention may further include a red light emitting layer, a green light emitting layer, and a yellow light emitting layer.

The compound of the present invention may be employed in a blue light emitting layer of a quantum dot organic electroluminescent device in which a quantum dot layer as well as a light emitting phosphor layer is formed on the light emitting surface, enabling the organic electroluminescent device to emit deep blue light with high efficiency.

A detailed structure of the organic electroluminescent device according to one embodiment of the present invention, a method for fabricating the device, and materials for the organic layers are as follows.

First, an anode material is coated on a substrate to form an anode. The substrate may be any of those used in general electroluminescent devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

A hole injecting material is coated on the anode by vacuum thermal evaporation or spin coating to form a hole injecting layer. Then, a hole transport material is coated on the hole injecting layer by vacuum thermal evaporation or spin coating to form a hole transport layer.

The hole injecting material is not specially limited so long as it is usually used in the art. Specific examples of such materials include 4,4′,4″-tris(2-naphthylphenyl-phenylamino)triphenylamine (2-TNATA), N,N′-di(1-naphthyl)-N,N′-diphenylbenzidine (NPD), N,N′-diphenyl-N,N′-bis(3-methylphenyl)-1,1′-biphenyl-4,4′-diamine (TPD), N,N′-diphenyl-N,N′-bis(4-(phenyl-m-tolylamino)phenyl)biphenyl-4,4′-diamine (DNTPD), and 1,4,5,8,9,11-hexaazatriphenylenehexacarbonitrile (HAT-CN).

The hole transport material is not specially limited so long as it is commonly used in the art. Examples of such materials include N,N′-bis(3-methylphenyl)-N,N′-diphenyl-(1,1-biphenyl)-4,4′-diamine (TPD) and N,N′-di(naphthalen-1-yl)-N,N′-diphenylbenzidine (α-NPD).

Subsequently, a hole auxiliary layer and a light emitting layer are sequentially laminated on the hole transport layer. A hole blocking layer may be optionally formed on the light emitting layer by vacuum thermal evaporation or spin coating. The hole blocking layer is formed as a thin film and blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it can transport electrons and has a higher ionization potential than the light emitting compound. Representative examples of suitable hole blocking materials include BAlq, BCP, and TPBI.

Examples of materials for the hole blocking layer include, but are not limited to, BAlq, BCP, Bphen, TPBI, NTAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode, completing the fabrication of the organic electroluminescent device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic electroluminescent device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolate)aluminum (Alq3), TAZ, Balq, beryllium bis(benzoquinolin-10-olate (Bebq2), and oxadiazole derivatives such as PBD, BMD, and BND.

Each of the organic layers can be formed by a monomolecular deposition or solution process. According to the monomolecular deposition process, the material for each layer is evaporated into a thin film under heat and vacuum or reduced pressure. According to the solution process, the material for each layer is mixed with a suitable solvent, and then the mixture is formed into a thin film by a suitable method such as ink-jet printing, roll-to-roll coating, screen printing, spray coating, dip coating or spin coating.

The organic electroluminescent device of the present invention can be used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.

### BEST MODE FOR CARRYING OUT THE INVENTION

### Synthesis Example 1: Synthesis of Compound 12

### Synthesis Example 1-1: Synthesis of Intermediate A-1

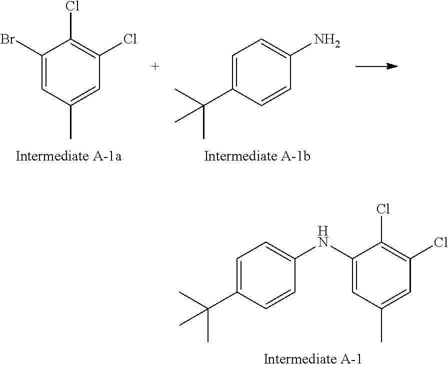

35 g of Intermediate A-1a, 23.9 g of Intermediate A-1b, 2.67 g of tris (dibenzylideneacetone)dipalladium(0), 1.82 g of bis(diphenylphosphino)-1,1′-binaphthyl, 28 g of sodium tert-butoxide, and 450 mL of toluene were placed in a reactor. The mixture was stirred under reflux for 3 h. The reaction mixture was cooled to room temperature and ethyl acetate and water were added thereto. The organic layer was separated and purified by silica gel chromatography to afford Intermediate A-1 (40.5 g, 90.1%).

### Synthesis Example 1-2: Synthesis of Intermediate A-2

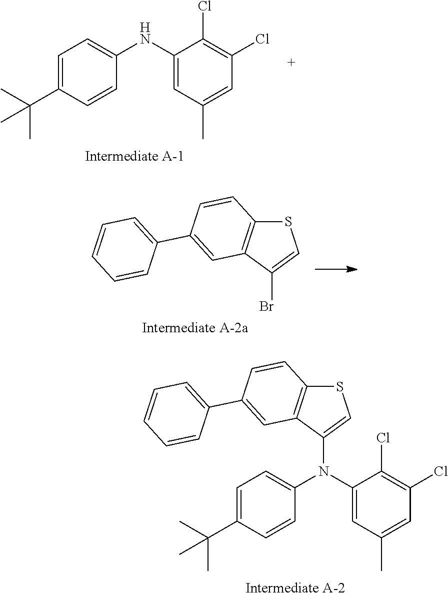 [SMILES: Cc1cc(Cl)c(Cl)c(Nc2ccc(C(C)(C)C)cc2)c1 ; Brc1csc2ccc(-c3ccccc3)cc12 ; Cc1cc(Cl)c(Cl)c(N(c2ccc(C(C)(C)C)cc2)c2csc3ccc(-c4ccccc4)cc23)c1]

24 g of Intermediate A-1, 24.8 g of Intermediate A-2a, 0.8 g of bis(tri-tert-butylphosphine)palladium(0), 12 g of sodium tert-butoxide, and 350 mL of toluene were placed in a reactor. The mixture was stirred under reflux for 6 h. The reaction mixture was cooled to room temperature and ethyl acetate and water were added thereto. The organic layer was separated and purified by silica gel chromatography to afford Intermediate A-2 (35.2 g, 87.5%).

### Synthesis Example 1-3: Synthesis of Intermediate A-3

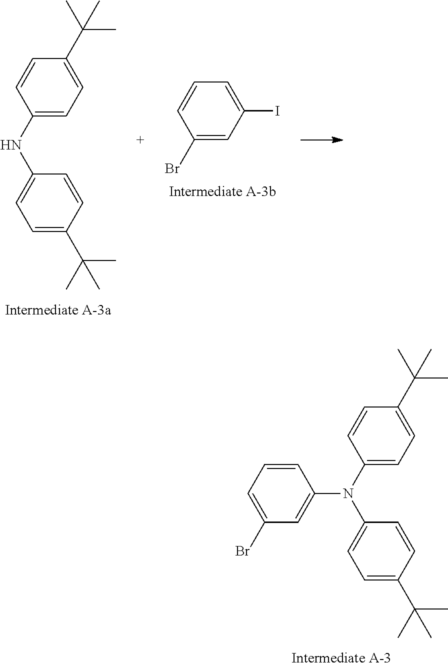 [SMILES: CC(C)(C)c1ccc(Nc2ccc(C(C)(C)C)cc2)cc1 ; Brc1cccc(I)c1 ; CC(C)(C)c1ccc(N(c2ccc(C(C)(C)C)cc2)c2cccc(Br)c2)cc1]

50 g of Intermediate A-3a, 60.3 g of Intermediate A-3b, 0.4 g of palladium(II) acetate, 25.6 g of sodium tert-butoxide, 1 g of Xantphos, and 500 mL of toluene were placed in a reactor. The mixture was stirred under reflux for 16 h. The reaction mixture was cooled to room temperature and ethyl acetate and water were added thereto. The organic layer was separated and purified by silica gel chromatography to afford Intermediate A-3 (59.6 g, 76.9%).

### Synthesis Example 1-4: Synthesis of Intermediate A-4

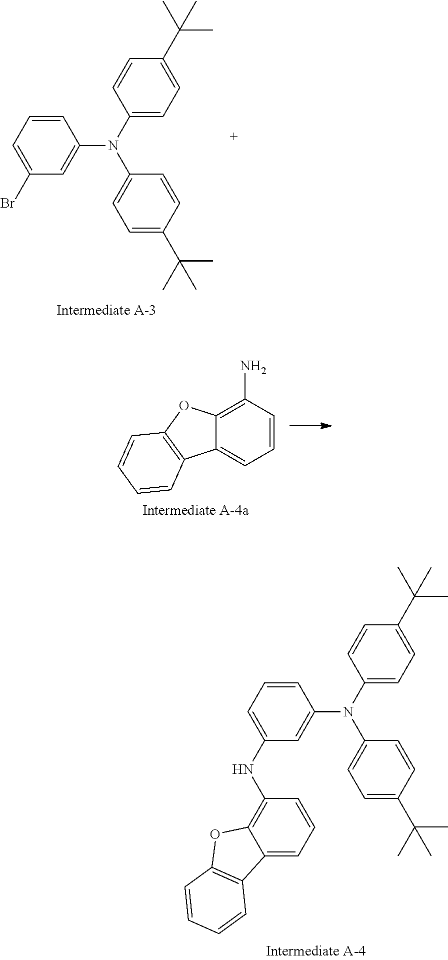 [SMILES: CC(C)(C)c1ccc(N(c2ccc(C(C)(C)C)cc2)c2cccc(Br)c2)cc1 ; Nc1cccc2c1oc1ccccc12 ; CC(C)(C)c1ccc(N(c2ccc(C(C)(C)C)cc2)c2cccc(Nc3cccc4c3oc3ccccc34)c2)cc1]

50 g of Intermediate A-3, 23.1 g of Intermediate A-4a, 2.1 g of tris(dibenzylideneacetone)dipalladium(0), 1.43 g of bis(diphenylphosphino)-1,1′-binaphthyl, 22 g of sodium tert-butoxide, and 500 mL of toluene were placed in a reactor. The mixture was stirred under reflux for 16 h. The reaction mixture was cooled to room temperature and ethyl acetate and water were added thereto. The organic layer was separated and purified by silica gel chromatography to afford Intermediate A-4 (43.4 g, 70.3%).

### Synthesis Example 1-5: Synthesis of Intermediate A-5

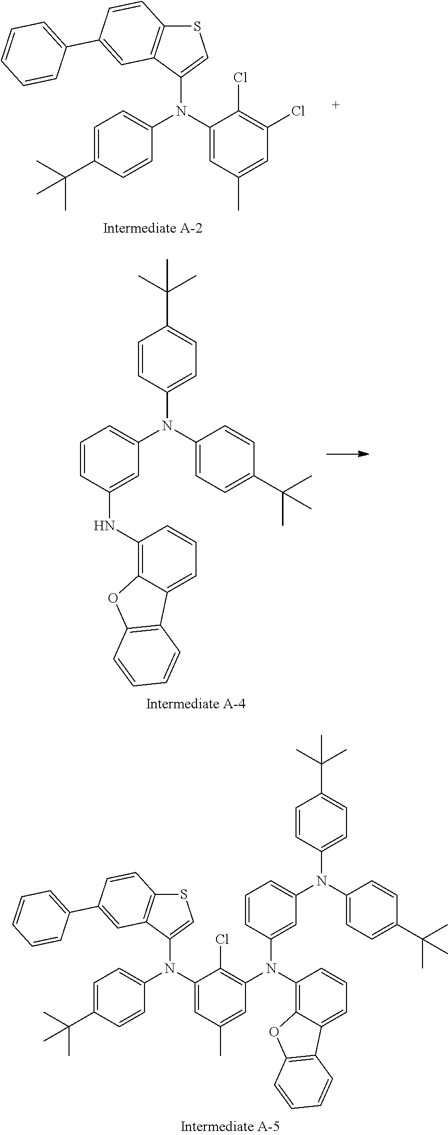 [SMILES: Cc1cc(Cl)c(Cl)c(N(c2ccc(C(C)(C)C)cc2)c2csc3ccc(-c4ccccc4)cc23)c1 ; CC(C)(C)c1ccc(N(c2ccc(C(C)(C)C)cc2)c2cccc(Nc3cccc4c3oc3ccccc34)c2)cc1 ; Cc1cc(N(c2ccc(C(C)(C)C)cc2)c2csc3ccc(-c4ccccc4)cc23)c(Cl)c(N(c2cccc(N(c3ccc(C(C)(C)C)cc3)c3ccc(C(C)(C)C)cc3)c2)c2cccc3c2oc2ccccc23)c1]

32 g of Intermediate A-2, 34.4 g of Intermediate A-4, 0.63 g of bis(tri-tert-butylphosphine)palladium(0), 11.9 g of sodium tert-butoxide, and 300 mL of toluene were placed in a reactor. The mixture was stirred under reflux for 16 h. The reaction mixture was cooled to room temperature and ethyl acetate and water were added thereto. The organic layer was separated and purified by silica gel chromatography to afford Intermediate A-5 (50.5 g, 80%).

### Synthesis Example 1-6: Synthesis of Compound 12

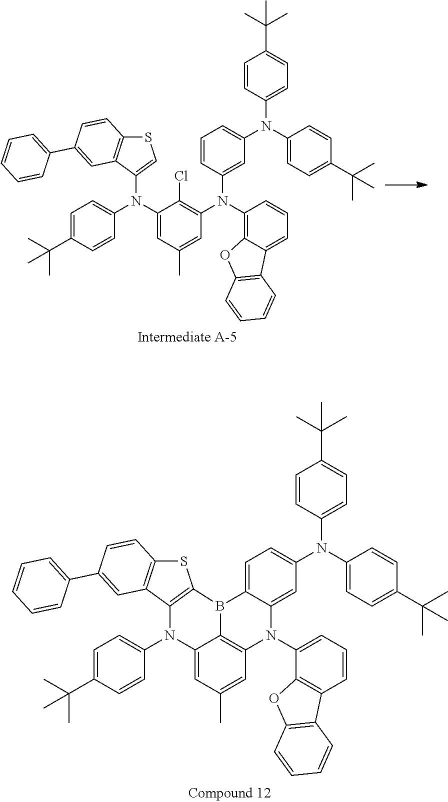 [SMILES: Cc1cc(N(c2ccc(C(C)(C)C)cc2)c2csc3ccc(-c4ccccc4)cc23)c(Cl)c(N(c2cccc(N(c3ccc(C(C)(C)C)cc3)c3ccc(C(C)(C)C)cc3)c2)c2cccc3c2oc2ccccc23)c1 ; Cc1cc2c3c(c1)N(c1cccc4c1oc1ccccc14)c1cc(N(c4ccc(C(C)(C)C)cc4)c4ccc(C(C)(C)C)cc4)ccc1B3c1sc3ccc(-c4ccccc4)cc3c1N2c1ccc(C(C)(C)C)cc1]

48 g of Intermediate A-5 and 300 mL of tert-butylbenzene were placed in a reactor and 83 mL of a 1.7 M tert-butyllithium pentane solution was added dropwise thereto at −78° C. The mixture was heated to 60° C., followed by stirring for 2 h. Then, nitrogen was blown into the mixture at 60° C. to completely remove pentane. After cooling to −78° C., 14.1 mL of boron tribromide was added dropwise. The resulting mixture was allowed to warm to room temperature, followed by stirring for 2 h. After cooling to 0° C., 25 mL of N,N-diisopropylethylamine was added dropwise. The mixture was heated to 120° C., followed by stirring for 16 h. The reaction mixture was cooled to room temperature and a 10% aqueous solution of sodium acetate and ethyl acetate were added thereto. The organic layer was separated, concentrated under reduced pressure, and purified by silica gel chromatography to afford Compound 12 (7.2 g, 15.4%).

MS (MALDI-TOF): m/z 991.47 [M⁺]

### Synthesis Example 2: Synthesis of Compound 13

### Synthesis Example 2-1: Synthesis of Intermediate B-1

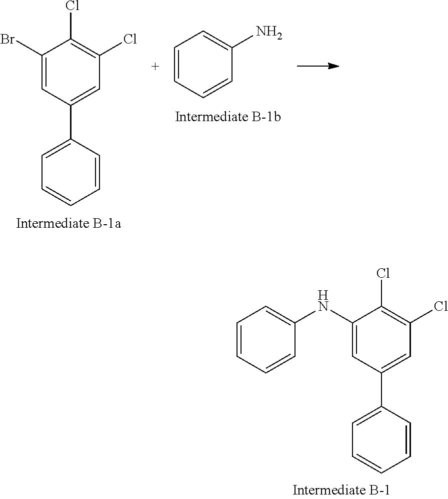 [SMILES: Clc1cc(-c2ccccc2)cc(Br)c1Cl ; Nc1ccccc1 ; Clc1cc(-c2ccccc2)cc(Nc2ccccc2)c1Cl]

Intermediate B-1 (yield 76.2%) was synthesized in the same manner as in Synthesis Example 1-1, except that Intermediate B-1a and Intermediate B-1b were used instead of Intermediate A-1a and Intermediate A-1b, respectively.

### Synthesis Example 2-2: Synthesis of Intermediate B-2

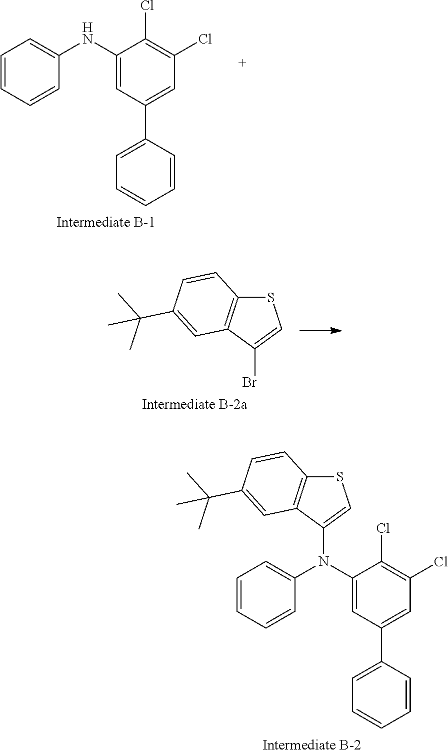 [SMILES: Clc1cc(-c2ccccc2)cc(Nc2ccccc2)c1Cl ; CC(C)(C)c1ccc2scc(Br)c2c1 ; CC(C)(C)c1ccc2scc(N(c3ccccc3)c3cc(-c4ccccc4)cc(Cl)c3Cl)c2c1]

Intermediate B-2 (yield 65.4%) was synthesized in the same manner as in Synthesis Example 1-2, except that Intermediate B-1 and Intermediate B-2a were used instead of Intermediate A-1 and Intermediate A-2a, respectively.

### Synthesis Example 2-3: Synthesis of Intermediate B-3

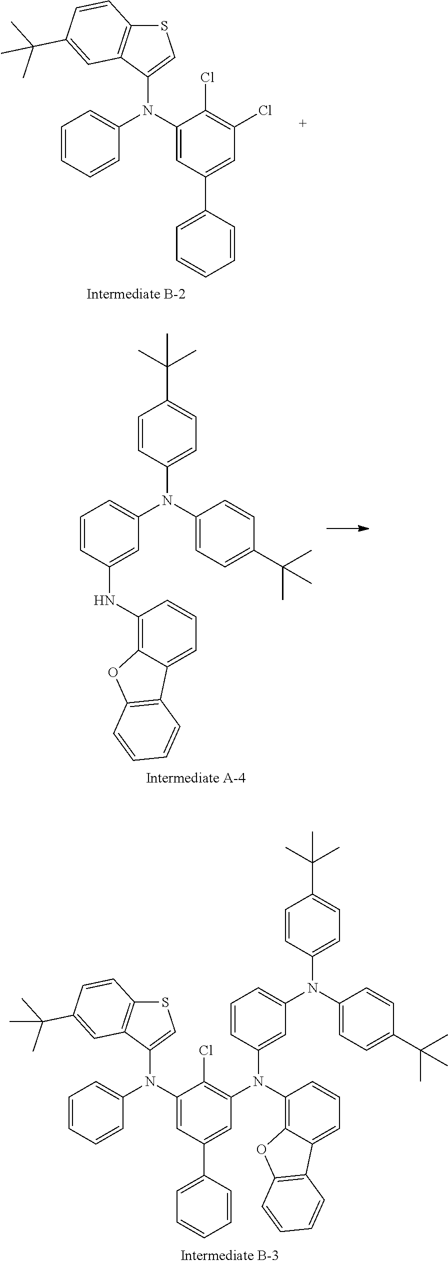 [SMILES: CC(C)(C)c1ccc2scc(N(c3ccccc3)c3cc(-c4ccccc4)cc(Cl)c3Cl)c2c1 ; CC(C)(C)c1ccc(N(c2ccc(C(C)(C)C)cc2)c2cccc(Nc3cccc4c3oc3ccccc34)c2)cc1 ; CC(C)(C)c1ccc(N(c2ccc(C(C)(C)C)cc2)c2cccc(N(c3cc(-c4ccccc4)cc(N(c4ccccc4)c4csc5ccc(C(C)(C)C)cc45)c3Cl)c3cccc4c3oc3ccccc34)c2)cc1]

Intermediate B-3 (yield 93.8%) was synthesized in the same manner as in Synthesis Example 1-5, except that Intermediate B-2 was used instead of Intermediate A-2.

### Synthesis Example 2-4: Synthesis of Compound 13

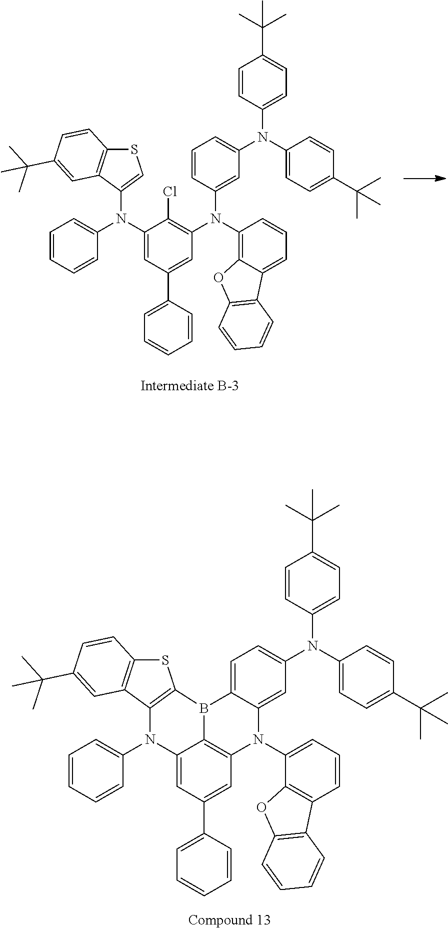

Compound 13 (yield 19.7%) was synthesized in the same manner as in Synthesis Example 1-6, except that Intermediate B-3 was used instead of Intermediate A-5.

MS (MALDI-TOF): m/z 977.46 [M⁺]

### Synthesis Example 3: Synthesis of Compound 73

### Synthesis Example 3-1: Synthesis of Intermediate C-1

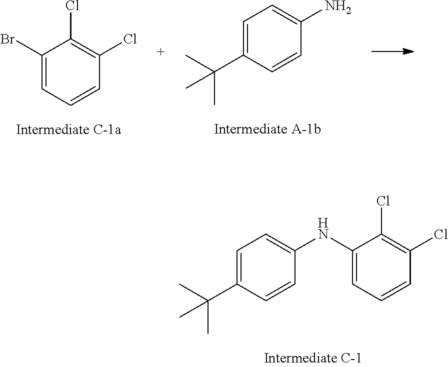 [SMILES: Clc1cccc(Br)c1Cl ; CC(C)(C)c1ccc(N)cc1 ; CC(C)(C)c1ccc(Nc2cccc(Cl)c2Cl)cc1]

Intermediate C-1 (yield 72.1%) was synthesized in the same manner as in Synthesis Example 1-1, except that Intermediate C-1a was used instead of Intermediate A-1a.

### Synthesis Example 3-2: Synthesis of Intermediate C-2

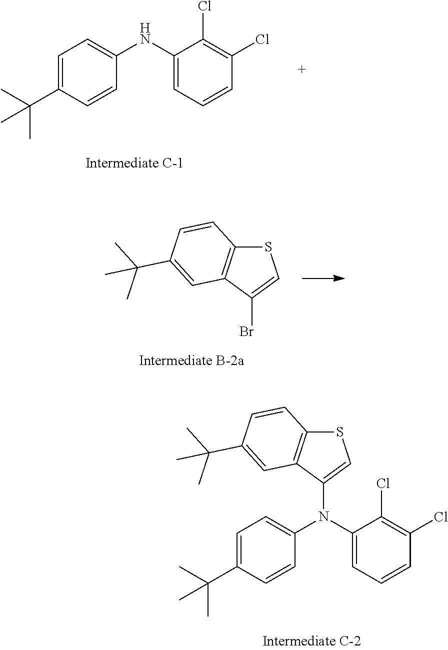 [SMILES: CC(C)(C)c1ccc(Nc2cccc(Cl)c2Cl)cc1 ; CC(C)(C)c1ccc2scc(Br)c2c1 ; CC(C)(C)c1ccc(N(c2cccc(Cl)c2Cl)c2csc3ccc(C(C)(C)C)cc23)cc1]

Intermediate C-2 (yield 78.3%) was synthesized in the same manner as in Synthesis Example 2-2, except that Intermediate C-1 was used instead of Intermediate B-1.

### Synthesis Example 3-3: Synthesis of Intermediate C-3

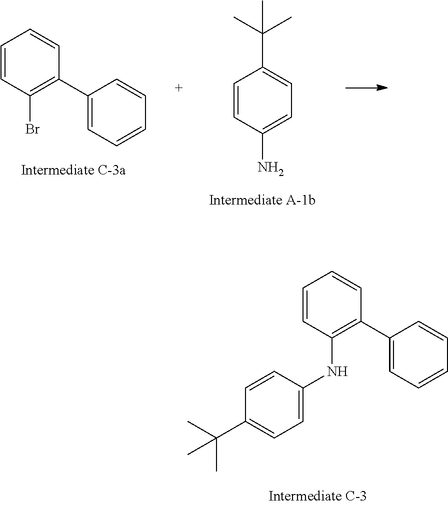 [SMILES: Brc1ccccc1-c1ccccc1 ; CC(C)(C)c1ccc(N)cc1 ; CC(C)(C)c1ccc(Nc2ccccc2-c2ccccc2)cc1]

Intermediate C-3 (yield 85.1%) was synthesized in the same manner as in Synthesis Example 1-1, except that Intermediate C-3a was used instead of Intermediate A-1a.

### Synthesis Example 3-4: Synthesis of Intermediate C-4

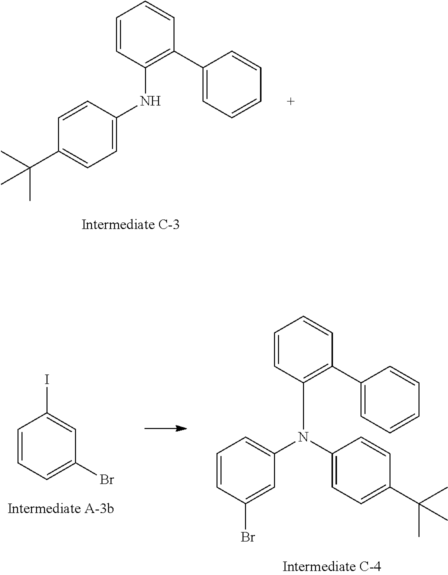 [SMILES: CC(C)(C)c1ccc(Nc2ccccc2-c2ccccc2)cc1 ; Brc1cccc(I)c1 ; CC(C)(C)c1ccc(N(c2cccc(Br)c2)c2ccccc2-c2ccccc2)cc1]

Intermediate C-4 (yield 46.2%) was synthesized in the same manner as in Synthesis Example 1-3, except that Intermediate C-3 was used instead of Intermediate A-3a.

### Synthesis Example 3-5: Synthesis of Intermediate C-5

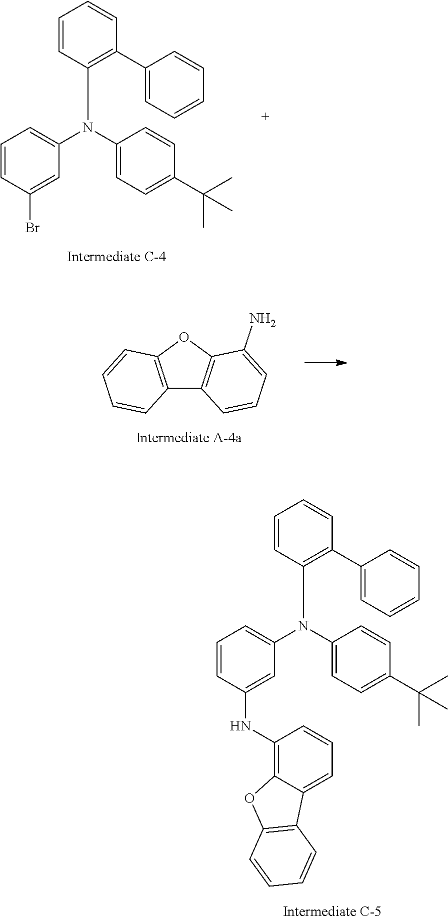 [SMILES: CC(C)(C)c1ccc(N(c2cccc(Br)c2)c2ccccc2-c2ccccc2)cc1 ; Nc1cccc2c1oc1ccccc12 ; CC(C)(C)c1ccc(N(c2cccc(Nc3cccc4c3oc3ccccc34)c2)c2ccccc2-c2ccccc2)cc1]

Intermediate C-5 (yield 90.4%) was synthesized in the same manner as in Synthesis Example 1-4, except that Intermediate C-4 was used instead of Intermediate A-3.

### Synthesis Example 3-6: Synthesis of Intermediate C-6

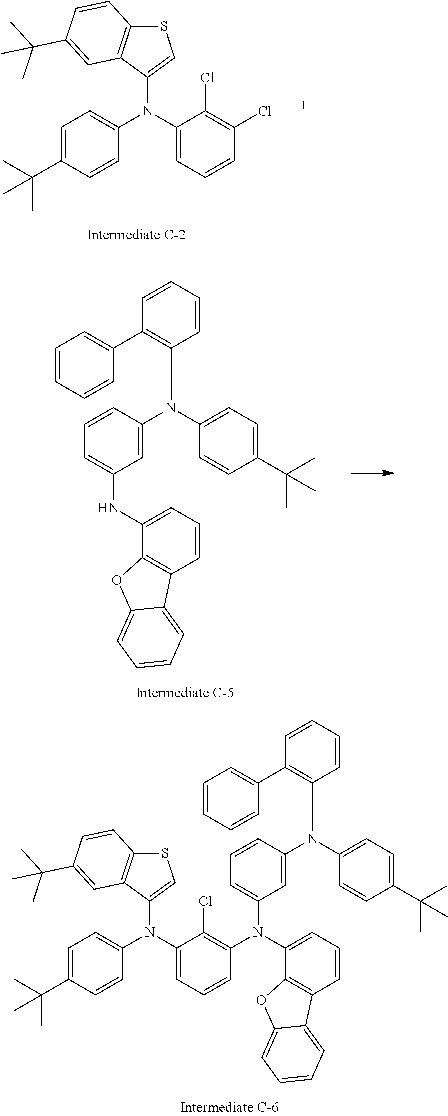 [SMILES: CC(C)(C)c1ccc(N(c2cccc(Cl)c2Cl)c2csc3ccc(C(C)(C)C)cc23)cc1 ; CC(C)(C)c1ccc(N(c2cccc(Nc3cccc4c3oc3ccccc34)c2)c2ccccc2-c2ccccc2)cc1 ; CC(C)(C)c1ccc(N(c2cccc(N(c3cccc(N(c4ccc(C(C)(C)C)cc4)c4csc5ccc(C(C)(C)C)cc45)c3Cl)c3cccc4c3oc3ccccc34)c2)c2ccccc2-c2ccccc2)cc1]

Intermediate C-6 (yield 81.6%) was synthesized in the same manner as in Synthesis Example 1-5, except that Intermediate C-2 and Intermediate C-5 were used instead of Intermediate A-2 and Intermediate A-4, respectively.

### Synthesis Example 3-7: Synthesis of Compound 73

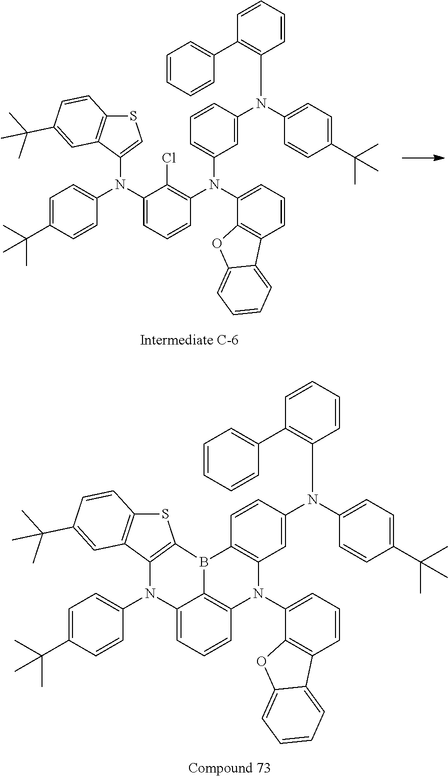

Compound 73 (yield 14.4%) was synthesized in the same manner as in Synthesis Example 1-6, except that Intermediate C-6 was used instead of Intermediate A-5.

MS (MALDI-TOF): m/z 977.46 [M⁺]

### Synthesis Example 4: Synthesis of Compound 76

### Synthesis Example 4-1: Synthesis of Intermediate D-1

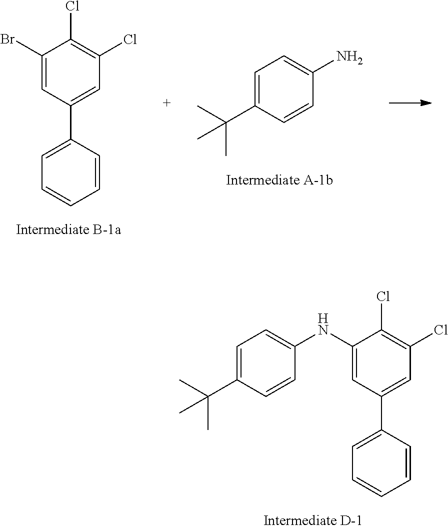 [SMILES: Clc1cc(-c2ccccc2)cc(Br)c1Cl ; CC(C)(C)c1ccc(N)cc1 ; CC(C)(C)c1ccc(Nc2cc(-c3ccccc3)cc(Cl)c2Cl)cc1]

Intermediate D-1 (yield 77.4%) was synthesized in the same manner as in Synthesis Example 1-1, except that Intermediate B-1a was used instead of Intermediate A-1 a.

### Synthesis Example 4-2: Synthesis of Intermediate D-2

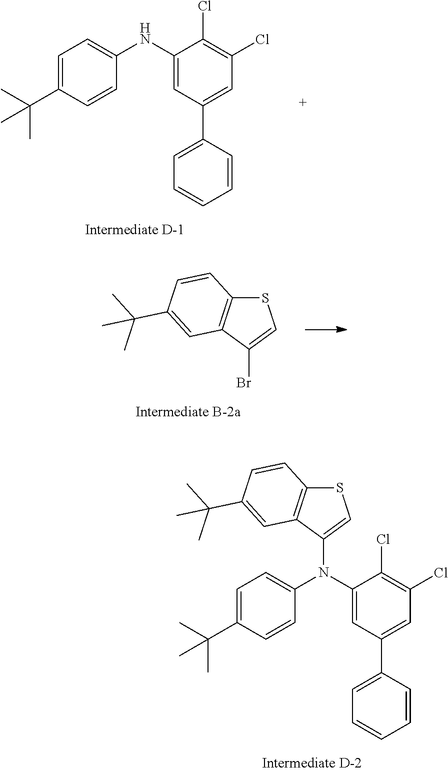 [SMILES: CC(C)(C)c1ccc(Nc2cc(-c3ccccc3)cc(Cl)c2Cl)cc1 ; CC(C)(C)c1ccc2scc(Br)c2c1 ; CC(C)(C)c1ccc(N(c2cc(-c3ccccc3)cc(Cl)c2Cl)c2csc3ccc(C(C)(C)C)cc23)cc1]

Intermediate D-2 (yield 75.1%) was synthesized in the same manner as in Synthesis Example 2-2, except that Intermediate D-1 was used instead of Intermediate B-1.

### Synthesis Example 4-3: Synthesis of Intermediate D-3

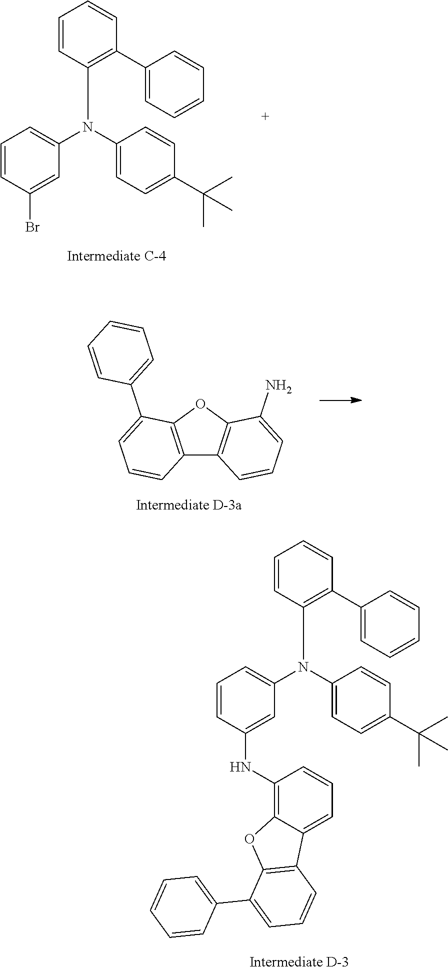 [SMILES: CC(C)(C)c1ccc(N(c2cccc(Br)c2)c2ccccc2-c2ccccc2)cc1 ; Nc1cccc2c1oc1c(-c3ccccc3)cccc12 ; CC(C)(C)c1ccc(N(c2cccc(Nc3cccc4c3oc3c(-c5ccccc5)cccc34)c2)c2ccccc2-c2ccccc2)cc1]

Intermediate D-3 (yield 65.8%) was synthesized in the same manner as in Synthesis Example 1-4, except that Intermediate C-4 and Intermediate D-3a were used instead of Intermediate A-3 and Intermediate A-4a, respectively.

### Synthesis Example 4-4: Synthesis of Intermediate D-4

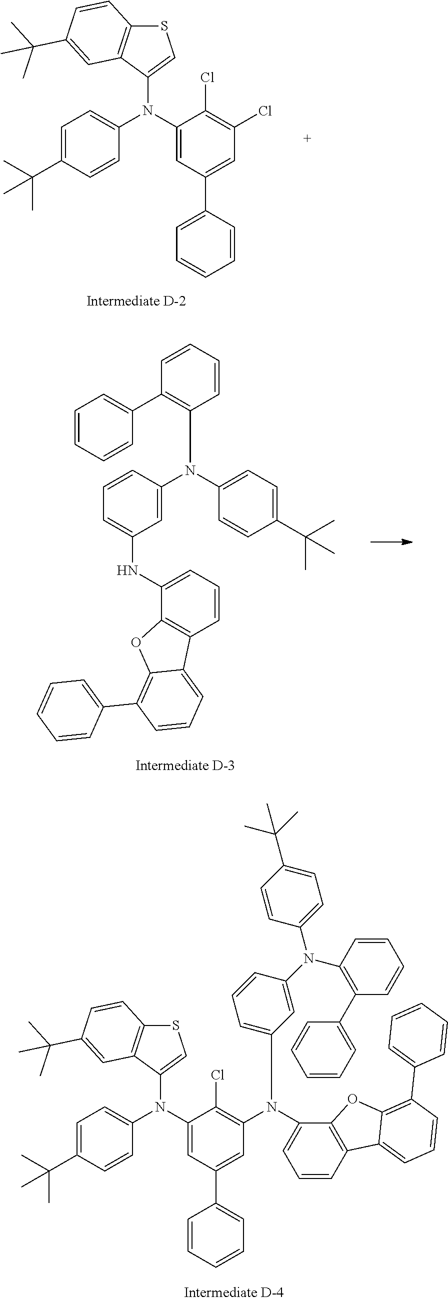

Intermediate D-4 (yield 64.9%) was synthesized in the same manner as in Synthesis Example 1-5, except that Intermediate D-2 and Intermediate D-3 were used instead of Intermediate A-2 and Intermediate A-4, respectively.

### Synthesis Example 4-5: Synthesis of Compound 76

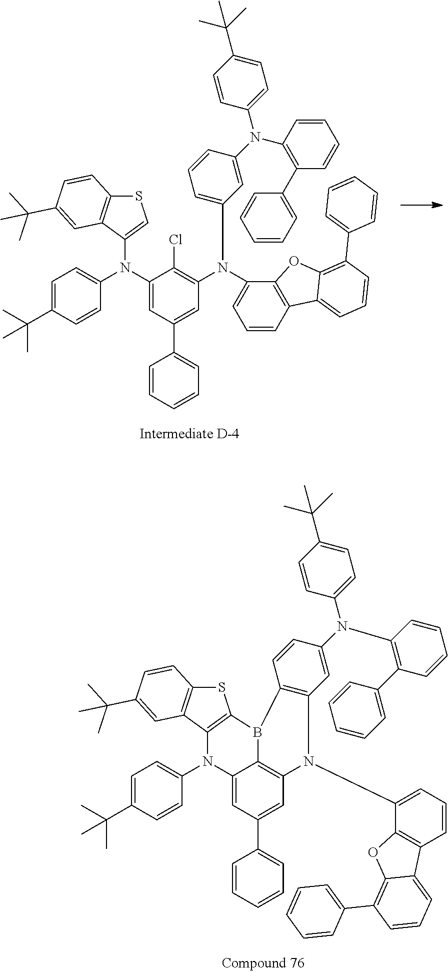 [SMILES: CC(C)(C)c1ccc(N(c2cccc(N(c3cc(-c4ccccc4)cc(N(c4ccc(C(C)(C)C)cc4)c4csc5ccc(C(C)(C)C)cc45)c3Cl)c3cccc4c3oc3c(-c5ccccc5)cccc34)c2)c2ccccc2-c2ccccc2)cc1 ; CC(C)(C)c1ccc(N(c2ccc3c(c2)N(c2cccc4c2oc2c(-c5ccccc5)cccc24)c2cc(-c4ccccc4)cc4c2B3c2sc3ccc(C(C)(C)C)cc3c2N4c2ccc(C(C)(C)C)cc2)c2ccccc2-c2ccccc2)cc1]

Compound 76 (yield 12.2%) was synthesized in the same manner as in Synthesis Example 1-6, except that Intermediate D-4 was used instead of Intermediate A-5.

MS (MALDI-TOF): m/z 1129.52 [M⁺]

### Synthesis Example 5: Synthesis of Compound 106

### Synthesis Example 5-1: Synthesis of Intermediate E-1

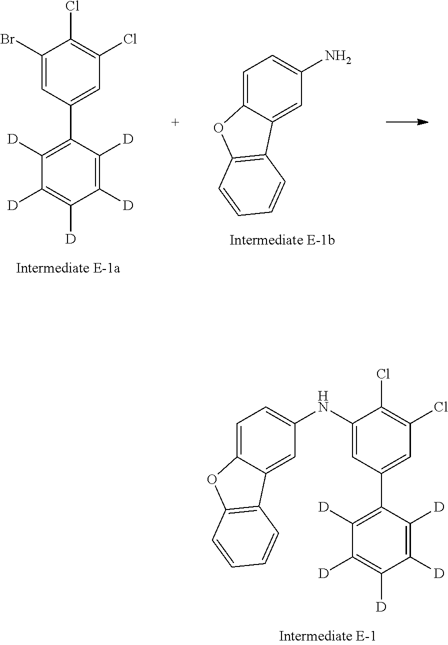 [SMILES: [2H]c1c([2H])c([2H])c(-c2cc(Cl)c(Cl)c(Br)c2)c([2H])c1[2H] ; Nc1ccc2oc3ccccc3c2c1 ; [2H]c1c([2H])c([2H])c(-c2cc(Cl)c(Cl)c(Nc3ccc4oc5ccccc5c4c3)c2)c([2H])c1[2H]]

Intermediate E-1 (yield 73.1%) was synthesized in the same manner as in Synthesis Example 1-1, except that Intermediate E-1 a and Intermediate E-1 b were used instead of Intermediate A-1 a and Intermediate A-1b, respectively.

### Synthesis Example 5-2: Synthesis of Intermediate E-2

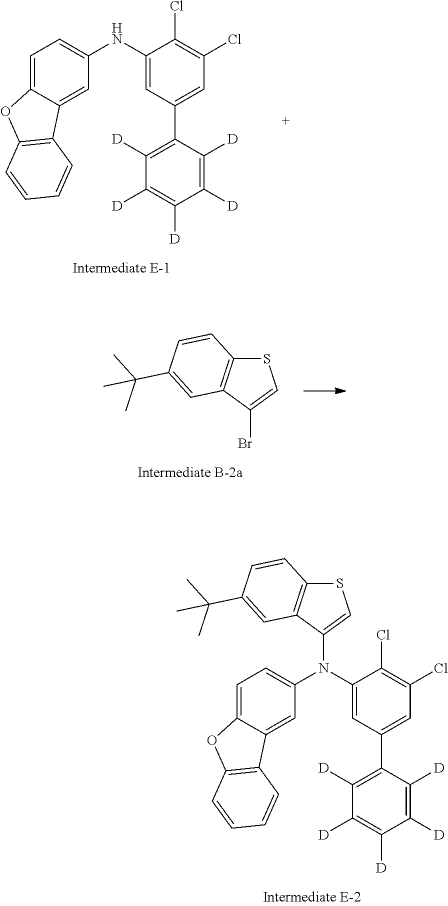 [SMILES: [2H]c1c([2H])c([2H])c(-c2cc(Cl)c(Cl)c(Nc3ccc4oc5ccccc5c4c3)c2)c([2H])c1[2H] ; CC(C)(C)c1ccc2scc(Br)c2c1 ; [2H]c1c([2H])c([2H])c(-c2cc(Cl)c(Cl)c(N(c3ccc4oc5ccccc5c4c3)c3csc4ccc(C(C)(C)C)cc34)c2)c([2H])c1[2H]]

Intermediate E-2 (yield 63.2%) was synthesized in the same manner as in Synthesis Example 1-2, except that Intermediate E-1 and Intermediate B-2a were used instead of Intermediate A-1 and Intermediate A-2a, respectively.

### Synthesis Example 5-3: Synthesis of Intermediate E-3

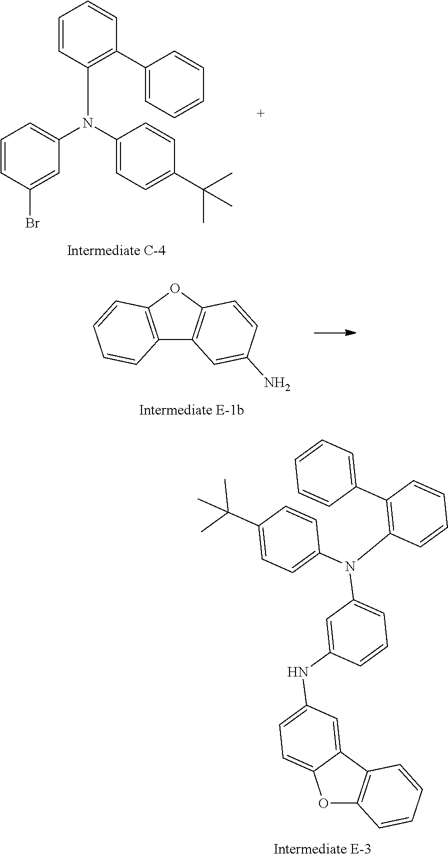 [SMILES: CC(C)(C)c1ccc(N(c2cccc(Br)c2)c2ccccc2-c2ccccc2)cc1 ; Nc1ccc2oc3ccccc3c2c1 ; CC(C)(C)c1ccc(N(c2cccc(Nc3ccc4oc5ccccc5c4c3)c2)c2ccccc2-c2ccccc2)cc1]

Intermediate E-3 (yield 82.1%) was synthesized in the same manner as in Synthesis Example 3-5, except that Intermediate E-1b was used instead of Intermediate A-4a.

### Synthesis Example 5-4: Synthesis of Intermediate E-4

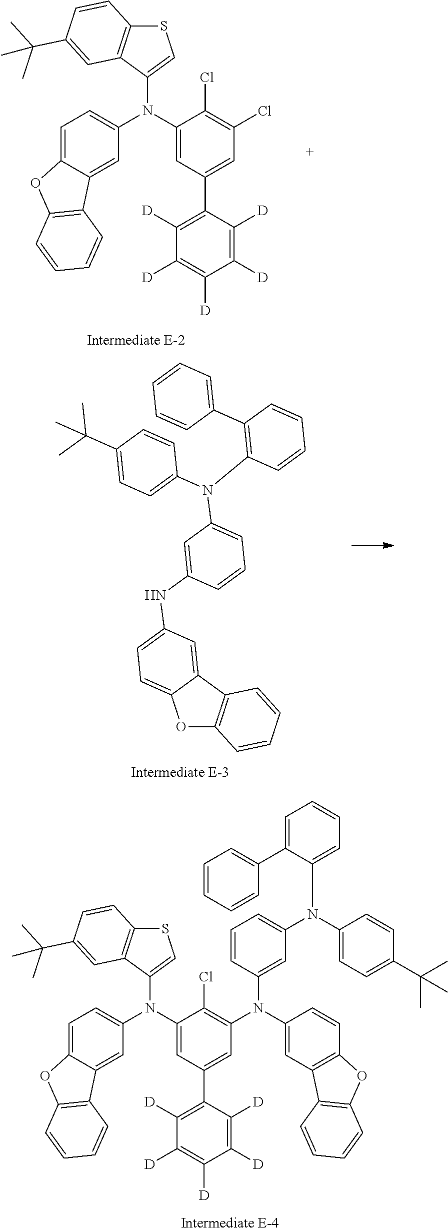 [SMILES: [2H]c1c([2H])c([2H])c(-c2cc(Cl)c(Cl)c(N(c3ccc4oc5ccccc5c4c3)c3csc4ccc(C(C)(C)C)cc34)c2)c([2H])c1[2H] ; CC(C)(C)c1ccc(N(c2cccc(Nc3ccc4oc5ccccc5c4c3)c2)c2ccccc2-c2ccccc2)cc1 ; [2H]c1c([2H])c([2H])c(-c2cc(N(c3cccc(N(c4ccc(C(C)(C)C)cc4)c4ccccc4-c4ccccc4)c3)c3ccc4oc5ccccc5c4c3)c(Cl)c(N(c3ccc4oc5ccccc5c4c3)c3csc4ccc(C(C)(C)C)cc34)c2)c([2H])c1[2H]]

Intermediate E-4 (yield 75.3%) was synthesized in the same manner as in Synthesis Example 1-5, except that Intermediate E-2 and Intermediate E-3 were used instead of Intermediate A-2 and Intermediate A-4, respectively.

### Synthesis Example 5-5: Synthesis of Compound 106

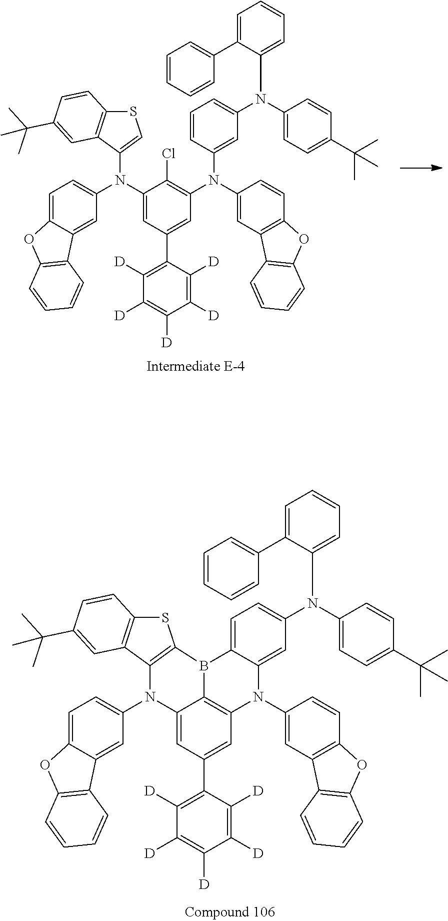

Compound 106 (yield 14.2%) was synthesized in the same manner as in Synthesis Example 1-6, except that Intermediate E-4 was used instead of Intermediate A-5.

MS (MALDI-TOF): m/z 1092.47 [M⁺]

### Synthesis Example 6: Synthesis of Compound 116

### Synthesis Example 6-1: Synthesis of Intermediate F-1

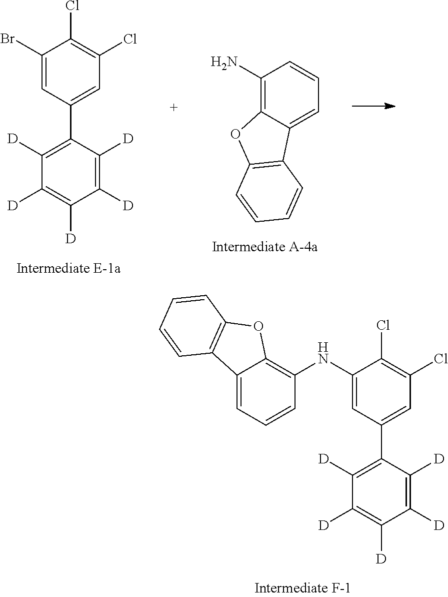 [SMILES: [2H]c1c([2H])c([2H])c(-c2cc(Cl)c(Cl)c(Br)c2)c([2H])c1[2H] ; Nc1cccc2c1oc1ccccc12 ; [2H]c1c([2H])c([2H])c(-c2cc(Cl)c(Cl)c(Nc3cccc4c3oc3ccccc34)c2)c([2H])c1[2H]]

Intermediate F-1 (yield 86.2%) was synthesized in the same manner as in Synthesis Example 1-1, except that Intermediate E-1a and Intermediate A-4a were used instead of Intermediate A-1a and Intermediate A-1b, respectively.

### Synthesis Example 6-2: Synthesis of Intermediate F-2

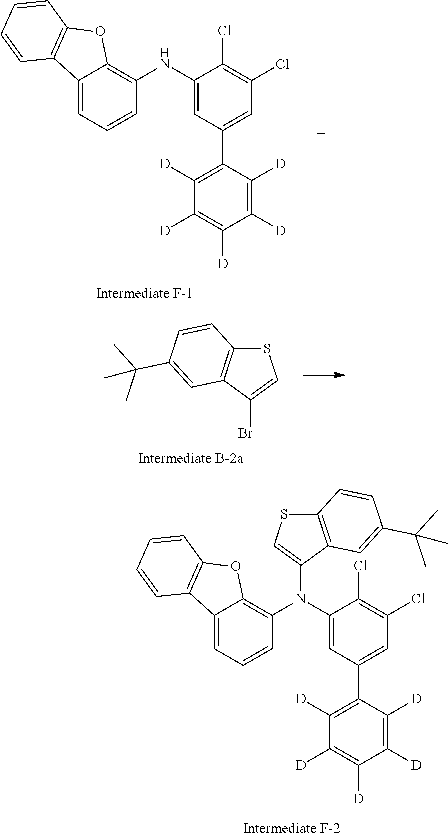 [SMILES: [2H]c1c([2H])c([2H])c(-c2cc(Cl)c(Cl)c(Nc3cccc4c3oc3ccccc34)c2)c([2H])c1[2H] ; CC(C)(C)c1ccc2scc(Br)c2c1 ; [2H]c1c([2H])c([2H])c(-c2cc(Cl)c(Cl)c(N(c3csc4ccc(C(C)(C)C)cc34)c3cccc4c3oc3ccccc34)c2)c([2H])c1[2H]]

Intermediate F-2 (yield 80.3%) was synthesized in the same manner as in Synthesis Example 1-2, except that Intermediate F-1 and Intermediate B-2a were used instead of Intermediate A-1 and Intermediate A-2a, respectively.

### Synthesis Example 6-3: Synthesis of Intermediate F-3

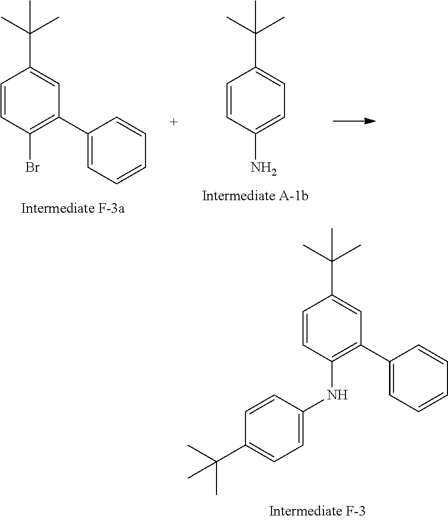 [SMILES: CC(C)(C)c1ccc(Br)c(-c2ccccc2)c1 ; CC(C)(C)c1ccc(N)cc1 ; CC(C)(C)c1ccc(Nc2ccc(C(C)(C)C)cc2-c2ccccc2)cc1]

Intermediate F-3 (yield 92%) was synthesized in the same manner as in Synthesis Example 1-1, except that Intermediate F-3a was used instead of Intermediate A-1 a.

### Synthesis Example 6-4: Synthesis of Intermediate F-4

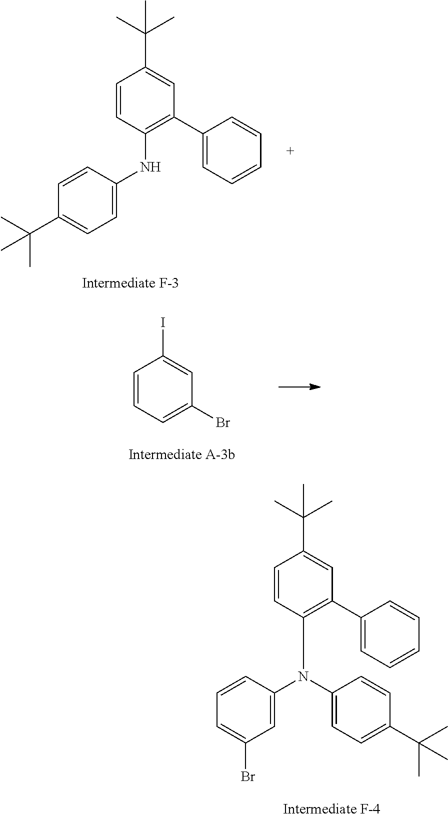 [SMILES: CC(C)(C)c1ccc(Nc2ccc(C(C)(C)C)cc2-c2ccccc2)cc1 ; Brc1cccc(I)c1 ; CC(C)(C)c1ccc(N(c2cccc(Br)c2)c2ccc(C(C)(C)C)cc2-c2ccccc2)cc1]

Intermediate F-4 (yield 45.2%) was synthesized in the same manner as in Synthesis Example 1-3, except that Intermediate F-3 was used instead of Intermediate A-3a.

### Synthesis Example 6-5: Synthesis of Intermediate F-5

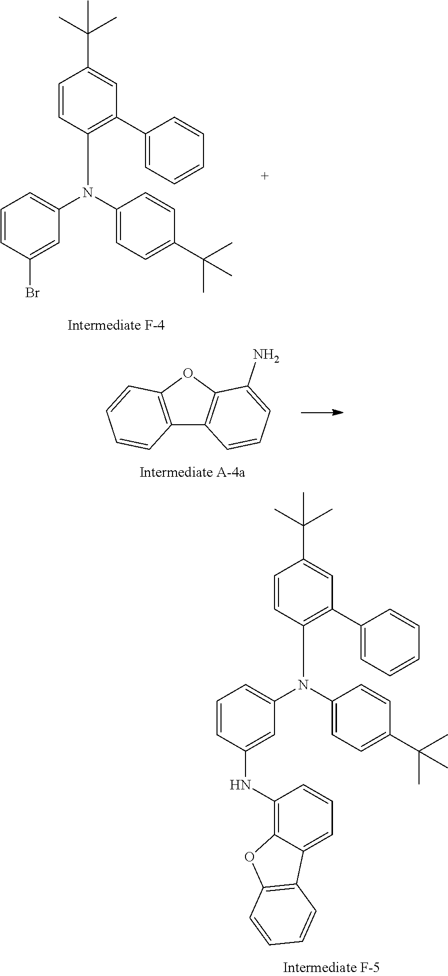 [SMILES: CC(C)(C)c1ccc(N(c2cccc(Br)c2)c2ccc(C(C)(C)C)cc2-c2ccccc2)cc1 ; Nc1cccc2c1oc1ccccc12 ; CC(C)(C)c1ccc(N(c2cccc(Nc3cccc4c3oc3ccccc34)c2)c2ccc(C(C)(C)C)cc2-c2ccccc2)cc1]

Intermediate F-5 (yield 84.4%) was synthesized in the same manner as in Synthesis Example 1-4, except that Intermediate F-4 was used instead of Intermediate A-3.

### Synthesis Example 6-6: Synthesis of Intermediate F-6

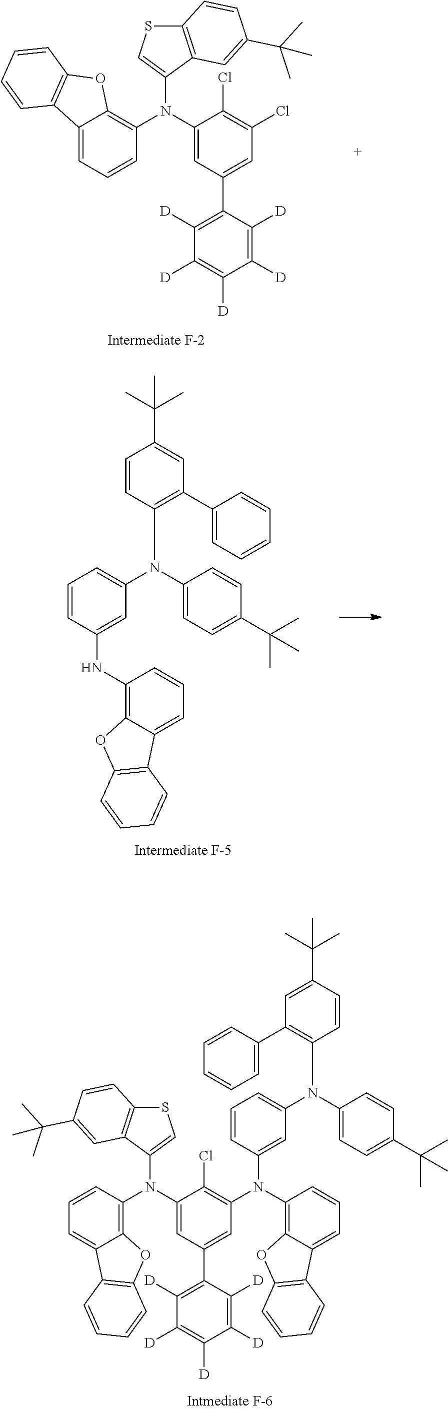

Intermediate F-6 (yield 78.2%) was synthesized in the same manner as in Synthesis Example 1-5, except that Intermediate F-2 and Intermediate F-5 were used instead of Intermediate A-2 and Intermediate A-4, respectively.

### Synthesis Example 6-7: Synthesis of Compound 116

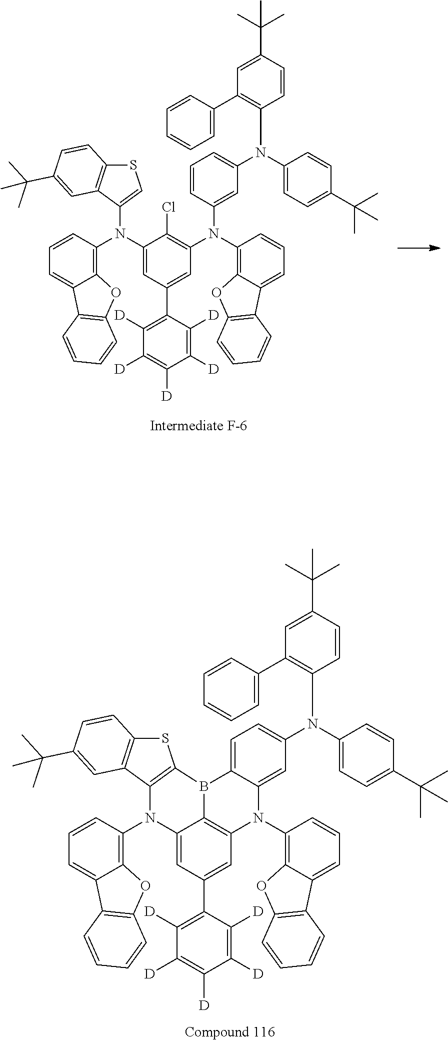

Compound 116 (yield 13.2%) was synthesized in the same manner as in Synthesis Example 1-6, except that Intermediate F-6 was used instead of Intermediate A-5.

MS (MALDI-TOF): m/z 1148.53 [M⁺]

### Synthesis Example 7: Synthesis of Compound 151

Compound 151 (yield 8.7%) was synthesized in the same manner as in Synthesis Example 3, except that dibenzo[b,d]thiophen-4-amine was used instead of Intermediate A-4a in Synthesis Example 3-5.

MS (MALDI-TOF): m/z 993.43 [M⁺]

### Synthesis Example 8: Synthesis of Compound 154

### Synthesis Example 8-1: Synthesis of Intermediate G-1

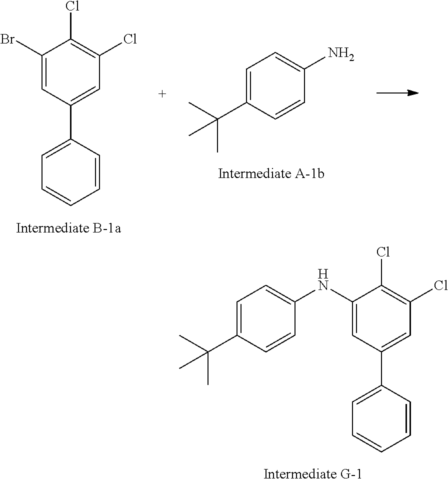 [SMILES: Clc1cc(-c2ccccc2)cc(Br)c1Cl ; CC(C)(C)c1ccc(N)cc1 ; CC(C)(C)c1ccc(Nc2cc(-c3ccccc3)cc(Cl)c2Cl)cc1]

Intermediate G-1 (yield 78%) was synthesized in the same manner as in Synthesis Example 1-1, except that Intermediate B-1a was used instead of Intermediate A-1 a.

### Synthesis Example 8-2: Synthesis of Intermediate G-2

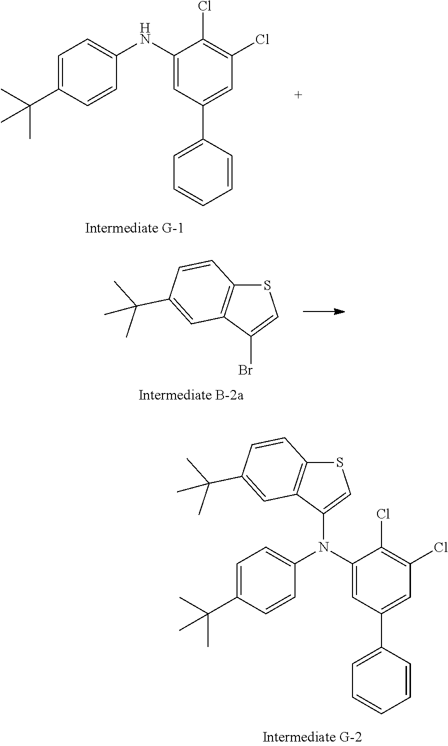 [SMILES: CC(C)(C)c1ccc(Nc2cc(-c3ccccc3)cc(Cl)c2Cl)cc1 ; CC(C)(C)c1ccc2scc(Br)c2c1 ; CC(C)(C)c1ccc(N(c2cc(-c3ccccc3)cc(Cl)c2Cl)c2csc3ccc(C(C)(C)C)cc23)cc1]

Intermediate G-2 (yield 72.1%) was synthesized in the same manner as in Synthesis Example 2-2, except that Intermediate G-1 was used instead of Intermediate B-1.

### Synthesis Example 8-3: Synthesis of Intermediate G-3

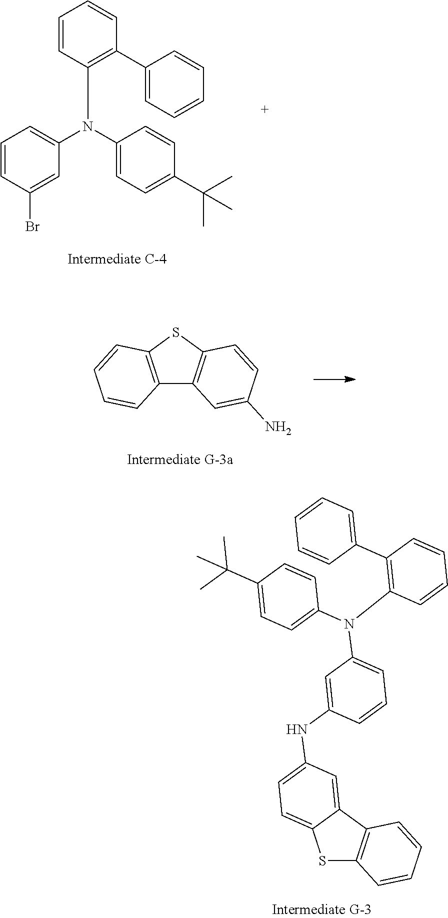 [SMILES: CC(C)(C)c1ccc(N(c2cccc(Br)c2)c2ccccc2-c2ccccc2)cc1 ; Nc1ccc2sc3ccccc3c2c1 ; CC(C)(C)c1ccc(N(c2cccc(Nc3ccc4sc5ccccc5c4c3)c2)c2ccccc2-c2ccccc2)cc1]

Intermediate G-3 (yield 88.3%) was synthesized in the same manner as in Synthesis Example 3-3, except that Intermediate G-3a was used instead of Intermediate A-4a.

### Synthesis Example 8-4: Synthesis of Intermediate G-4

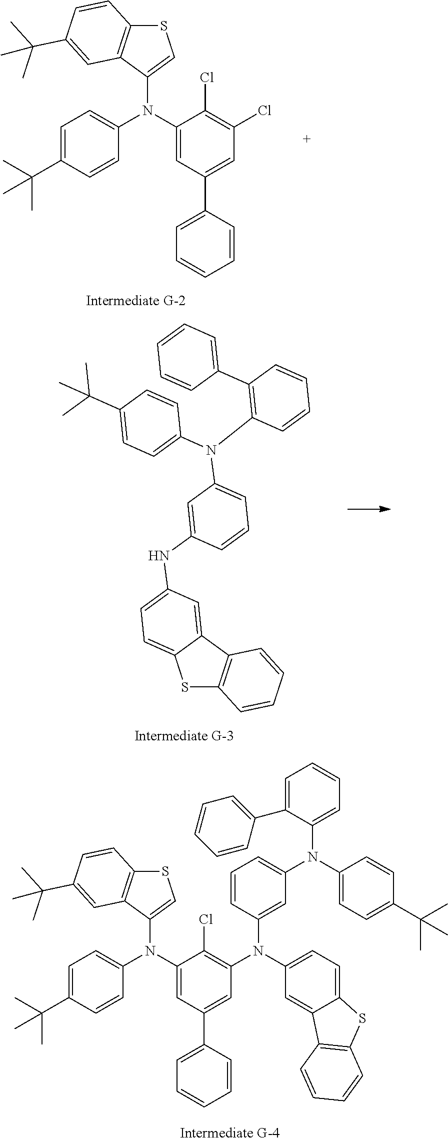 [SMILES: CC(C)(C)c1ccc(N(c2cc(-c3ccccc3)cc(Cl)c2Cl)c2csc3ccc(C(C)(C)C)cc23)cc1 ; CC(C)(C)c1ccc(N(c2cccc(Nc3ccc4sc5ccccc5c4c3)c2)c2ccccc2-c2ccccc2)cc1 ; CC(C)(C)c1ccc(N(c2cccc(N(c3ccc4sc5ccccc5c4c3)c3cc(-c4ccccc4)cc(N(c4ccc(C(C)(C)C)cc4)c4csc5ccc(C(C)(C)C)cc45)c3Cl)c2)c2ccccc2-c2ccccc2)cc1]

Intermediate G-4 (yield 68%) was synthesized in the same manner as in Synthesis Example 1-5, except that Intermediate G-2 and Intermediate G-3 were used instead of Intermediate A-2 and Intermediate A-4, respectively.

### Synthesis Example 8-5: Synthesis of Compound 154

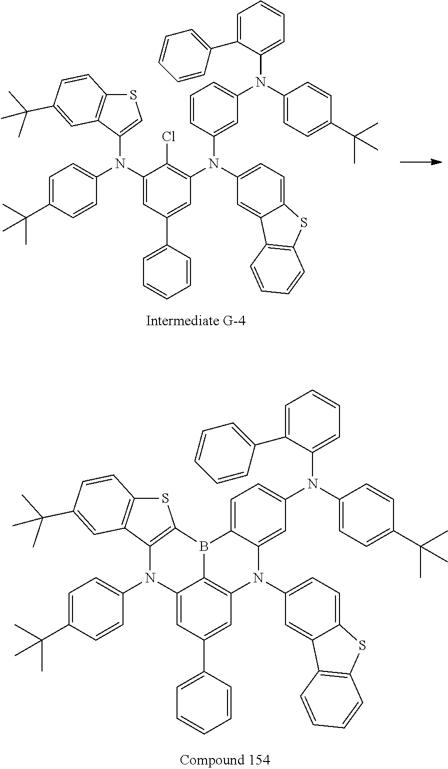

Compound 154 (yield 13%) was synthesized in the same manner as in Synthesis Example 1-6, except that Intermediate G-4 was used instead of Intermediate A-5.

MS (MALDI-TOF): m/z 1069.46 [M⁺]

### Examples 1-7: Fabrication of Organic Electroluminescent Devices

ITO glass was patterned to have a light emitting area of 2 mm×2 mm, followed by cleaning. After the cleaned ITO glass was mounted in a vacuum chamber, the base pressure was adjusted to 1×10⁻⁷ torr. The compound represented by Acceptor-1 as an electron acceptor and the compound represented by Formula F were deposited in a ratio of 3:97 on the ITO to form a 100 Å thick hole injecting layer. The compound represented by Formula F was used to form a 550 Å thick hole transport layer. Subsequently, the compound represented by Formula G was used to form a 50 Å thick electron blocking layer. A mixture of the host represented by BH-1 and the inventive compound (2 wt %) shown in Table 1 was used to form a 200 Å thick light emitting layer. Thereafter, the compound represented by Formula H was used to form a 50 Å hole blocking layer on the light emitting layer. A mixture of the compound represented by Formula E-1 and the compound represented by Formula E-2 in a ratio of 1:1 was used to form a 250 Å thick electron transport layer on the hole blocking layer. The compound represented by Formula E-2 was used to form a 10 Å thick electron injecting layer on the electron transport layer. Al was used to form a 1000 Å thick Al electrode on the electron injecting layer, completing the fabrication of an organic electroluminescent device. The luminescent properties of the organic electroluminescent device were measured at 0.4 mA.

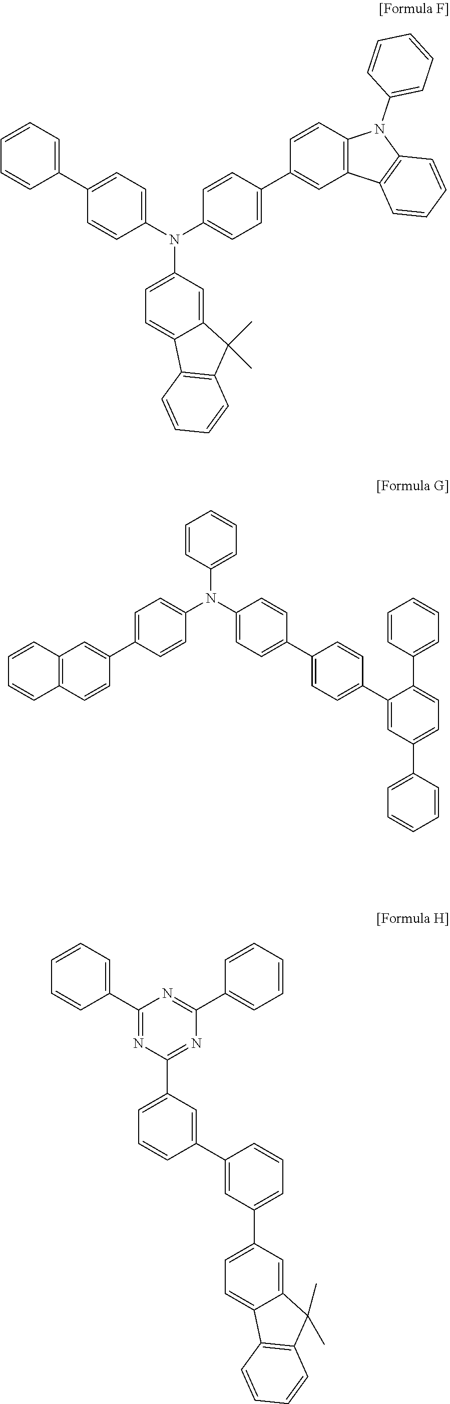 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21]

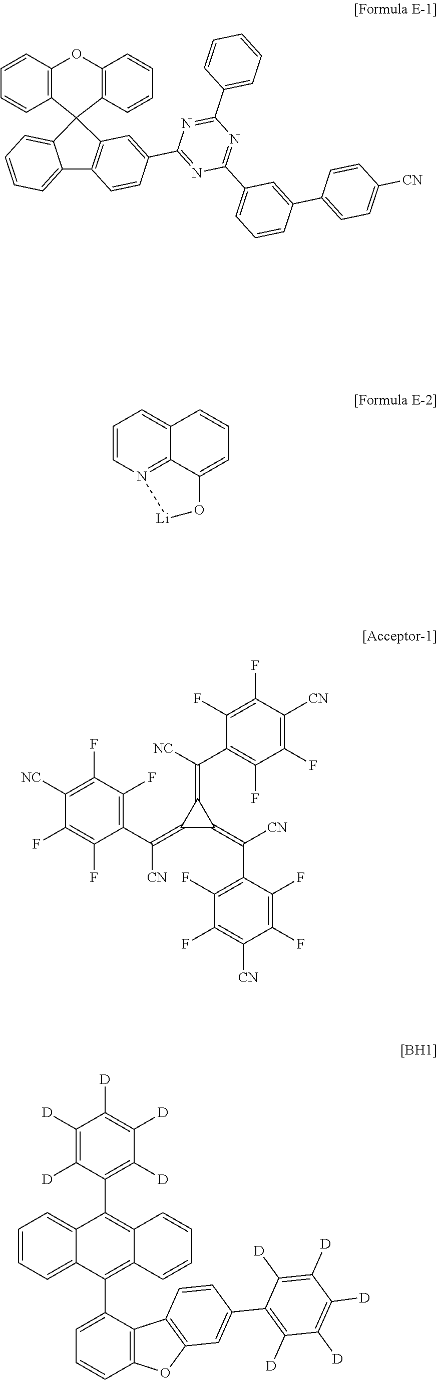

### Comparative Examples 1 and 2

Organic electroluminescent devices were fabricated in the same manner as in Examples 1-7, except that BD1 or BD2 was used as a host compound instead of the inventive compound. The luminescent properties of the organic electroluminescent devices were measured at 0.4 mA. The structures of BD1 and BD2 are as follow:

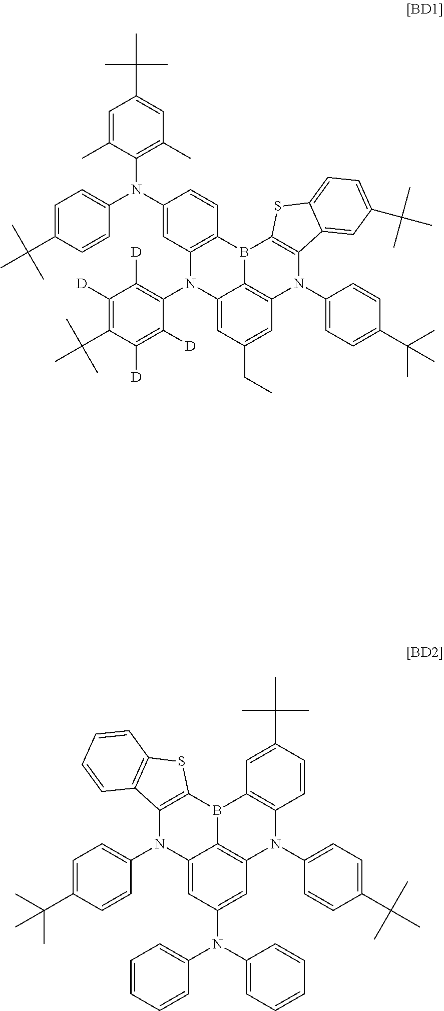

The organic electroluminescent devices of Examples 1-7 and Comparative Examples 1 and 2 were measured for voltage, external quantum efficiency, and lifetime. The results are shown in Table 1.

TABLE 1

| | | | External | |
|---|---|---|---|---|
| Example | | Driving | quantum | Lifetime |
| No. | Dopant | voltage (V) | efficiency (%) | (T97, hr) |
| Example 1 | Compound 12 | 3.4 | 9.6 | 190 |
| Example 2 | Compound 13 | 3.4 | 10.8 | 225 |
| Example 3 | Compound 73 | 3.4 | 10.6 | 250 |
| Example 4 | Compound 76 | 3.3 | 9.9 | 195 |
| Example 5 | Compound 106 | 3.3 | 10.2 | 329 |
| Example 6 | Compound 116 | 3.3 | 9.9 | 265 |
| Example 7 | Compound 154 | 3.4 | 10.0 | 191 |
| Comparative | BD1 | 3.3 | 8.6 | 133 |
| Example 1 | | | | |
| Comparative | BD2 | 3.4 | 8.1 | 158 |
| Example 2 | | | | |

As can be seen from the results in Table 1, the organic electroluminescent devices of Examples 1-7, each of which employed the inventive compound as a dopant in the light emitting layer, showed significantly improved life characteristics and high external quantum efficiencies compared to the devices of Comparative Examples 1 and 2, each of which employed a compound whose structural features are contrasted with those of the inventive compound. These results concluded that the use of the inventive compounds makes the organic electroluminescent devices highly efficient and long lasting.

### Experimental Example 1: Measurement of EL Maximum Peak Wavelengths

The EL maximum peak wavelengths of Compounds 12, 73, and 151 were measured under the same conditions as in Examples 1-7.

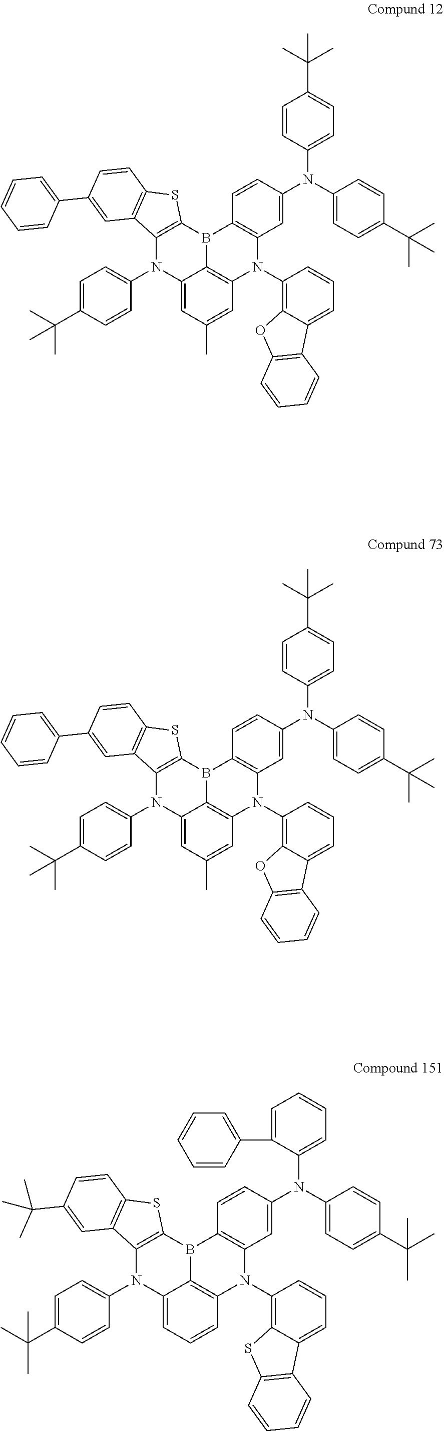

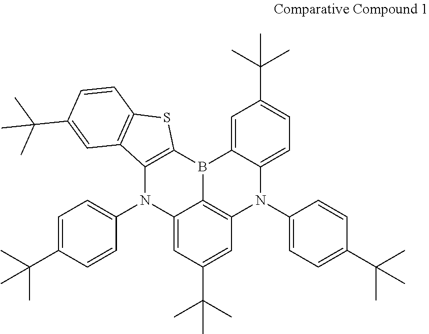 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(C(C)(C)C)cc2c43)cc1]

TABLE 2

| | Compound No. | | | |
|---|---|---|---|---|
| | Compound | Compound | Compound | Comparative |
| | 12 | 73 | 151 | Compound 1 |
| EL λₘₐₓ (nm) | 453 | 452 | 452 | 461 |

As can be seen from the results in Table 2, the EL maximum peaks of the inventive polycyclic compounds represented by Formula A-1 or A-2 in which R₆ is represented by Structural Formula 1 were shifted to shorter wavelengths of <454 nm (blue shifted) compared to that of the comparative compound. As a result, the use of the inventive compounds as dopants in the light emitting layers of the organic electroluminescent devices can achieve blue light emission with improved color purity.

### INDUSTRIAL APPLICABILITY

The polycyclic compound of the present invention can be used to fabricate a highly efficient and long-lasting organic electroluminescent device with significantly improved life characteristics and luminous efficiency. Therefore, the polycyclic compound of the present invention can find useful industrial applications in various displays, including flat panel displays, flexible displays, displays for automotive applications, displays for virtual reality, and displays for augmented reality, and lighting systems, including monochromatic flat panel lighting systems, white flat panel lighting systems, flexible monochromatic lighting systems, and flexible white lighting systems.

What is claimed is:

1. An organic electroluminescent compound represented by Formula A-1 or A-2: 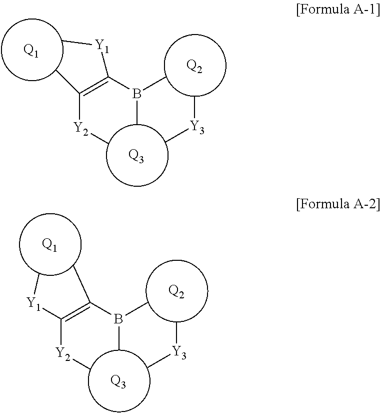
wherein Q₁ to Q₃ are the same as or different from each other and are each independently selected from substituted or unsubstituted C₆-C₅₀ monocyclic or polycyclic aromatic hydrocarbon rings, substituted or unsubstituted C₂-C₅₀ monocyclic or polycyclic aromatic heterocyclic rings, substituted or unsubstituted C₆-C₅₀ fused polycyclic non-aromatic hydrocarbon rings, and substituted or unsubstituted C₂-C₅₀ fused polycyclic non-aromatic heterocyclic rings, Y₁ to Y₃ are the same as or different from each other and are each independently N—R₁, CR₂R₃, O, S, Se, and SiR₄R₅, and R₁ to R₅ are the same as or different from each other and are each independently selected from hydrogen, deuterium, substituted or unsubstituted C₁-C₃₀ alkyl, substituted or unsubstituted C₂-C₃₀ alkenyl, substituted or unsubstituted C₆-C₅₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₅₀ heteroaryl, substituted or unsubstituted C₆-C₅₀ fused polycyclic non-aromatic hydrocarbon rings, substituted or unsubstituted C₂-C₅₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, nitro, cyano, and halogen, with the proviso that each of R₁ to R₅ is optionally bonded to either one of the rings Q₁ to Q₃ to form an alicyclic or aromatic monocyclic or polycyclic ring, R₂ and R₃ are optionally linked to each other to form an alicyclic or aromatic monocyclic or polycyclic ring, and R₄ and R₅ are optionally linked to each other to form an alicyclic or aromatic monocyclic or polycyclic ring, with the proviso that at least one of Y₂ and Y₃ is N—R₆ and R₆ is represented by Structural Formula 1: 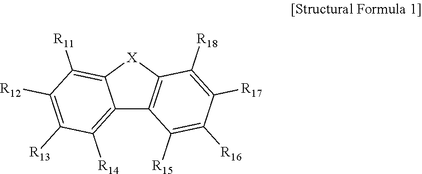
wherein X is O or S, R₁₁ to R₁₈ are the same as or different from each other and are each independently selected from hydrogen, deuterium, substituted or unsubstituted C₁-C₃₀ alkyl, substituted or unsubstituted C₂-C₃₀ alkenyl, substituted or unsubstituted C₂-C₃₀ alkynyl, substituted or unsubstituted C₆-C₆₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₆₀ heteroaryl, substituted or unsubstituted C₆-C₆₀ fused polycyclic non-aromatic hydrocarbon rings, substituted or unsubstituted C₂-C₆₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₆-C₃₀ arylthioxy, substituted or unsubstituted amine, substituted or unsubstituted silyl, substituted or unsubstituted germanium, substituted or unsubstituted boron, substituted or unsubstituted aluminum, phosphoryl, hydroxyl, selenium, tellurium, nitro, cyano, and halogen, with the proviso that either one of R₁₁ to R₁₈ is optionally bonded to Y₂ or Y₃, the others of R₁₁ to R₁₈ are optionally linked to each other or one or more adjacent substituents to form an alicyclic or aromatic monocyclic or polycyclic ring, and the carbon atoms in the alicyclic or aromatic monocyclic or polycyclic ring are optionally substituted with one or more heteroatoms selected from N, S, and O.

2. The organic electroluminescent compound according to claim 1, wherein the compound represented by Formula A-1 or A-2 is a compound represented by Formula A-3 or A-4: 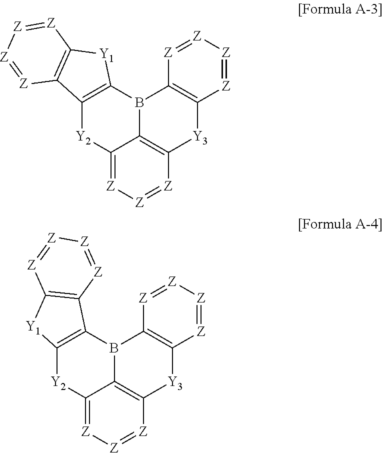
wherein each Z is independently CR or N, each R is independently selected from hydrogen, deuterium, substituted or unsubstituted C₁-C₃₀ alkyl, substituted or unsubstituted C₂-C₃₀ alkenyl, substituted or unsubstituted C₂-C₃₀ alkynyl, substituted or unsubstituted C₆-C₅₀ aryl, substituted or unsubstituted C₃-C₃₀ cycloalkyl, substituted or unsubstituted C₃-C₃₀ cycloalkenyl, substituted or unsubstituted C₁-C₃₀ heterocycloalkyl, substituted or unsubstituted C₂-C₅₀ heteroaryl, substituted or unsubstituted C₆-C₅₀ fused polycyclic non-aromatic hydrocarbon rings, substituted or unsubstituted C₂-C₅₀ fused polycyclic non-aromatic heterocyclic rings, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, substituted or unsubstituted boron, substituted or unsubstituted aluminum, phosphoryl, hydroxyl, selenium, tellurium, nitro, cyano, and halogen, the moieties Z are the same as or different from each other, the groups R are the same as or different from each other, with the proviso that the groups R are optionally linked to each other or one or more adjacent substituents to form an alicyclic or aromatic monocyclic or polycyclic ring and the carbon atoms in the alicyclic or aromatic monocyclic or polycyclic ring are optionally substituted with one or more heteroatoms selected from N, S, and O, and Y₁ to Y₃ are as defined in Formulae A-1 and A-2.

3. The organic electroluminescent compound according to claim 1, wherein the organic electroluminescent compound represented by Formula A-1 or A-2 is selected from the following compounds:

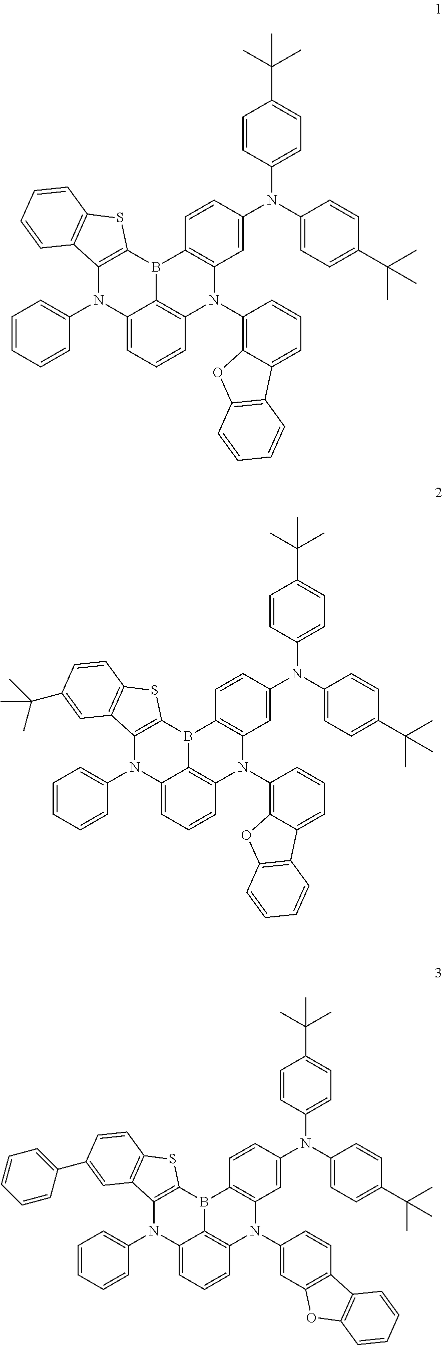

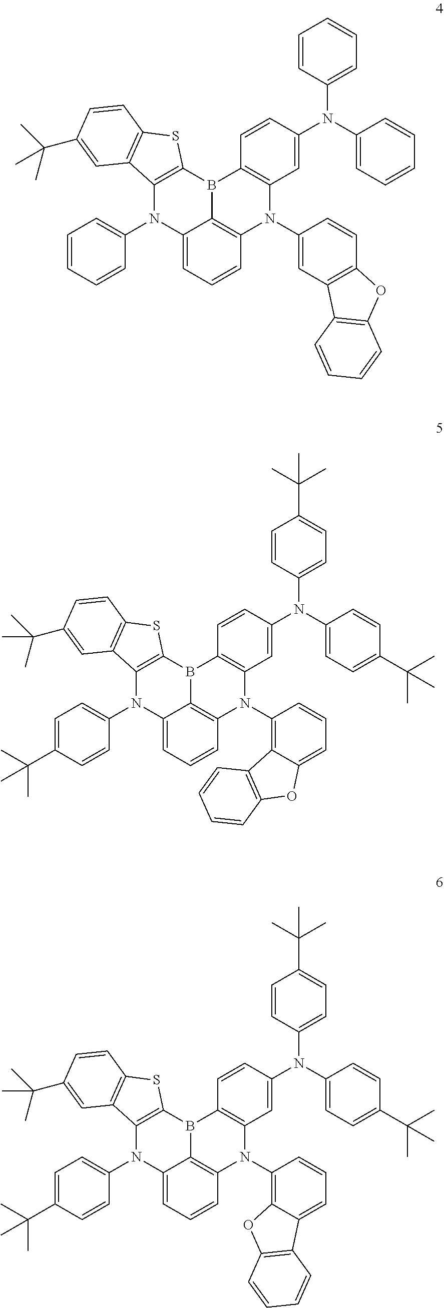

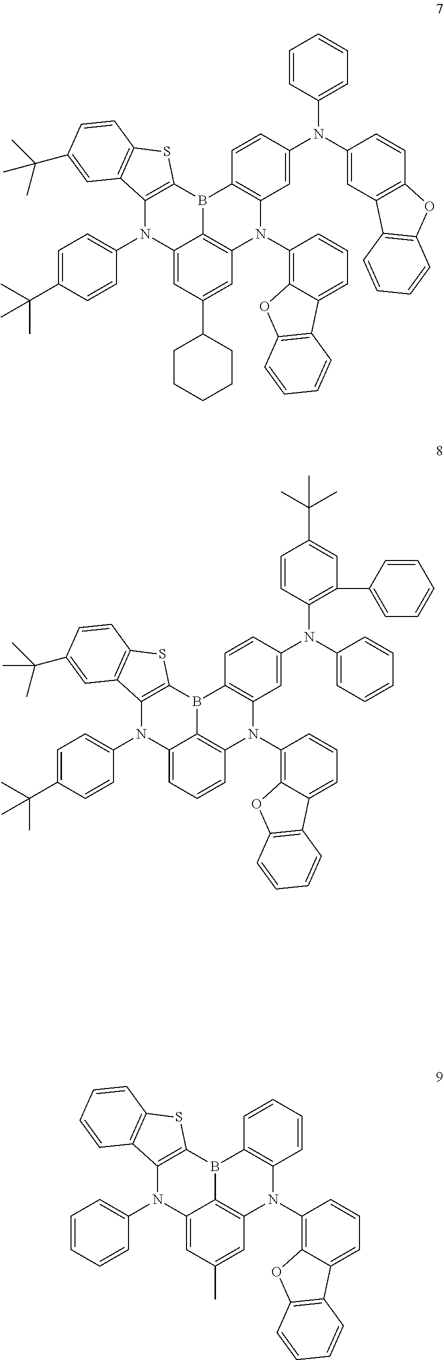 [SMILES: CC(C)(C)c1ccc(N2c3cc(C4CCCCC4)cc4c3B(c3ccc(N(c5ccccc5)c5ccc6oc7ccccc7c6c5)cc3N4c3cccc4c3oc3ccccc34)c3sc4ccc(C(C)(C)C)cc4c32)cc1 ; CC(C)(C)c1ccc(N2c3cccc4c3B(c3ccc(N(c5ccccc5)c5ccc(C(C)(C)C)cc5-c5ccccc5)cc3N4c3cccc4c3oc3ccccc34)c3sc4ccc(C(C)(C)C)cc4c32)cc1 ; Cc1cc2c3c(c1)N(c1cccc4c1oc1ccccc14)c1ccccc1B3c1sc3ccccc3c1N2c1ccccc1]

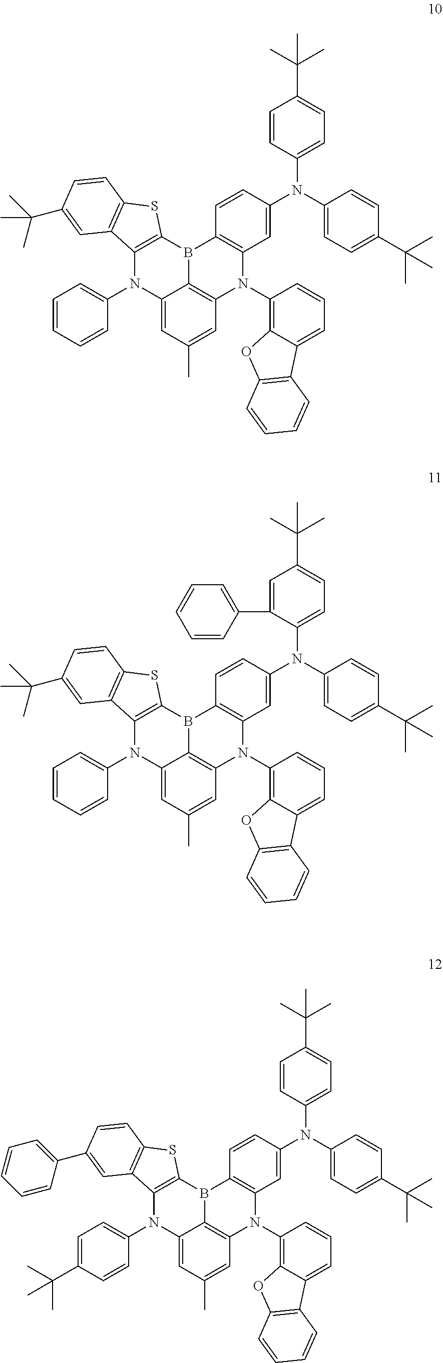

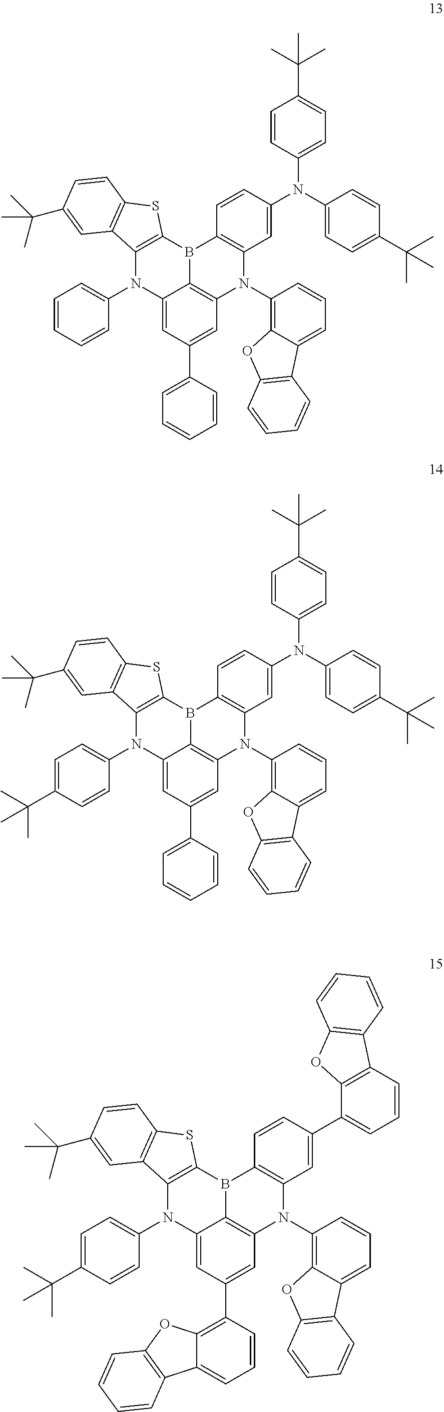

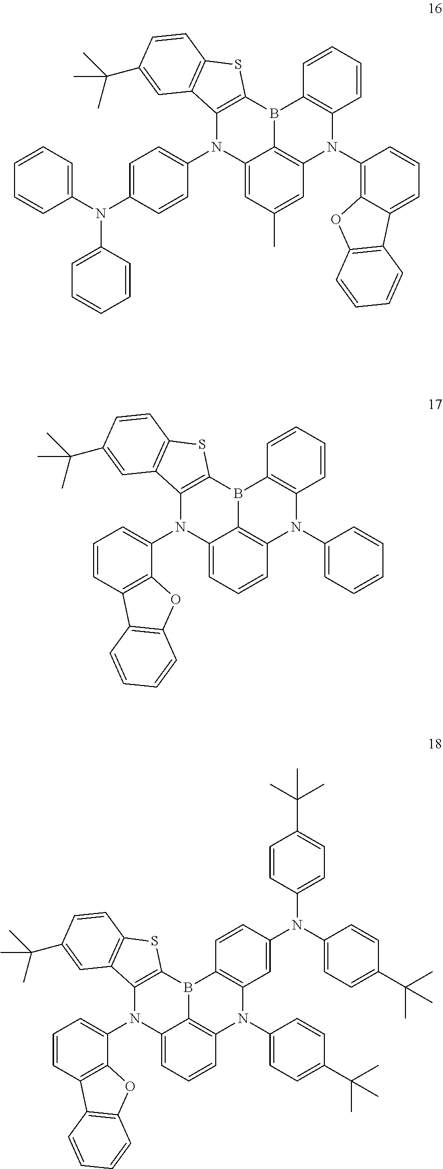 [SMILES: Cc1cc2c3c(c1)N(c1cccc4c1oc1ccccc14)c1ccccc1B3c1sc3ccc(C(C)(C)C)cc3c1N2c1ccc(N(c2ccccc2)c2ccccc2)cc1 ; CC(C)(C)c1ccc2sc3c(c2c1)N(c1cccc2c1oc1ccccc12)c1cccc2c1B3c1ccccc1N2c1ccccc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(C(C)(C)C)cc3c2N4c2cccc3c2oc2ccccc23)cc1]

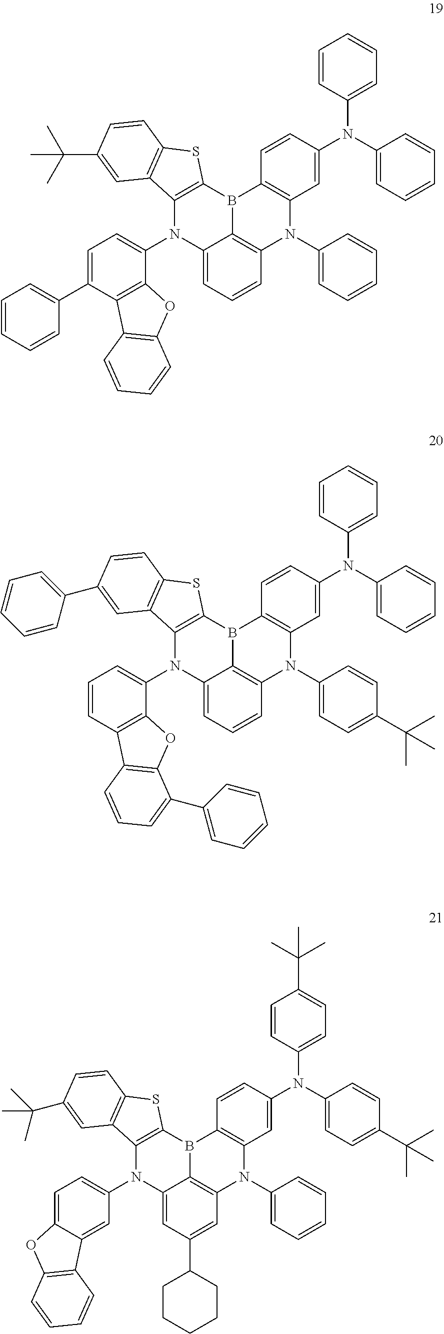

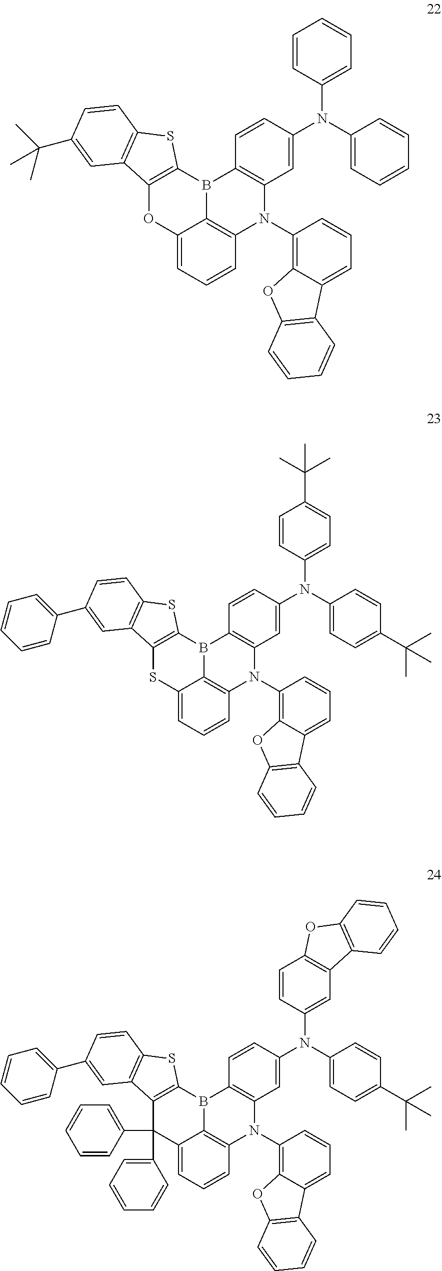 [SMILES: CC(C)(C)c1ccc2sc3c(c2c1)Oc1cccc2c1B3c1ccc(N(c3ccccc3)c3ccccc3)cc1N2c1cccc2c1oc1ccccc12 ; CC(C)(C)c1ccc(N(c2ccc(C(C)(C)C)cc2)c2ccc3c(c2)N(c2cccc4c2oc2ccccc24)c2cccc4c2B3c2sc3ccc(-c5ccccc5)cc3c2S4)cc1 ; CC(C)(C)c1ccc(N(c2ccc3c(c2)N(c2cccc4c2oc2ccccc24)c2cccc4c2B3c2sc3ccc(-c5ccccc5)cc3c2C4(c2ccccc2)c2ccccc2)c2ccc3oc4ccccc4c3c2)cc1]

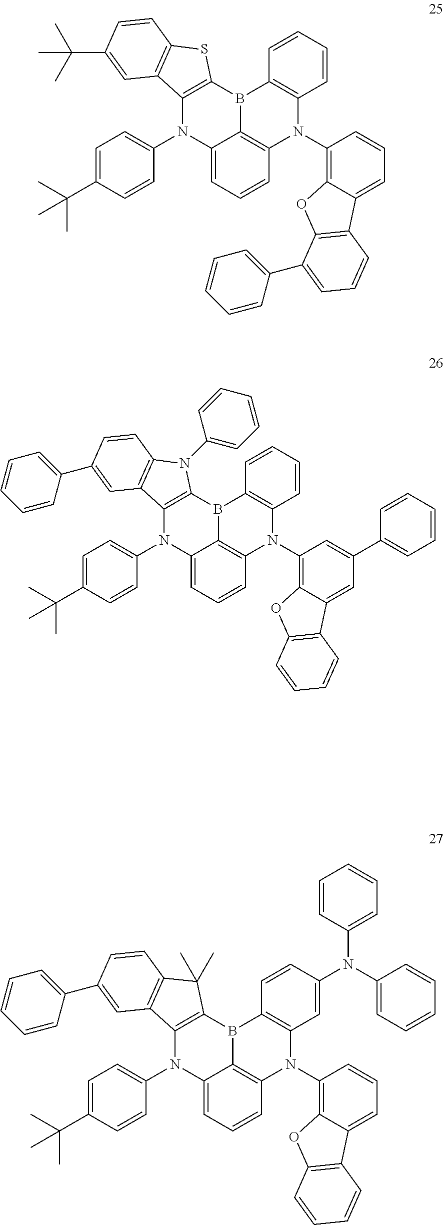 [SMILES: CC(C)(C)c1ccc(N2c3cccc4c3B(c3ccccc3N4c3cccc4c3oc3c(-c5ccccc5)cccc34)c3sc4ccc(C(C)(C)C)cc4c32)cc1 ; CC(C)(C)c1ccc(N2c3cccc4c3B(c3ccccc3N4c3cc(-c4ccccc4)cc4c3oc3ccccc34)c3c2c2cc(-c4ccccc4)ccc2n3-c2ccccc2)cc1 ; CC(C)(C)c1ccc(N2C3=C(B4c5ccc(N(c6ccccc6)c6ccccc6)cc5N(c5cccc6c5oc5ccccc56)c5cccc2c54)C(C)(C)c2ccc(-c4ccccc4)cc23)cc1]

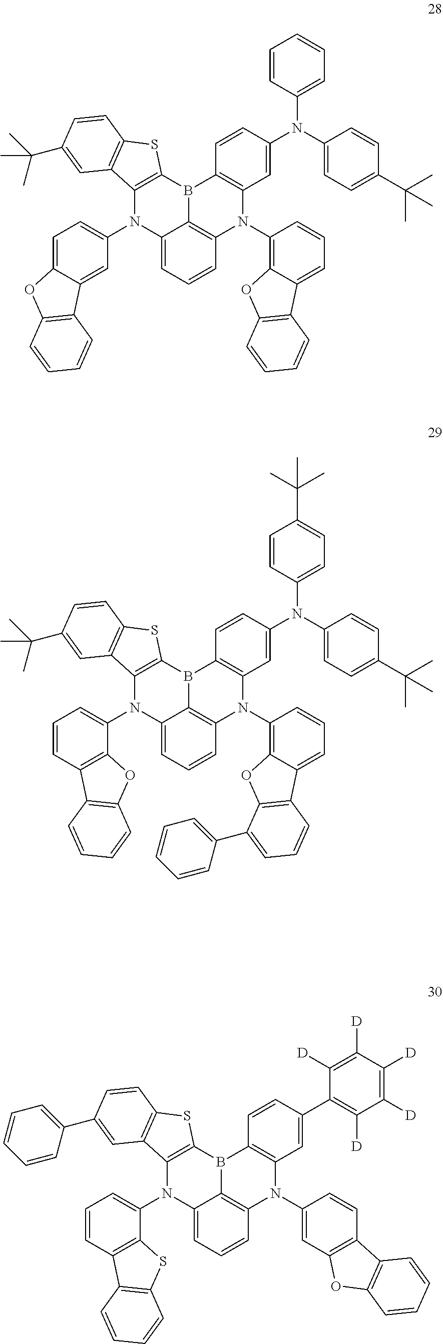

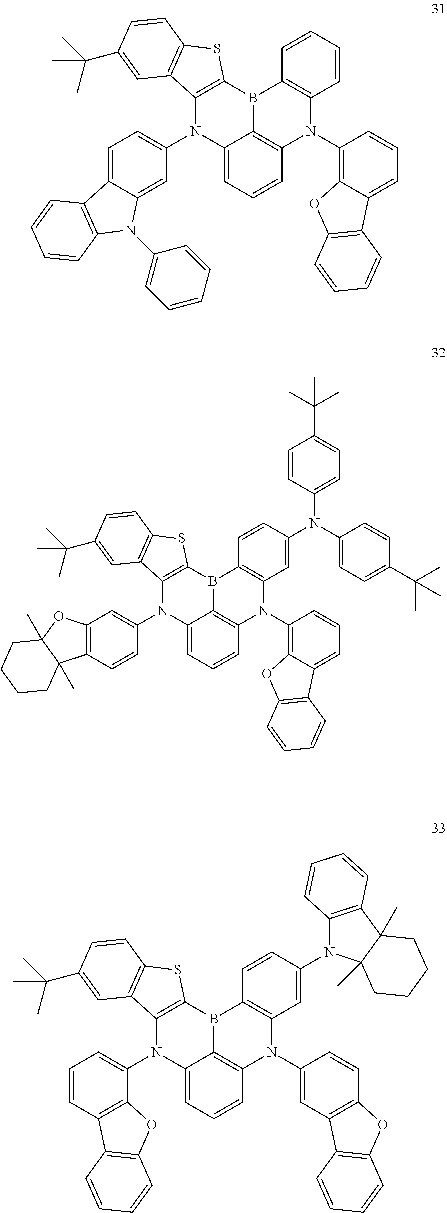

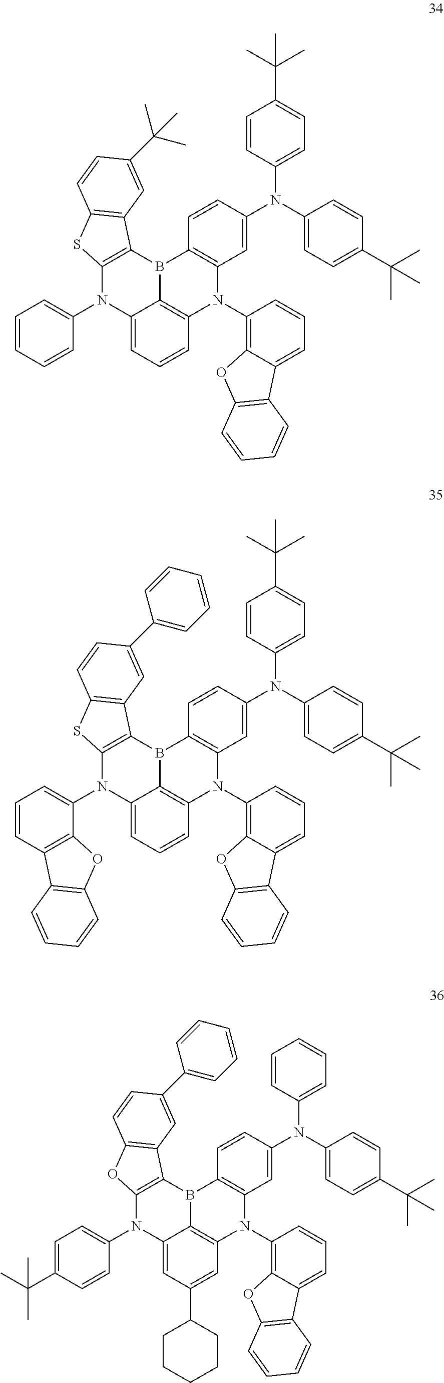

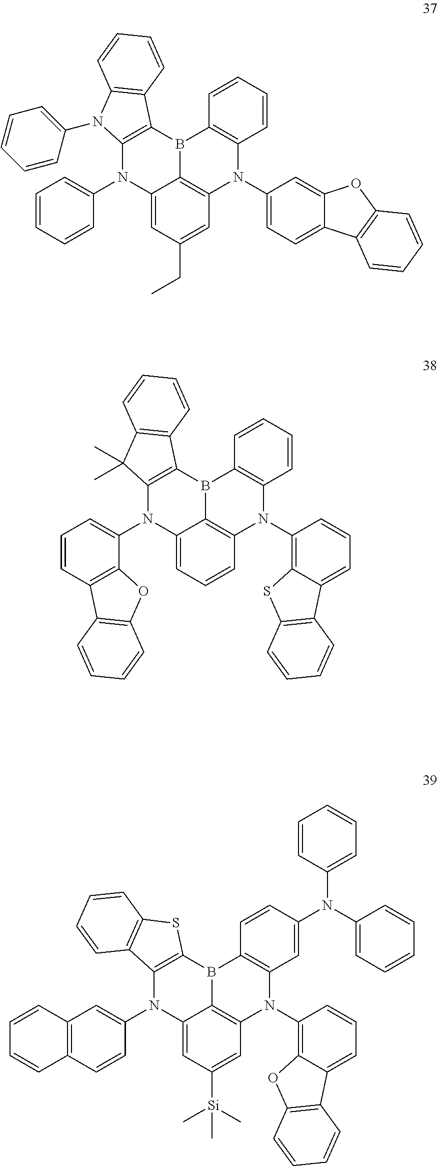 [SMILES: CCc1cc2c3c(c1)N(c1ccccc1)c1c(c4ccccc4n1-c1ccccc1)B3c1ccccc1N2c1ccc2c(c1)oc1ccccc12 ; CC1(C)C2=C(B3c4ccccc4N(c4cccc5c4sc4ccccc45)c4cccc(c43)N2c2cccc3c2oc2ccccc23)c2ccccc21 ; C[Si](C)(C)c1cc2c3c(c1)N(c1cccc4c1oc1ccccc14)c1cc(N(c4ccccc4)c4ccccc4)ccc1B3c1sc3ccccc3c1N2c1ccc2ccccc2c1]

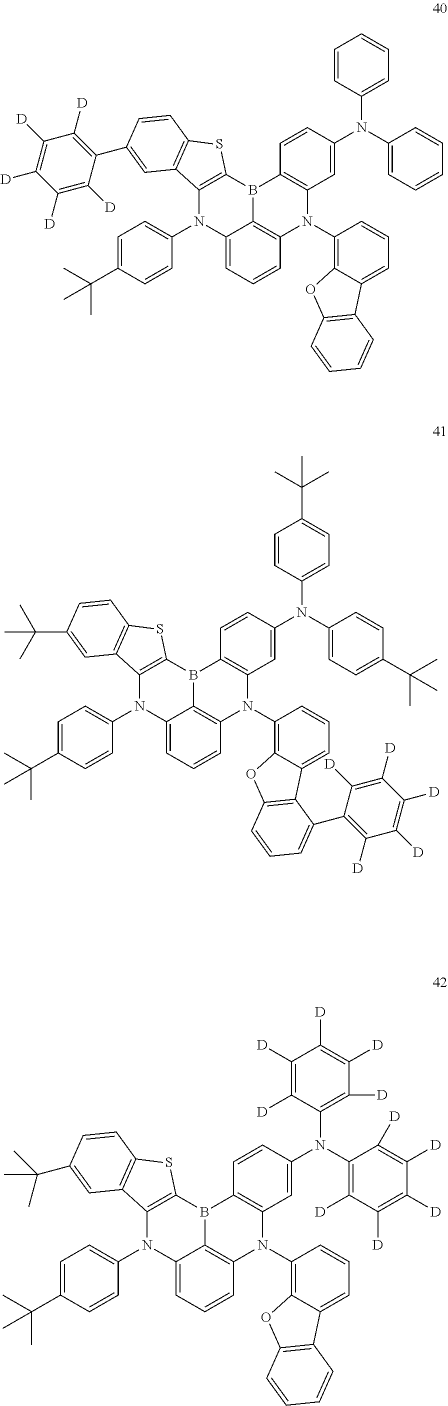

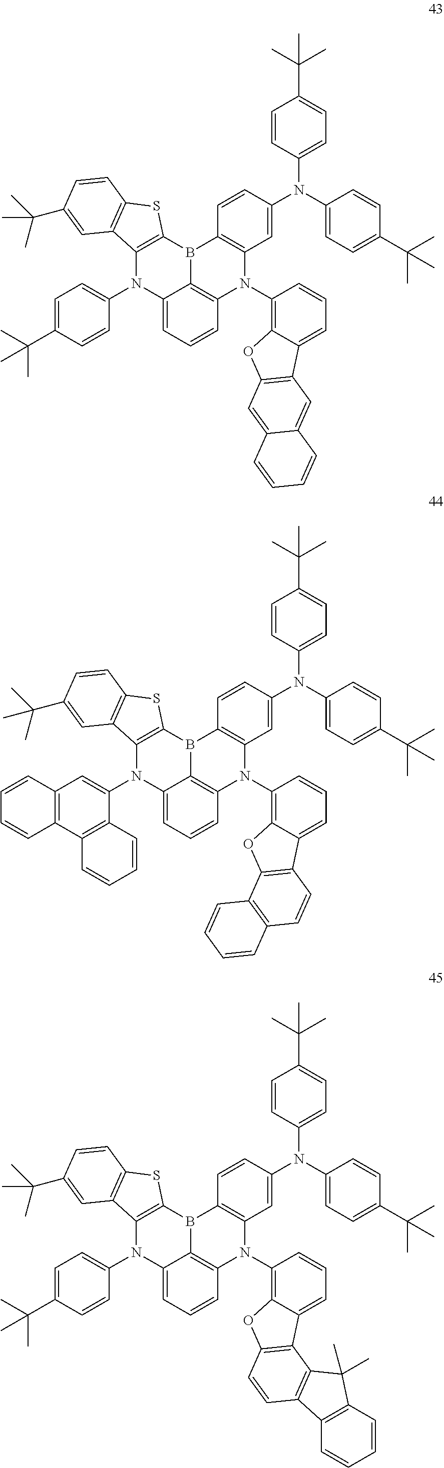

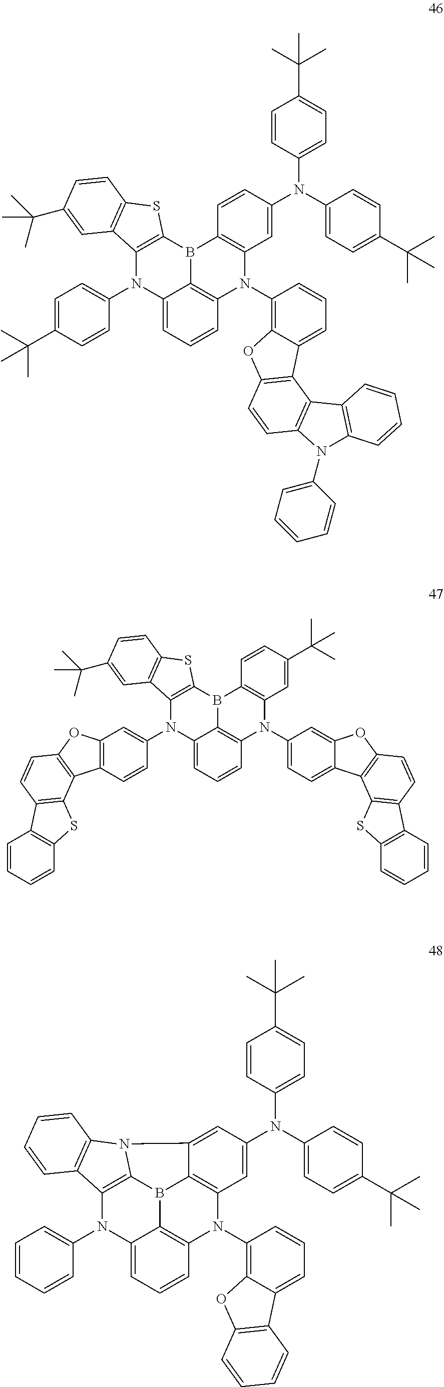 [SMILES: CC(C)(C)c1ccc(N(c2ccc(C(C)(C)C)cc2)c2ccc3c(c2)N(c2cccc4c2oc2ccc5c(c6ccccc6n5-c5ccccc5)c24)c2cccc4c2B3c2sc3ccc(C(C)(C)C)cc3c2N4c2ccc(C(C)(C)C)cc2)cc1 ; CC(C)(C)c1ccc2c(c1)N(c1ccc3c(c1)oc1ccc4c5ccccc5sc4c13)c1cccc3c1B2c1sc2ccc(C(C)(C)C)cc2c1N3c1ccc2c(c1)oc1ccc3c4ccccc4sc3c12 ; CC(C)(C)c1ccc(N(c2ccc(C(C)(C)C)cc2)c2cc3c4c(c2)-n2c5c(c6ccccc62)N(c2ccccc2)c2cccc(c2B45)N3c2cccc3c2oc2ccccc23)cc1]

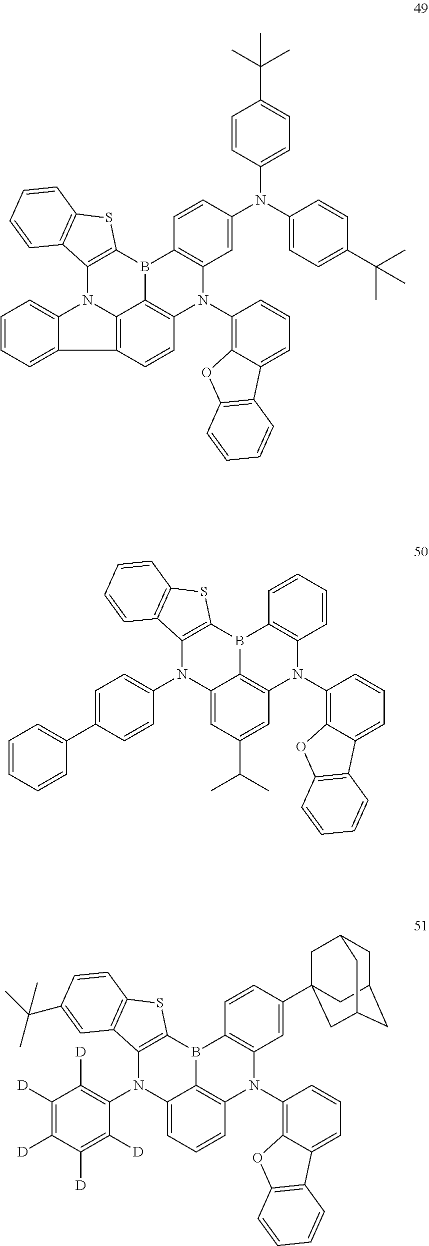

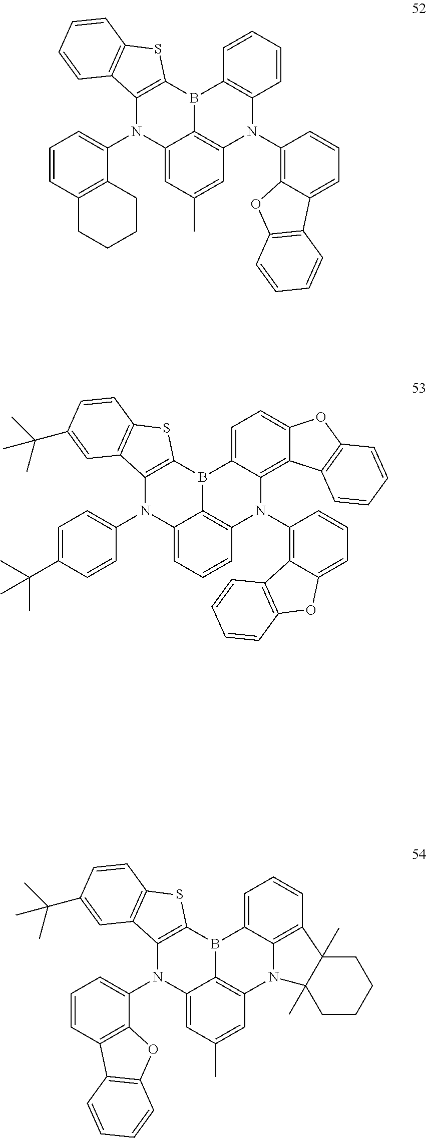 [SMILES: Cc1cc2c3c(c1)N(c1cccc4c1oc1ccccc14)c1ccccc1B3c1sc3ccccc3c1N2c1cccc2c1CCCC2 ; CC(C)(C)c1ccc(N2c3cccc4c3B(c3ccc5oc6ccccc6c5c3N4c3cccc4oc5ccccc5c34)c3sc4ccc(C(C)(C)C)cc4c32)cc1 ; Cc1cc2c3c(c1)N1c4c(cccc4C4(C)CCCCC14C)B3c1sc3ccc(C(C)(C)C)cc3c1N2c1cccc2c1oc1ccccc12]

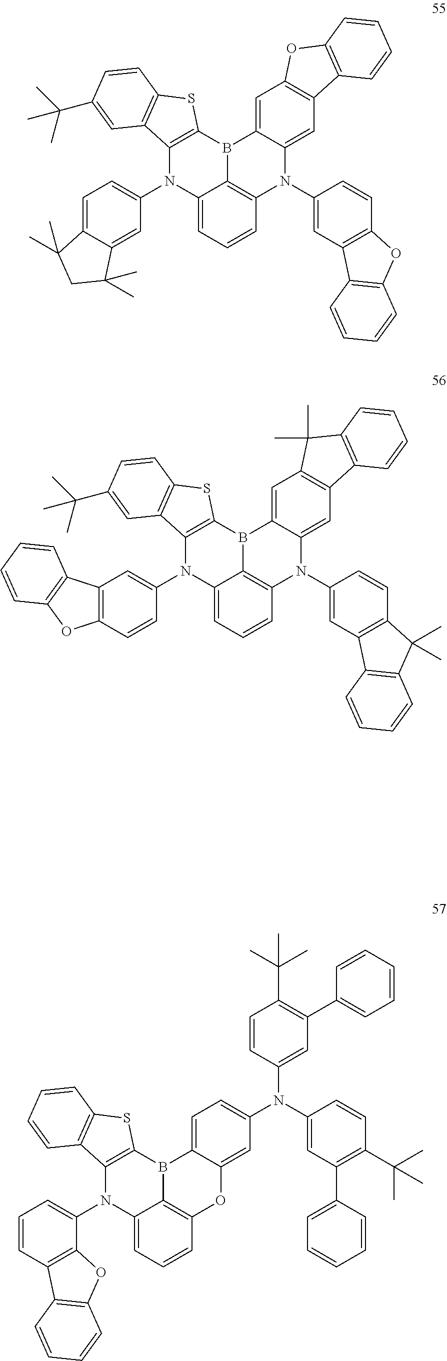 [SMILES: CC(C)(C)c1ccc2sc3c(c2c1)N(c1ccc2c(c1)C(C)(C)CC2(C)C)c1cccc2c1B3c1cc3oc4ccccc4c3cc1N2c1ccc2oc3ccccc3c2c1 ; CC(C)(C)c1ccc2sc3c(c2c1)N(c1ccc2oc4ccccc4c2c1)c1cccc2c1B3c1cc3c(cc1N2c1ccc2c(c1)-c1ccccc1C2(C)C)-c1ccccc1C3(C)C ; CC(C)(C)c1ccc(N(c2ccc3c(c2)Oc2cccc4c2B3c2sc3ccccc3c2N4c2cccc3c2oc2ccccc23)c2ccc(C(C)(C)C)c(-c3ccccc3)c2)cc1-c1ccccc1]

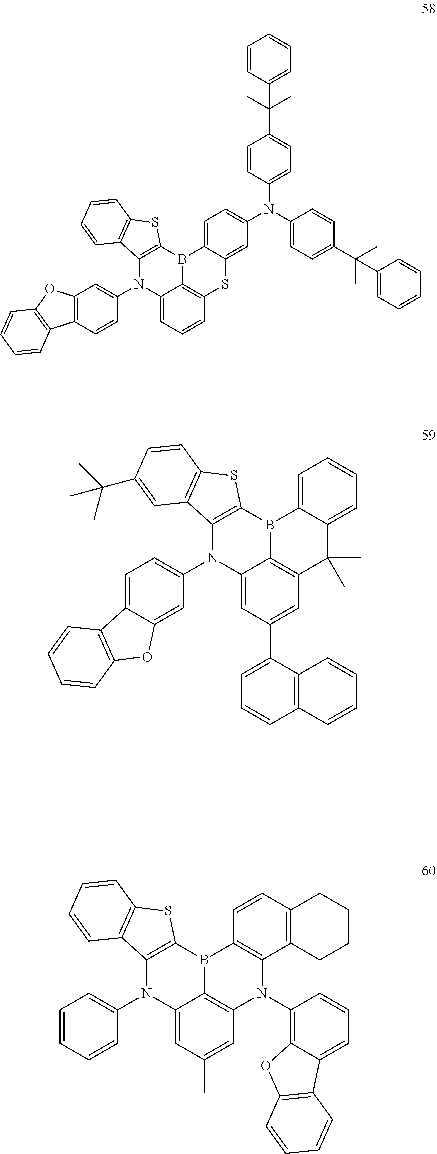 [SMILES: CC(C)(c1ccccc1)c1ccc(N(c2ccc(C(C)(C)c3ccccc3)cc2)c2ccc3c(c2)Sc2cccc4c2B3c2sc3ccccc3c2N4c2ccc3c(c2)oc2ccccc23)cc1 ; CC(C)(C)c1ccc2sc3c(c2c1)N(c1ccc2c(c1)oc1ccccc12)c1cc(-c2cccc4ccccc24)cc2c1B3c1ccccc1C2(C)C ; Cc1cc2c3c(c1)N(c1cccc4c1oc1ccccc14)c1c(ccc4c1CCCC4)B3c1sc3ccccc3c1N2c1ccccc1]

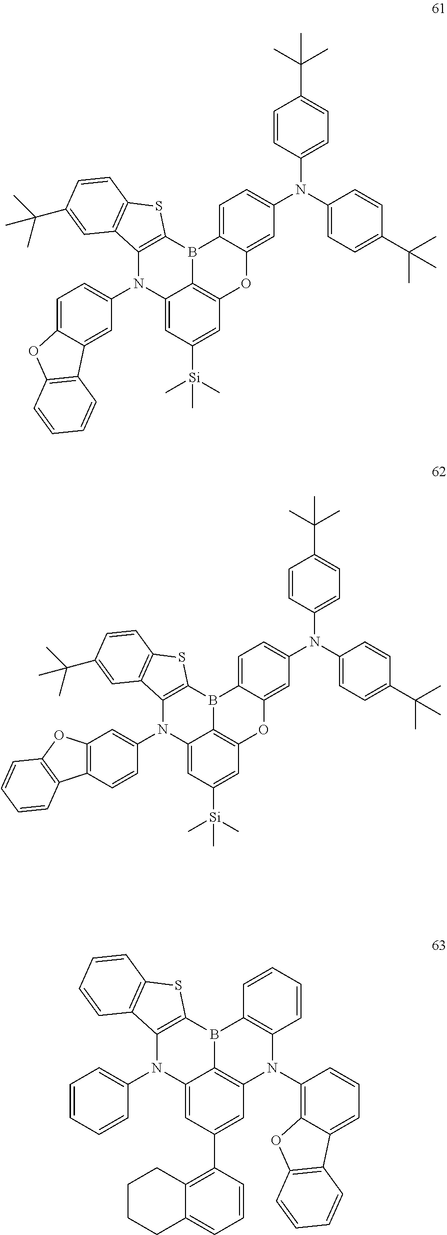 [SMILES: CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3oc4ccccc4c3c2)cc1 ; CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3c(c2)oc2ccccc23)cc1 ; c1ccc(N2c3cc(-c4cccc5c4CCCC5)cc4c3B(c3ccccc3N4c3cccc4c3oc3ccccc34)c3sc4ccccc4c32)cc1]

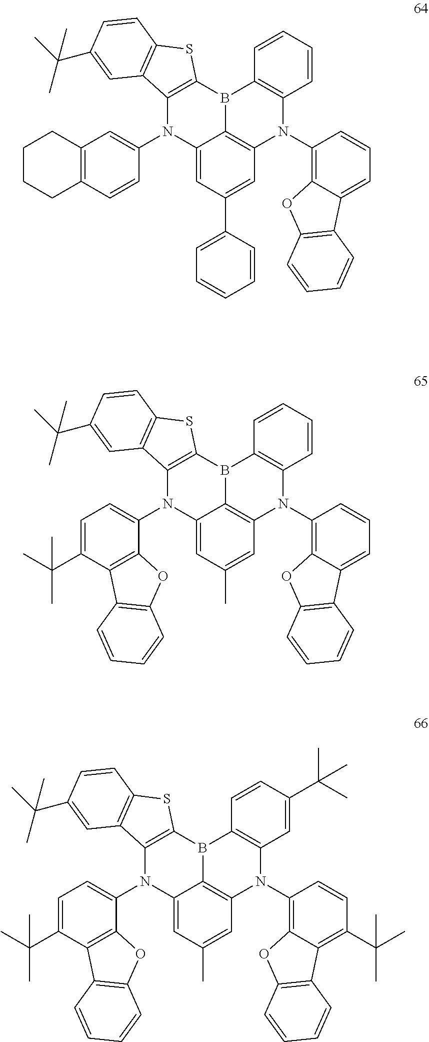 [SMILES: CC(C)(C)c1ccc2sc3c(c2c1)N(c1ccc2c(c1)CCCC2)c1cc(-c2ccccc2)cc2c1B3c1ccccc1N2c1cccc2c1oc1ccccc12 ; Cc1cc2c3c(c1)N(c1ccc(C(C)(C)C)c4c1oc1ccccc14)c1c(sc4ccc(C(C)(C)C)cc14)B3c1ccccc1N2c1cccc2c1oc1ccccc12 ; Cc1cc2c3c(c1)N(c1ccc(C(C)(C)C)c4c1oc1ccccc14)c1c(sc4ccc(C(C)(C)C)cc14)B3c1ccc(C(C)(C)C)cc1N2c1ccc(C(C)(C)C)c2c1oc1ccccc12]

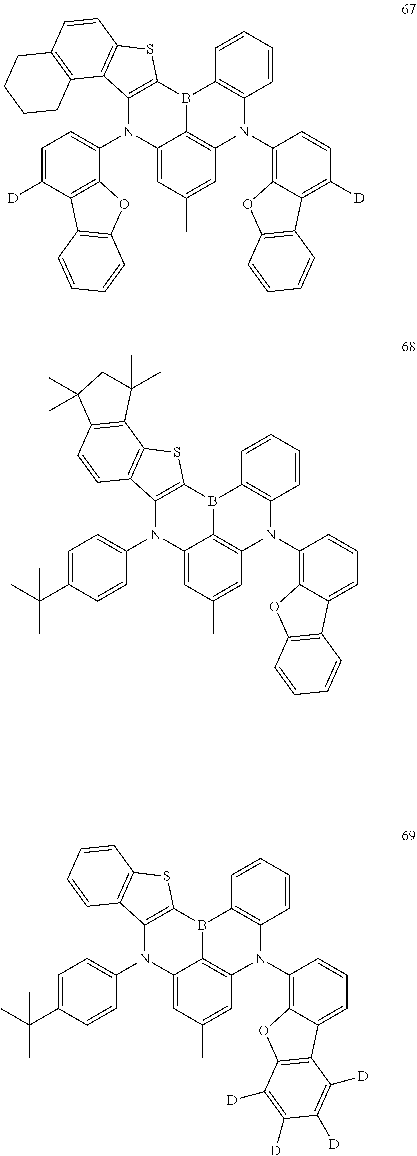 [SMILES: [2H]c1ccc(N2c3ccccc3B3c4sc5ccc6c(c5c4N(c4ccc([2H])c5c4oc4ccccc45)c4cc(C)cc2c43)CCCC6)c2oc3ccccc3c12 ; Cc1cc2c3c(c1)N(c1cccc4c1oc1ccccc14)c1ccccc1B3c1sc3c4c(ccc3c1N2c1ccc(C(C)(C)C)cc1)C(C)(C)CC4(C)C ; [2H]c1c([2H])c([2H])c2c(oc3c(N4c5ccccc5B5c6sc7ccccc7c6N(c6ccc(C(C)(C)C)cc6)c6cc(C)cc4c65)cccc32)c1[2H]]

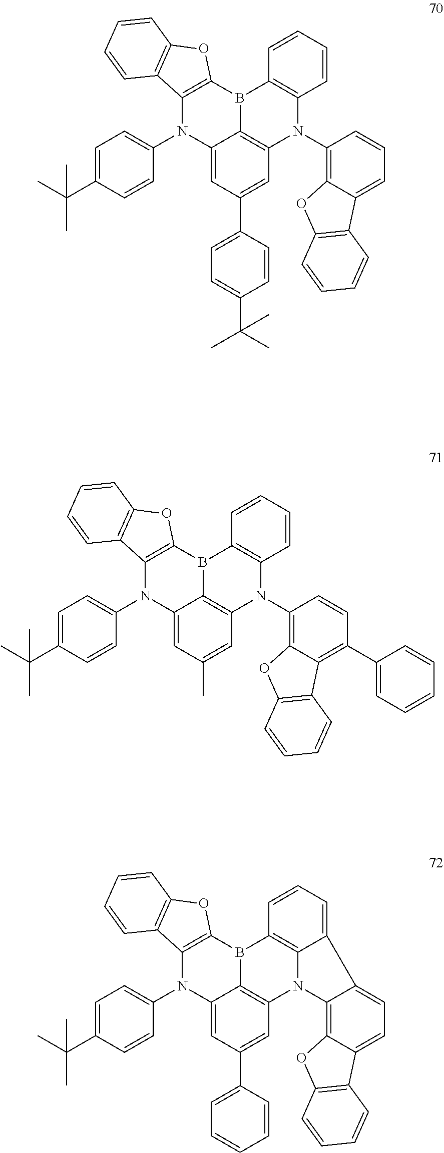 [SMILES: CC(C)(C)c1ccc(-c2cc3c4c(c2)N(c2cccc5c2oc2ccccc25)c2ccccc2B4c2oc4ccccc4c2N3c2ccc(C(C)(C)C)cc2)cc1 ; Cc1cc2c3c(c1)N(c1ccc(-c4ccccc4)c4c1oc1ccccc14)c1ccccc1B3c1oc3ccccc3c1N2c1ccc(C(C)(C)C)cc1 ; CC(C)(C)c1ccc(N2c3cc(-c4ccccc4)cc4c3B(c3oc5ccccc5c32)c2cccc3c5ccc6c7ccccc7oc6c5n-4c23)cc1]

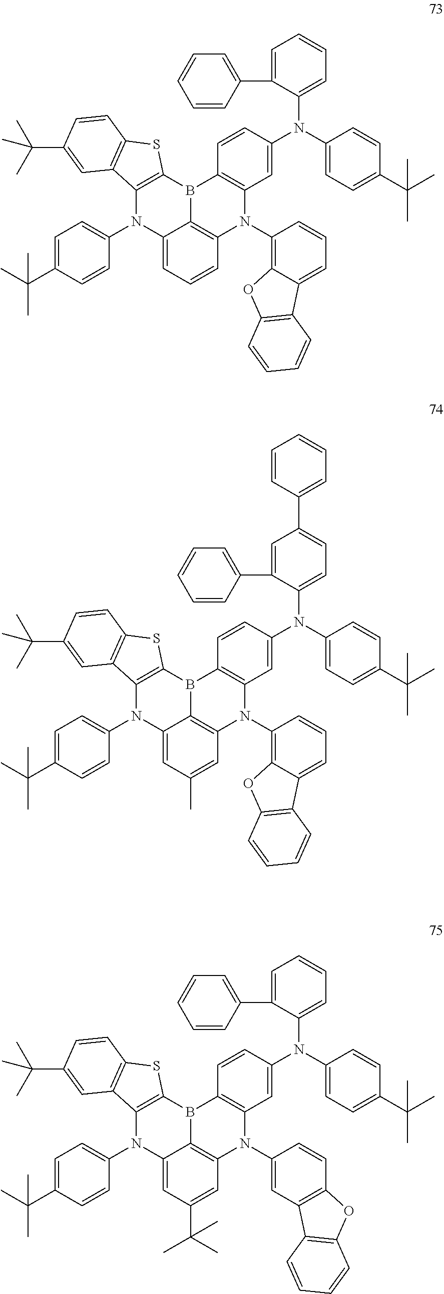

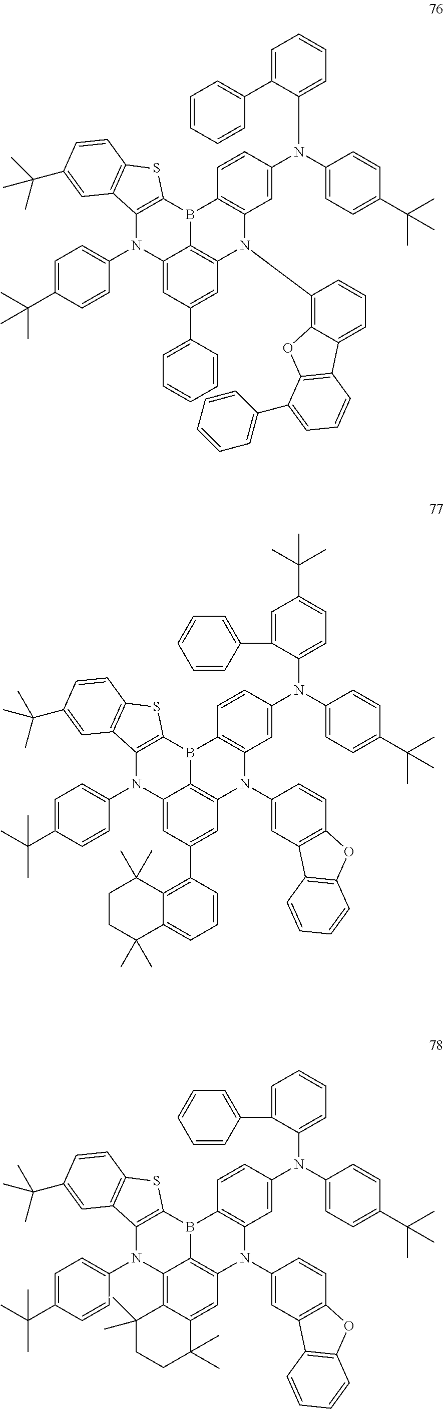

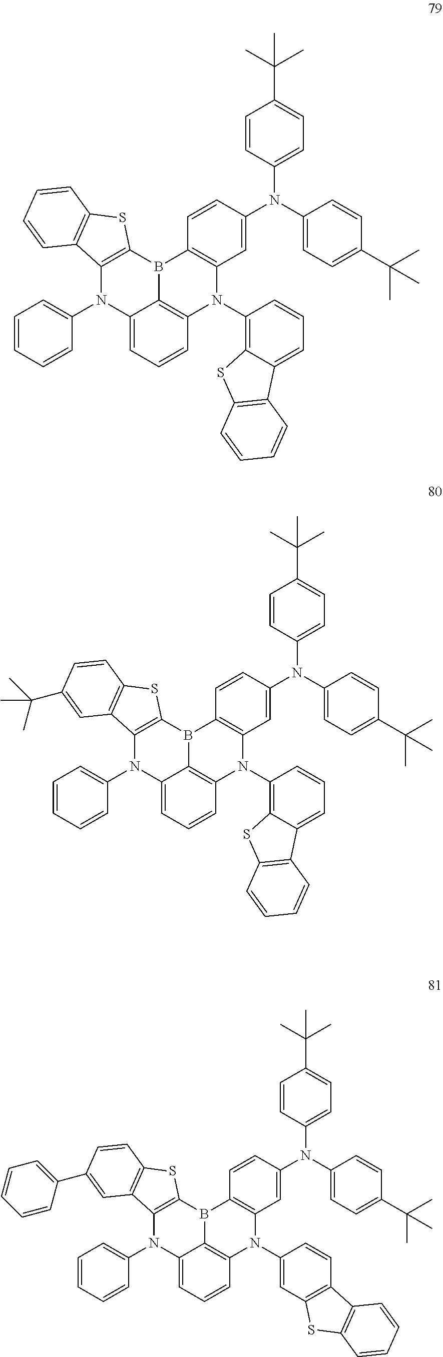

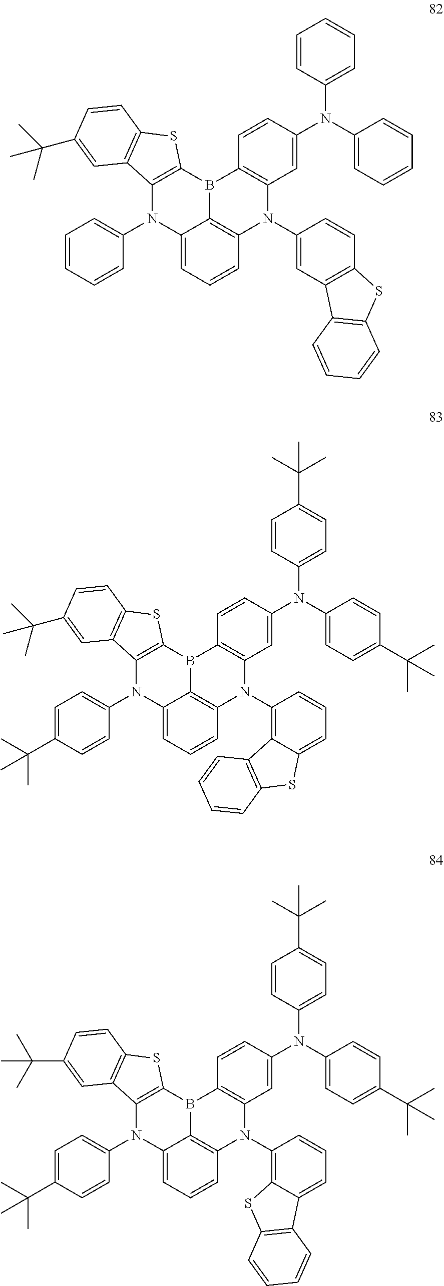

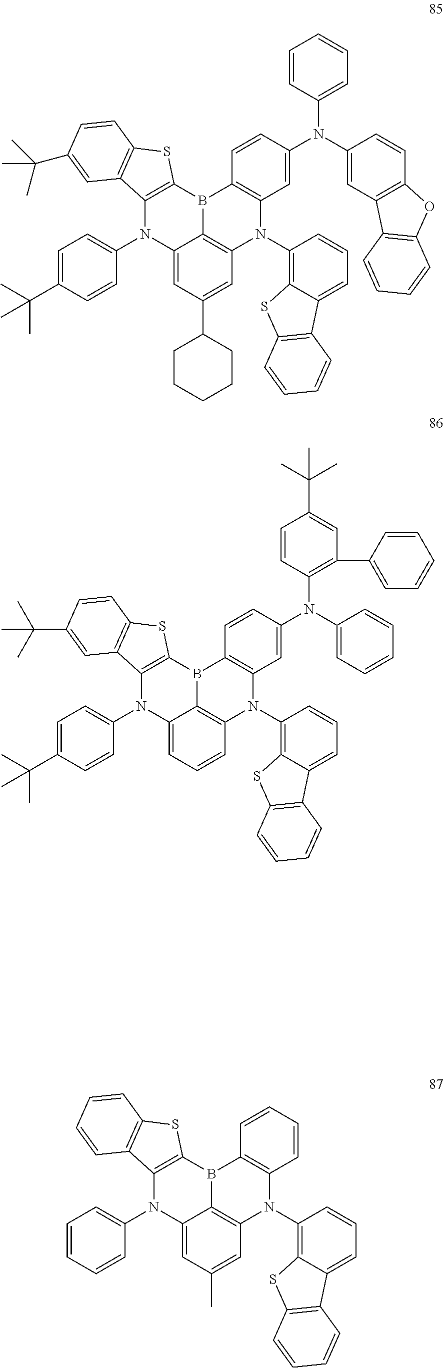 [SMILES: CC(C)(C)c1ccc(N2c3cc(C4CCCCC4)cc4c3B(c3ccc(N(c5ccccc5)c5ccc6oc7ccccc7c6c5)cc3N4c3cccc4c3sc3ccccc34)c3sc4ccc(C(C)(C)C)cc4c32)cc1 ; CC(C)(C)c1ccc(N2c3cccc4c3B(c3ccc(N(c5ccccc5)c5ccc(C(C)(C)C)cc5-c5ccccc5)cc3N4c3cccc4c3sc3ccccc34)c3sc4ccc(C(C)(C)C)cc4c32)cc1 ; Cc1cc2c3c(c1)N(c1cccc4c1sc1ccccc14)c1ccccc1B3c1sc3ccccc3c1N2c1ccccc1]

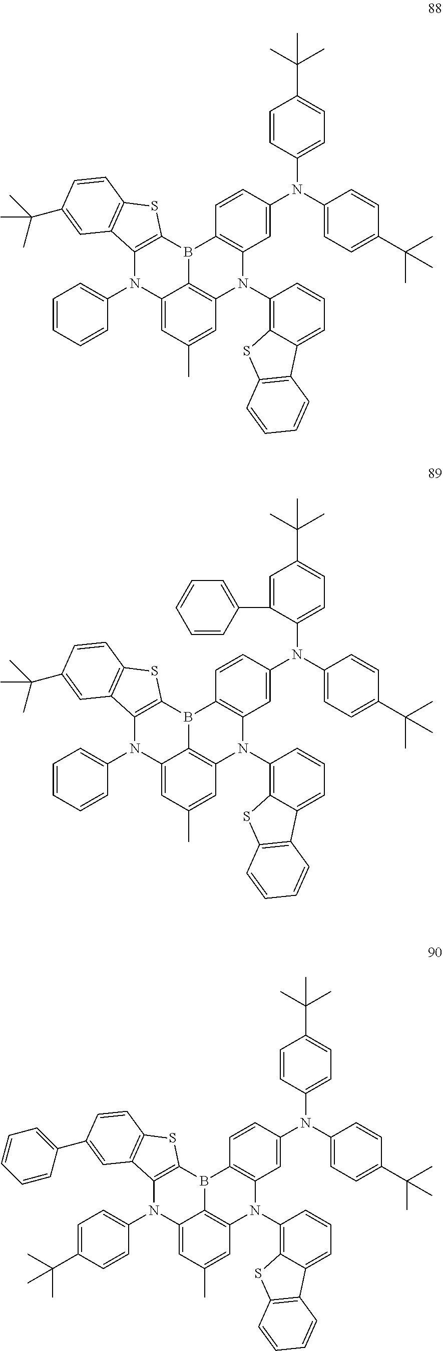

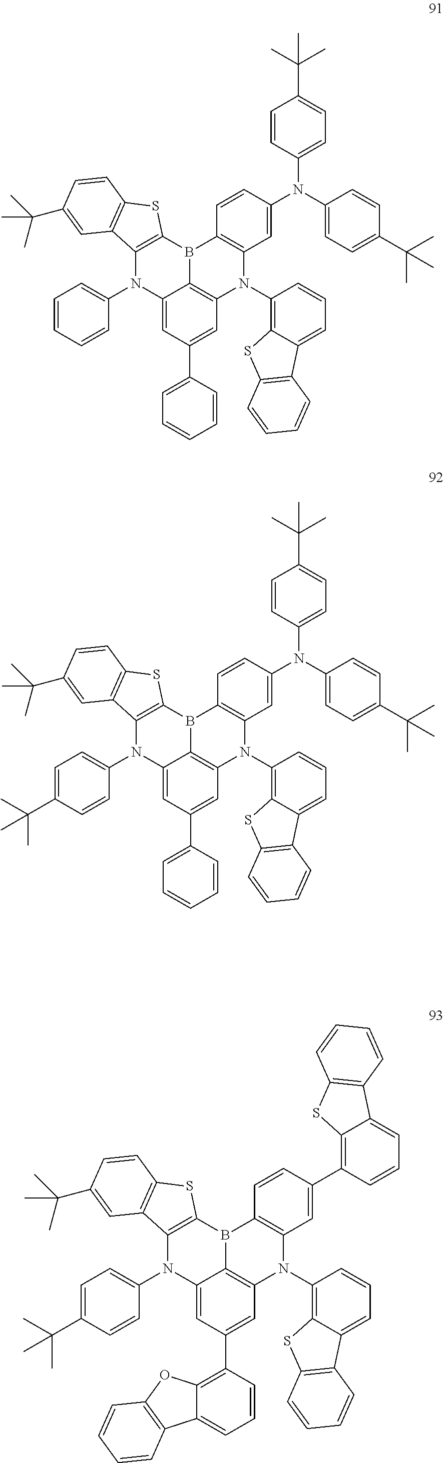

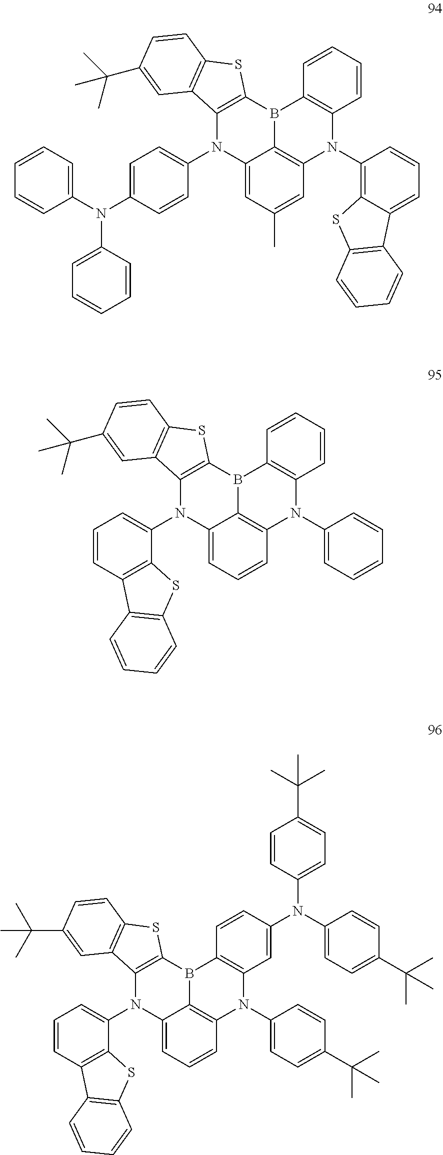 [SMILES: Cc1cc2c3c(c1)N(c1cccc4c1sc1ccccc14)c1ccccc1B3c1sc3ccc(C(C)(C)C)cc3c1N2c1ccc(N(c2ccccc2)c2ccccc2)cc1 ; CC(C)(C)c1ccc2sc3c(c2c1)N(c1cccc2c1sc1ccccc12)c1cccc2c1B3c1ccccc1N2c1ccccc1 ; CC(C)(C)c1ccc(N(c2ccc(C(C)(C)C)cc2)c2ccc3c(c2)N(c2ccc(C(C)(C)C)cc2)c2cccc4c2B3c2sc3ccc(C(C)(C)C)cc3c2N4c2cccc3c2sc2ccccc23)cc1]

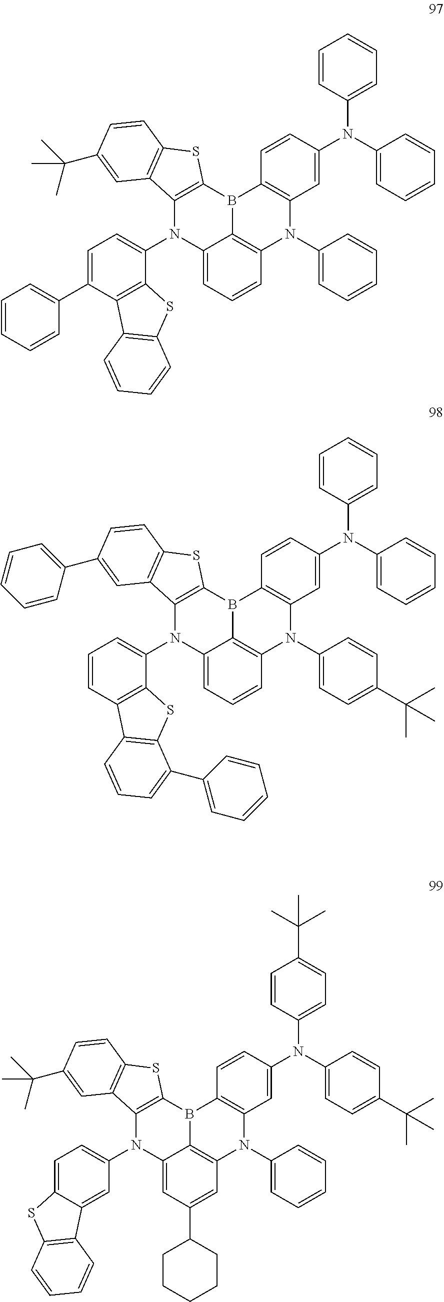

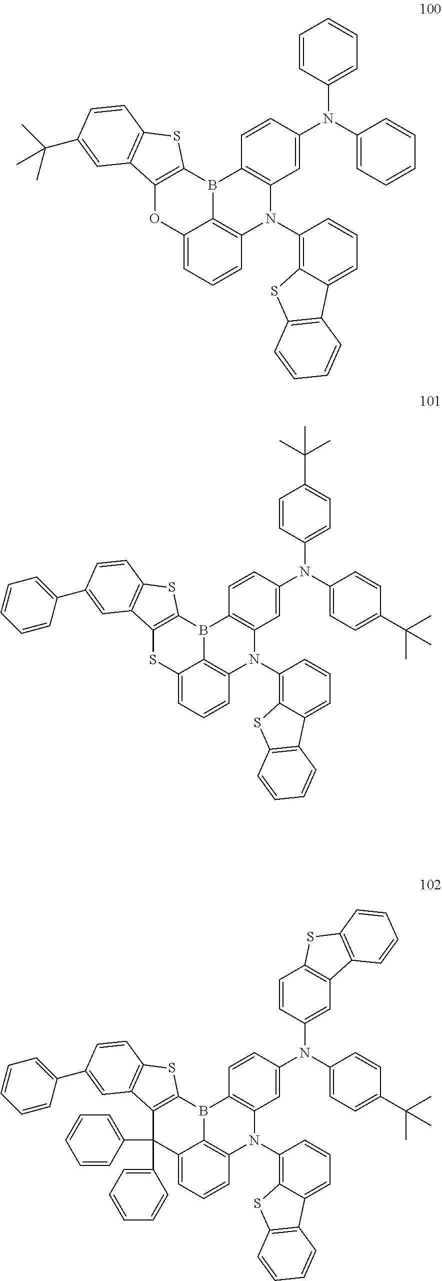 [SMILES: CC(C)(C)c1ccc2sc3c(c2c1)Oc1cccc2c1B3c1ccc(N(c3ccccc3)c3ccccc3)cc1N2c1cccc2c1sc1ccccc12 ; CC(C)(C)c1ccc(N(c2ccc(C(C)(C)C)cc2)c2ccc3c(c2)N(c2cccc4c2sc2ccccc24)c2cccc4c2B3c2sc3ccc(-c5ccccc5)cc3c2S4)cc1 ; CC(C)(C)c1ccc(N(c2ccc3c(c2)N(c2cccc4c2sc2ccccc24)c2cccc4c2B3c2sc3ccc(-c5ccccc5)cc3c2C4(c2ccccc2)c2ccccc2)c2ccc3sc4ccccc4c3c2)cc1]

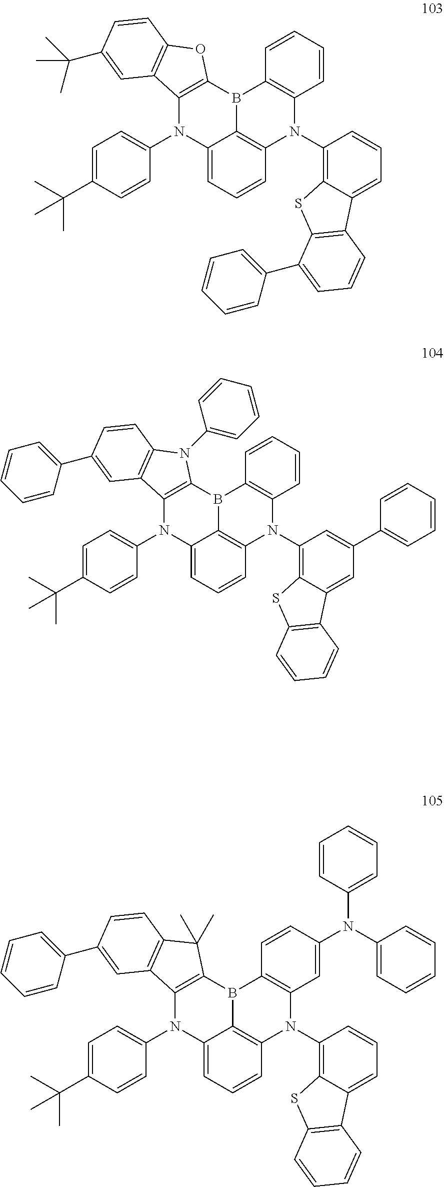 [SMILES: CC(C)(C)c1ccc(N2c3cccc4c3B(c3ccccc3N4c3cccc4c3sc3c(-c5ccccc5)cccc34)c3oc4ccc(C(C)(C)C)cc4c32)cc1 ; CC(C)(C)c1ccc(N2c3cccc4c3B(c3ccccc3N4c3cc(-c4ccccc4)cc4c3sc3ccccc34)c3c2c2cc(-c4ccccc4)ccc2n3-c2ccccc2)cc1 ; CC(C)(C)c1ccc(N2C3=C(B4c5ccc(N(c6ccccc6)c6ccccc6)cc5N(c5cccc6c5sc5ccccc56)c5cccc2c54)C(C)(C)c2ccc(-c4ccccc4)cc23)cc1]

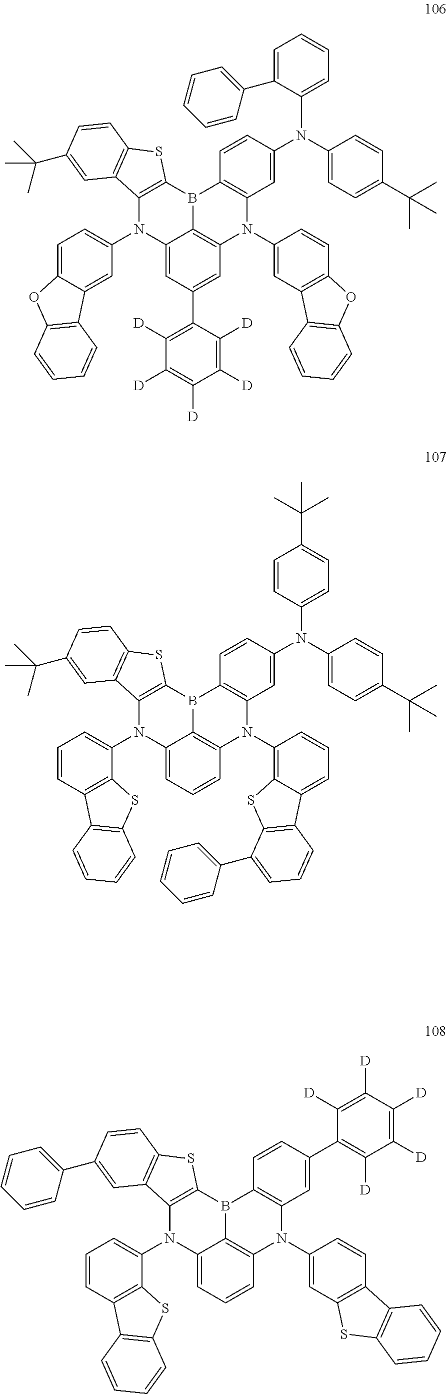

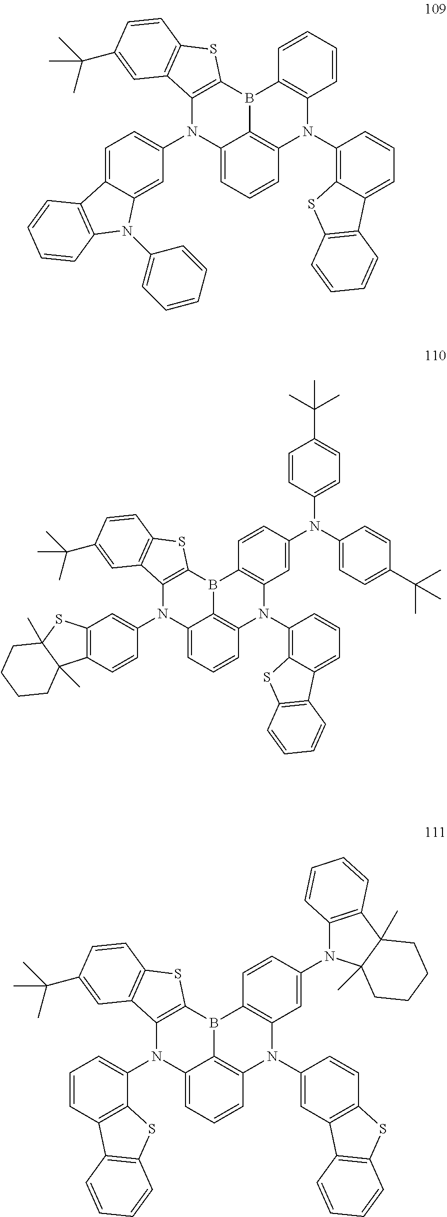

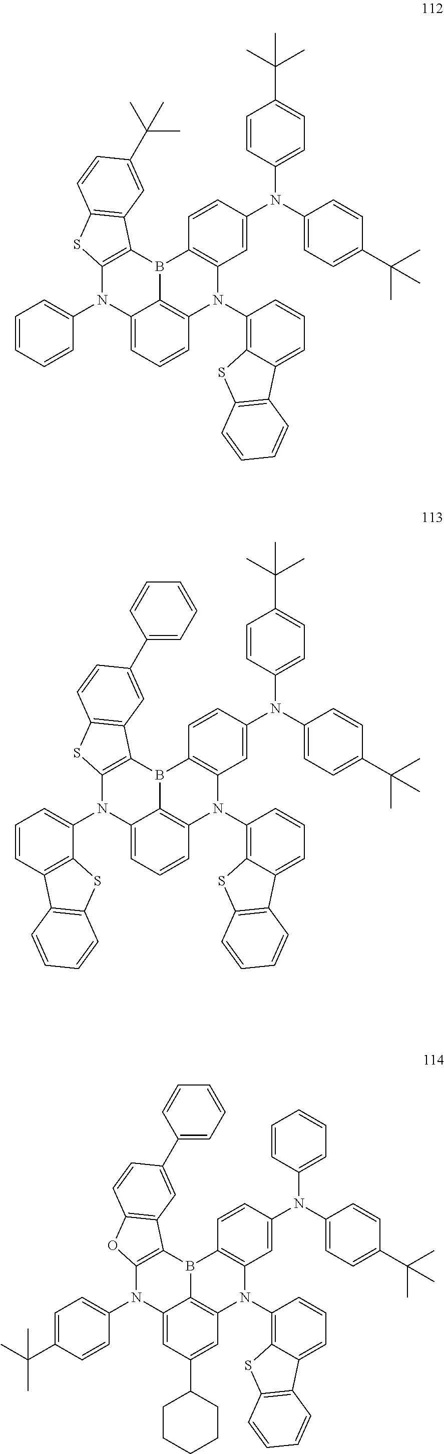

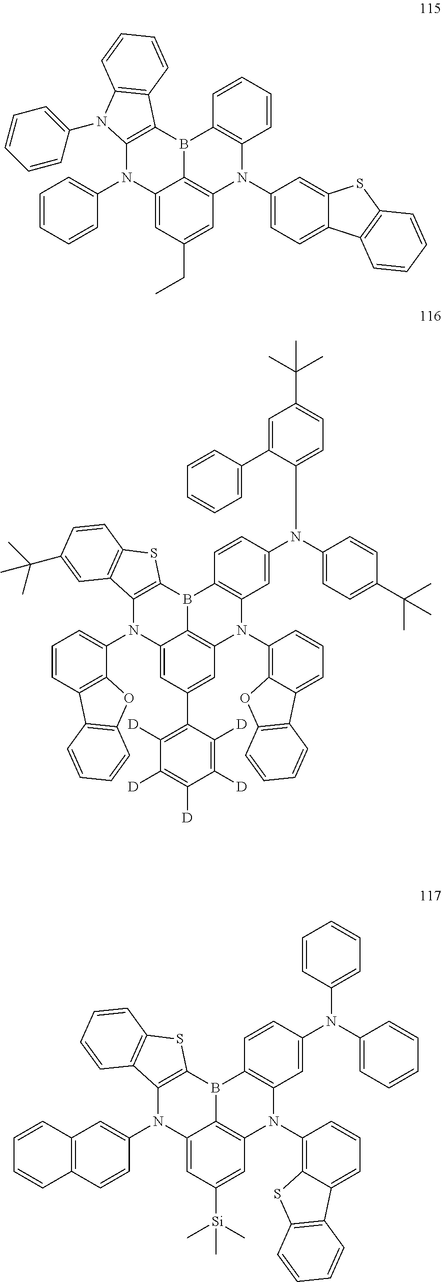 [SMILES: CCc1cc2c3c(c1)N(c1ccccc1)c1c(c4ccccc4n1-c1ccccc1)B3c1ccccc1N2c1ccc2c(c1)sc1ccccc12 ; [2H]c1c([2H])c([2H])c(-c2cc3c4c(c2)N(c2cccc5c2oc2ccccc25)c2c(sc5ccc(C(C)(C)C)cc25)B4c2ccc(N(c4ccc(C(C)(C)C)cc4)c4ccc(C(C)(C)C)cc4-c4ccccc4)cc2N3c2cccc3c2oc2ccccc23)c([2H])c1[2H] ; C[Si](C)(C)c1cc2c3c(c1)N(c1cccc4c1sc1ccccc14)c1cc(N(c4ccccc4)c4ccccc4)ccc1B3c1sc3ccccc3c1N2c1ccc2ccccc2c1]

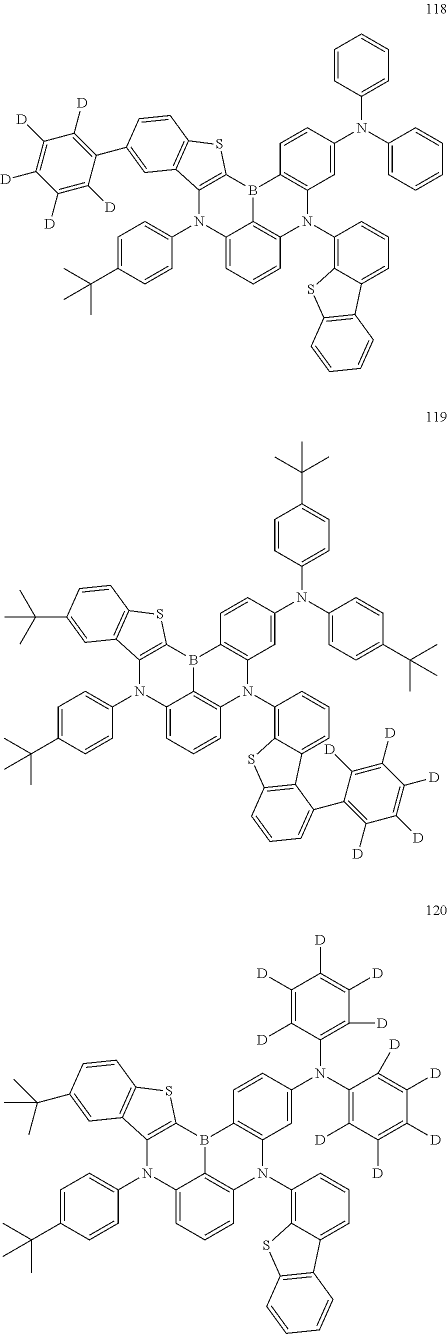

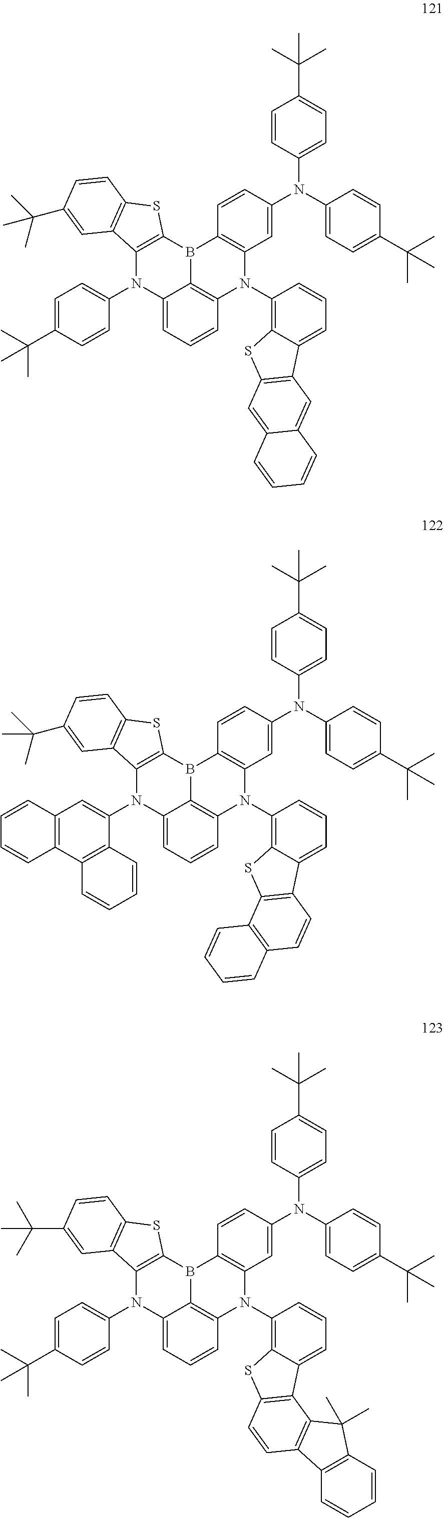

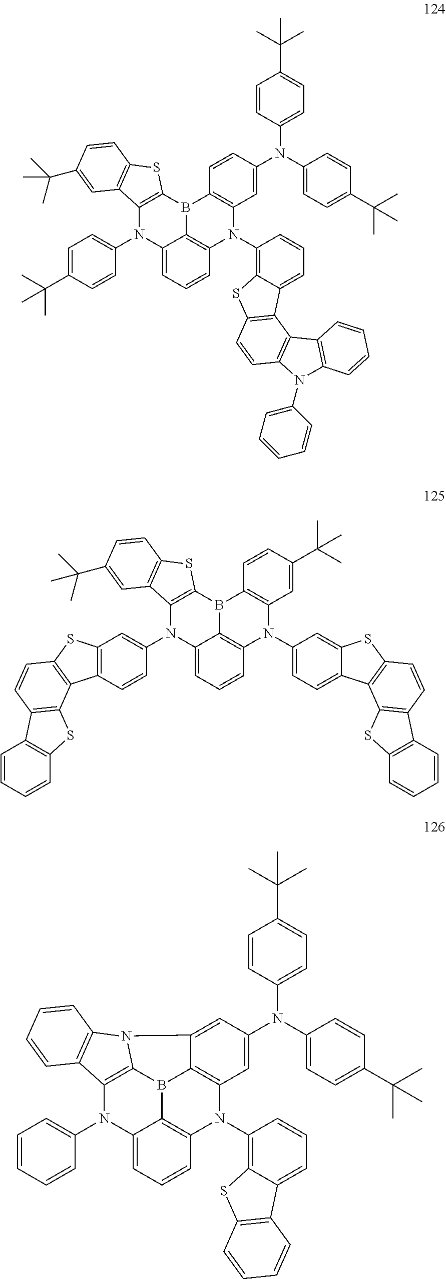 [SMILES: CC(C)(C)c1ccc(N(c2ccc(C(C)(C)C)cc2)c2ccc3c(c2)N(c2cccc4c2sc2ccc5c(c6ccccc6n5-c5ccccc5)c24)c2cccc4c2B3c2sc3ccc(C(C)(C)C)cc3c2N4c2ccc(C(C)(C)C)cc2)cc1 ; CC(C)(C)c1ccc2c(c1)N(c1ccc3c(c1)sc1ccc4c5ccccc5sc4c13)c1cccc3c1B2c1sc2ccc(C(C)(C)C)cc2c1N3c1ccc2c(c1)sc1ccc3c4ccccc4sc3c12 ; CC(C)(C)c1ccc(N(c2ccc(C(C)(C)C)cc2)c2cc3c4c(c2)-n2c5c(c6ccccc62)N(c2ccccc2)c2cccc(c2B45)N3c2cccc3c2sc2ccccc23)cc1]

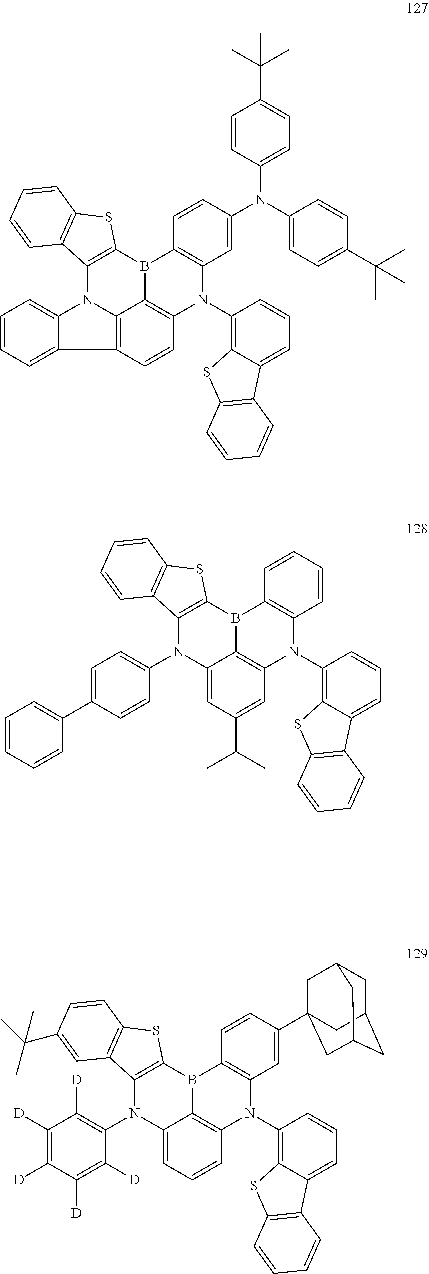

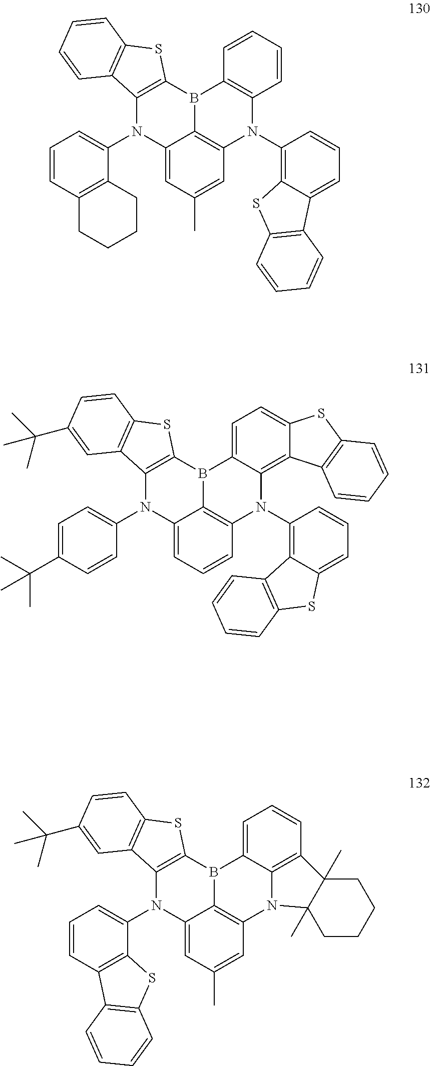 [SMILES: Cc1cc2c3c(c1)N(c1cccc4c1sc1ccccc14)c1ccccc1B3c1sc3ccccc3c1N2c1cccc2c1CCCC2 ; CC(C)(C)c1ccc(N2c3cccc4c3B(c3ccc5sc6ccccc6c5c3N4c3cccc4sc5ccccc5c34)c3sc4ccc(C(C)(C)C)cc4c32)cc1 ; Cc1cc2c3c(c1)N1c4c(cccc4C4(C)CCCCC14C)B3c1sc3ccc(C(C)(C)C)cc3c1N2c1cccc2c1sc1ccccc12]

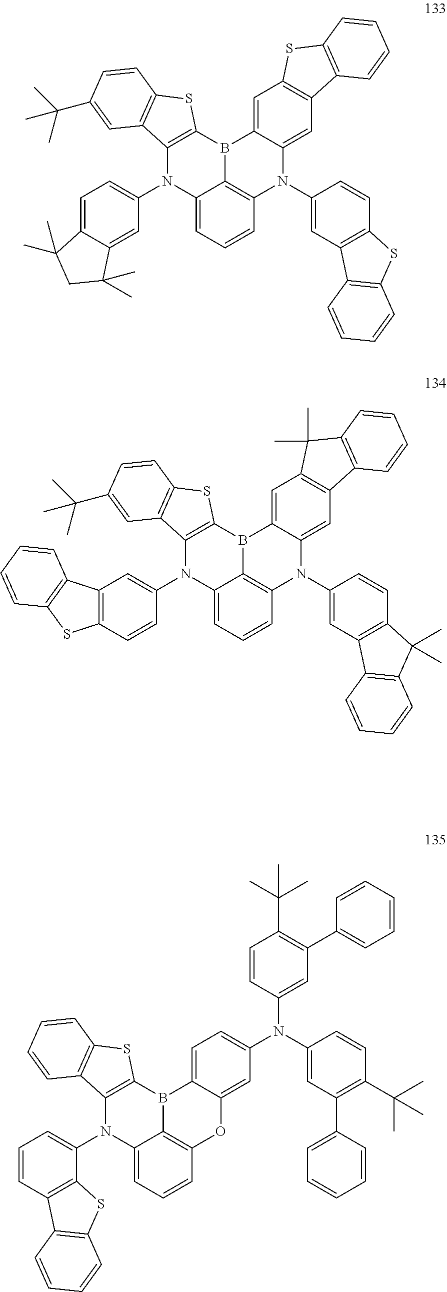 [SMILES: CC(C)(C)c1ccc2sc3c(c2c1)N(c1ccc2c(c1)C(C)(C)CC2(C)C)c1cccc2c1B3c1cc3sc4ccccc4c3cc1N2c1ccc2sc3ccccc3c2c1 ; CC(C)(C)c1ccc2sc3c(c2c1)N(c1ccc2sc4ccccc4c2c1)c1cccc2c1B3c1cc3c(cc1N2c1ccc2c(c1)-c1ccccc1C2(C)C)-c1ccccc1C3(C)C ; CC(C)(C)c1ccc(N(c2ccc3c(c2)Oc2cccc4c2B3c2sc3ccccc3c2N4c2cccc3c2sc2ccccc23)c2ccc(C(C)(C)C)c(-c3ccccc3)c2)cc1-c1ccccc1]

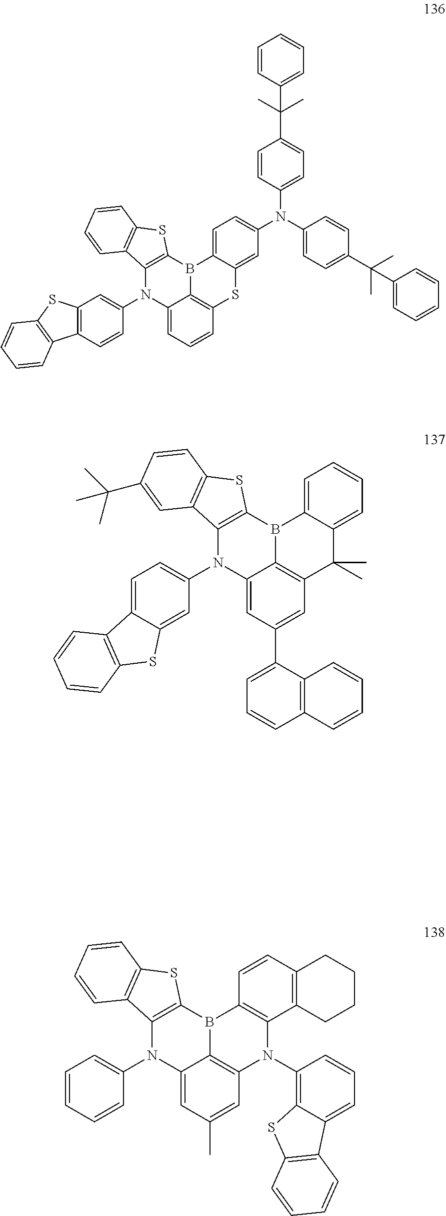 [SMILES: CC(C)(c1ccccc1)c1ccc(N(c2ccc(C(C)(C)c3ccccc3)cc2)c2ccc3c(c2)Sc2cccc4c2B3c2sc3ccccc3c2N4c2ccc3c(c2)sc2ccccc23)cc1 ; CC(C)(C)c1ccc2sc3c(c2c1)N(c1ccc2c(c1)sc1ccccc12)c1cc(-c2cccc4ccccc24)cc2c1B3c1ccccc1C2(C)C ; Cc1cc2c3c(c1)N(c1cccc4c1sc1ccccc14)c1c(ccc4c1CCCC4)B3c1sc3ccccc3c1N2c1ccccc1]

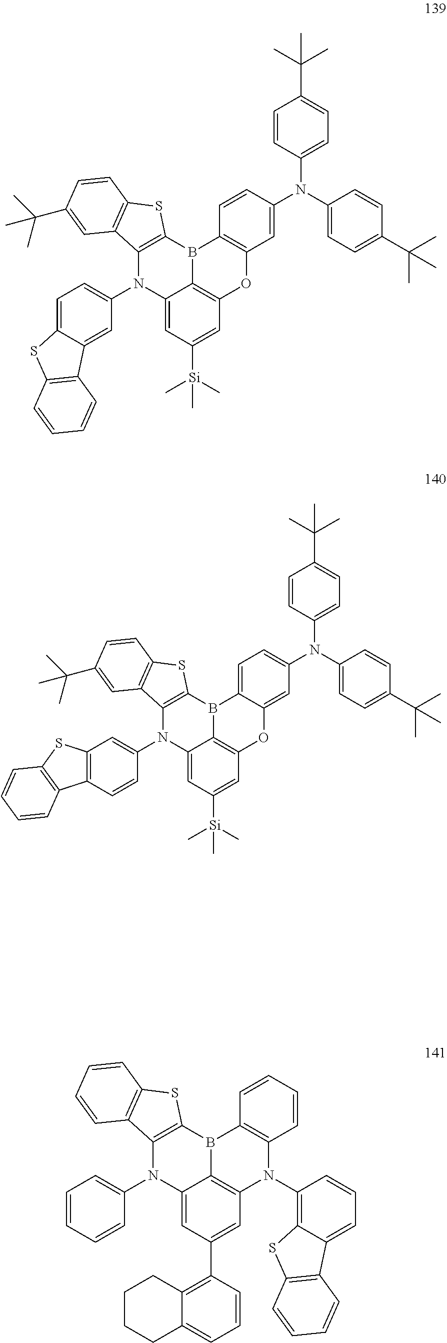 [SMILES: CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3sc4ccccc4c3c2)cc1 ; CC(C)(C)c1ccc(N(c2ccc(C(C)(C)C)cc2)c2ccc3c(c2)Oc2cc([Si](C)(C)C)cc4c2B3c2sc3ccc(C(C)(C)C)cc3c2N4c2ccc3c(c2)sc2ccccc23)cc1 ; c1ccc(N2c3cc(-c4cccc5c4CCCC5)cc4c3B(c3ccccc3N4c3cccc4c3sc3ccccc34)c3sc4ccccc4c32)cc1]

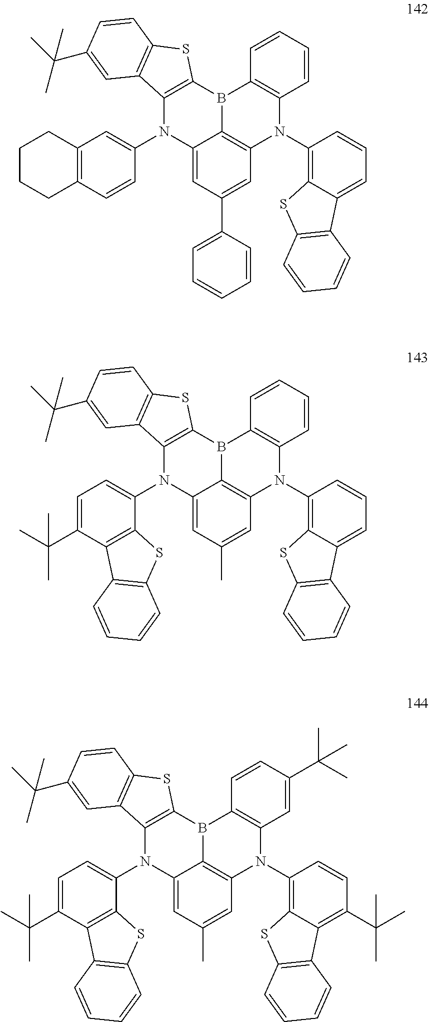 [SMILES: CC(C)(C)c1ccc2sc3c(c2c1)N(c1ccc2c(c1)CCCC2)c1cc(-c2ccccc2)cc2c1B3c1ccccc1N2c1cccc2c1sc1ccccc12 ; Cc1cc2c3c(c1)N(c1ccc(C(C)(C)C)c4c1sc1ccccc14)c1c(sc4ccc(C(C)(C)C)cc14)B3c1ccccc1N2c1cccc2c1sc1ccccc12 ; Cc1cc2c3c(c1)N(c1ccc(C(C)(C)C)c4c1sc1ccccc14)c1c(sc4ccc(C(C)(C)C)cc14)B3c1ccc(C(C)(C)C)cc1N2c1ccc(C(C)(C)C)c2c1sc1ccccc12]

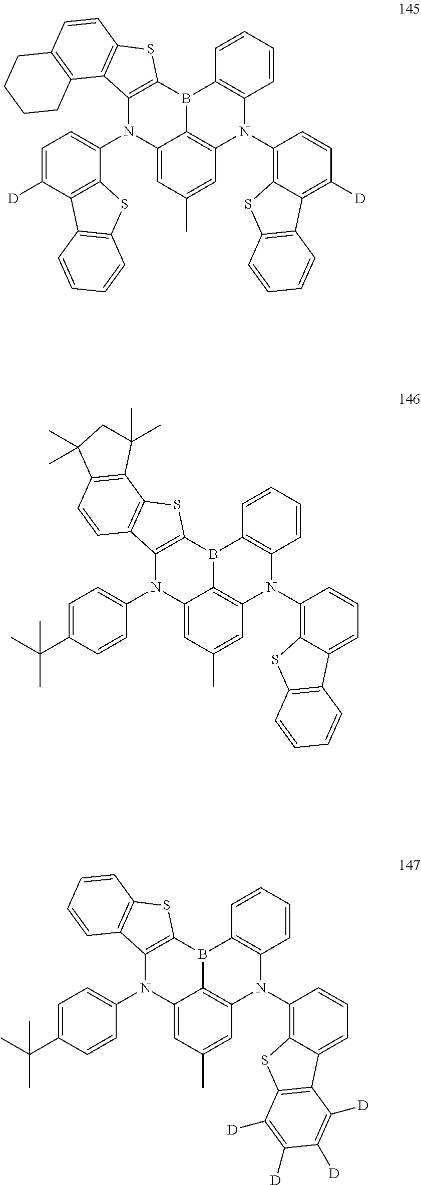 [SMILES: [2H]c1ccc(N2c3ccccc3B3c4sc5ccc6c(c5c4N(c4ccc([2H])c5c4sc4ccccc45)c4cc(C)cc2c43)CCCC6)c2sc3ccccc3c12 ; Cc1cc2c3c(c1)N(c1cccc4c1sc1ccccc14)c1ccccc1B3c1sc3c4c(ccc3c1N2c1ccc(C(C)(C)C)cc1)C(C)(C)CC4(C)C ; [2H]c1c([2H])c([2H])c2c(sc3c(N4c5ccccc5B5c6sc7ccccc7c6N(c6ccc(C(C)(C)C)cc6)c6cc(C)cc4c65)cccc32)c1[2H]]

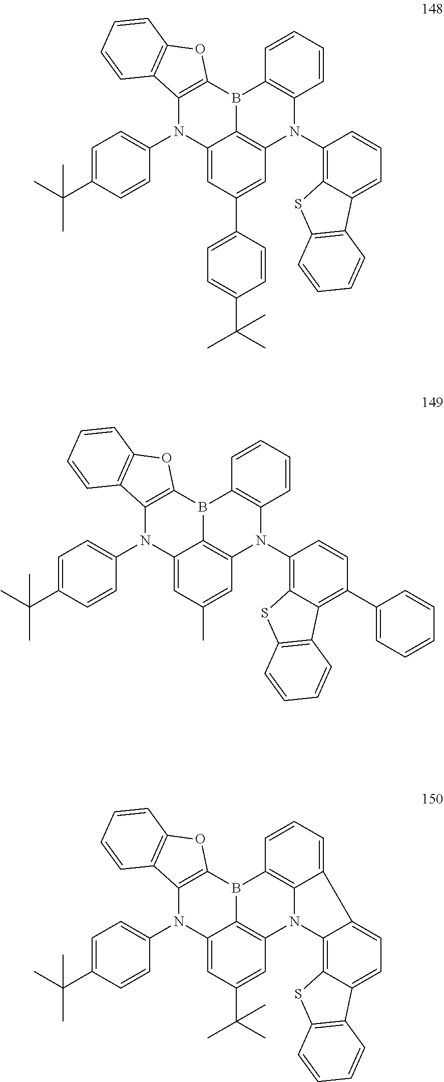 [SMILES: CC(C)(C)c1ccc(-c2cc3c4c(c2)N(c2cccc5c2sc2ccccc25)c2ccccc2B4c2oc4ccccc4c2N3c2ccc(C(C)(C)C)cc2)cc1 ; Cc1cc2c3c(c1)N(c1ccc(-c4ccccc4)c4c1sc1ccccc14)c1ccccc1B3c1oc3ccccc3c1N2c1ccc(C(C)(C)C)cc1 ; CC(C)(C)c1ccc(N2c3cc(C(C)(C)C)cc4c3B(c3oc5ccccc5c32)c2cccc3c5ccc6c7ccccc7sc6c5n-4c23)cc1]

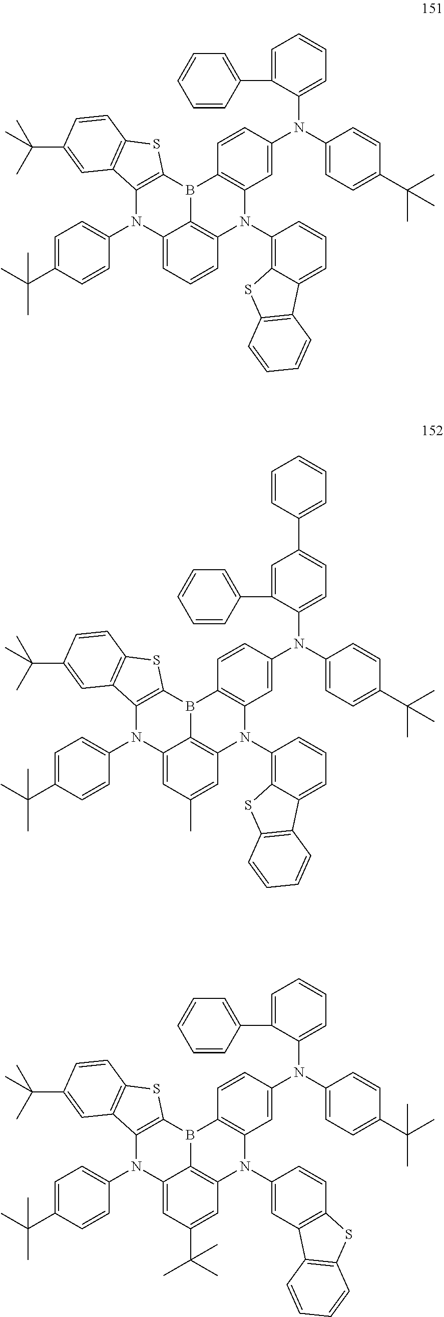

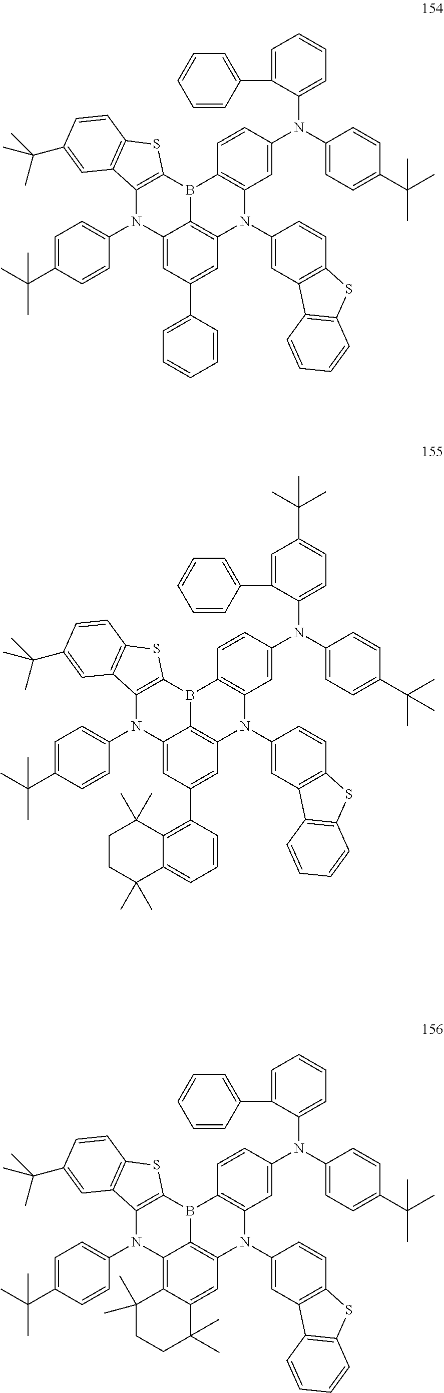

4. An organic electroluminescent device comprising a first electrode, a second electrode opposite to the first electrode, and one or more organic layers interposed between the first and second electrodes wherein one of the organic layers comprises the compound represented by Formula A-1 or A-2 according to claim 1.

5. The organic electroluminescent device according to claim 4, wherein the organic layers comprise an electron injecting layer, an electron transport layer, a hole injecting layer, a hole transport layer, an electron blocking layer, a hole blocking layer, and/or a light emitting layer, at least one of which comprises the organic electroluminescent compound represented by Formula A-1 or A-2.

6. The organic electroluminescent device according to claim 5, wherein the light emitting layer is composed of a host and the compound represented by Formula A-1 or A-2 as a dopant.

7. The organic electroluminescent device according to claim 6, wherein the host is an anthracene compound represented by Formula B: 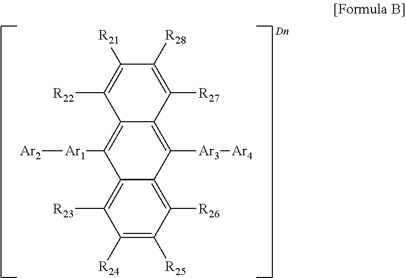
wherein R₂₁ to R₂₈ are the same as or different from each other and are each independently selected from hydrogen, substituted or unsubstituted C₁-C₃₀ alkyl, substituted or unsubstituted C₂-C₃₀ alkenyl, substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted C₂-C₅₀ fused polycyclic non-aromatic heterocyclic rings, nitro, cyano, and halogen, An and Ar₃ are the same as or different from each other and are each independently substituted or unsubstituted C₆-C₃₀ arylene or substituted or unsubstituted C₅-C₃₀ heteroarylene, Are and Ar₄ are the same as or different from each other and are each independently selected from hydrogen, substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and substituted or unsubstituted C₂-C₅₀ fused polycyclic non-aromatic heterocyclic rings, Dₙ represents the number of deuterium atoms replacing hydrogen atoms in Ar₁ to Ar₄, and n is an integer from 0 to 30.

8. The organic electroluminescent device according to claim 7, wherein the compound represented by Formula B is selected from the following compounds:

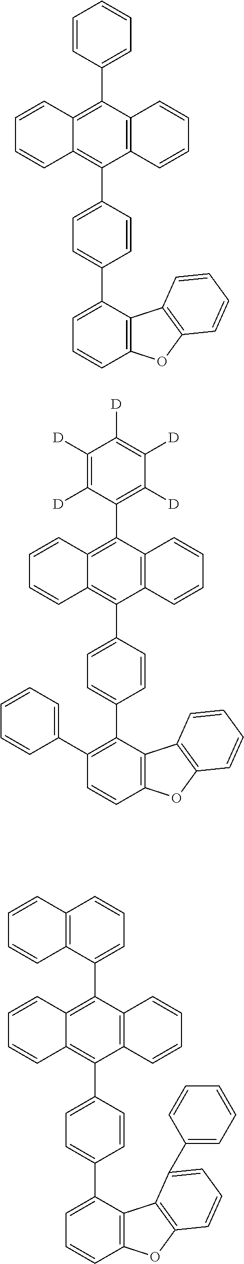

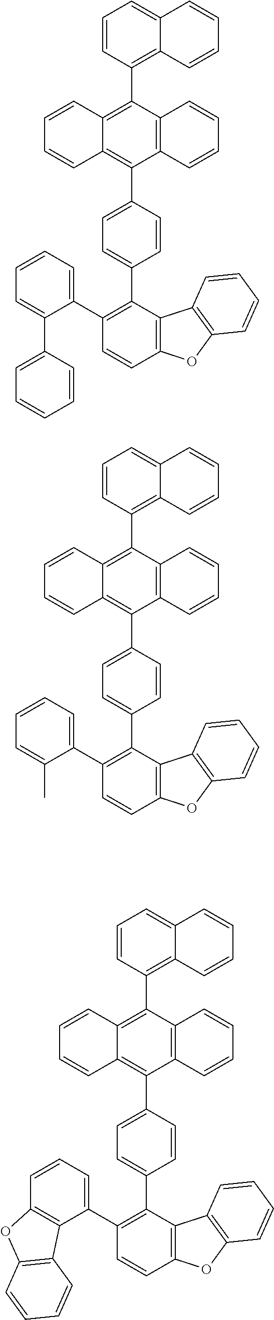 [SMILES: c1ccc(-c2ccccc2-c2ccc3oc4ccccc4c3c2-c2ccc(-c3c4ccccc4c(-c4cccc5ccccc45)c4ccccc34)cc2)cc1 ; Cc1ccccc1-c1ccc2oc3ccccc3c2c1-c1ccc(-c2c3ccccc3c(-c3cccc4ccccc34)c3ccccc23)cc1 ; c1ccc2c(-c3c4ccccc4c(-c4ccc(-c5c(-c6cccc7oc8ccccc8c67)ccc6oc7ccccc7c56)cc4)c4ccccc34)cccc2c1]

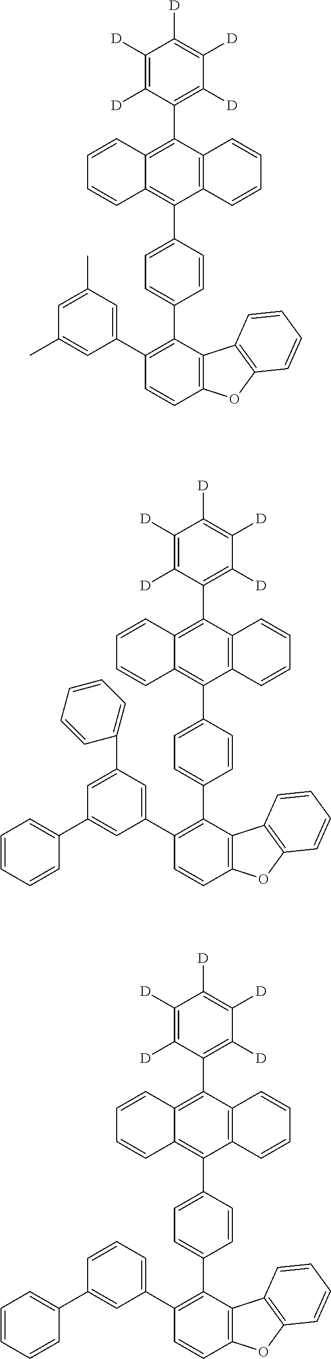 [SMILES: [2H]c1c([2H])c([2H])c(-c2c3ccccc3c(-c3ccc(-c4c(-c5cc(C)cc(C)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cc(-c6ccccc6)cc(-c6ccccc6)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cccc(-c6ccccc6)c5)ccc5oc6ccccc6c45)cc3)c3ccccc23)c([2H])c1[2H]]

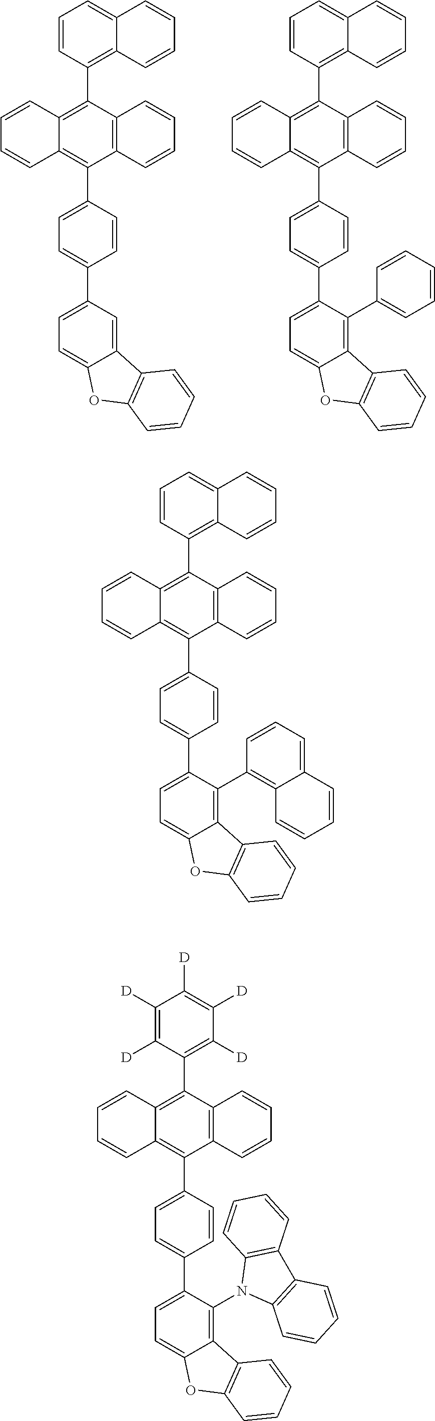

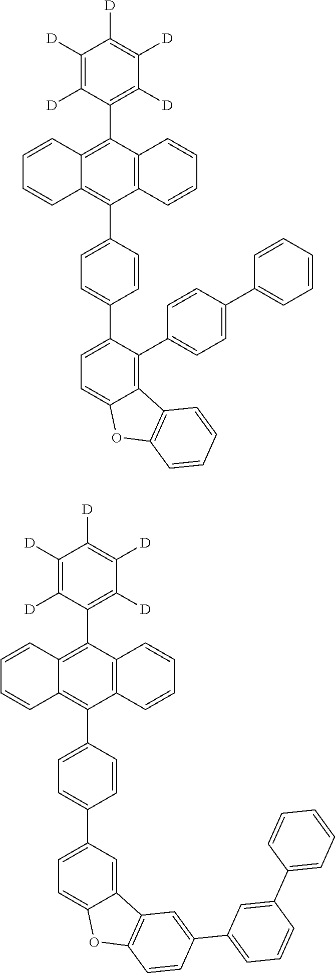 [SMILES: [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H]]

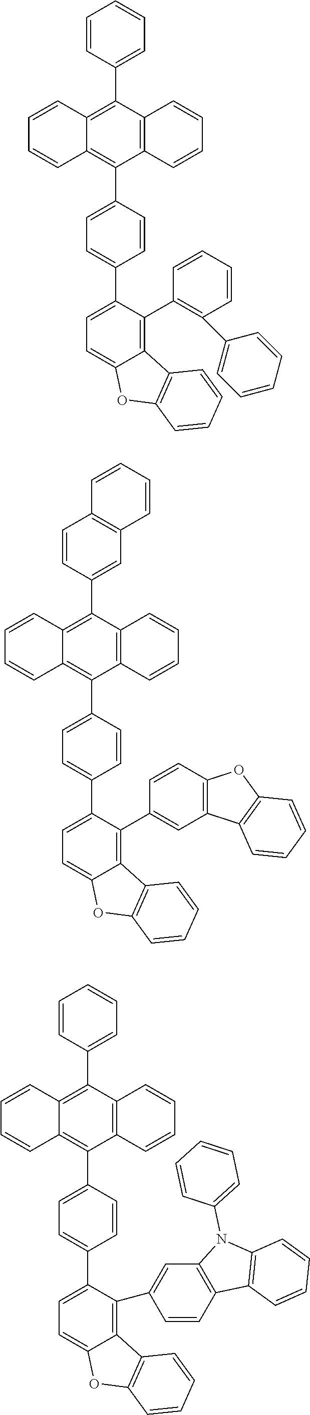 [SMILES: c1ccc(-c2ccccc2-c2c(-c3ccc(-c4c5ccccc5c(-c5ccccc5)c5ccccc45)cc3)ccc3oc4ccccc4c23)cc1 ; c1ccc2cc(-c3c4ccccc4c(-c4ccc(-c5ccc6oc7ccccc7c6c5-c5ccc6oc7ccccc7c6c5)cc4)c4ccccc34)ccc2c1 ; c1ccc(-c2c3ccccc3c(-c3ccc(-c4ccc5oc6ccccc6c5c4-c4ccc5c6ccccc6n(-c6ccccc6)c5c4)cc3)c3ccccc23)cc1]

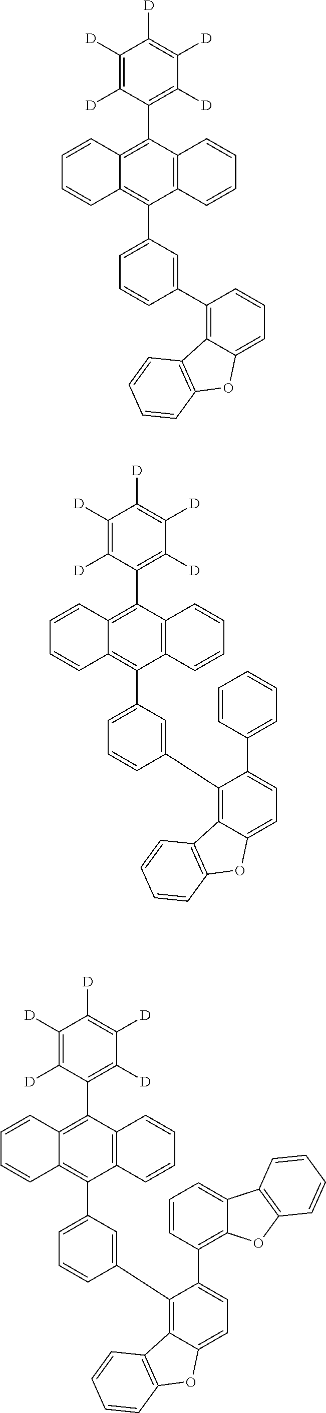 [SMILES: [2H]c1c([2H])c([2H])c(-c2c3ccccc3c(-c3cccc(-c4cccc5oc6ccccc6c45)c3)c3ccccc23)c([2H])c1[2H] ; [2H]c1c([2H])c([2H])c(-c2c3ccccc3c(-c3cccc(-c4c(-c5ccccc5)ccc5oc6ccccc6c45)c3)c3ccccc23)c([2H])c1[2H] ; [2H]c1c([2H])c([2H])c(-c2c3ccccc3c(-c3cccc(-c4c(-c5cccc6c5oc5ccccc56)ccc5oc6ccccc6c45)c3)c3ccccc23)c([2H])c1[2H]]

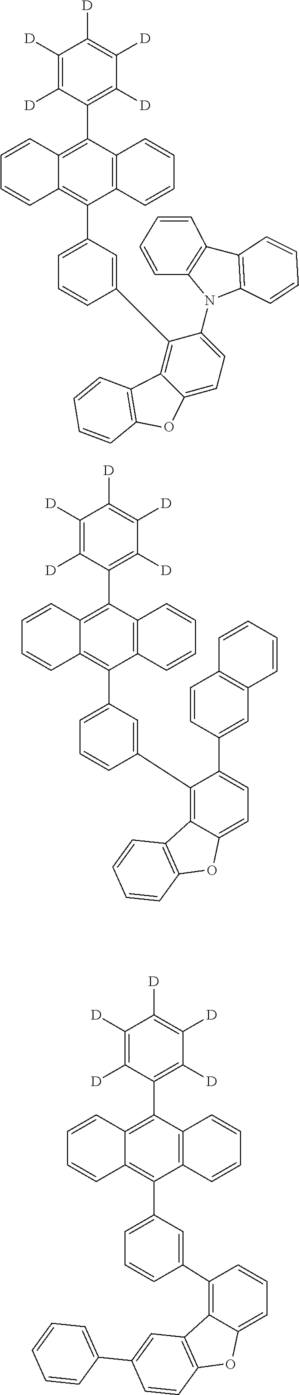

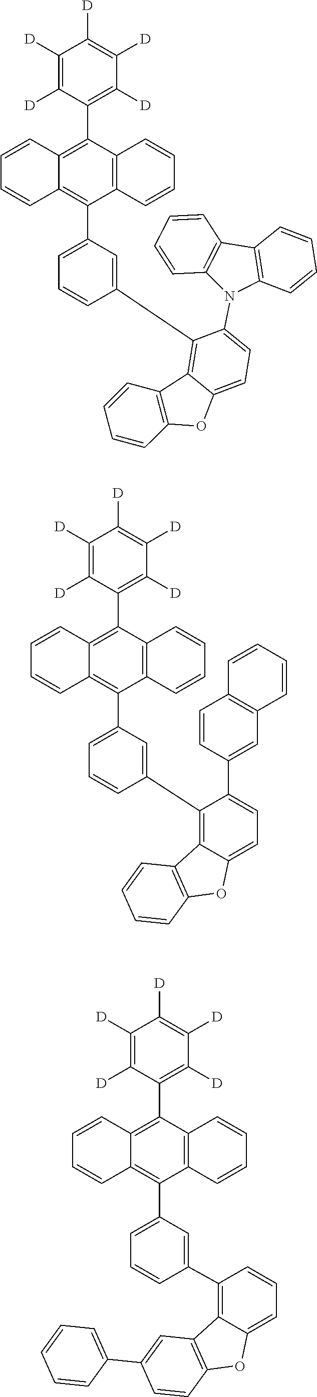 [SMILES: [2H]c1c([2H])c([2H])c(-c2c3ccccc3c(-c3cccc(-c4c(-n5c6ccccc6c6ccccc65)ccc5oc6ccccc6c45)c3)c3ccccc23)c([2H])c1[2H] ; [2H]c1c([2H])c([2H])c(-c2c3ccccc3c(-c3cccc(-c4c(-c5ccc6ccccc6c5)ccc5oc6ccccc6c45)c3)c3ccccc23)c([2H])c1[2H] ; [2H]c1c([2H])c([2H])c(-c2c3ccccc3c(-c3cccc(-c4cccc5oc6ccc(-c7ccccc7)cc6c45)c3)c3ccccc23)c([2H])c1[2H]]

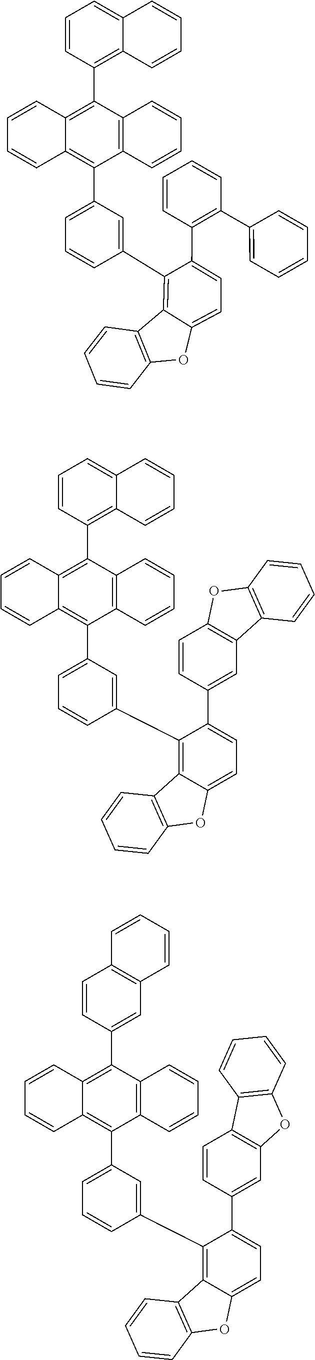 [SMILES: c1ccc(-c2ccccc2-c2ccc3oc4ccccc4c3c2-c2cccc(-c3c4ccccc4c(-c4cccc5ccccc45)c4ccccc34)c2)cc1 ; c1cc(-c2c3ccccc3c(-c3cccc4ccccc34)c3ccccc23)cc(-c2c(-c3ccc4oc5ccccc5c4c3)ccc3oc4ccccc4c23)c1 ; c1cc(-c2c3ccccc3c(-c3ccc4ccccc4c3)c3ccccc23)cc(-c2c(-c3ccc4c(c3)oc3ccccc34)ccc3oc4ccccc4c23)c1]

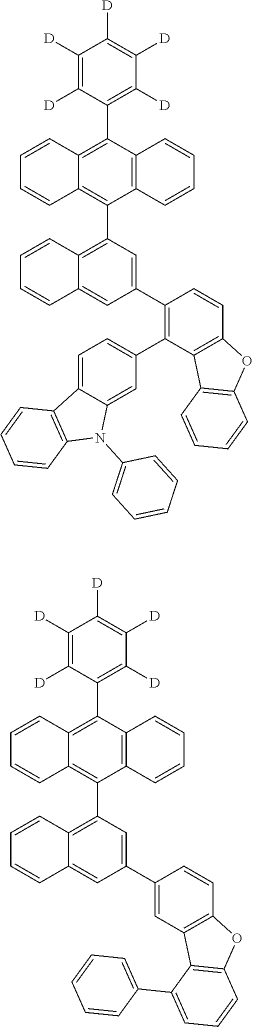 [SMILES: [2H]c1c([2H])c([2H])c(-c2c3ccccc3c(-c3cc(-c4ccc5oc6ccccc6c5c4-c4ccc5c6ccccc6n(-c6ccccc6)c5c4)cc4ccccc34)c3ccccc23)c([2H])c1[2H] ; [2H]c1c([2H])c([2H])c(-c2c3ccccc3c(-c3cc(-c4ccc5oc6cccc(-c7ccccc7)c6c5c4)cc4ccccc34)c3ccccc23)c([2H])c1[2H]]

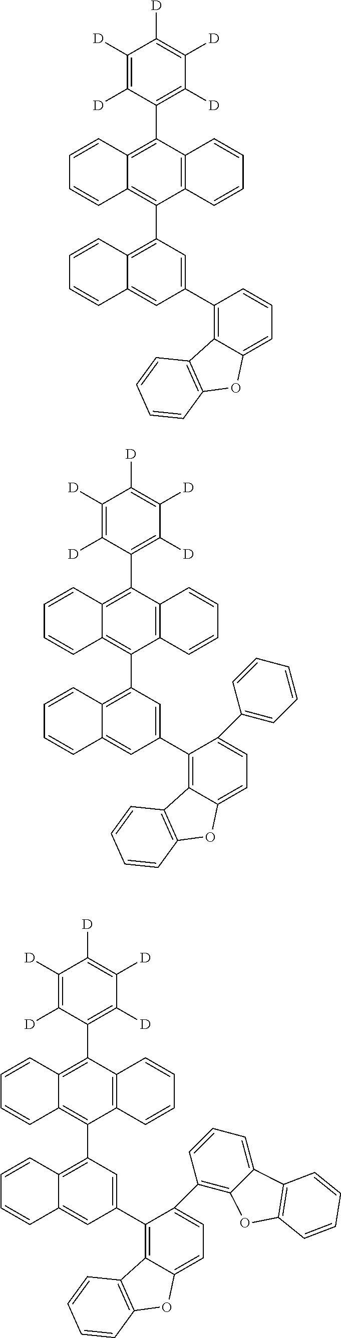

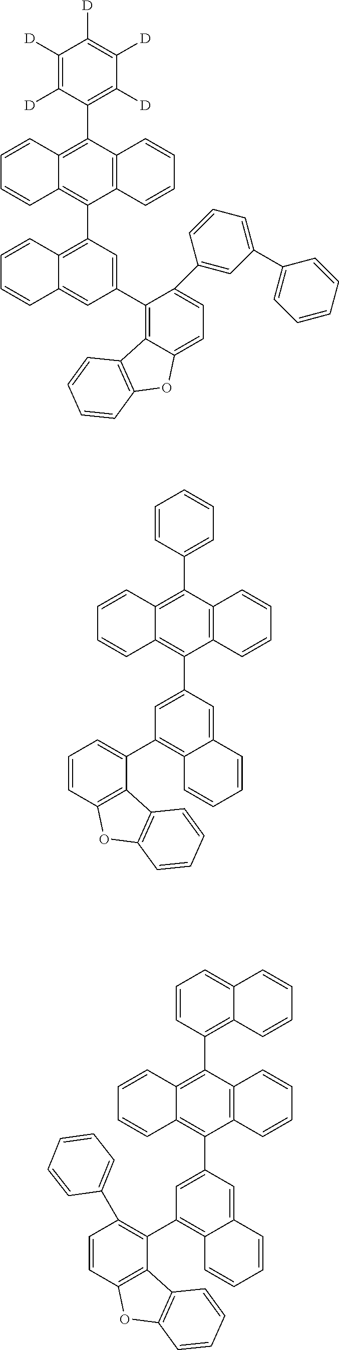 [SMILES: [2H]c1c([2H])c([2H])c(-c2c3ccccc3c(-c3cc(-c4c(-c5cccc(-c6ccccc6)c5)ccc5oc6ccccc6c45)cc4ccccc34)c3ccccc23)c([2H])c1[2H] ; c1ccc(-c2c3ccccc3c(-c3cc(-c4cccc5oc6ccccc6c45)c4ccccc4c3)c3ccccc23)cc1 ; c1ccc(-c2ccc3oc4ccccc4c3c2-c2cc(-c3c4ccccc4c(-c4cccc5ccccc45)c4ccccc34)cc3ccccc23)cc1]

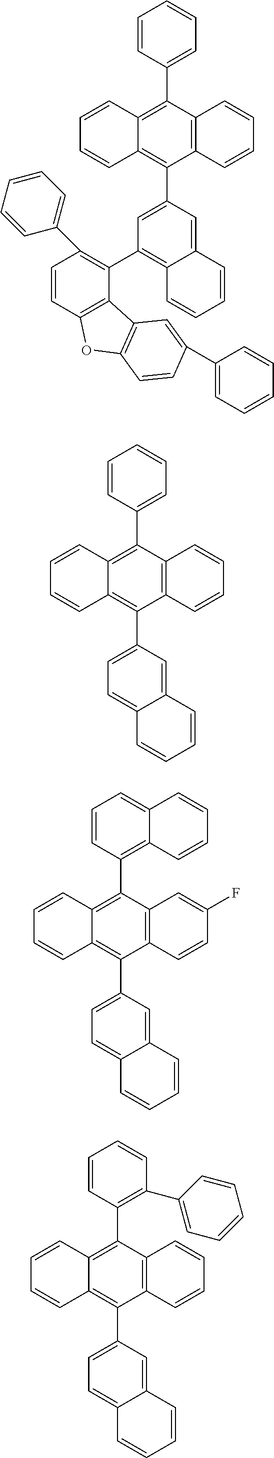

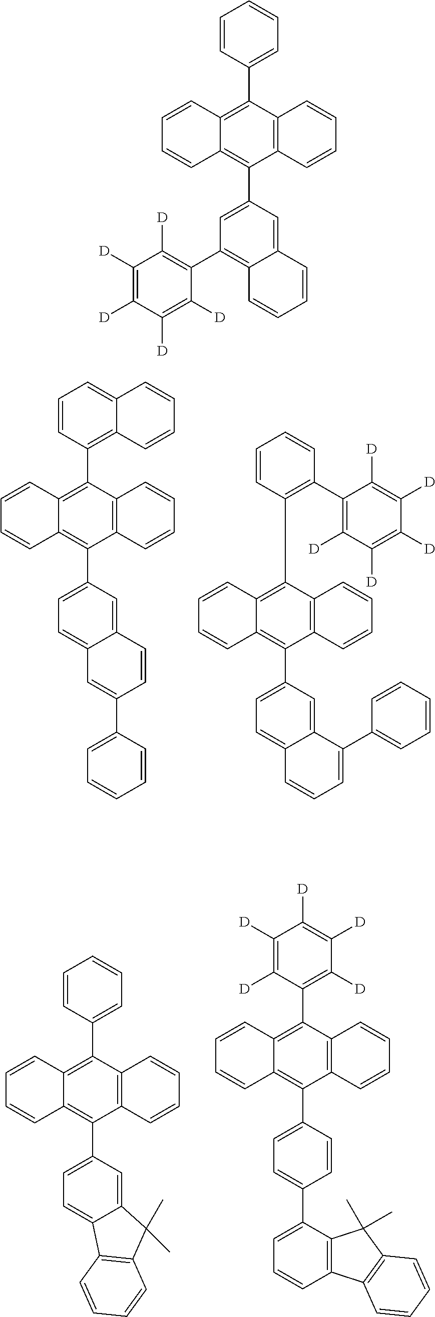

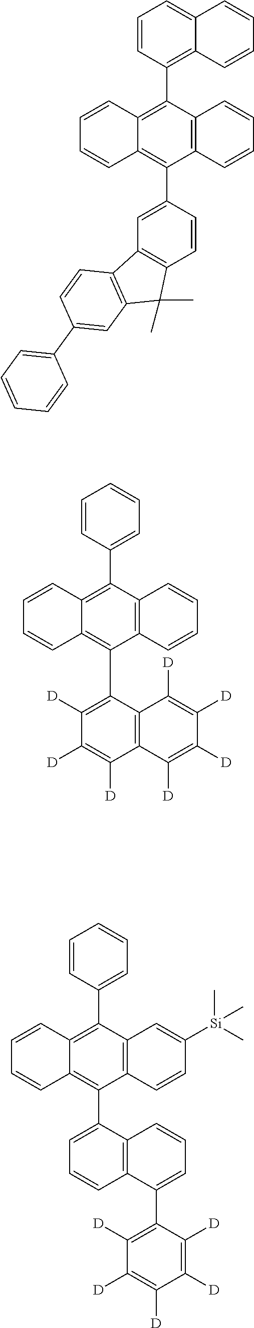

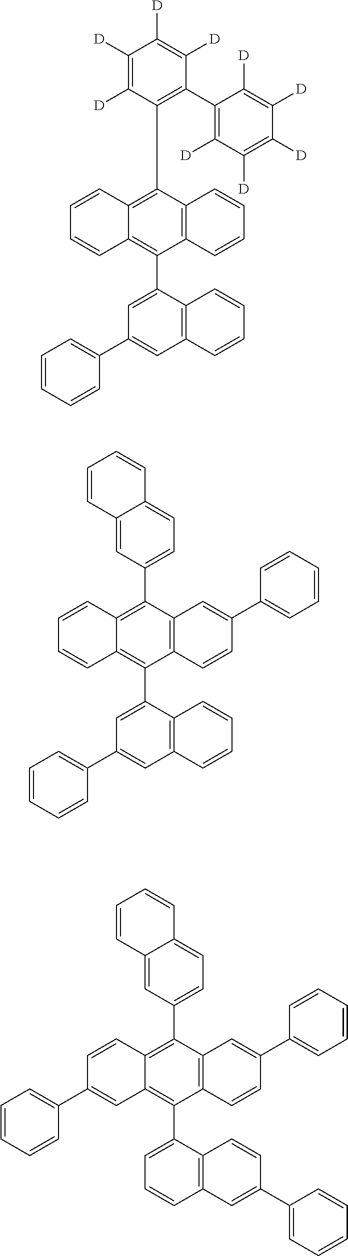

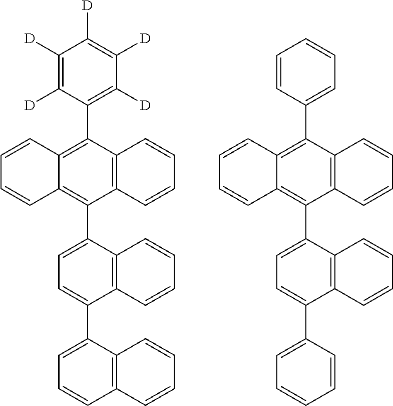

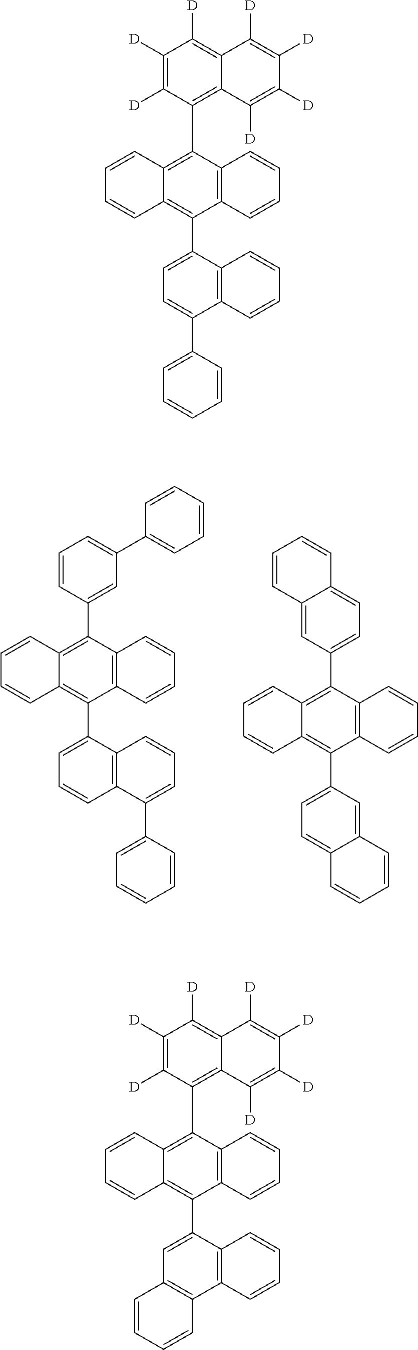

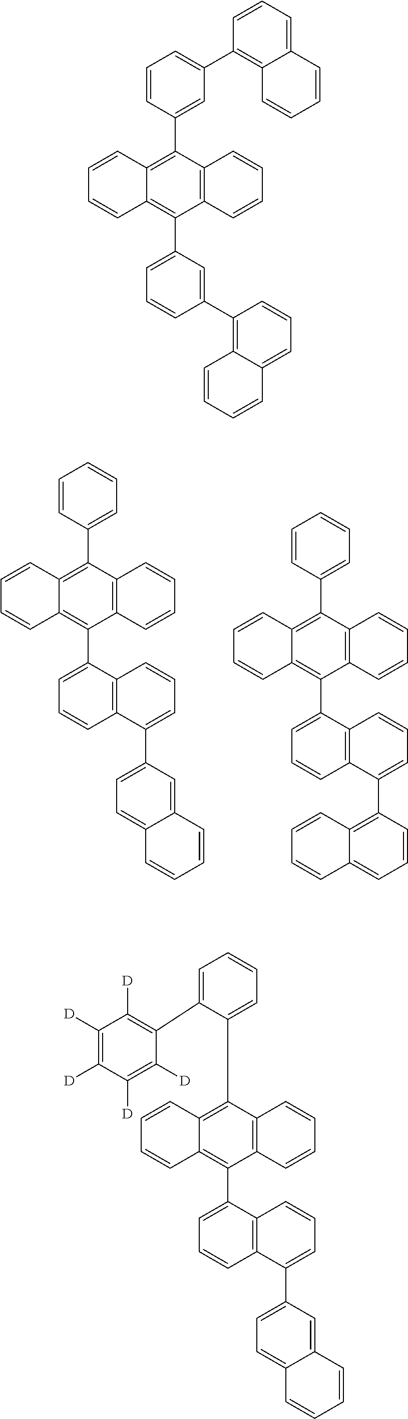

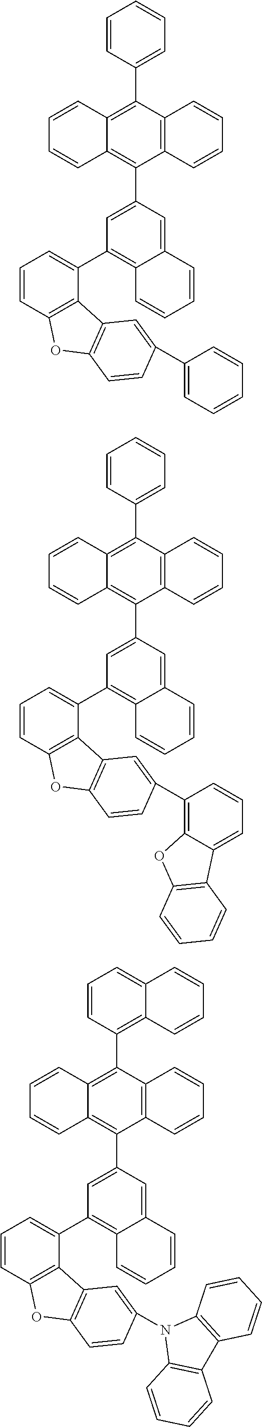

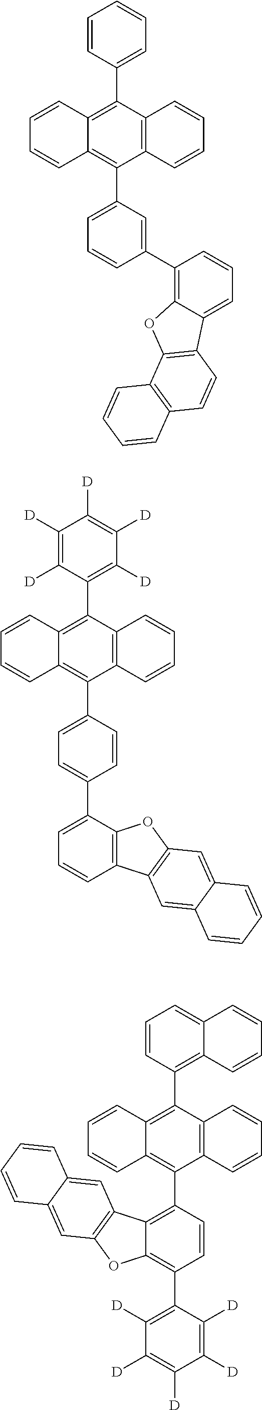 [SMILES: c1ccc(-c2c3ccccc3c(-c3cccc(-c4cccc5c4oc4c6ccccc6ccc54)c3)c3ccccc23)cc1 ; [2H]c1c([2H])c([2H])c(-c2c3ccccc3c(-c3ccc(-c4cccc5c4oc4cc6ccccc6cc45)cc3)c3ccccc23)c([2H])c1[2H] ; [2H]c1c([2H])c([2H])c(-c2ccc(-c3c4ccccc4c(-c4cccc5ccccc45)c4ccccc34)c3c2oc2cc4ccccc4cc23)c([2H])c1[2H]]

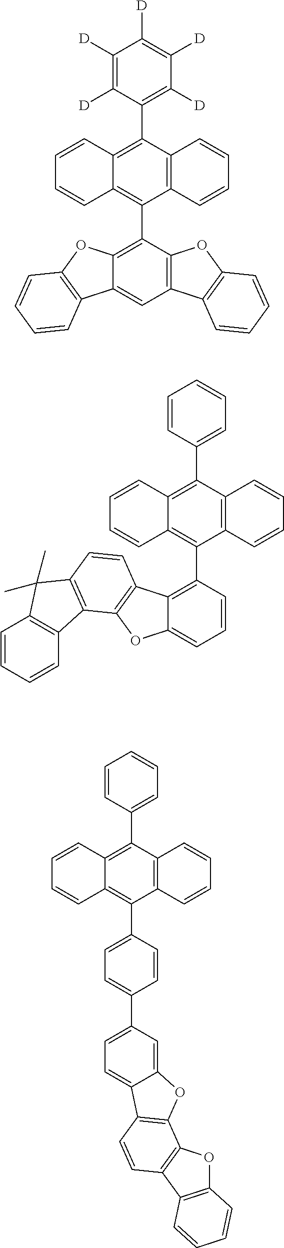 [SMILES: [2H]c1c([2H])c([2H])c(-c2c3ccccc3c(-c3c4oc5ccccc5c4cc4c3oc3ccccc34)c3ccccc23)c([2H])c1[2H] ; CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5c(c4)oc4c5ccc5c6ccccc6oc54)cc3)c3ccccc23)cc1]

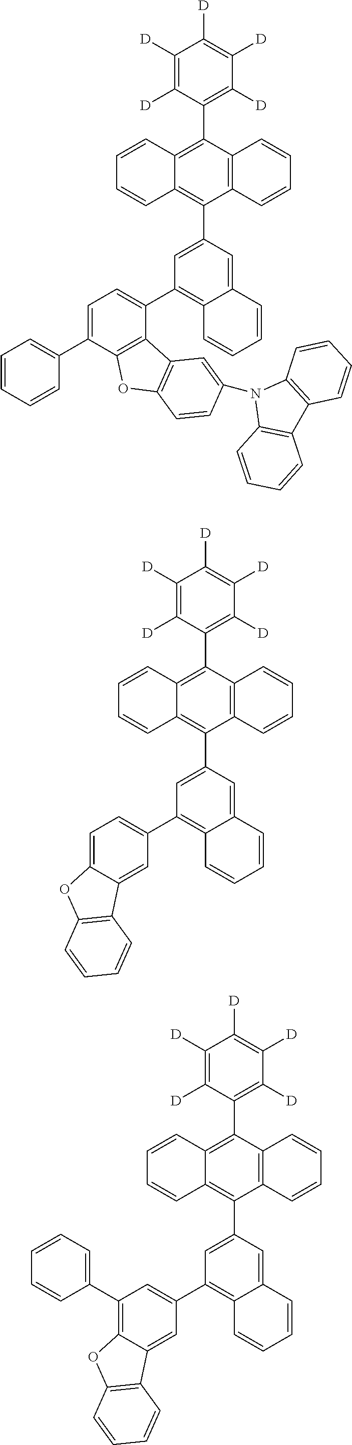 [SMILES: [2H]c1c([2H])c([2H])c(-c2c3ccccc3c(-c3cc(-c4ccc(-c5ccccc5)c5oc6ccc(-n7c8ccccc8c8ccccc87)cc6c45)c4ccccc4c3)c3ccccc23)c([2H])c1[2H] ; [2H]c1c([2H])c([2H])c(-c2c3ccccc3c(-c3cc(-c4ccc5oc6ccccc6c5c4)c4ccccc4c3)c3ccccc23)c([2H])c1[2H] ; [2H]c1c([2H])c([2H])c(-c2c3ccccc3c(-c3cc(-c4cc(-c5ccccc5)c5oc6ccccc6c5c4)c4ccccc4c3)c3ccccc23)c([2H])c1[2H]]

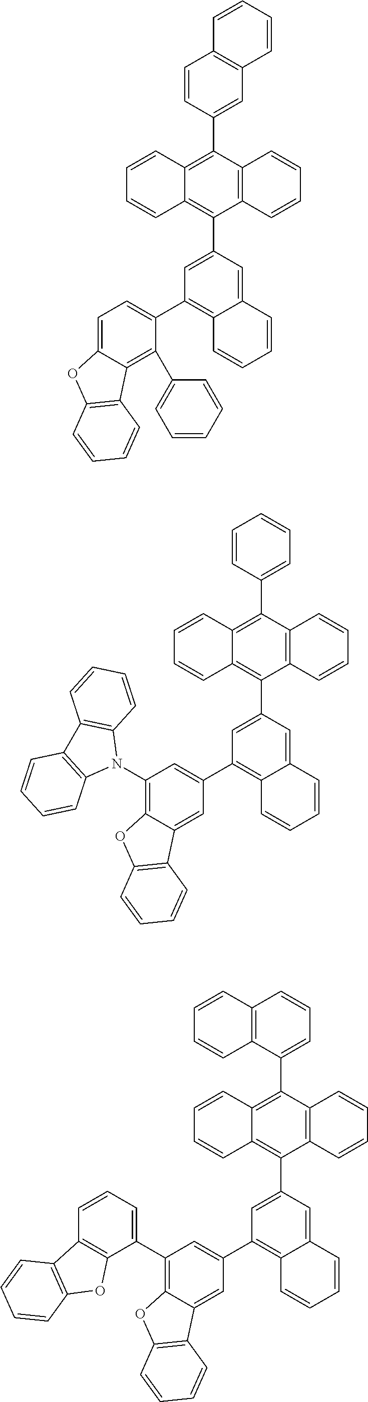 [SMILES: c1ccc(-c2c(-c3cc(-c4c5ccccc5c(-c5ccc6ccccc6c5)c5ccccc45)cc4ccccc34)ccc3oc4ccccc4c23)cc1 ; c1ccc(-c2c3ccccc3c(-c3cc(-c4cc(-n5c6ccccc6c6ccccc65)c5oc6ccccc6c5c4)c4ccccc4c3)c3ccccc23)cc1 ; c1ccc2c(-c3cc(-c4cccc5c4oc4ccccc45)c4oc5ccccc5c4c3)cc(-c3c4ccccc4c(-c4cccc5ccccc45)c4ccccc34)cc2c1]

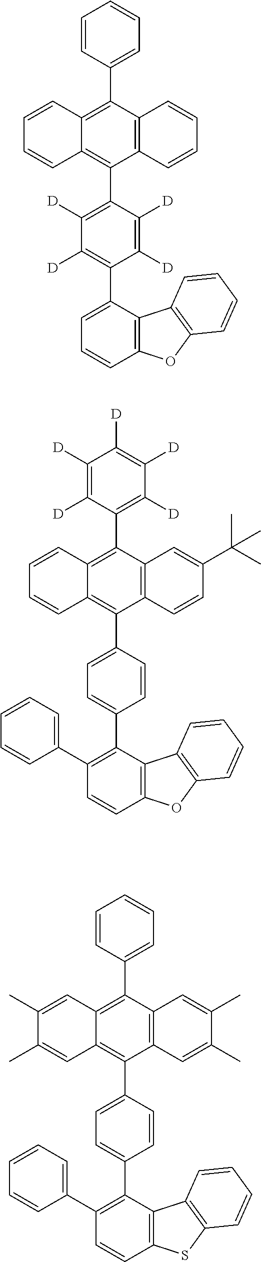

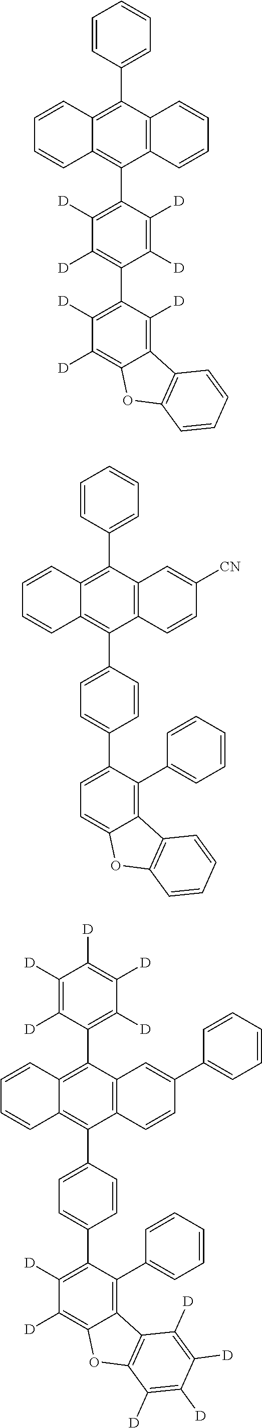 [SMILES: [2H]c1c([2H])c(-c2c3ccccc3c(-c3ccccc3)c3ccccc23)c([2H])c([2H])c1-c1c([2H])c([2H])c2oc3ccccc3c2c1[2H] ; N#Cc1ccc2c(-c3ccc(-c4ccc5oc6ccccc6c5c4-c4ccccc4)cc3)c3ccccc3c(-c3ccccc3)c2c1 ; [2H]c1c([2H])c([2H])c(-c2c3ccccc3c(-c3ccc(-c4c([2H])c([2H])c5oc6c([2H])c([2H])c([2H])c([2H])c6c5c4-c4ccccc4)cc3)c3ccc(-c4ccccc4)cc23)c([2H])c1[2H]]

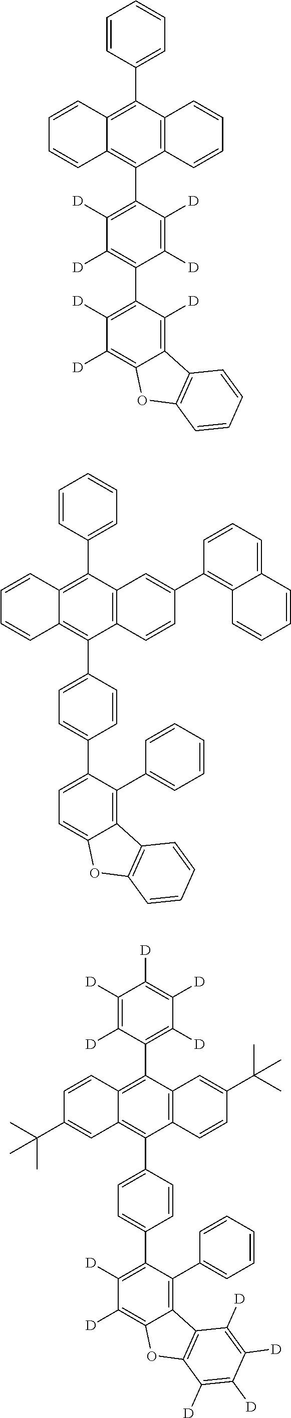 [SMILES: [2H]c1c([2H])c(-c2c3ccccc3c(-c3ccccc3)c3ccccc23)c([2H])c([2H])c1-c1c([2H])c([2H])c2oc3ccccc3c2c1[2H] ; c1ccc(-c2c3ccccc3c(-c3ccc(-c4ccc5oc6ccccc6c5c4-c4ccccc4)cc3)c3ccc(-c4cccc5ccccc45)cc23)cc1 ; [2H]c1c([2H])c([2H])c(-c2c3ccc(C(C)(C)C)cc3c(-c3ccc(-c4c([2H])c([2H])c5oc6c([2H])c([2H])c([2H])c([2H])c6c5c4-c4ccccc4)cc3)c3ccc(C(C)(C)C)cc23)c([2H])c1[2H]]

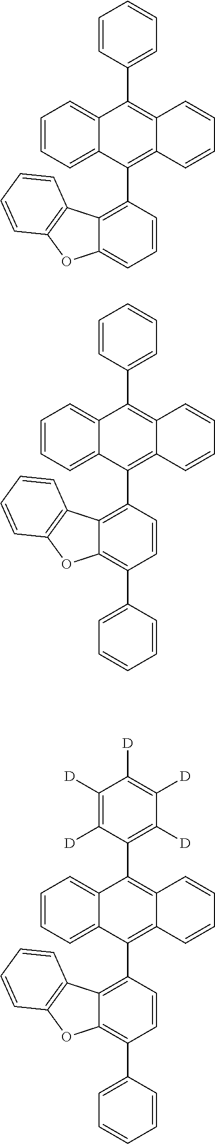

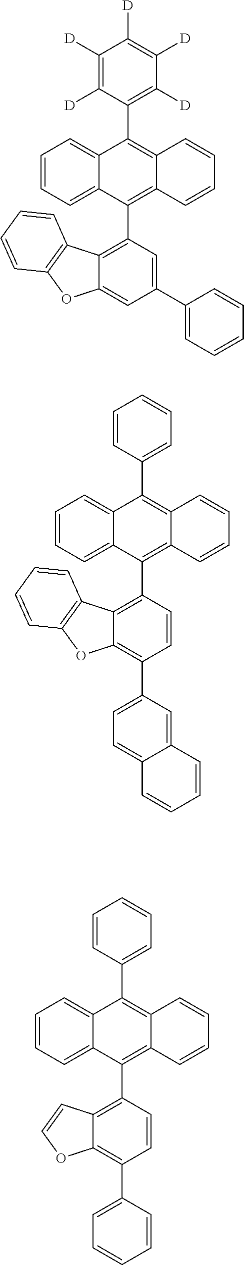 [SMILES: [2H]c1c([2H])c([2H])c(-c2c3ccccc3c(-c3cc(-c4ccccc4)cc4oc5ccccc5c34)c3ccccc23)c([2H])c1[2H] ; c1ccc(-c2c3ccccc3c(-c3ccc(-c4ccc5ccccc5c4)c4oc5ccccc5c34)c3ccccc23)cc1 ; c1ccc(-c2c3ccccc3c(-c3ccc(-c4ccccc4)c4occc34)c3ccccc23)cc1]

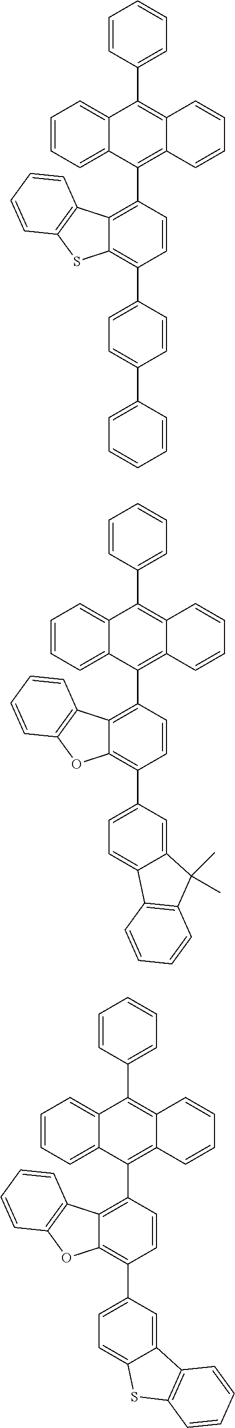

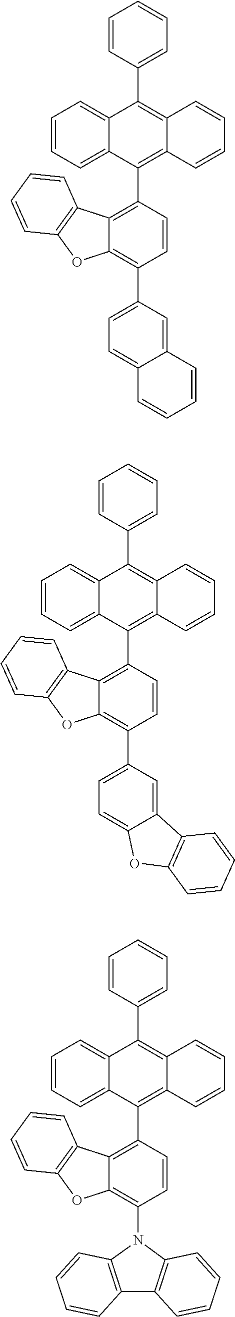 [SMILES: c1ccc(-c2c3ccccc3c(-c3ccc(-c4ccc5ccccc5c4)c4oc5ccccc5c34)c3ccccc23)cc1 ; c1ccc(-c2c3ccccc3c(-c3ccc(-c4ccc5oc6ccccc6c5c4)c4oc5ccccc5c34)c3ccccc23)cc1 ; c1ccc(-c2c3ccccc3c(-c3ccc(-n4c5ccccc5c5ccccc54)c4oc5ccccc5c34)c3ccccc23)cc1]

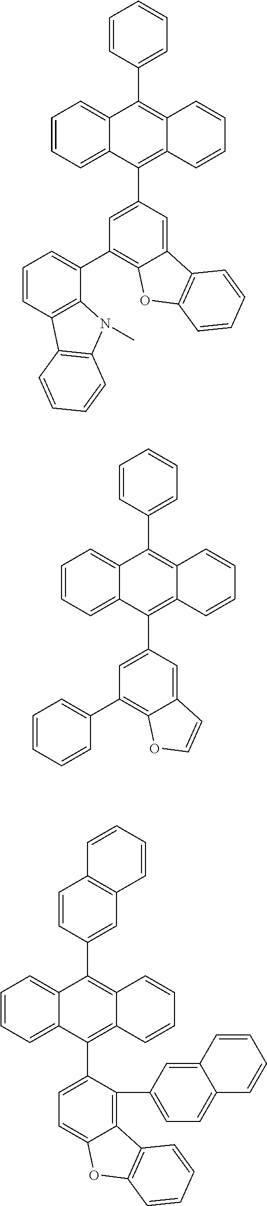 [SMILES: Cn1c2ccccc2c2cccc(-c3cc(-c4c5ccccc5c(-c5ccccc5)c5ccccc45)cc4c3oc3ccccc34)c21 ; c1ccc(-c2c3ccccc3c(-c3cc(-c4ccccc4)c4occc4c3)c3ccccc23)cc1 ; c1ccc2cc(-c3c4ccccc4c(-c4ccc5oc6ccccc6c5c4-c4ccc5ccccc5c4)c4ccccc34)ccc2c1]

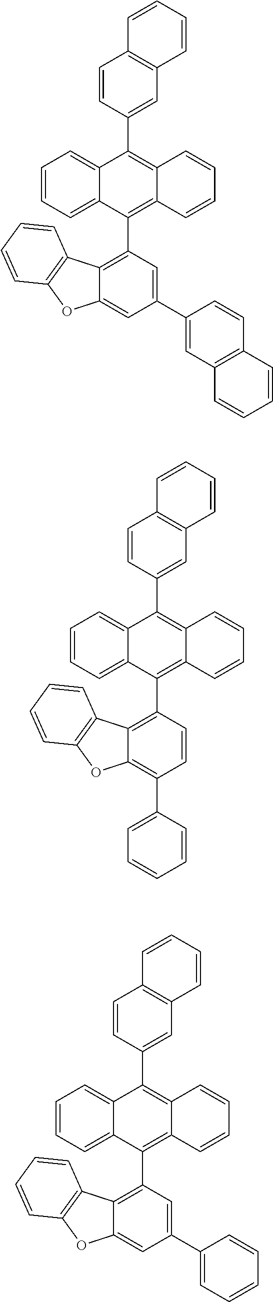 [SMILES: c1ccc2cc(-c3cc(-c4c5ccccc5c(-c5ccc6ccccc6c5)c5ccccc45)c4c(c3)oc3ccccc34)ccc2c1 ; c1ccc(-c2ccc(-c3c4ccccc4c(-c4ccc5ccccc5c4)c4ccccc34)c3c2oc2ccccc23)cc1 ; c1ccc(-c2cc(-c3c4ccccc4c(-c4ccc5ccccc5c4)c4ccccc34)c3c(c2)oc2ccccc23)cc1]

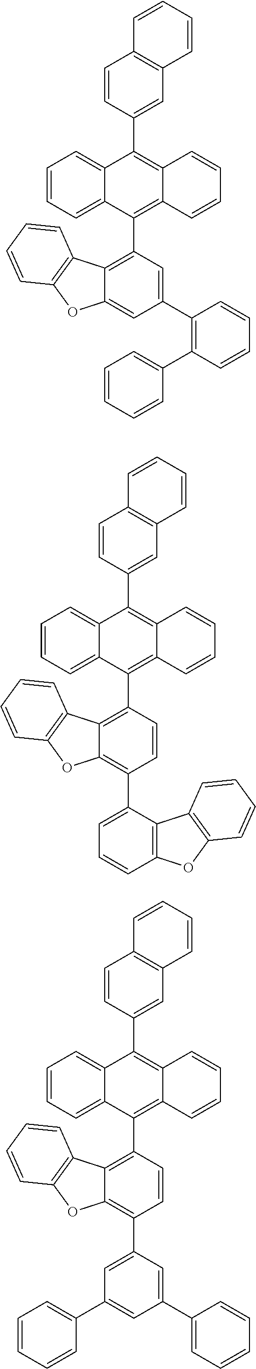

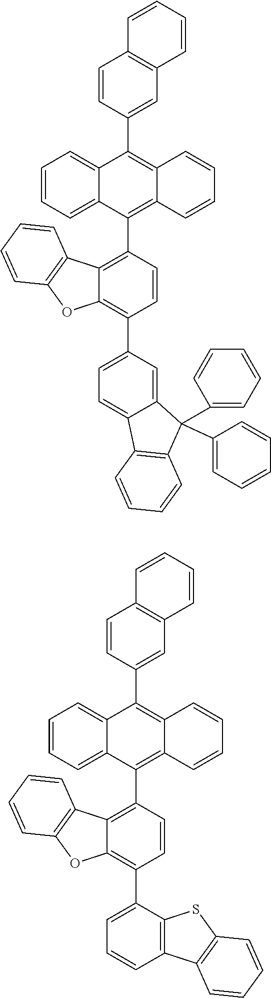

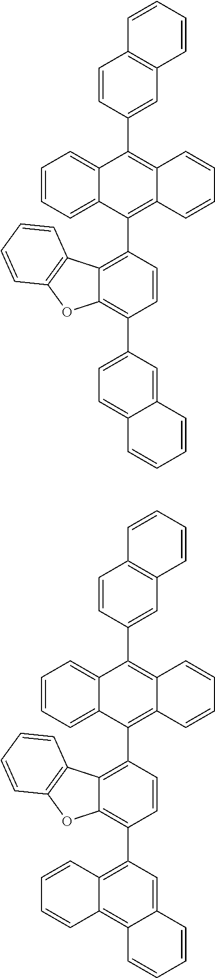

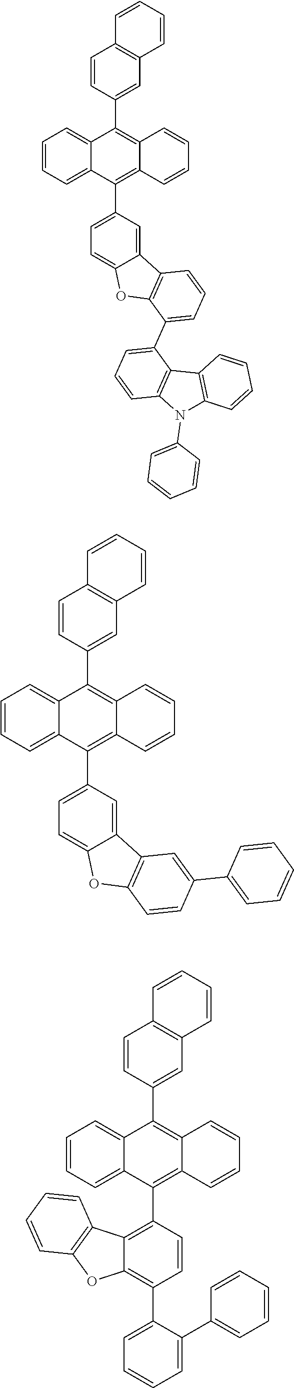 [SMILES: c1ccc(-n2c3ccccc3c3c(-c4cccc5c4oc4ccc(-c6c7ccccc7c(-c7ccc8ccccc8c7)c7ccccc67)cc45)cccc32)cc1 ; c1ccc(-c2ccc3oc4ccc(-c5c6ccccc6c(-c6ccc7ccccc7c6)c6ccccc56)cc4c3c2)cc1 ; c1ccc(-c2ccccc2-c2ccc(-c3c4ccccc4c(-c4ccc5ccccc5c4)c4ccccc34)c3c2oc2ccccc23)cc1]

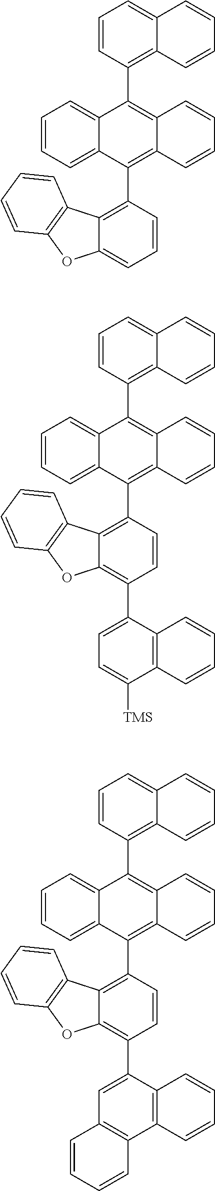 [SMILES: c1ccc2c(-c3c4ccccc4c(-c4cccc5oc6ccccc6c45)c4ccccc34)cccc2c1 ; C[Si](C)(C)c1ccc(-c2ccc(-c3c4ccccc4c(-c4cccc5ccccc45)c4ccccc34)c3c2oc2ccccc23)c2ccccc12 ; c1ccc2c(-c3c4ccccc4c(-c4ccc(-c5cc6ccccc6c6ccccc56)c5oc6ccccc6c45)c4ccccc34)cccc2c1]

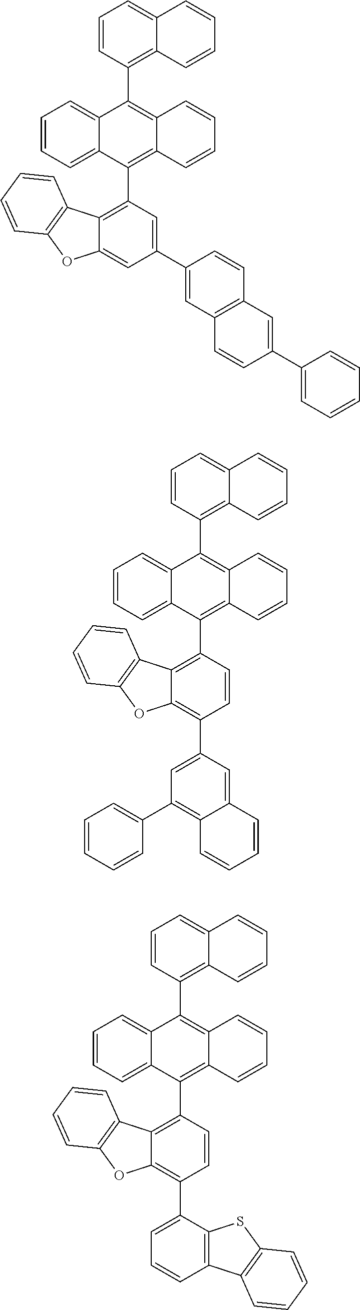

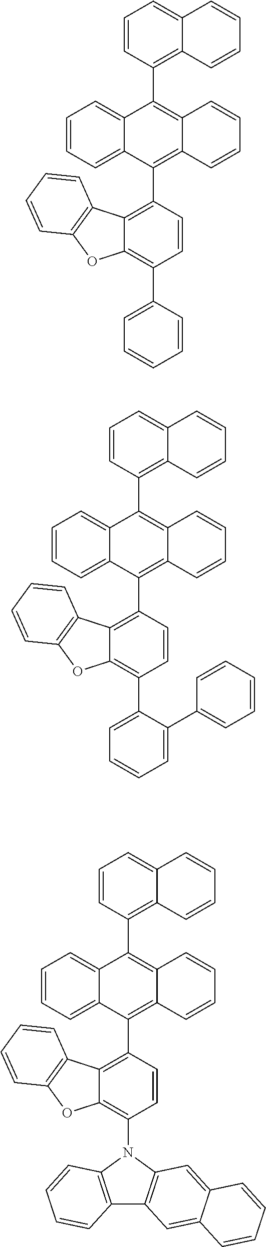

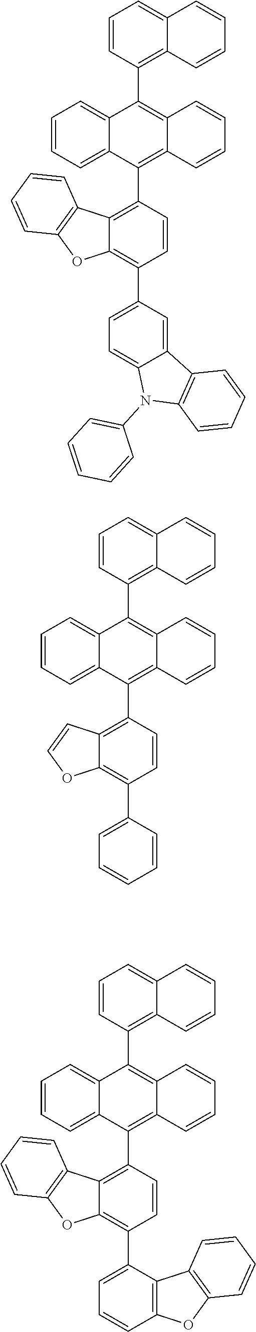

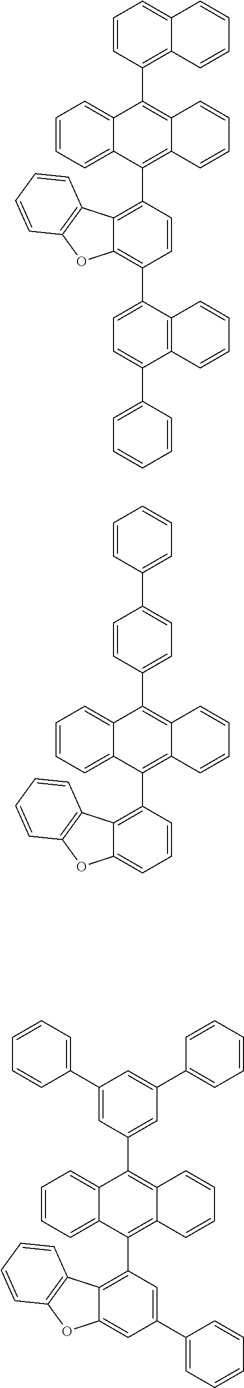

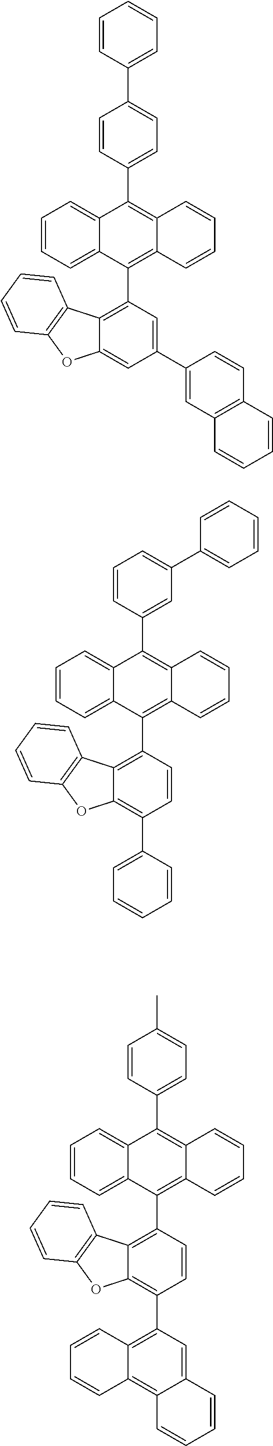

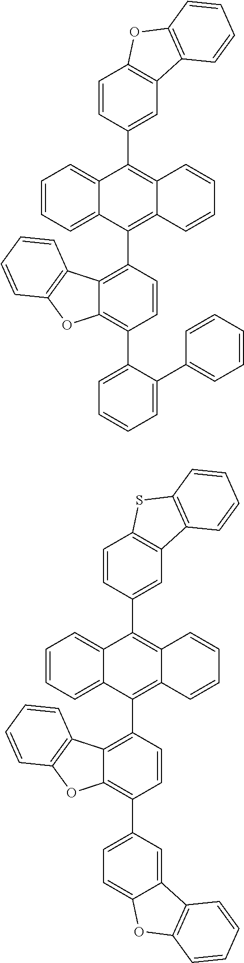 [SMILES: c1ccc(-c2ccccc2-c2ccc(-c3c4ccccc4c(-c4ccc5oc6ccccc6c5c4)c4ccccc34)c3c2oc2ccccc23)cc1 ; c1ccc2c(c1)oc1ccc(-c3ccc(-c4c5ccccc5c(-c5ccc6sc7ccccc7c6c5)c5ccccc45)c4c3oc3ccccc34)cc12]

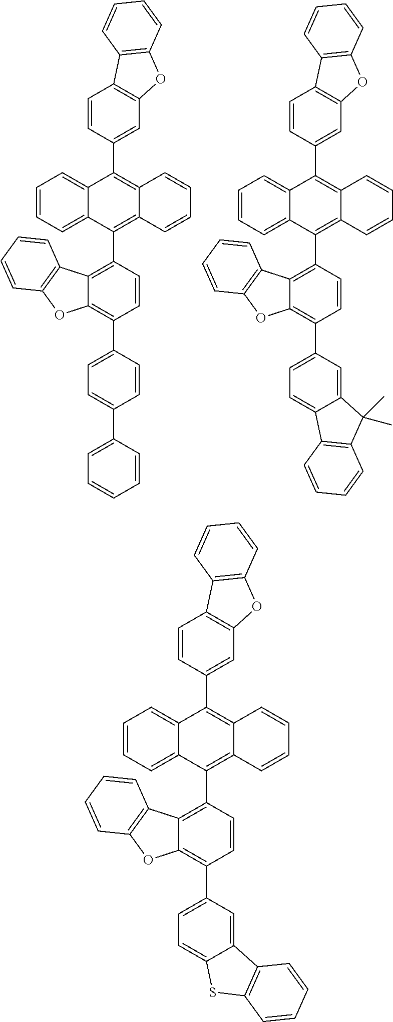

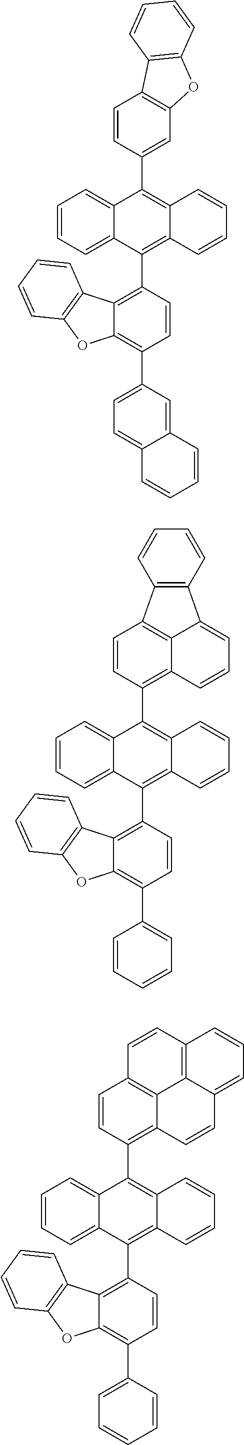

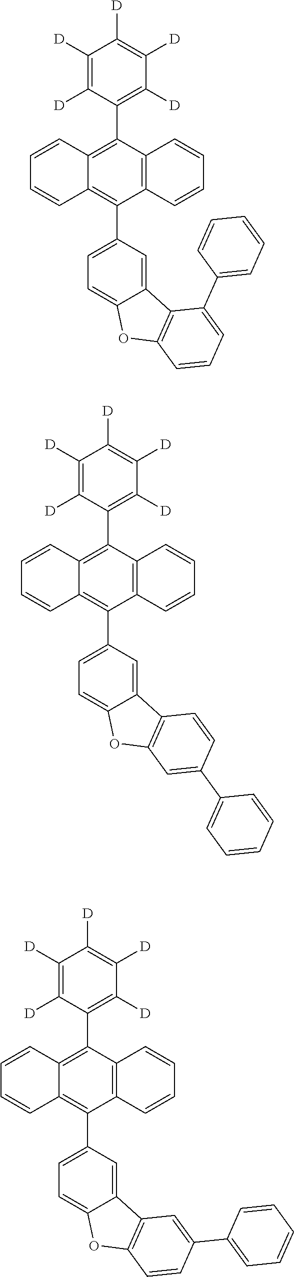 [SMILES: [2H]c1c([2H])c([2H])c(-c2c3ccccc3c(-c3ccc4oc5cccc(-c6ccccc6)c5c4c3)c3ccccc23)c([2H])c1[2H] ; [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H]]

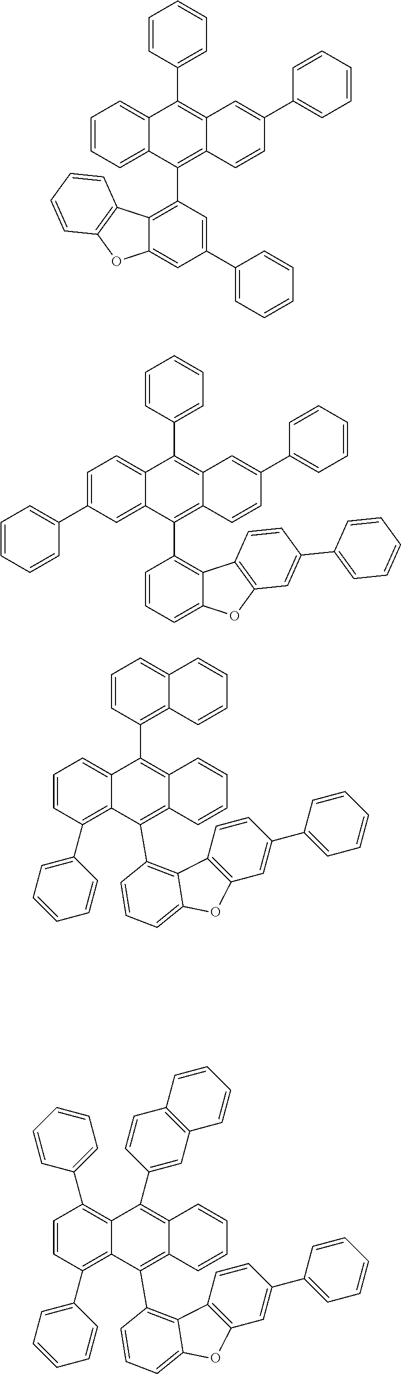

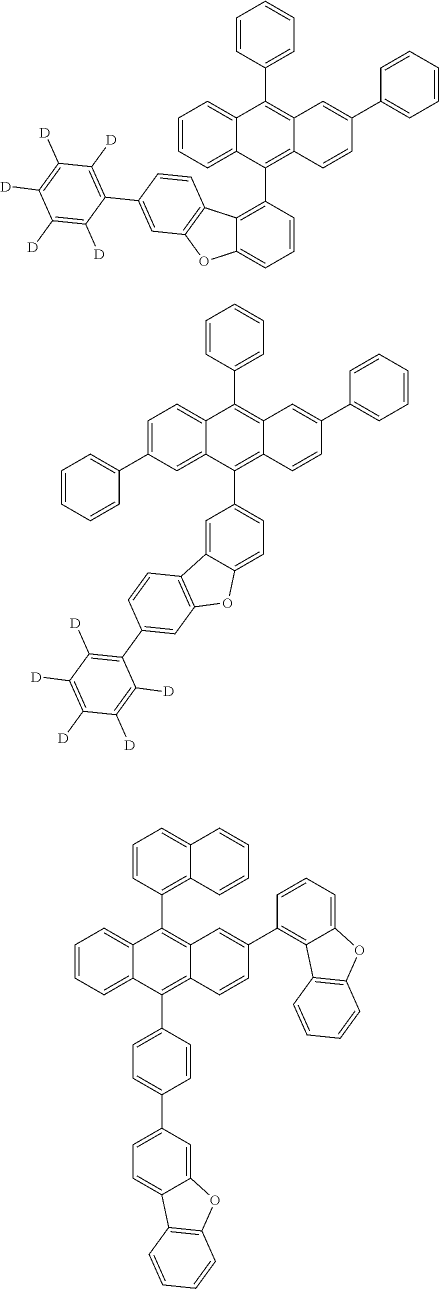 [SMILES: [2H]c1c([2H])c([2H])c(-c2ccc3c(c2)oc2cccc(-c4c5ccccc5c(-c5ccccc5)c5cc(-c6ccccc6)ccc45)c23)c([2H])c1[2H] ; [2H]c1c([2H])c([2H])c(-c2ccc3c(c2)oc2ccc(-c4c5ccc(-c6ccccc6)cc5c(-c5ccccc5)c5ccc(-c6ccccc6)cc45)cc23)c([2H])c1[2H] ; c1ccc2c(-c3c4ccccc4c(-c4ccc(-c5ccc6c(c5)oc5ccccc56)cc4)c4ccc(-c5cccc6oc7ccccc7c56)cc34)cccc2c1]

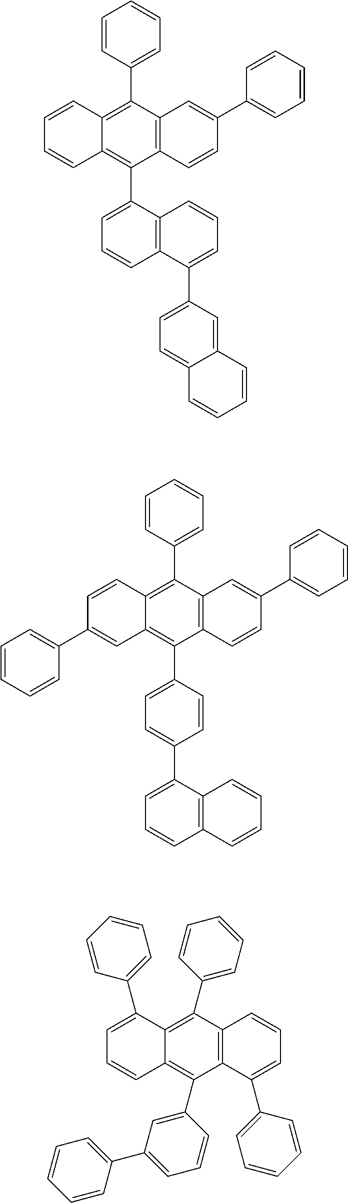

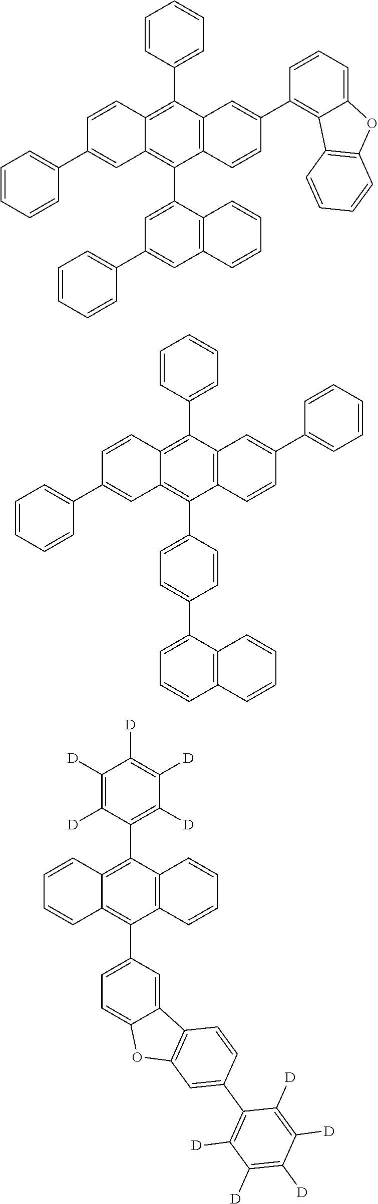

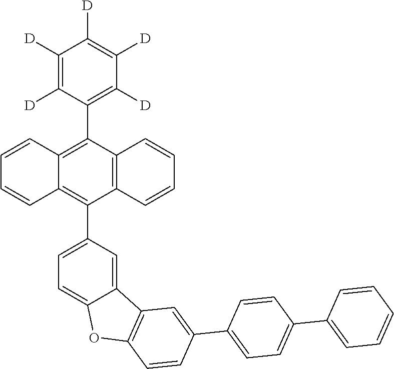 [SMILES: [2H]c1c([2H])c([2H])c(-c2c3ccccc3c(-c3ccc4oc5ccc(-c6ccc(-c7ccccc7)cc6)cc5c4c3)c3ccccc23)c([2H])c1[2H]]

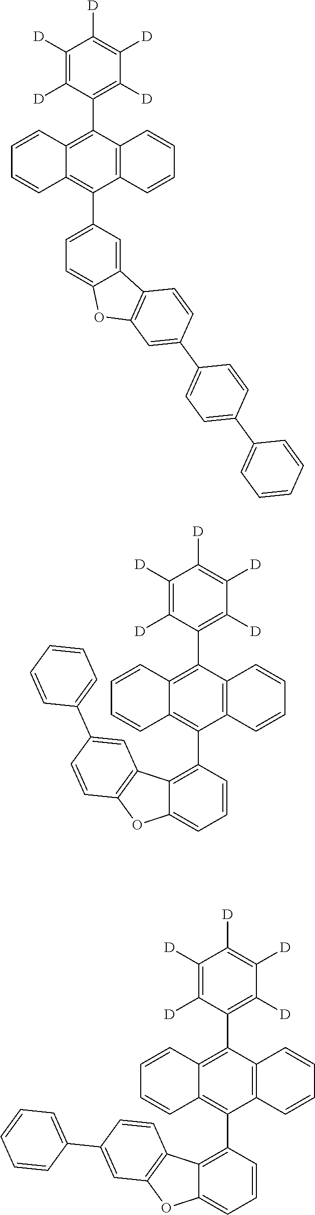 [SMILES: [2H]c1c([2H])c([2H])c(-c2c3ccccc3c(-c3ccc4oc5cc(-c6ccc(-c7ccccc7)cc6)ccc5c4c3)c3ccccc23)c([2H])c1[2H] ; [2H]c1c([2H])c([2H])c(-c2c3ccccc3c(-c3cccc4oc5ccc(-c6ccccc6)cc5c34)c3ccccc23)c([2H])c1[2H] ; [2H]c1c([2H])c([2H])c(-c2c3ccccc3c(-c3cccc4oc5cc(-c6ccccc6)ccc5c34)c3ccccc23)c([2H])c1[2H]]

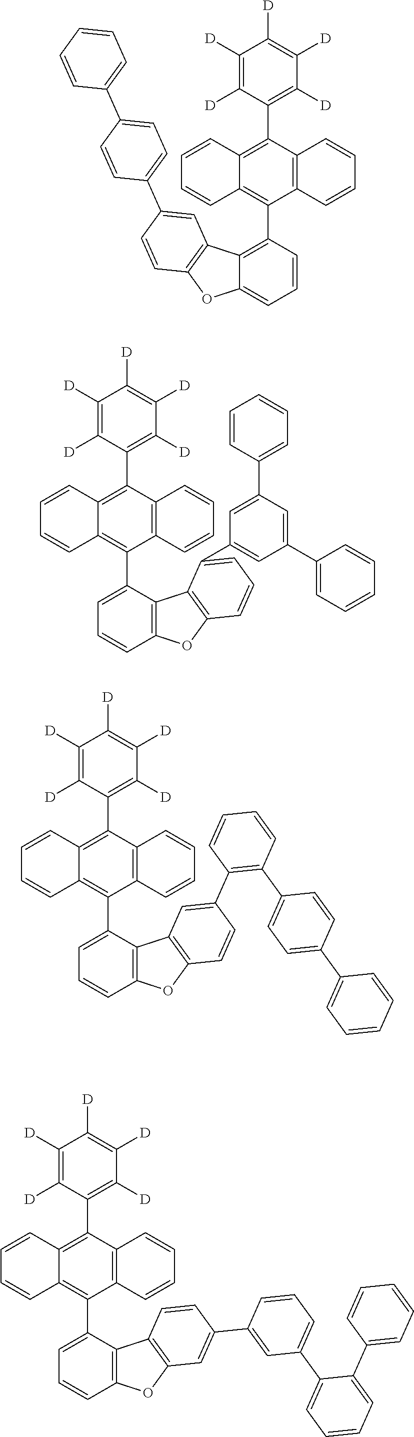 [SMILES: [2H]c1c([2H])c([2H])c(-c2c3ccccc3c(-c3cccc4oc5ccc(-c6ccc(-c7ccccc7)cc6)cc5c34)c3ccccc23)c([2H])c1[2H] ; [2H]c1c([2H])c([2H])c(-c2c3ccccc3c(-c3cccc4oc5cccc(-c6cc(-c7ccccc7)cc(-c7ccccc7)c6)c5c34)c3ccccc23)c([2H])c1[2H] ; [2H]c1c([2H])c([2H])c(-c2c3ccccc3c(-c3cccc4oc5ccc(-c6ccccc6-c6ccc(-c7ccccc7)cc6)cc5c34)c3ccccc23)c([2H])c1[2H] ; [2H]c1c([2H])c([2H])c(-c2c3ccccc3c(-c3cccc4oc5cc(-c6cccc(-c7ccccc7-c7ccccc7)c6)ccc5c34)c3ccccc23)c([2H])c1[2H]]

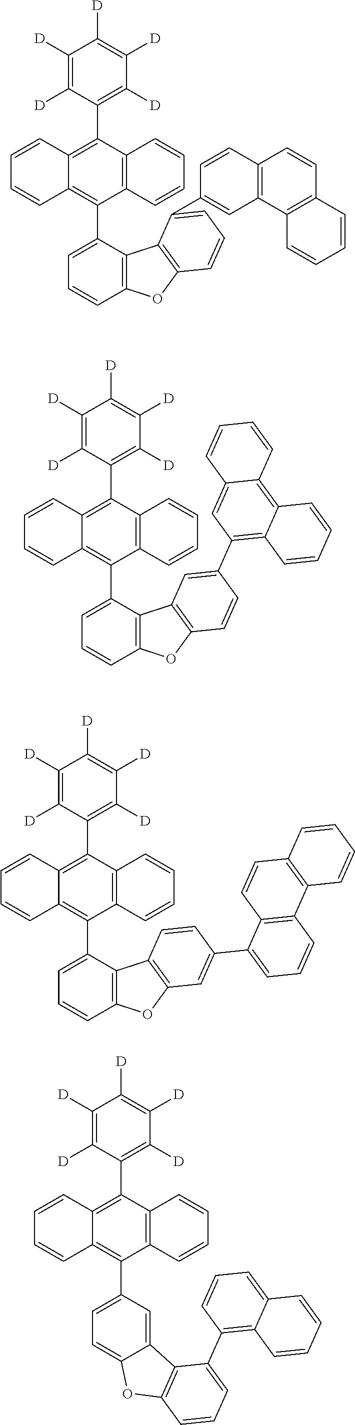 [SMILES: [2H]c1c([2H])c([2H])c(-c2c3ccccc3c(-c3cccc4oc5cccc(-c6ccc7ccc8ccccc8c7c6)c5c34)c3ccccc23)c([2H])c1[2H] ; [2H]c1c([2H])c([2H])c(-c2c3ccccc3c(-c3cccc4oc5ccc(-c6cc7ccccc7c7ccccc67)cc5c34)c3ccccc23)c([2H])c1[2H] ; [2H]c1c([2H])c([2H])c(-c2c3ccccc3c(-c3cccc4oc5cc(-c6cccc7c6ccc6ccccc67)ccc5c34)c3ccccc23)c([2H])c1[2H] ; [2H]c1c([2H])c([2H])c(-c2c3ccccc3c(-c3ccc4oc5cccc(-c6cccc7ccccc67)c5c4c3)c3ccccc23)c([2H])c1[2H]]

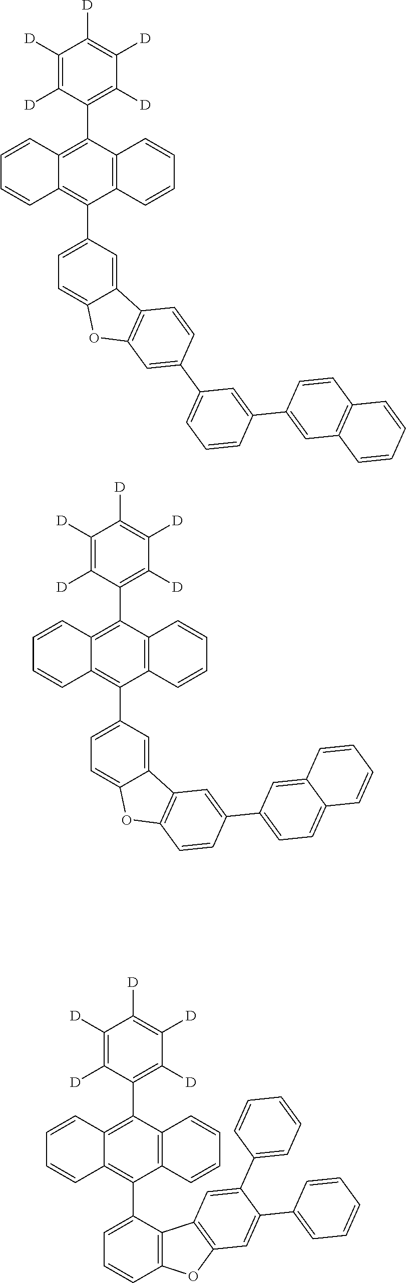 [SMILES: [2H]c1c([2H])c([2H])c(-c2c3ccccc3c(-c3ccc4oc5cc(-c6cccc(-c7ccc8ccccc8c7)c6)ccc5c4c3)c3ccccc23)c([2H])c1[2H] ; [2H]c1c([2H])c([2H])c(-c2c3ccccc3c(-c3ccc4oc5ccc(-c6ccc7ccccc7c6)cc5c4c3)c3ccccc23)c([2H])c1[2H] ; [2H]c1c([2H])c([2H])c(-c2c3ccccc3c(-c3cccc4oc5cc(-c6ccccc6)c(-c6ccccc6)cc5c34)c3ccccc23)c([2H])c1[2H]]

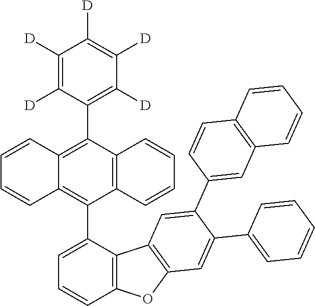 [SMILES: [2H]c1c([2H])c([2H])c(-c2c3ccccc3c(-c3cccc4oc5cc(-c6ccccc6)c(-c6ccc7ccccc7c6)cc5c34)c3ccccc23)c([2H])c1[2H]]

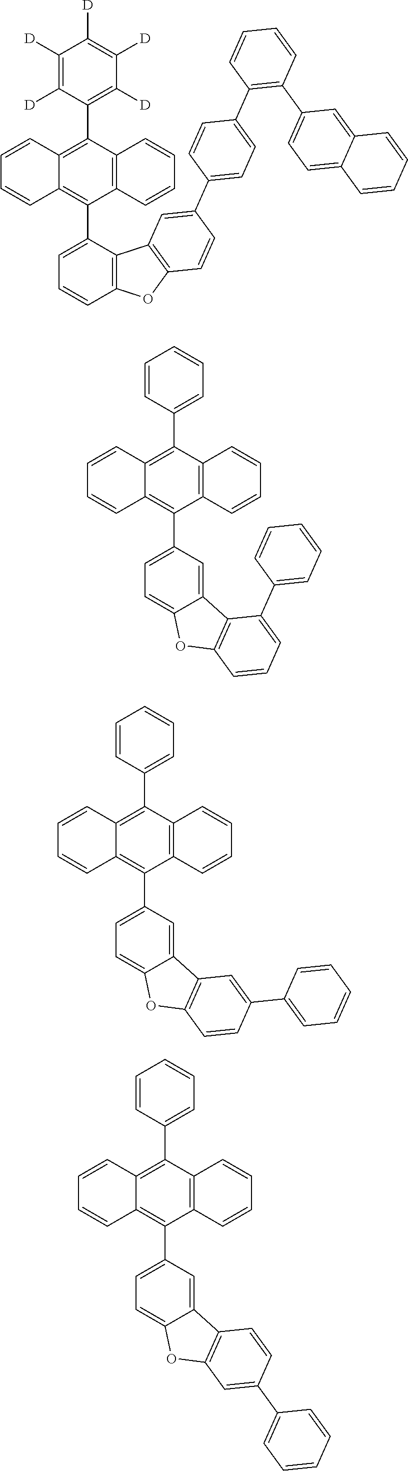

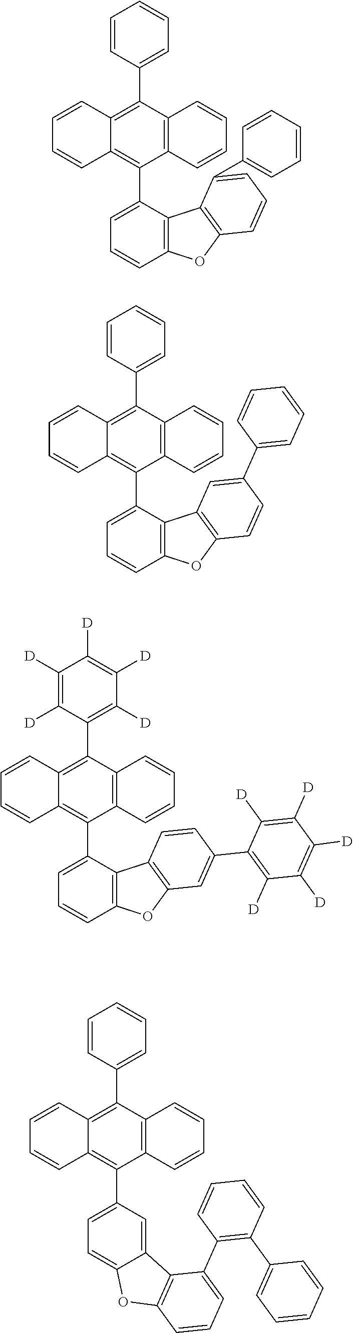

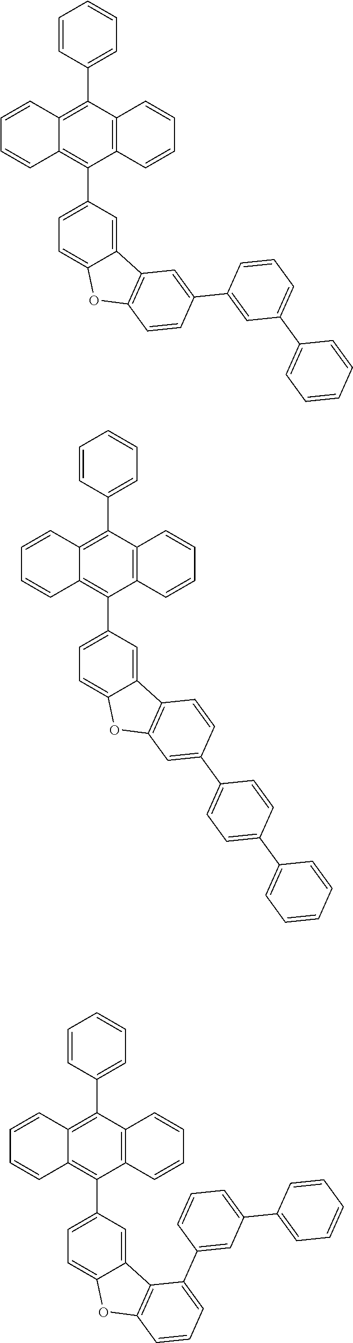 [SMILES: c1ccc(-c2cccc(-c3ccc4oc5ccc(-c6c7ccccc7c(-c7ccccc7)c7ccccc67)cc5c4c3)c2)cc1 ; c1ccc(-c2ccc(-c3ccc4c(c3)oc3ccc(-c5c6ccccc6c(-c6ccccc6)c6ccccc56)cc34)cc2)cc1 ; c1ccc(-c2cccc(-c3cccc4oc5ccc(-c6c7ccccc7c(-c7ccccc7)c7ccccc67)cc5c34)c2)cc1]

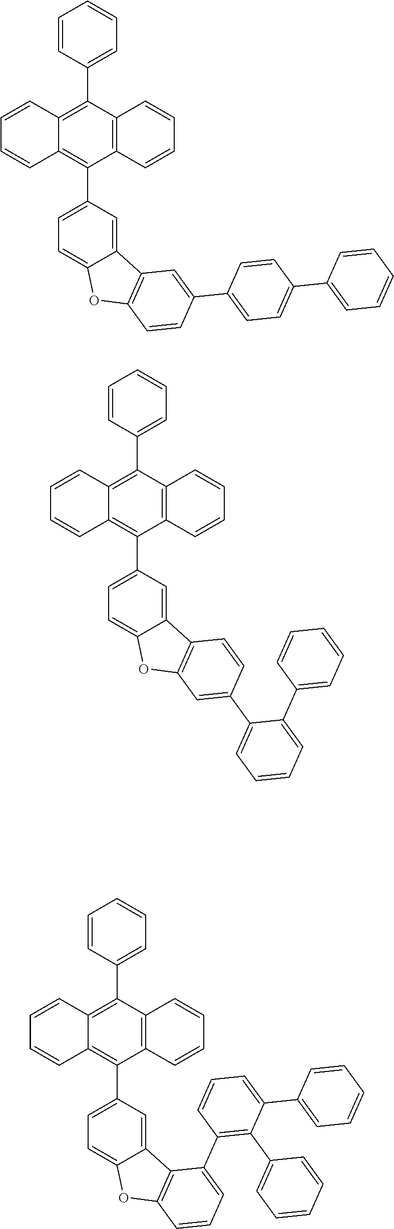

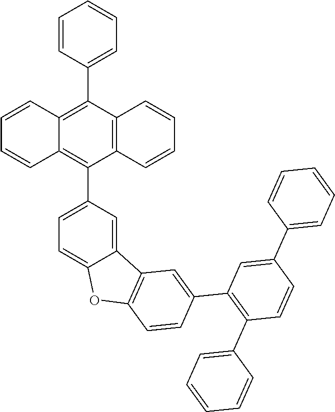 [SMILES: c1ccc(-c2ccc(-c3ccccc3)c(-c3ccc4oc5ccc(-c6c7ccccc7c(-c7ccccc7)c7ccccc67)cc5c4c3)c2)cc1]

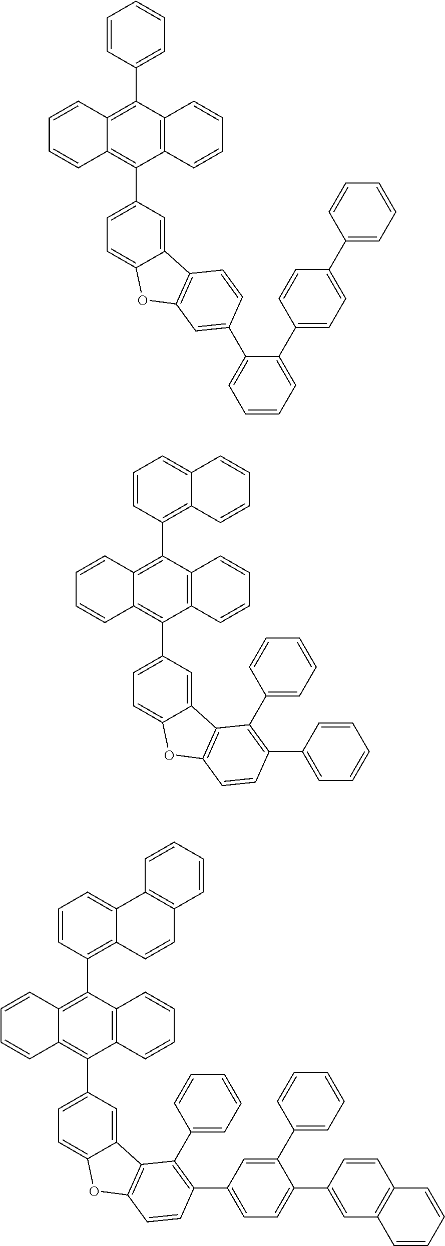 [SMILES: c1ccc(-c2ccc(-c3ccccc3-c3ccc4c(c3)oc3ccc(-c5c6ccccc6c(-c6ccccc6)c6ccccc56)cc34)cc2)cc1 ; c1ccc(-c2ccc3oc4ccc(-c5c6ccccc6c(-c6cccc7ccccc67)c6ccccc56)cc4c3c2-c2ccccc2)cc1 ; c1ccc(-c2cc(-c3ccc4oc5ccc(-c6c7ccccc7c(-c7cccc8c7ccc7ccccc78)c7ccccc67)cc5c4c3-c3ccccc3)ccc2-c2ccc3ccccc3c2)cc1]

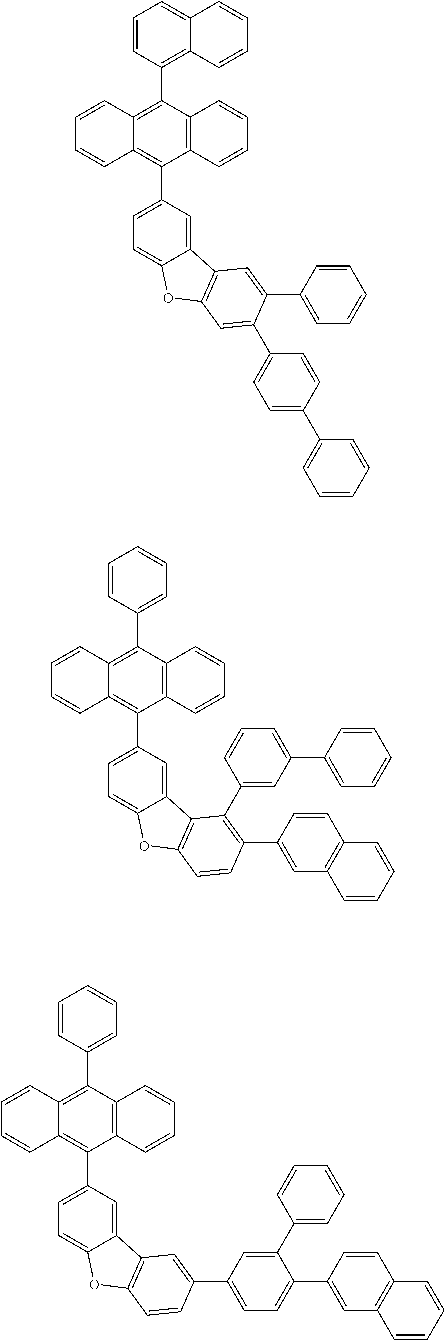 [SMILES: c1ccc(-c2ccc(-c3cc4oc5ccc(-c6c7ccccc7c(-c7cccc8ccccc78)c7ccccc67)cc5c4cc3-c3ccccc3)cc2)cc1 ; c1ccc(-c2cccc(-c3c(-c4ccc5ccccc5c4)ccc4oc5ccc(-c6c7ccccc7c(-c7ccccc7)c7ccccc67)cc5c34)c2)cc1 ; c1ccc(-c2cc(-c3ccc4oc5ccc(-c6c7ccccc7c(-c7ccccc7)c7ccccc67)cc5c4c3)ccc2-c2ccc3ccccc3c2)cc1]

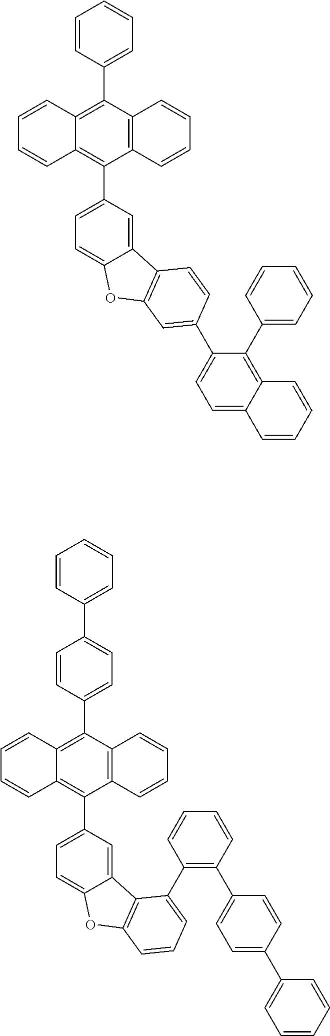 [SMILES: c1ccc(-c2c(-c3ccc4c(c3)oc3ccc(-c5c6ccccc6c(-c6ccccc6)c6ccccc56)cc34)ccc3ccccc23)cc1 ; c1ccc(-c2ccc(-c3ccccc3-c3cccc4oc5ccc(-c6c7ccccc7c(-c7ccc(-c8ccccc8)cc7)c7ccccc67)cc5c34)cc2)cc1]

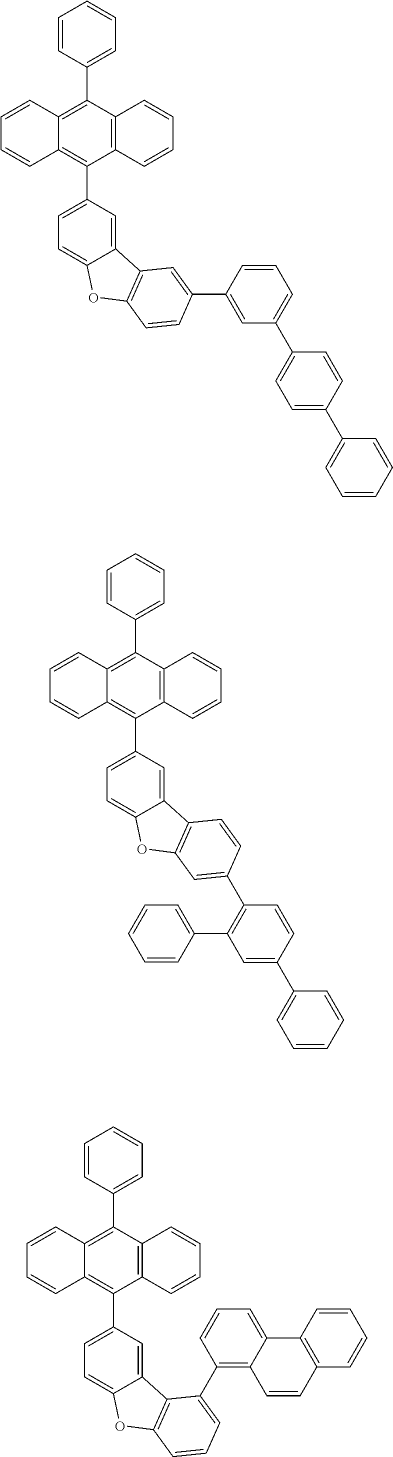 [SMILES: c1ccc(-c2ccc(-c3cccc(-c4ccc5oc6ccc(-c7c8ccccc8c(-c8ccccc8)c8ccccc78)cc6c5c4)c3)cc2)cc1 ; c1ccc(-c2ccc(-c3ccc4c(c3)oc3ccc(-c5c6ccccc6c(-c6ccccc6)c6ccccc56)cc34)c(-c3ccccc3)c2)cc1 ; c1ccc(-c2c3ccccc3c(-c3ccc4oc5cccc(-c6cccc7c6ccc6ccccc67)c5c4c3)c3ccccc23)cc1]

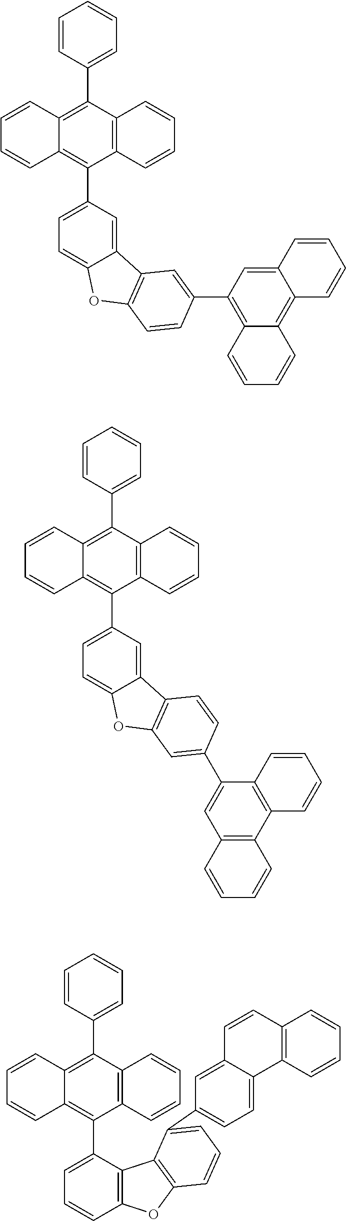 [SMILES: c1ccc(-c2c3ccccc3c(-c3ccc4oc5ccc(-c6cc7ccccc7c7ccccc67)cc5c4c3)c3ccccc23)cc1 ; c1ccc(-c2c3ccccc3c(-c3ccc4oc5cc(-c6cc7ccccc7c7ccccc67)ccc5c4c3)c3ccccc23)cc1 ; c1ccc(-c2c3ccccc3c(-c3cccc4oc5cccc(-c6ccc7c(ccc8ccccc87)c6)c5c34)c3ccccc23)cc1]

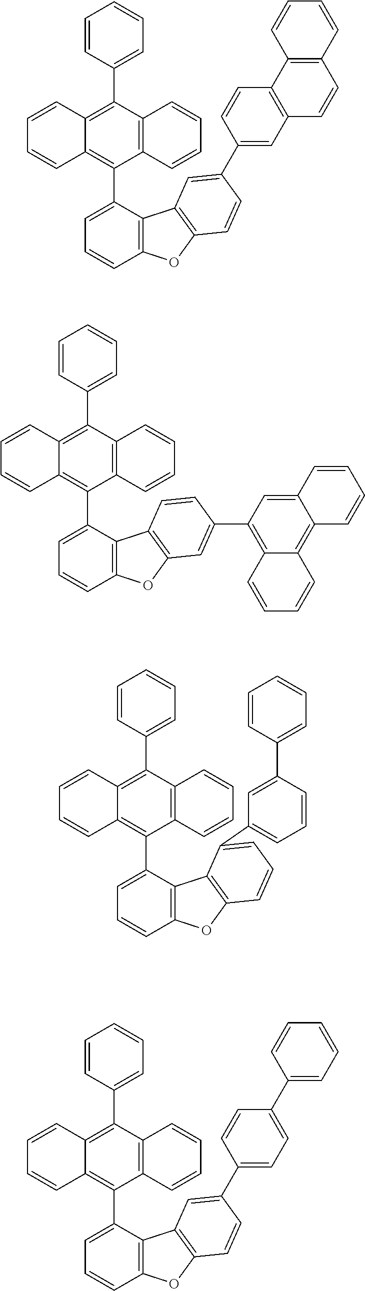 [SMILES: c1ccc(-c2c3ccccc3c(-c3cccc4oc5ccc(-c6ccc7c(ccc8ccccc87)c6)cc5c34)c3ccccc23)cc1 ; c1ccc(-c2c3ccccc3c(-c3cccc4oc5cc(-c6cc7ccccc7c7ccccc67)ccc5c34)c3ccccc23)cc1 ; c1ccc(-c2cccc(-c3cccc4oc5cccc(-c6c7ccccc7c(-c7ccccc7)c7ccccc67)c5c34)c2)cc1 ; c1ccc(-c2ccc(-c3ccc4oc5cccc(-c6c7ccccc7c(-c7ccccc7)c7ccccc67)c5c4c3)cc2)cc1]

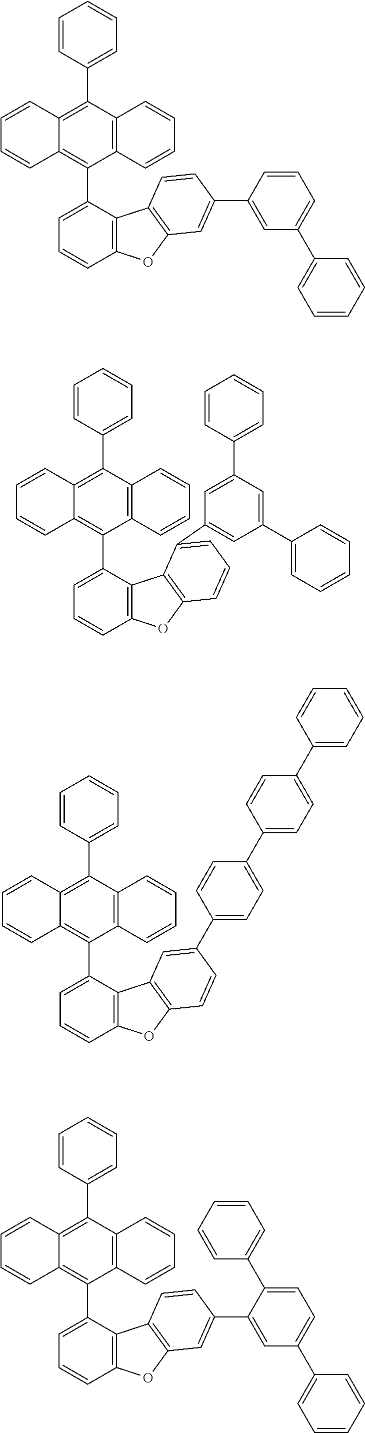 [SMILES: c1ccc(-c2cccc(-c3ccc4c(c3)oc3cccc(-c5c6ccccc6c(-c6ccccc6)c6ccccc56)c34)c2)cc1 ; c1ccc(-c2cc(-c3ccccc3)cc(-c3cccc4oc5cccc(-c6c7ccccc7c(-c7ccccc7)c7ccccc67)c5c34)c2)cc1 ; c1ccc(-c2ccc(-c3ccc(-c4ccc5oc6cccc(-c7c8ccccc8c(-c8ccccc8)c8ccccc78)c6c5c4)cc3)cc2)cc1 ; c1ccc(-c2ccc(-c3ccccc3)c(-c3ccc4c(c3)oc3cccc(-c5c6ccccc6c(-c6ccccc6)c6ccccc56)c34)c2)cc1]

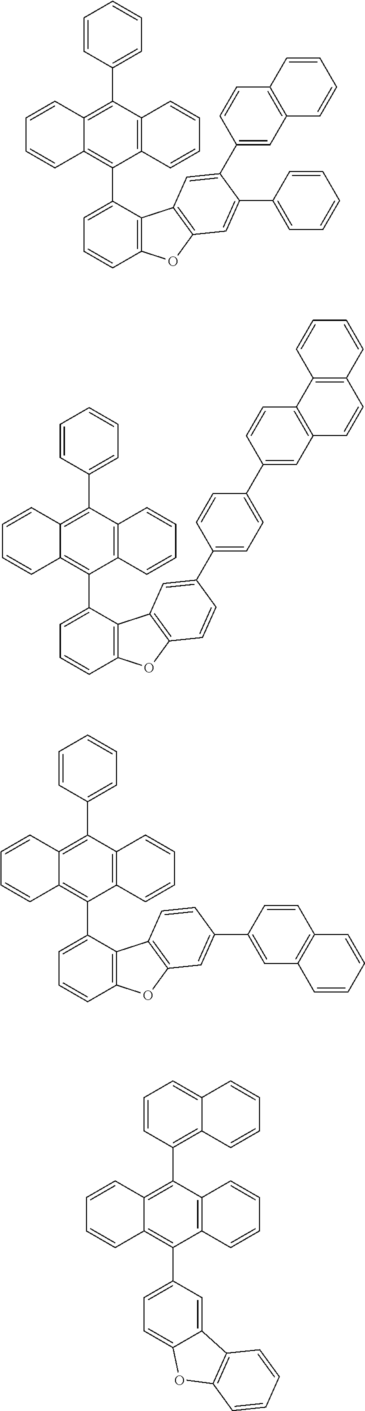 [SMILES: c1ccc(-c2cc3oc4cccc(-c5c6ccccc6c(-c6ccccc6)c6ccccc56)c4c3cc2-c2ccc3ccccc3c2)cc1 ; c1ccc(-c2c3ccccc3c(-c3cccc4oc5ccc(-c6ccc(-c7ccc8c(ccc9ccccc98)c7)cc6)cc5c34)c3ccccc23)cc1 ; c1ccc(-c2c3ccccc3c(-c3cccc4oc5cc(-c6ccc7ccccc7c6)ccc5c34)c3ccccc23)cc1 ; c1ccc2c(-c3c4ccccc4c(-c4ccc5oc6ccccc6c5c4)c4ccccc34)cccc2c1]

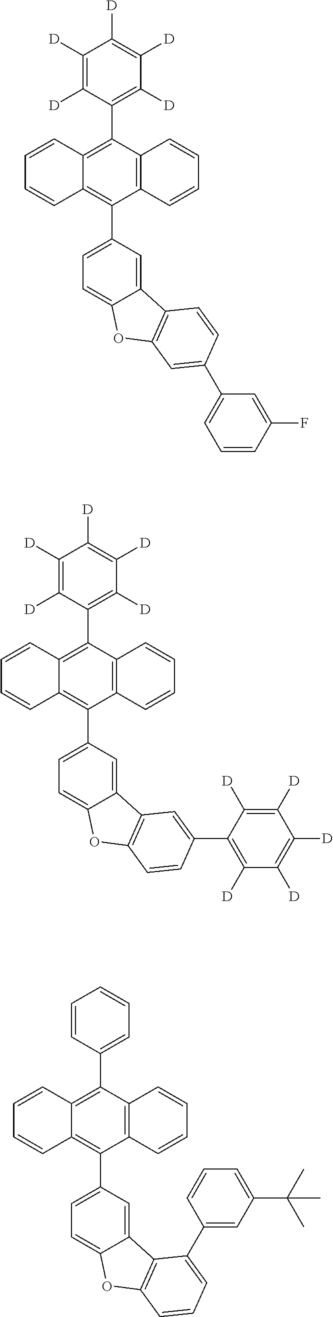 [SMILES: [2H]c1c([2H])c([2H])c(-c2c3ccccc3c(-c3ccc4oc5cc(-c6cccc(F)c6)ccc5c4c3)c3ccccc23)c([2H])c1[2H] ; [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; CC(C)(C)c1cccc(-c2cccc3oc4ccc(-c5c6ccccc6c(-c6ccccc6)c6ccccc56)cc4c23)c1]

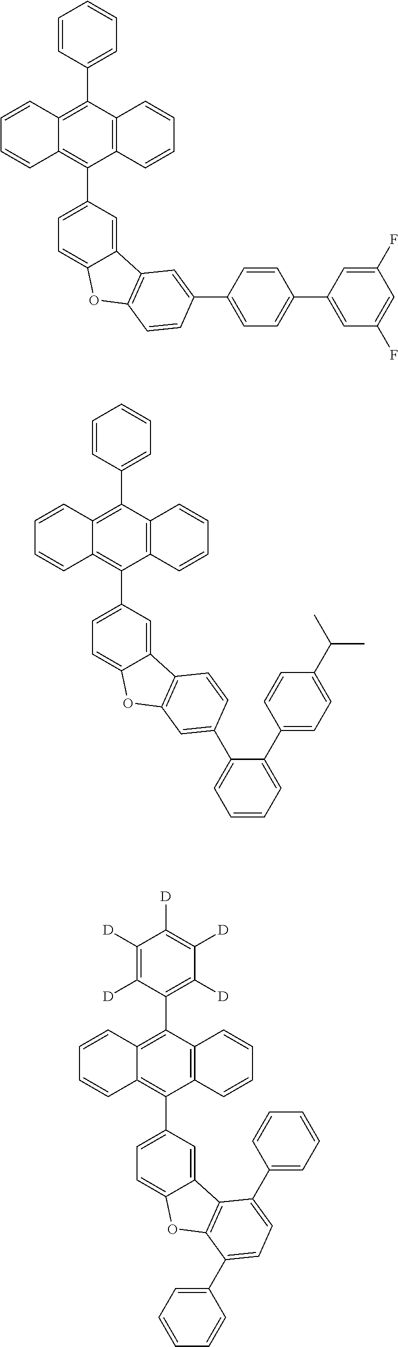 [SMILES: Fc1cc(F)cc(-c2ccc(-c3ccc4oc5ccc(-c6c7ccccc7c(-c7ccccc7)c7ccccc67)cc5c4c3)cc2)c1 ; CC(C)c1ccc(-c2ccccc2-c2ccc3c(c2)oc2ccc(-c4c5ccccc5c(-c5ccccc5)c5ccccc45)cc23)cc1 ; [2H]c1c([2H])c([2H])c(-c2c3ccccc3c(-c3ccc4oc5c(-c6ccccc6)ccc(-c6ccccc6)c5c4c3)c3ccccc23)c([2H])c1[2H]]

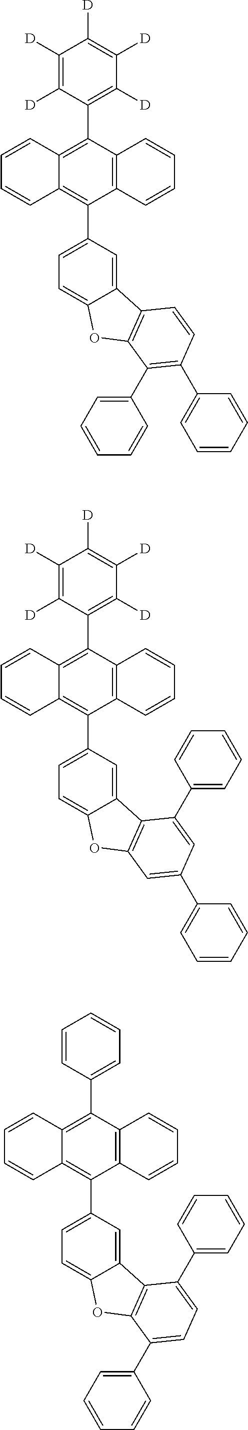 [SMILES: [2H]c1c([2H])c([2H])c(-c2c3ccccc3c(-c3ccc4oc5c(-c6ccccc6)c(-c6ccccc6)ccc5c4c3)c3ccccc23)c([2H])c1[2H] ; [2H]c1c([2H])c([2H])c(-c2c3ccccc3c(-c3ccc4oc5cc(-c6ccccc6)cc(-c6ccccc6)c5c4c3)c3ccccc23)c([2H])c1[2H] ; c1ccc(-c2c3ccccc3c(-c3ccc4oc5c(-c6ccccc6)ccc(-c6ccccc6)c5c4c3)c3ccccc23)cc1]

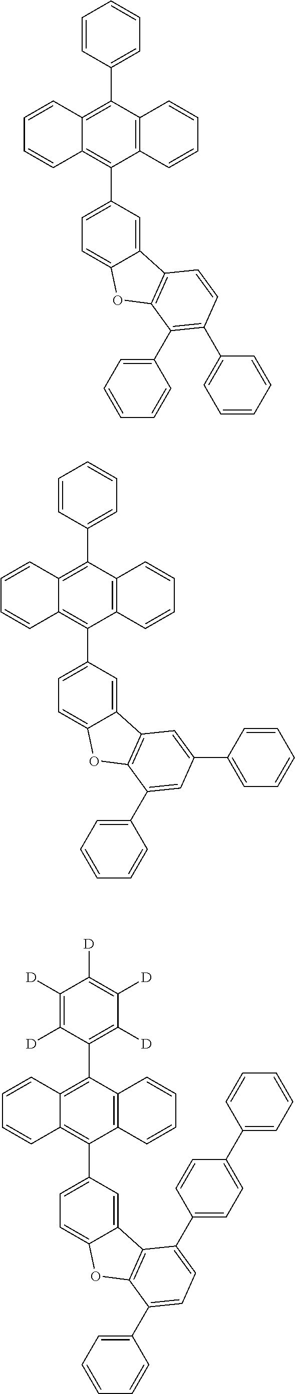 [SMILES: c1ccc(-c2ccc3c(oc4ccc(-c5c6ccccc6c(-c6ccccc6)c6ccccc56)cc43)c2-c2ccccc2)cc1 ; c1ccc(-c2cc(-c3ccccc3)c3oc4ccc(-c5c6ccccc6c(-c6ccccc6)c6ccccc56)cc4c3c2)cc1 ; [2H]c1c([2H])c([2H])c(-c2c3ccccc3c(-c3ccc4oc5c(-c6ccccc6)ccc(-c6ccc(-c7ccccc7)cc6)c5c4c3)c3ccccc23)c([2H])c1[2H]]

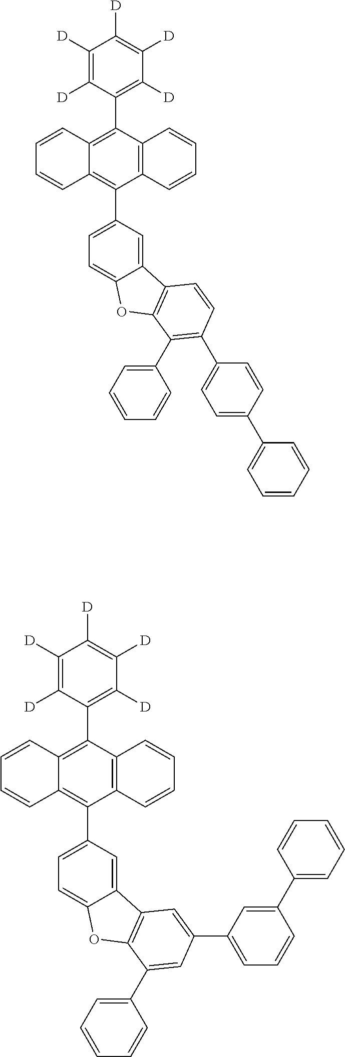 [SMILES: [2H]c1c([2H])c([2H])c(-c2c3ccccc3c(-c3ccc4oc5c(-c6ccccc6)c(-c6ccc(-c7ccccc7)cc6)ccc5c4c3)c3ccccc23)c([2H])c1[2H] ; [2H]c1c([2H])c([2H])c(-c2c3ccccc3c(-c3ccc4oc5c(-c6ccccc6)cc(-c6cccc(-c7ccccc7)c6)cc5c4c3)c3ccccc23)c([2H])c1[2H]]

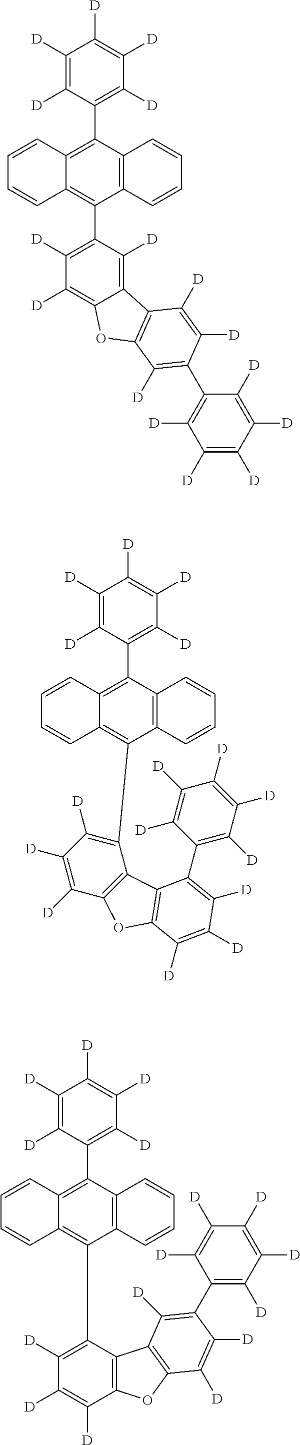 [SMILES: [2H]c1c([2H])c([2H])c(-c2c([2H])c([2H])c3c(oc4c([2H])c([2H])c(-c5c6ccccc6c(-c6c([2H])c([2H])c([2H])c([2H])c6[2H])c6ccccc56)c([2H])c43)c2[2H])c([2H])c1[2H] ; [2H]c1c([2H])c([2H])c(-c2c3ccccc3c(-c3c([2H])c([2H])c([2H])c4oc5c([2H])c([2H])c([2H])c(-c6c([2H])c([2H])c([2H])c([2H])c6[2H])c5c34)c3ccccc23)c([2H])c1[2H] ; [2H]c1c([2H])c([2H])c(-c2c([2H])c([2H])c3oc4c([2H])c([2H])c([2H])c(-c5c6ccccc6c(-c6c([2H])c([2H])c([2H])c([2H])c6[2H])c6ccccc56)c4c3c2[2H])c([2H])c1[2H]]

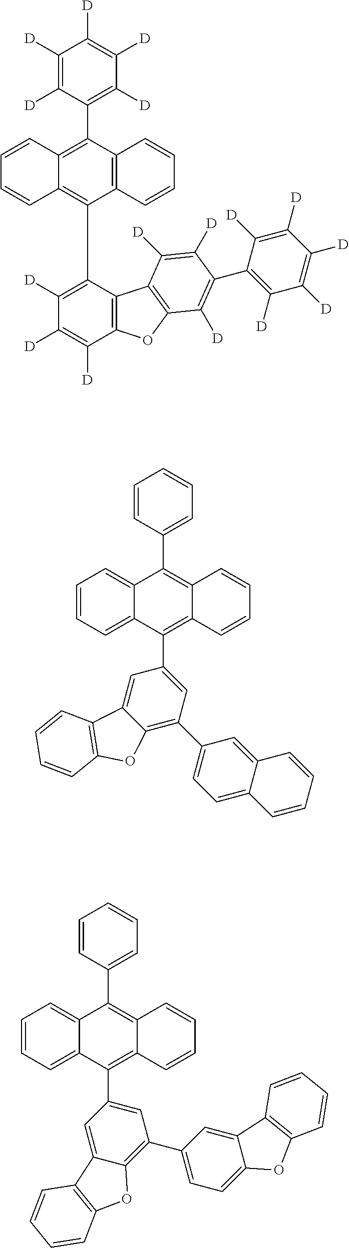 [SMILES: [2H]c1c([2H])c([2H])c(-c2c([2H])c([2H])c3c(oc4c([2H])c([2H])c([2H])c(-c5c6ccccc6c(-c6c([2H])c([2H])c([2H])c([2H])c6[2H])c6ccccc56)c43)c2[2H])c([2H])c1[2H] ; c1ccc(-c2c3ccccc3c(-c3cc(-c4ccc5ccccc5c4)c4oc5ccccc5c4c3)c3ccccc23)cc1 ; c1ccc(-c2c3ccccc3c(-c3cc(-c4ccc5oc6ccccc6c5c4)c4oc5ccccc5c4c3)c3ccccc23)cc1]

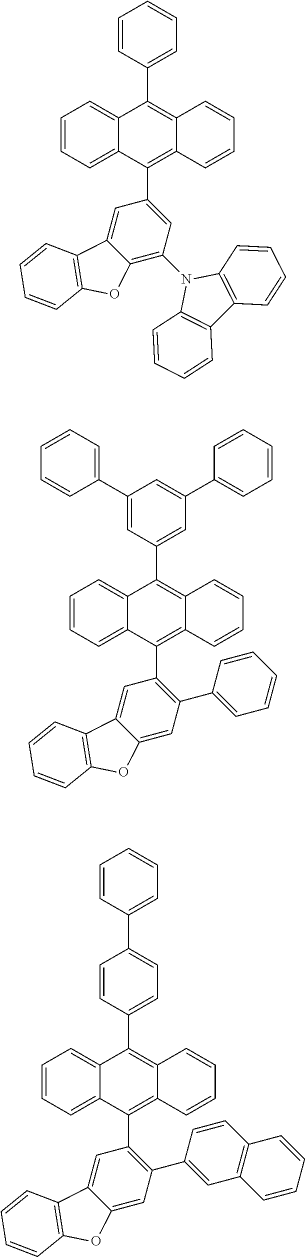 [SMILES: c1ccc(-c2c3ccccc3c(-c3cc(-n4c5ccccc5c5ccccc54)c4oc5ccccc5c4c3)c3ccccc23)cc1 ; c1ccc(-c2cc(-c3ccccc3)cc(-c3c4ccccc4c(-c4cc5c(cc4-c4ccccc4)oc4ccccc45)c4ccccc34)c2)cc1 ; c1ccc(-c2ccc(-c3c4ccccc4c(-c4cc5c(cc4-c4ccc6ccccc6c4)oc4ccccc45)c4ccccc34)cc2)cc1]

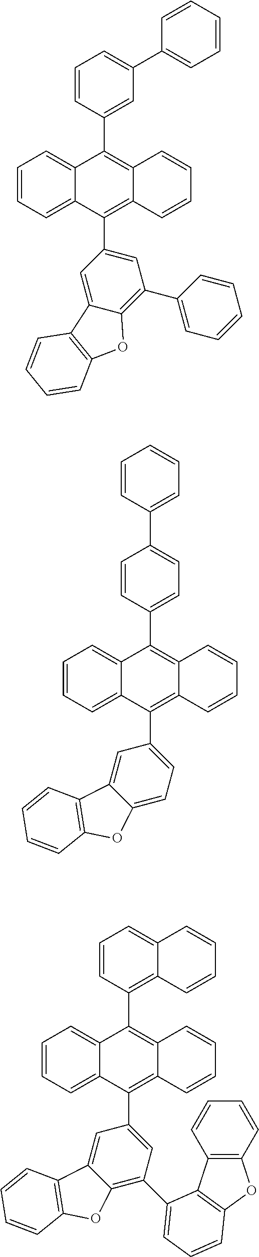 [SMILES: c1ccc(-c2cccc(-c3c4ccccc4c(-c4cc(-c5ccccc5)c5oc6ccccc6c5c4)c4ccccc34)c2)cc1 ; c1ccc(-c2ccc(-c3c4ccccc4c(-c4ccc5oc6ccccc6c5c4)c4ccccc34)cc2)cc1 ; c1ccc2c(-c3c4ccccc4c(-c4cc(-c5cccc6oc7ccccc7c56)c5oc6ccccc6c5c4)c4ccccc34)cccc2c1]

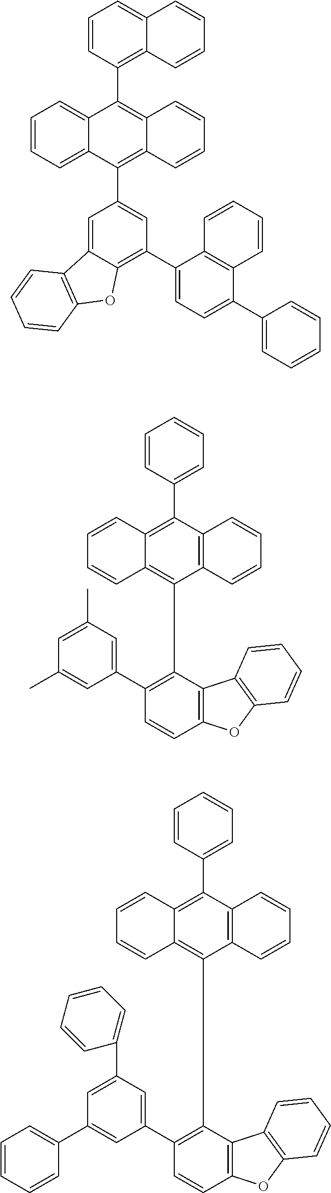 [SMILES: c1ccc(-c2ccc(-c3cc(-c4c5ccccc5c(-c5cccc6ccccc56)c5ccccc45)cc4c3oc3ccccc34)c3ccccc23)cc1 ; Cc1cc(C)cc(-c2ccc3oc4ccccc4c3c2-c2c3ccccc3c(-c3ccccc3)c3ccccc23)c1 ; c1ccc(-c2cc(-c3ccccc3)cc(-c3ccc4oc5ccccc5c4c3-c3c4ccccc4c(-c4ccccc4)c4ccccc34)c2)cc1]

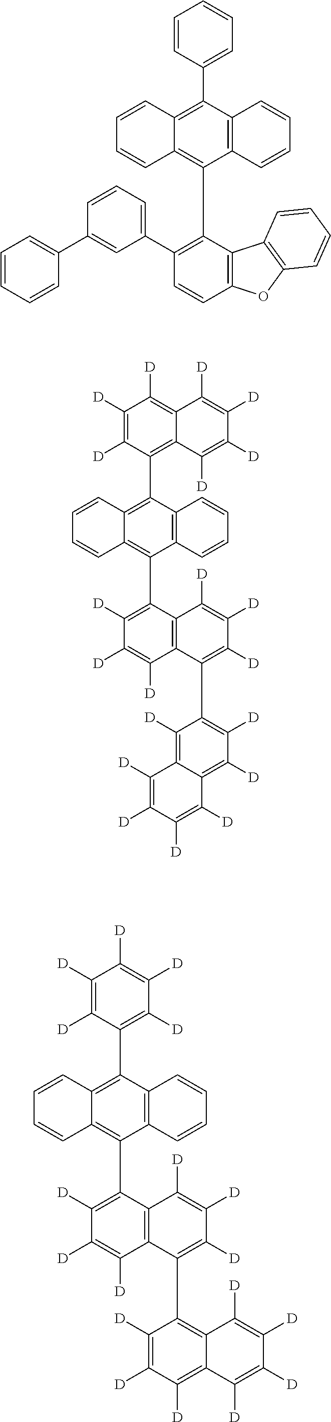 [SMILES: c1ccc(-c2cccc(-c3ccc4oc5ccccc5c4c3-c3c4ccccc4c(-c4ccccc4)c4ccccc34)c2)cc1 ; [2H]c1c([2H])c([2H])c2c([2H])c(-c3c([2H])c([2H])c([2H])c4c(-c5c6ccccc6c(-c6c([2H])c([2H])c([2H])c7c([2H])c([2H])c([2H])c([2H])c67)c6ccccc56)c([2H])c([2H])c([2H])c34)c([2H])c([2H])c2c1[2H] ; [2H]c1c([2H])c([2H])c(-c2c3ccccc3c(-c3c([2H])c([2H])c([2H])c4c(-c5c([2H])c([2H])c([2H])c6c([2H])c([2H])c([2H])c([2H])c56)c([2H])c([2H])c([2H])c34)c3ccccc23)c([2H])c1[2H]]

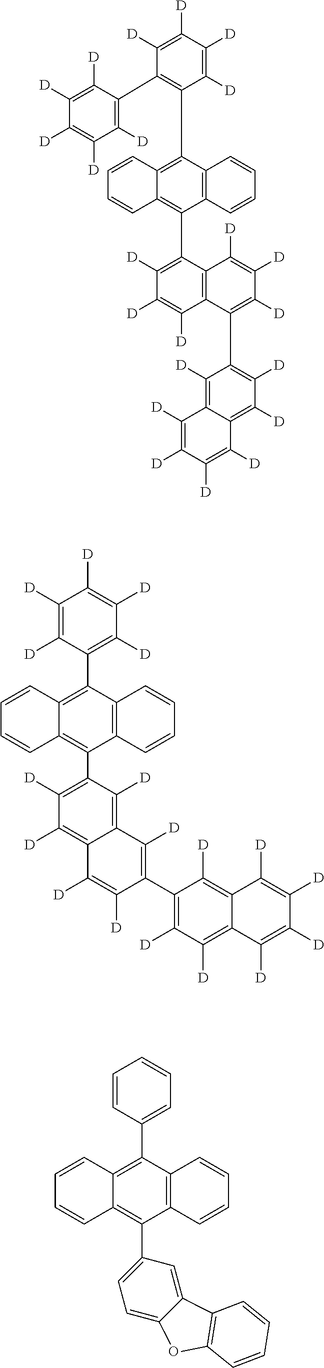 [SMILES: [2H]c1c([2H])c([2H])c(-c2c([2H])c([2H])c([2H])c([2H])c2-c2c3ccccc3c(-c3c([2H])c([2H])c([2H])c4c(-c5c([2H])c([2H])c6c([2H])c([2H])c([2H])c([2H])c6c5[2H])c([2H])c([2H])c([2H])c34)c3ccccc23)c([2H])c1[2H] ; [2H]c1c([2H])c([2H])c(-c2c3ccccc3c(-c3c([2H])c([2H])c4c([2H])c([2H])c(-c5c([2H])c([2H])c6c([2H])c([2H])c([2H])c([2H])c6c5[2H])c([2H])c4c3[2H])c3ccccc23)c([2H])c1[2H] ; c1ccc(-c2c3ccccc3c(-c3ccc4oc5ccccc5c4c3)c3ccccc23)cc1]

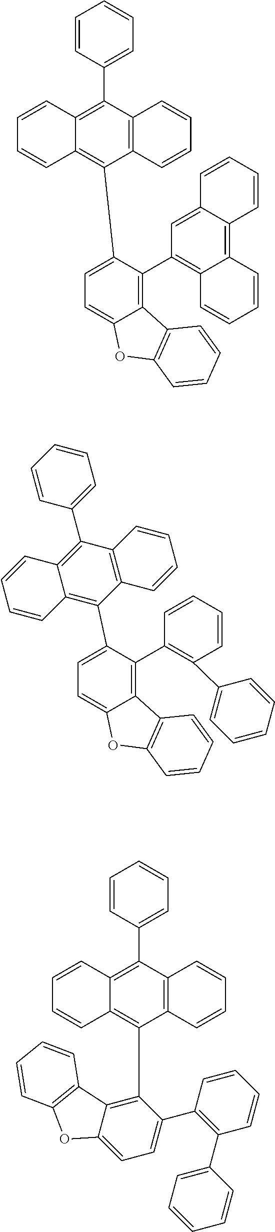 [SMILES: c1ccc(-c2c3ccccc3c(-c3ccc4oc5ccccc5c4c3-c3cc4ccccc4c4ccccc34)c3ccccc23)cc1 ; c1ccc(-c2ccccc2-c2c(-c3c4ccccc4c(-c4ccccc4)c4ccccc34)ccc3oc4ccccc4c23)cc1 ; c1ccc(-c2ccccc2-c2ccc3oc4ccccc4c3c2-c2c3ccccc3c(-c3ccccc3)c3ccccc23)cc1]

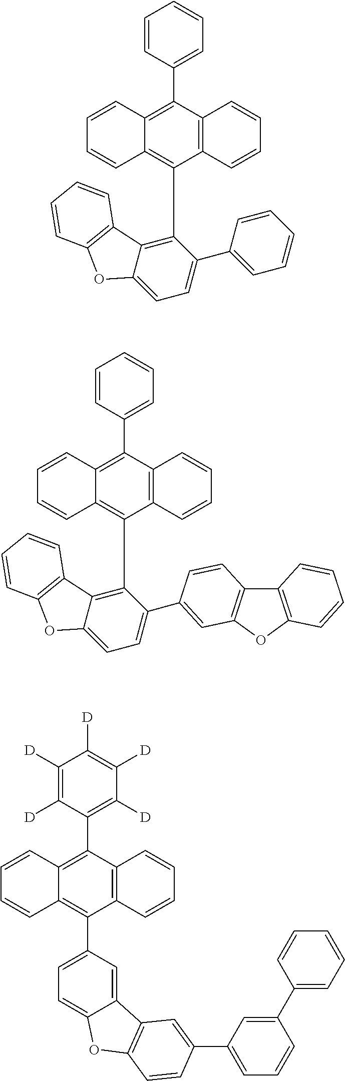 [SMILES: c1ccc(-c2ccc3oc4ccccc4c3c2-c2c3ccccc3c(-c3ccccc3)c3ccccc23)cc1 ; c1ccc(-c2c3ccccc3c(-c3c(-c4ccc5c(c4)oc4ccccc45)ccc4oc5ccccc5c34)c3ccccc23)cc1 ; [2H]c1c([2H])c([2H])c(-c2c3ccccc3c(-c3ccc4oc5ccc(-c6cccc(-c7ccccc7)c6)cc5c4c3)c3ccccc23)c([2H])c1[2H]]

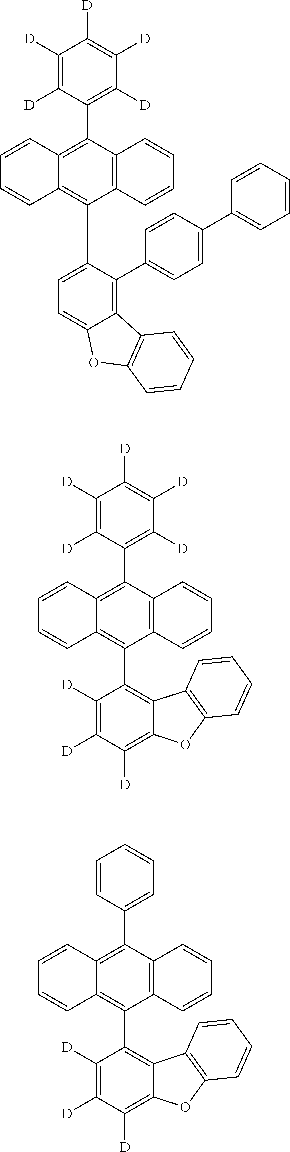 [SMILES: [2H]c1c([2H])c([2H])c(-c2c3ccccc3c(-c3ccc4oc5ccccc5c4c3-c3ccc(-c4ccccc4)cc3)c3ccccc23)c([2H])c1[2H] ; [2H]c1c([2H])c([2H])c(-c2c3ccccc3c(-c3c([2H])c([2H])c([2H])c4oc5ccccc5c34)c3ccccc23)c([2H])c1[2H] ; [2H]c1c([2H])c(-c2c3ccccc3c(-c3ccccc3)c3ccccc23)c2c(oc3ccccc32)c1[2H]]

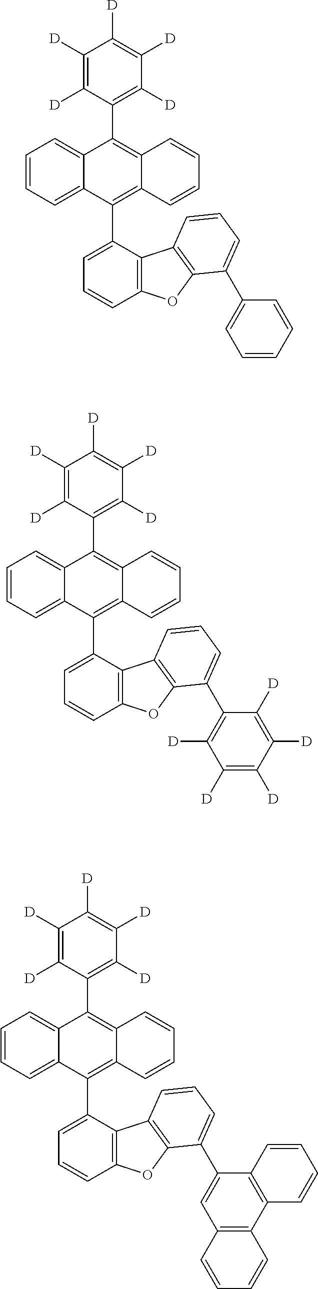 [SMILES: [2H]c1c([2H])c([2H])c(-c2c3ccccc3c(-c3cccc4oc5c(-c6ccccc6)cccc5c34)c3ccccc23)c([2H])c1[2H] ; [2H]c1c([2H])c([2H])c(-c2c3ccccc3c(-c3cccc4oc5c(-c6c([2H])c([2H])c([2H])c([2H])c6[2H])cccc5c34)c3ccccc23)c([2H])c1[2H] ; [2H]c1c([2H])c([2H])c(-c2c3ccccc3c(-c3cccc4oc5c(-c6cc7ccccc7c7ccccc67)cccc5c34)c3ccccc23)c([2H])c1[2H]]

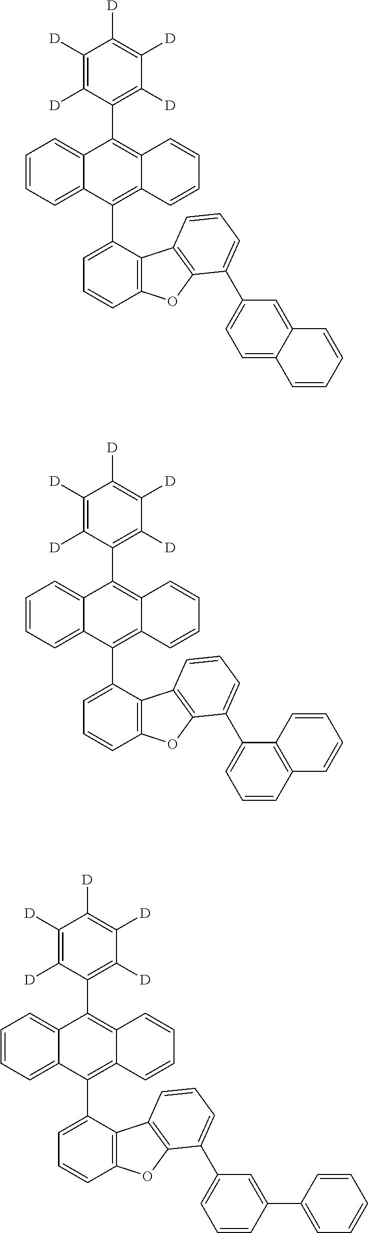 [SMILES: [2H]c1c([2H])c([2H])c(-c2c3ccccc3c(-c3cccc4oc5c(-c6ccc7ccccc7c6)cccc5c34)c3ccccc23)c([2H])c1[2H] ; [2H]c1c([2H])c([2H])c(-c2c3ccccc3c(-c3cccc4oc5c(-c6cccc7ccccc67)cccc5c34)c3ccccc23)c([2H])c1[2H] ; [2H]c1c([2H])c([2H])c(-c2c3ccccc3c(-c3cccc4oc5c(-c6cccc(-c7ccccc7)c6)cccc5c34)c3ccccc23)c([2H])c1[2H]]

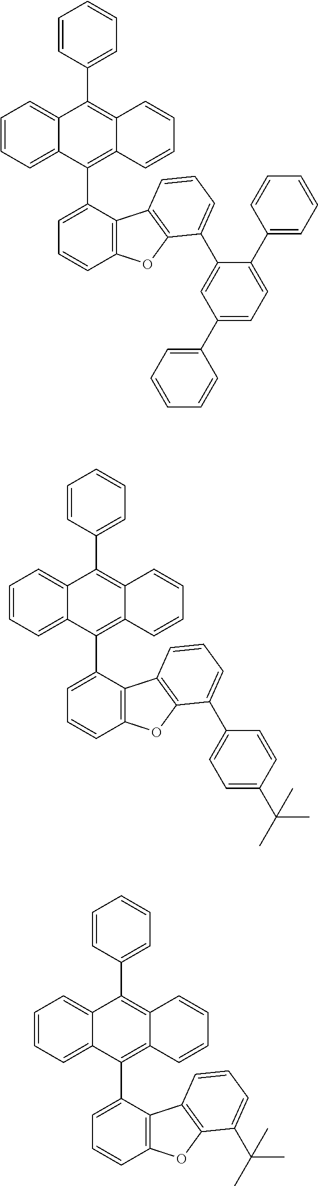 [SMILES: c1ccc(-c2ccc(-c3ccccc3)c(-c3cccc4c3oc3cccc(-c5c6ccccc6c(-c6ccccc6)c6ccccc56)c34)c2)cc1 ; CC(C)(C)c1ccc(-c2cccc3c2oc2cccc(-c4c5ccccc5c(-c5ccccc5)c5ccccc45)c23)cc1 ; CC(C)(C)c1cccc2c1oc1cccc(-c3c4ccccc4c(-c4ccccc4)c4ccccc34)c12]

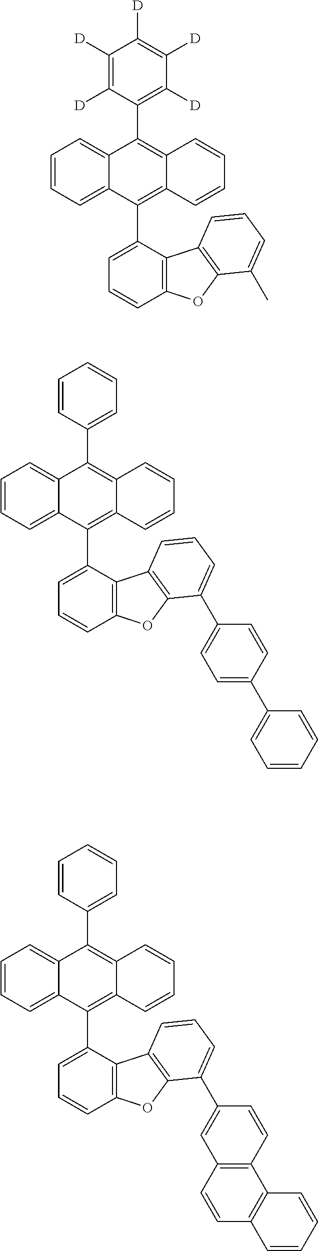 [SMILES: [2H]c1c([2H])c([2H])c(-c2c3ccccc3c(-c3cccc4oc5c(C)cccc5c34)c3ccccc23)c([2H])c1[2H] ; c1ccc(-c2ccc(-c3cccc4c3oc3cccc(-c5c6ccccc6c(-c6ccccc6)c6ccccc56)c34)cc2)cc1 ; c1ccc(-c2c3ccccc3c(-c3cccc4oc5c(-c6ccc7c(ccc8ccccc87)c6)cccc5c34)c3ccccc23)cc1]

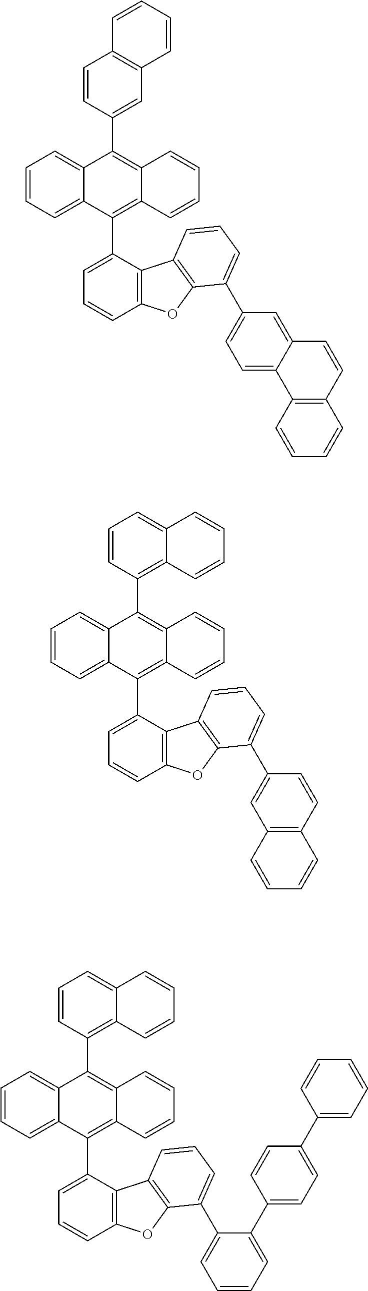 [SMILES: c1ccc2cc(-c3c4ccccc4c(-c4cccc5oc6c(-c7ccc8c(ccc9ccccc98)c7)cccc6c45)c4ccccc34)ccc2c1 ; c1ccc2cc(-c3cccc4c3oc3cccc(-c5c6ccccc6c(-c6cccc7ccccc67)c6ccccc56)c34)ccc2c1 ; c1ccc(-c2ccc(-c3ccccc3-c3cccc4c3oc3cccc(-c5c6ccccc6c(-c6cccc7ccccc67)c6ccccc56)c34)cc2)cc1]

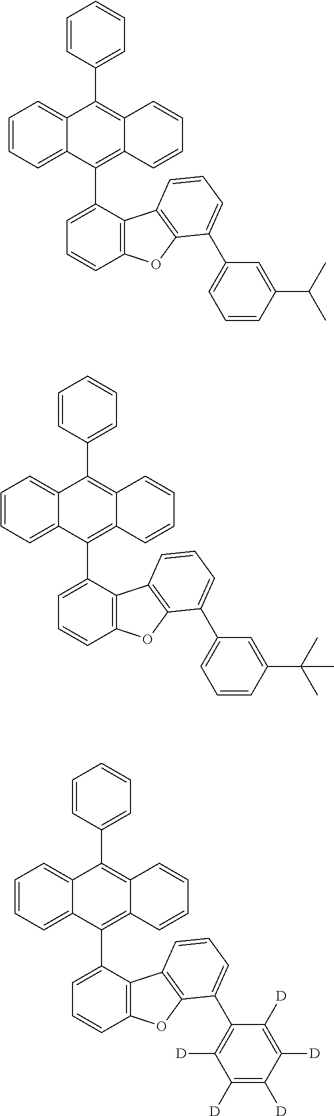 [SMILES: CC(C)c1cccc(-c2cccc3c2oc2cccc(-c4c5ccccc5c(-c5ccccc5)c5ccccc45)c23)c1 ; CC(C)(C)c1cccc(-c2cccc3c2oc2cccc(-c4c5ccccc5c(-c5ccccc5)c5ccccc45)c23)c1 ; [2H]c1c([2H])c([2H])c(-c2cccc3c2oc2cccc(-c4c5ccccc5c(-c5ccccc5)c5ccccc45)c23)c([2H])c1[2H]]

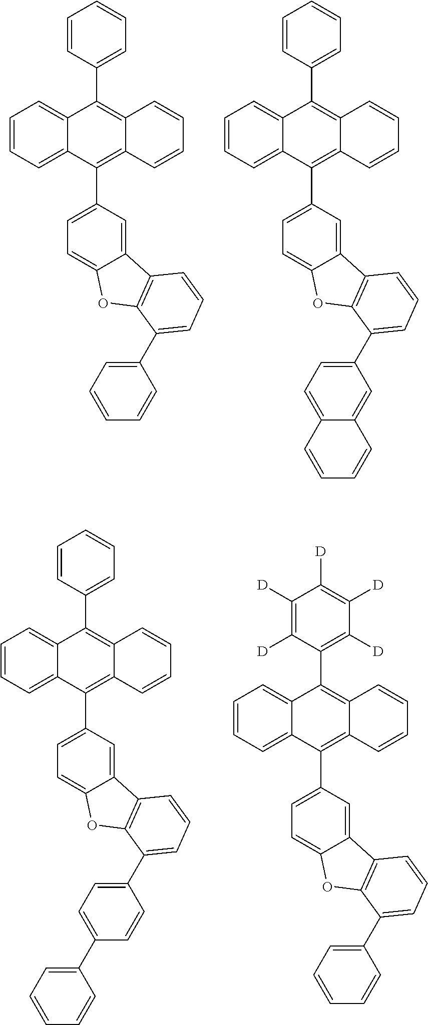

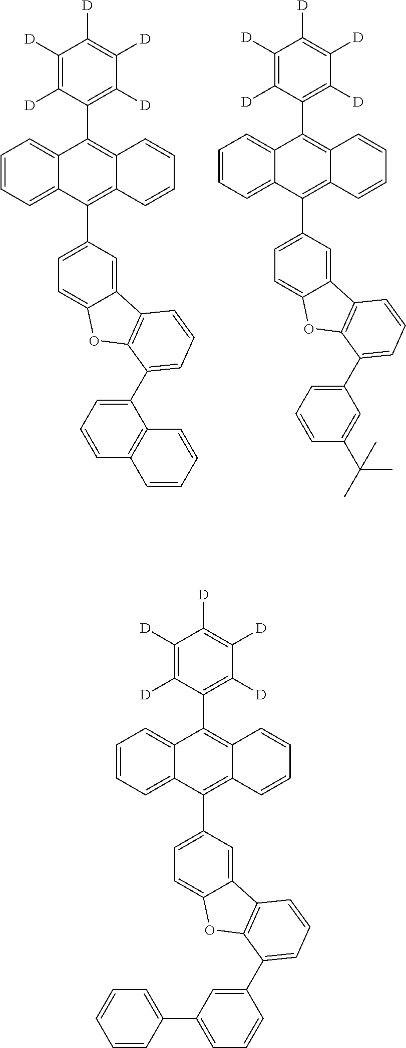

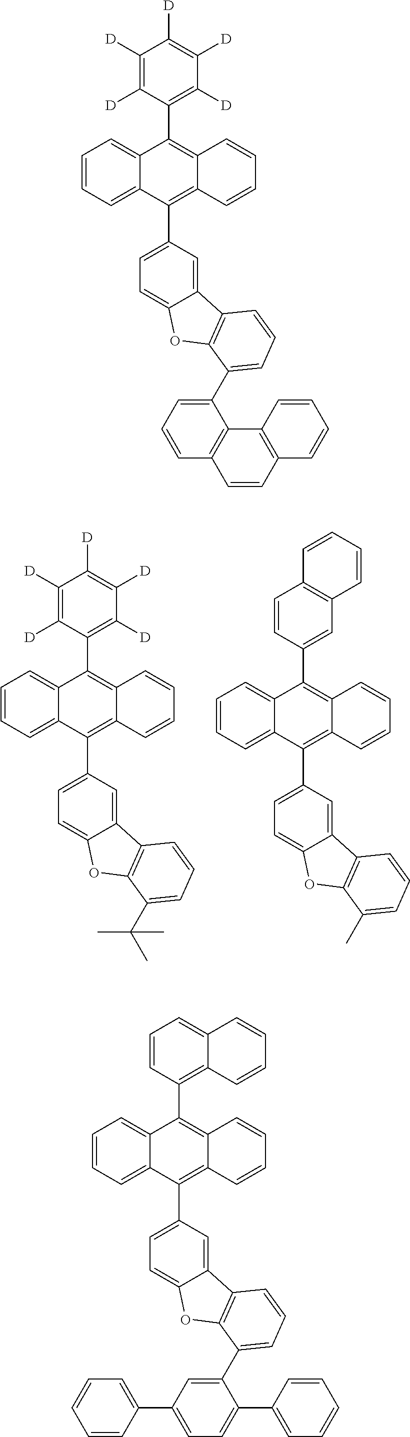

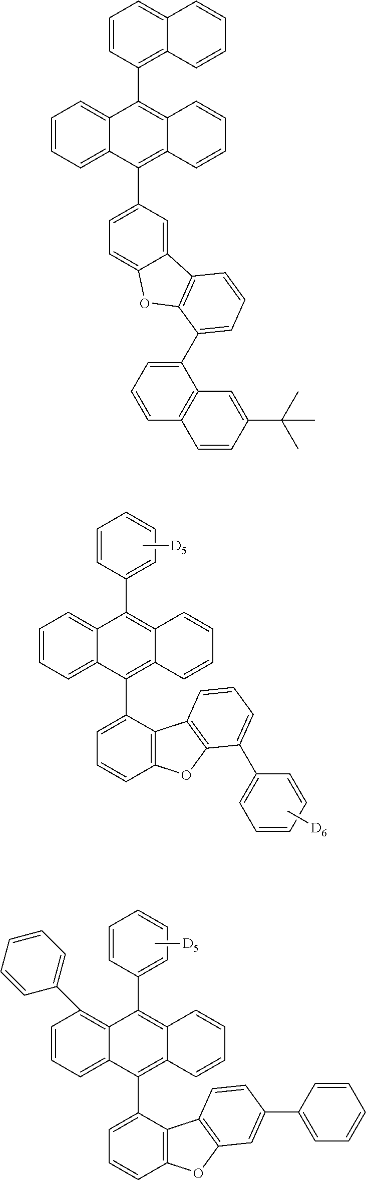

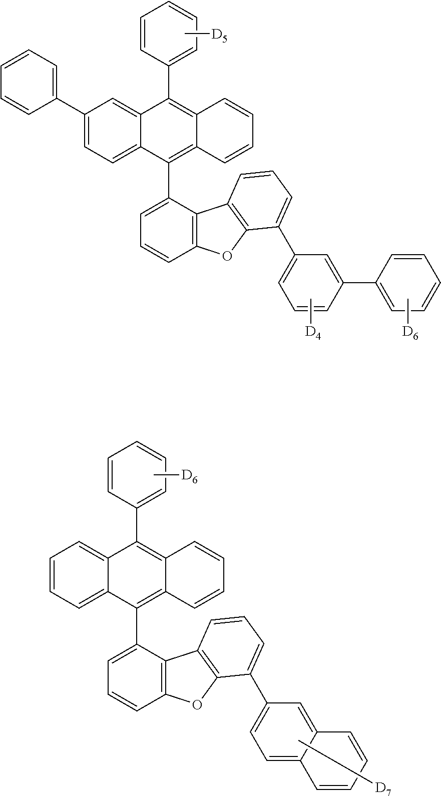

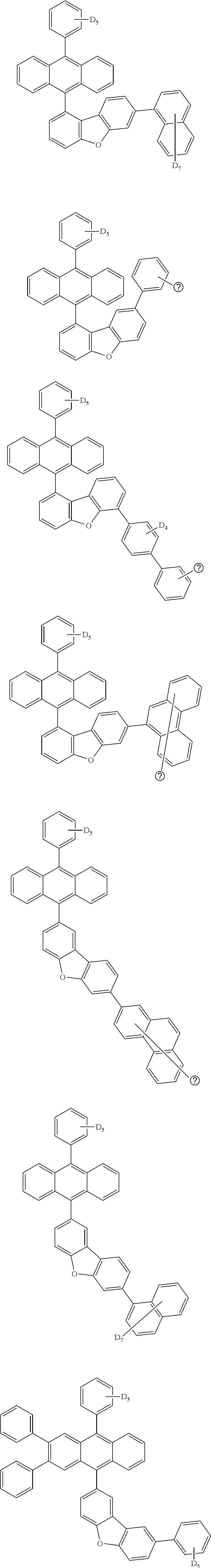

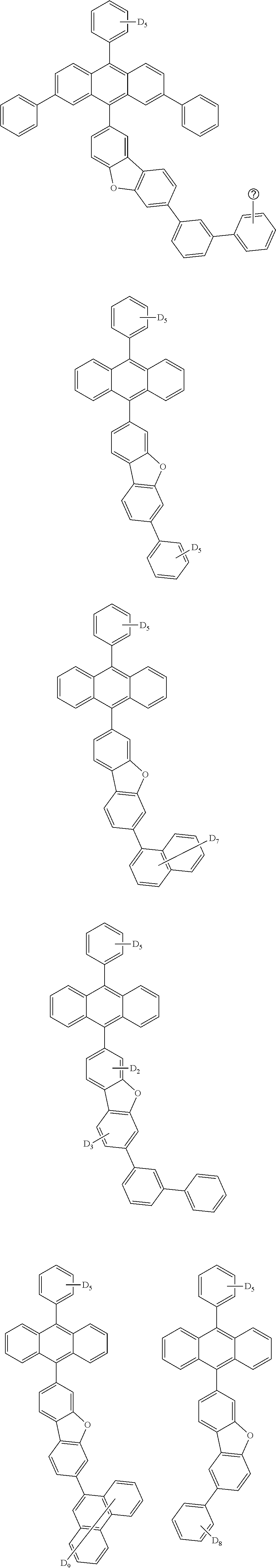

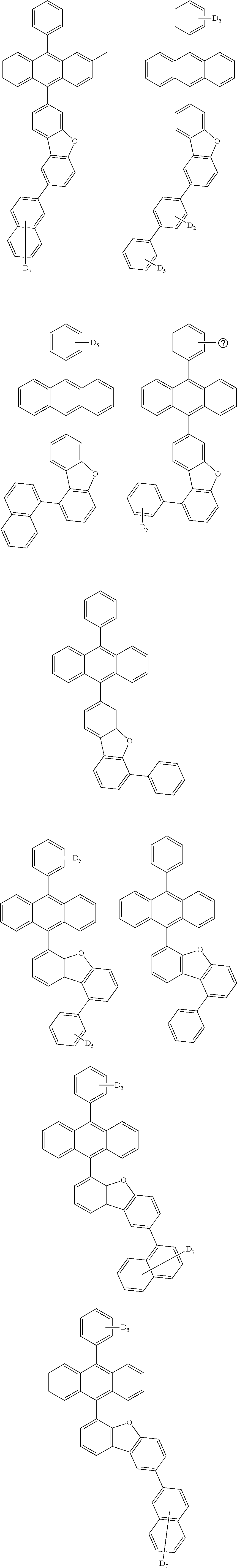

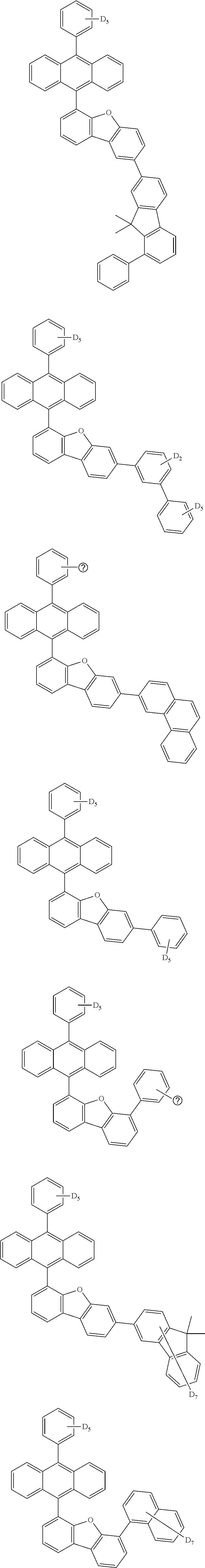

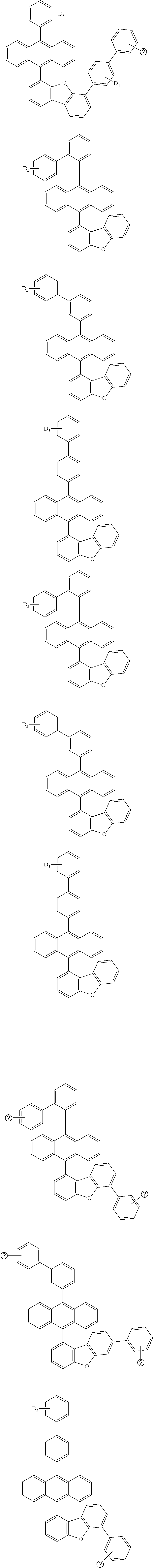

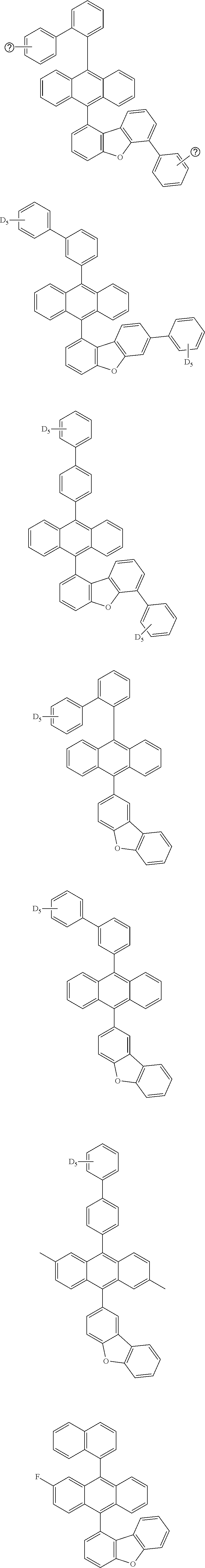

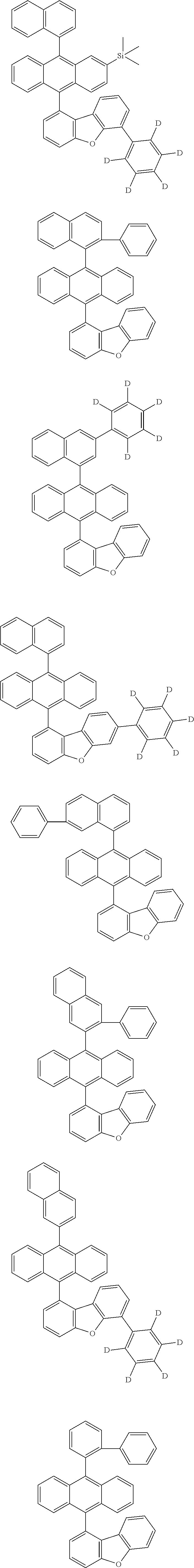

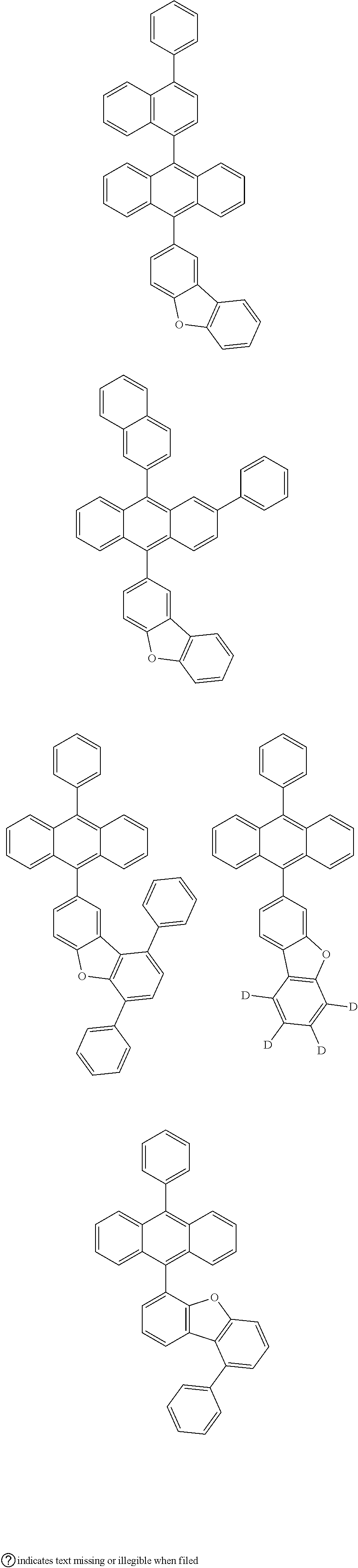 [SMILES: c1ccc(-c2ccc(-c3c4ccccc4c(-c4ccc5oc6ccccc6c5c4)c4ccccc34)c3ccccc23)cc1 ; c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5c(-c6ccccc6)ccc(-c6ccccc6)c5c4c3)c3ccccc23)cc1 ; [2H]c1c([2H])c([2H])c2c(oc3cc(-c4c5ccccc5c(-c5ccccc5)c5ccccc45)ccc32)c1[2H] ; c1ccc(-c2c3ccccc3c(-c3cccc4c3oc3cccc(-c5ccccc5)c34)c3ccccc23)cc1]

9. The organic electroluminescent device according to claim 6, wherein the light emitting layer comprising the compound represented by Formula A-1 or A-2 has an electroluminescence (EL) maximum peak at a wavelength of 454 nm or less.

10. The organic electroluminescent device according to claim 5, wherein one or more of the layers are formed by a deposition or solution process.

11. The organic electroluminescent device according to claim 4, wherein the organic electroluminescent device is used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.
